(19) United States
(12) Patent Application Publication
(10) Pub. No.: US 2017/0179401 A1
(43) Pub. Date: Jun. 22, 2017

(54) ORGANIC LIGHT-EMITTING DEVICE

(71) Applicant: SAMSUNG DISPLAY CO., LTD., Yongin-si (KR)

(72) Inventors: Seulong Kim, Yongin-si (KR); Younsun Kim, Yongin-si (KR); Dongwoo Shin, Yongin-si (KR); Jungsub Lee, Yongin-si (KR); Naoyuki Ito, Yongin-si (KR); Jino Lim, Yongin-si (KR); Hyein Jeong, Yongin-si (KR)

(21) Appl. No.: 15/192,848

(22) Filed: Jun. 24, 2016

(30) Foreign Application Priority Data
Dec. 22, 2015 (KR) 10-2015-0184076

(51) Int. Cl. H01L 51/00; C09K 11/02; C09K 11/06; H01L 51/50

(52) U.S. Cl. CPC H01L 51/0067; H01L 51/5004; H01L 51/504; H01L 51/0072; C09K 11/025; C09K 11/06; H01L 51/0085; H01L 51/0071; H01L 51/0073; H01L 51/0054; H01L 51/0074; H01L 51/0052; H01L 51/0058; H01L 51/006; H01L 51/5012; H01L 51/506; H01L 51/5072; H01L 2251/552; H01L 51/5092; H01L 51/5096; H01L 51/5016; C09K 2211/1007; C09K 2211/1029; C09K 2211/185; C09K 2211/1011; C09K 2211/1014

(57) ABSTRACT

According to one or more embodiments, an organic light-emitting device includes: a first electrode; a second electrode facing the first electrode; an emission layer between the first electrode and the second electrode; a hole transport region between the first electrode and the emission layer; and an electron transport region between the emission layer and the second electrode. The emission layer includes a first compound represented by Formula 1, and at least one selected from the hole transport region and the electron transport region includes a second compound represented by Formula 2A or 2B:

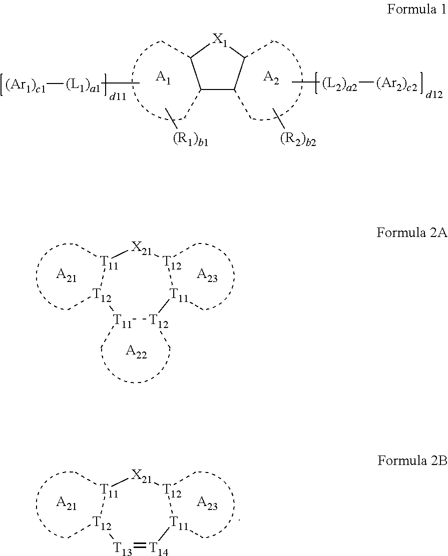

### CROSS-REFERENCE TO RELATED APPLICATION

This application claims priority to and the benefit of Korean Patent Application No. 10-2015-0184076, filed on Dec. 22, 2015, in the Korean Intellectual Property Office, the disclosure of which is incorporated herein in its entirety by reference.

### BACKGROUND

1. Field

One or more embodiments of the present disclosure relate to an organic light-emitting device.

2. Description of the Related Art

Organic light-emitting devices are self-emission devices that have wide viewing angles, high contrast ratios, short response times, and/or excellent brightness, driving voltage, and/or response speed characteristics, compared to other devices in the art.

The organic light-emitting device may include a first electrode disposed on a substrate, and a hole transport region, an emission layer, an electron transport region, and a second electrode, which are sequentially disposed on the first electrode. Holes provided from the first electrode may move toward the emission layer through the hole transport region, and electrons provided from the second electrode may move toward the emission layer through the electron transport region. Carriers, such as holes and electrons, recombine in the emission layer to produce excitons. These excitons transition from an excited state to a ground state, thereby generating light.

### SUMMARY

An aspect according to one or more embodiments of the present disclosure is directed toward an organic light-emitting device having a low driving voltage and high efficiency.

Additional aspects will be set forth in part in the description which follows and, in part, will be apparent from the description, or may be learned by practice of the presented embodiments.

According to one or more embodiments, an organic light-emitting device includes:

a first electrode;

a second electrode facing the first electrode;

an emission layer between the first electrode and the second electrode;

a hole transport region between the first electrode and the emission layer;

and

an electron transport region between the emission layer and the second electrode,

wherein the emission layer includes a first compound,

at least one selected from the hole transport region and the electron transport region includes a second compound,

the first compound is represented by Formula 1, provided that a case where Formula 1 is 4,4′-bis(N-carbazolyl)-1,1′-biphenyl (CBP) is excluded (Formula 1 is not CBP), and the second compound is represented by Formula 2A or 2B:

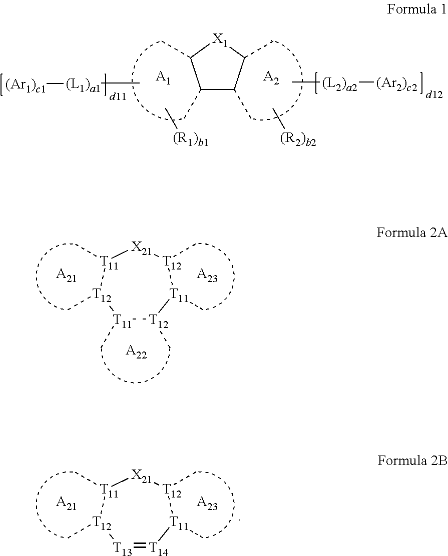

In Formulae 1, 2A, and 2B,

rings A₁ and A₂ may each independently be selected from a C₅-C₆₀ carbocyclic group and a C₁-C₆₀ heterocyclic group,

rings A₁ and A₂ may each be condensed with a 5-membered ring in Formula 1,

rings A₂₁, A₂₂, and A₂₃ may each independently be a C₅-C₆₀ carbocyclic group or a C₁-C₆₀ heterocyclic group, each substituted with at least one *-[(L₂₂)ₐ₂₂-(R₂₂)_{b22}],

T₁₁ and T₁₂ may each independently be carbon or nitrogen, T₁₃ may be N or C(R₂₇), T₁₄ may be N or C(R₂₈), two or more selected from three T₁₁(s) in Formula 2A may be identical to or different from each other, two or more selected from three T₁₂(s) in Formula 2A may be identical to or different from each other, two T₁₁(s) in Formula 2B may be identical to or different from each other, two T₁₂(s) in Formula 2B may be identical to or different from each other, T₁₁ and T₁₂ may be connected to each other via a single bond or a double bond, wherein the three T₁₁(s) and three T₁₂(s) in Formula 2A may be not all nitrogen, and the two T₁₁(s), two T₁₂(s), T₁₃, and T₁₄ in Formula 2B may be not all nitrogen,

rings A₂₁, A₂₂, and A₂₃ may each be condensed (e.g., fused) with a central 7-membered ring in Formulae 2A and 2B, such that they each share a T₁₁ and a T₁₂ with the central 7-membered ring.

X₁ may be selected from N[(L₃)ₐ₃-(Ar₃)_{c3}], Si(R₃)(R₄), O, S, and Se,

X₂₁ may be selected from O, S, Se, C(R₂₃)(R₂₄), Si(R₂₃)(R₂₄), and N[(L₂₁)ₐ₂₁-(R₂₁)_{b21}],

L₁ to L₃, L₂₁, and L₂₂ may each independently be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

a1 to a3, a21, and a22 may each independently be an integer selected from 0 to 5,

Ar₁ to Ar₃ may each independently be selected from a substituted or unsubstituted C₁-C₆₀ alkyl group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂),

c1 to c3 may each independently be an integer selected from 1 to 3,

R₁ to R₄, R₂₁ to R₂₄, R₂₇, and R₂₈ may each independently be selected from hydrogen, deuterium (-D), —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅),

b1 and b2 may each independently be an integer selected from 1 to 6, and b21 and b22 may each independently be an integer selected from 1 to 3,

d11 and d12 may each independently be an integer selected from 0 to 4,

at least one substituent of the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, the substituted divalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may be selected from the group consisting of:

deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, a hydroxyl group, a cyano group, a nitro group, an amidino group, a hydrazino group, a hydrazono group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), and —P(═O)(Q₁₁)(Q₁₂);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, a biphenyl group, and a terphenyl group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), and —P(═O)(Q₂₁)(Q₂₂); and

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

wherein Q₁ to Q₆, Q₁₁ to Q₁₃, Q₂₁ to Q₂₃, and Q₃₁ to Q₃₃ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with a C₁-C₆₀ alkyl group, a C₆-C₆₀ aryl group substituted with a C₆-C₆₀ aryl group, a terphenyl group, a C₁-C₆₀ heteroaryl group, a C₁-C₆₀ heteroaryl group substituted with a C₁-C₆₀ alkyl group, a C₁-C₆₀ heteroaryl group substituted with a C₆-C₆₀ aryl group, a monovalent non-aromatic condensed polycyclic group, and a monovalent non-aromatic condensed heteropolycyclic group.

### BRIEF DESCRIPTION OF THE DRAWINGS

These and/or other aspects will become apparent and more readily appreciated from the following description of the exemplary embodiments, taken in conjunction with the accompanying drawings in which:

FIGS. 1 to 5 are schematic views of organic light-emitting devices, each according to various embodiments of the present disclosure.

### DETAILED DESCRIPTION

An organic light-emitting device according to an embodiment may include a first electrode, a second electrode facing the first electrode, an emission layer between the first electrode and the second electrode, a hole transport region between the first electrode and the emission layer, and an electron transport region between the emission layer and the second electrode, wherein the emission layer may include a first compound, and at least one selected from the hole transport region and the electron transport region may include a second compound.

The first compound may be represented by Formula 1, a case where Formula 1 is 4,4′-bis(N-carbazolyl)-1,1′-biphenyl (CBP) may be excluded, and the second compound may be represented by Formula 2A or 2B:

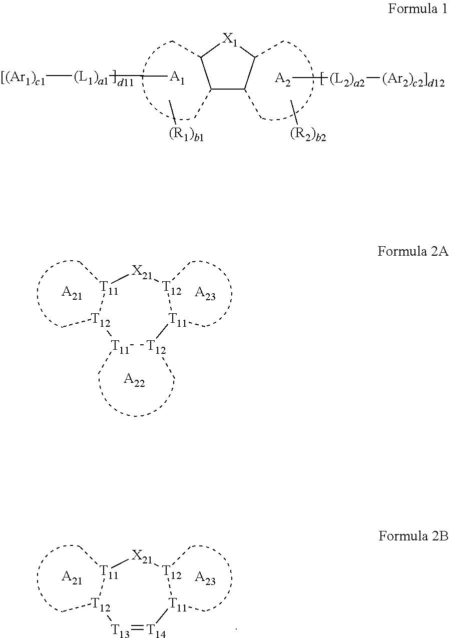

In Formula 1,

rings A₁ and A₂ may each independently be selected from a C₅-C₆₀ carbocyclic group and a C₁-C₆₀ heterocyclic group.

Rings A₁ and A₂ in Formula 1 may each be condensed with a 5-membered ring.

For example, rings A₁ and A₂ in Formula 1 may each independently be selected from a benzene group, a naphthalene group, an anthracene group, a phenanthrene group, an indene group, a fluorene group, a pyridine group, a pyrimidine group, a pyrazine group, a pyrrole group, a pyrazole group, an imidazole group, a quinoline group, a quinoxaline group, an isoquinoline group, a cinnoline group, a phthalazine group, a quinazoline group, a phenanthroline group, a phenanthridine group, a furan group, a thiophene group, an indole group, a benzofuran group, a benzothiophene group, a benzoxazole group, a benzothiazole group, a benzoimidazole group, a benzocarbazole group, a benzofluorene group, a benzonaphthofuran group, a benzonaphthothiophene group, a carbazole group, a dibenzofuran group, a dibenzothiophene group, a pyridoindole group, an indenopyridine group, a benzofuropyrimidine group, a benzofuropyridine group, an indenofluorene group, an indenoindole group, a benzoindole group, a naphthofuran group, a dipyridofuran group, a dipyridothiophene group, a pyrimidobenzofuran group, a pyridobenzofuran group, a pyrimidobenzothiophene group, a pyridobenzothiophene group, a group represented by Formula

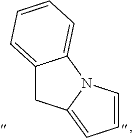 [SMILES: c1ccc2c(c1)Cc1cccn1-2]

a group represented by Formula

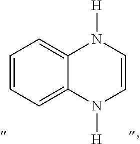

a group represented by Formula

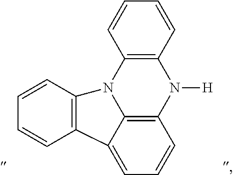 [SMILES: c1ccc2c(c1)Nc1cccc3c4ccccc4n-2c13]

and a group represented by Formula

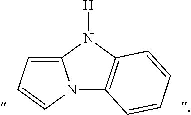 [SMILES: c1ccc2c(c1)[nH]c1cccn12]

Rings A₂₁, A₂₂, and A₂₃ in Formulae 2A and 2B may each independently be a C₅-C₆₀ carbocyclic group or a C₁-C₆₀ heterocyclic group, each substituted with at least one *-[(L₂₂)ₐ₂₂-(R₂₂)_{b22}]. L₂₂, a22, R₂₂, and b22 will be described in more detail below.

T₁₁ and T₁₂ in Formulae 2A and 2B may each independently be carbon or nitrogen, T₁₃ may be N or C(R₂₇), T₁₄ may be N or C(R₂₈), two or more selected from three T₁₁(s) in Formula 2A may be identical to or different from each other, two or more selected from three T₁₂(s) in Formula 2A may be identical to or different from each other, two T₁₁(s) in Formula 2B may be identical to or different from each other, two T₁₂(s) in Formula 2B may be identical to or different from each other, T₁₁ and T₁₂ may be connected to each other via a single bond or a double bond, wherein the three T₁₁(s) and three T₁₂(s) in Formula 2A may be not all nitrogen, and the two T₁₁(s), two T₁₂(s), T₁₃, and T₁₄ in Formula 2B may be not all nitrogen, and rings A₂₁, A₂₂, and A₂₃ may each be condensed (e.g., fused) with a central 7-membered ring in Formulae 2A and 2B, such that they each share a T₁₁ and a T₁₂ with the central 7-membered ring.

*-[(L₂₂)ₐ₂₂-(R₂₂)_{b22}] substituted (e.g., as a substitutent) in ring A₂₁, *-[(L₂₂)ₐ₂₂-(R₂₂)_{b22}] substituted (e.g., as a substitutent) in ring A₂₂, and *-[(L₂₂)ₐ₂₂-(R₂₂)_{b22}] substituted (e.g., as a substitutent) in ring A₂₃ may be identical to or different from one another.

In addition, when the number of *-[(L₂₂)ₐ₂₂-(R₂₂)_{b22}](s) substituted (e.g., as a substitutent) in ring A₂₁ is two or more, two or more *-[(L₂₂)ₐ₂₂-(R₂₂)_{b22}](s) may be identical to or different from each other, when the number of *-[(L₂₂)ₐ₂₂-(R₂₂)_{b22}](s) substituted (e.g., as a substitutent) in ring A₂₂ is two or more, two or more *-[(L₂₂)ₐ₂₂-(R₂₂)_{b22}](s) may be identical to or different from each other, and when the number of *-[(L₂₂)ₐ₂₂-(R₂₂)_{b22}](s) substituted (e.g., as a substitutent) in ring A₂₃ is two or more, two or more *-[(L₂₂)ₐ₂₂-(R₂₂)_{b22}](s) may be identical to or different from each other.

In various embodiments, rings A₂₁, A₂₂, and A₂₃ in Formulae 2A and 2B may each independently be selected from a benzene group, a naphthalene group, an anthracene group, an indene group, a fluorene group, a pyridine group, a pyrimidine group, a pyrazine group, a pyridazine group, a quinoline group, an isoquinoline group, a pyrrole group, a pyrazole group, an imidazole group, an oxazole group, a thiazole group, a cyclopentadiene group, a silole group, a selenophene group, a furan group, a thiophene group, an indole group, a benzimidazole group, a benzoxazole group, a benzothiazole group, an indene group, a benzosilole group, a benzoselenophene group, a benzofuran group, a benzothiophene group, a carbazole group, a fluorene group, a dibenzosilole group, a dibenzoselenophene group, a dibenzofuran group, a dibenzothiophene group, a pyrrolopyridine group, a cyclopentapyridine group, a silolopyridine group, a selenophenopyridine group, a furopyridine group, a thienopyridine group, a pyrrolopyrimidine group, a cyclopentapyrimidine group, a silolopyrimidine group, a selenophenopyrimidine group, a furopyrimidine group, a thienopyrimidine group, a pyrrolopyrazine group, a cyclopentapyrazine group, a silolopyrazine group, a selenophenopyrazine group, a furopyrazine group, a thienopyrazine group, a naphthopyrrole group, a cyclopentanaphthalene group, a naphthosilole group, a naphthoselenothiophene group, a naphthofuran group, a naphthothiophene group, a pyrroloquinoline group, a cyclopentaquinoline group, a siloloquinoline group, a selenophenoquinoline group, a furoquinoline group, a thienoquinoline group, a pyrroloisoquinoline group, a cyclopentaisoquinoline group, a siloloisoquinoline group, a selenophenoisoquinoline group, a furoisoquinoline group, a thienoisoquinoline group, an azacarbazole group, an azafluorene group, an azadibenzosilole group, an azadibenzoselenophene group, an azadibenzofuran group, an azadibenzothiophene group, an indenoquinoline group, an indenoisoquinoline group, an indenoquinoxaline group, a phenanthroline group, and an naphthoindole group, each substituted with at least one *-[(L₂₂)ₐ₂₂-(R₂₂)_{b22}].

In various embodiments, in the second compound represented by Formulae 2A and 2B, a case where rings A₂₁, A₂₂, and A₂₃ are all a benzene group substituted with at least one *-[(L₂₂)ₐ₂₂-(R₂₂)_{b22}] may be excluded.

In various embodiments, rings A₂₁, A₂₂, and A₂₃ in Formulae 2A and 2B may each independently be selected from groups represented by Formulae 2-1 to 2-36, each substituted with at least one *-[(L₂₂)ₐ₂₂-(R₂₂)_{b22}]:

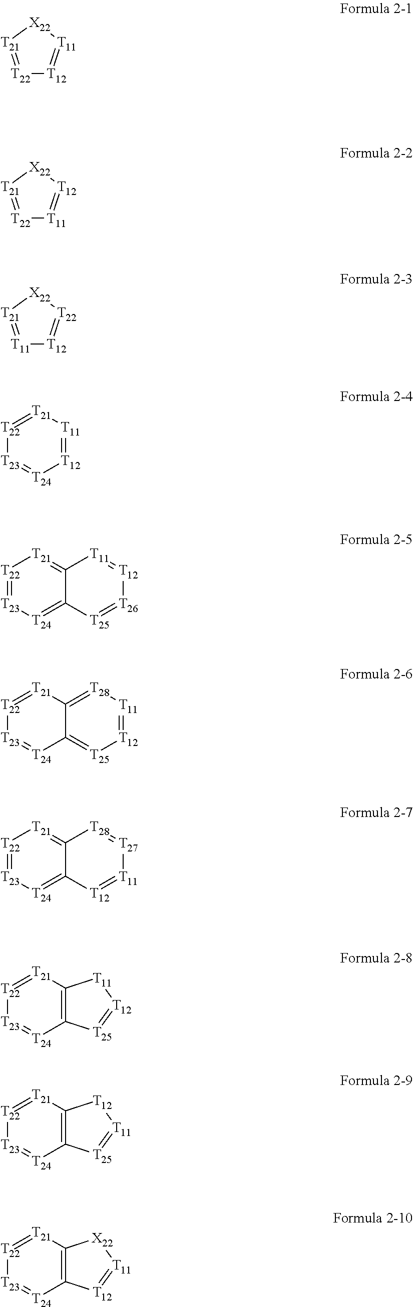

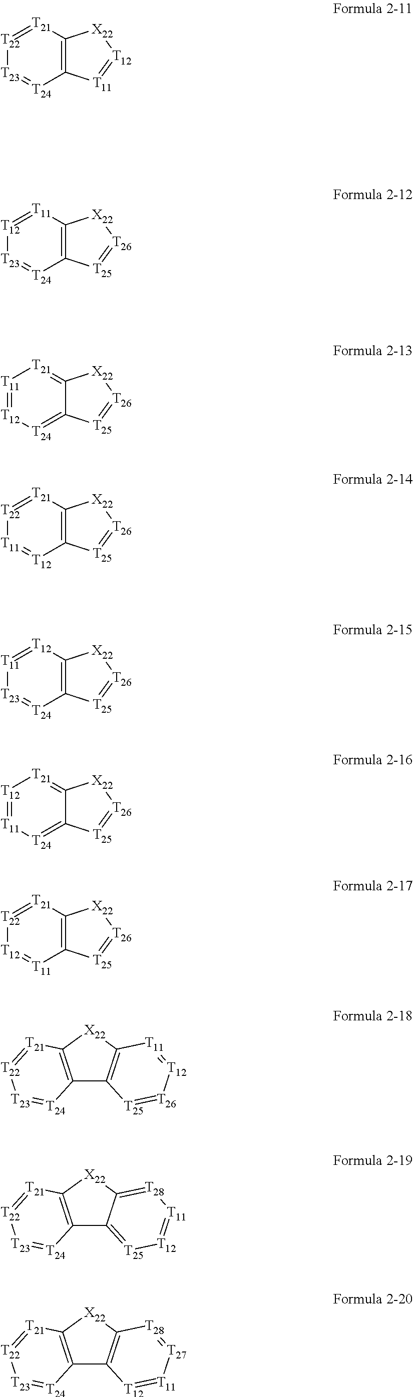

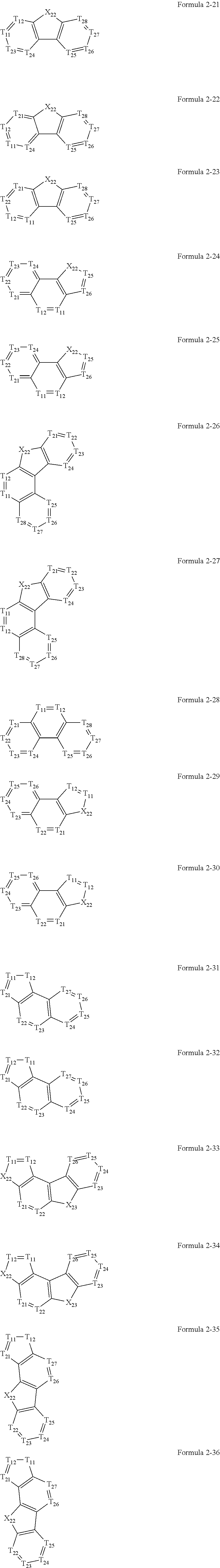

In Formulae 2-1 to 2-36,

T₁₁ and T₁₂ are the same as described above,

X₂₂ and X₂₃ may each independently be selected from O, S, Se, a moiety including C, a moiety including N, and a moiety including Si, and

T₂₁ to T₂₈ may each independently be selected from N and a moiety including C.

When both X₂₂ and X₂₃ are included in rings A₂₁ to A₂₃, X₂₂ and X₂₃ may be identical to or different from each other.

For example, in Formulae 2-1 to 2-36, X₂₂ and X₂₃ may each independently be O, S, Se, C(R₂₅)(R₂₆), N-[(L₂₂)ₐ₂₂-(R₂₂)_{b22}], or Si(R₂₅)(R₂₆), and T₂₁ to T₂₈ may each independently be N or C-[(L₂₂)ₐ₂₂-(R₂₂)_{b22}]. R₂₅, R₂₆, and R₃₀ may each independently be selected from groups represented by *-[(L₂₂)ₐ₂₂-(R₂₂)_{b22})] as described herein.

For example, in Formulae 2-1 to 2-36, X₂₂ and X₂₃ may each independently be O, S, Se, C(R₂₅)(R₂₆), N-[(L₂₂)ₐ₂₂-(R₂₂)_{b22}], or Si(R₂₅)(R₂₆), and T₂₁ to T₂₈ may each independently be N or C-[(L₂₂)ₐ₂₂-(R₂₂)_{b22}]. R₂₅ and R₂₆ may each independently be selected from groups represented by *-[(L₂₂)ₐ₂₂-(R₂₂)_{b22})] as described herein.

In various embodiments, rings A₂₁, A₂₂, and A₂₃ in Formulae 2A and 2B may each independently be selected from groups represented by Formulae 2-101 to 2-229:

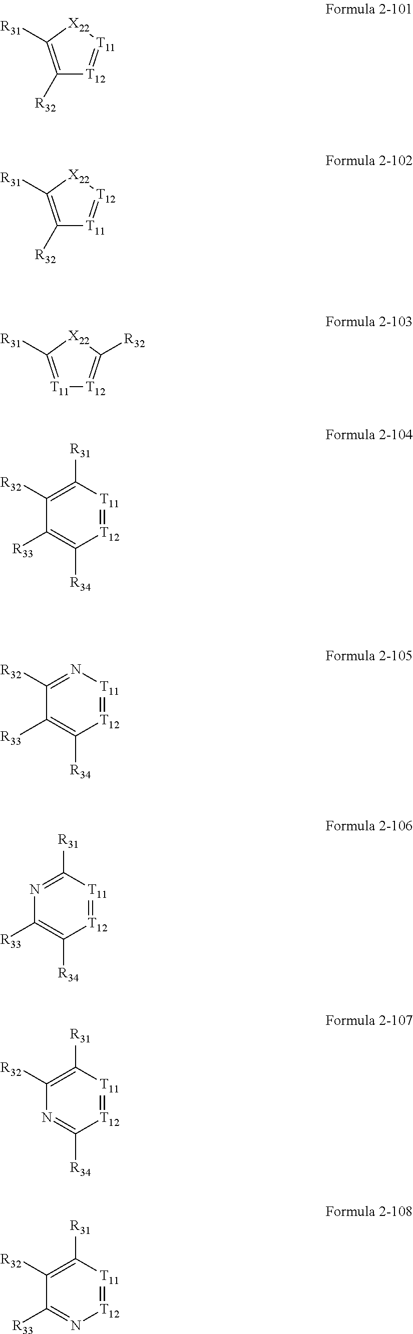

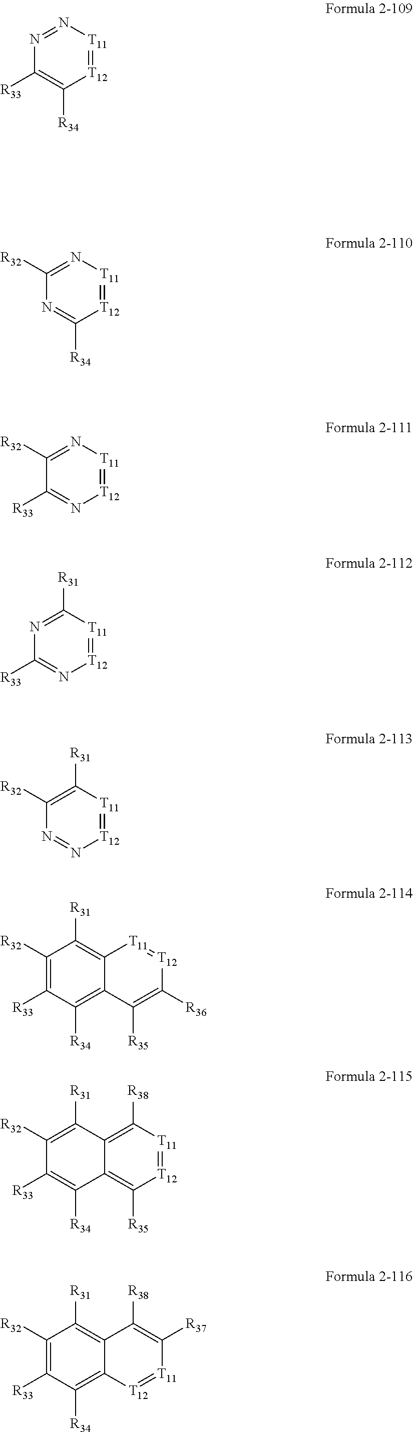

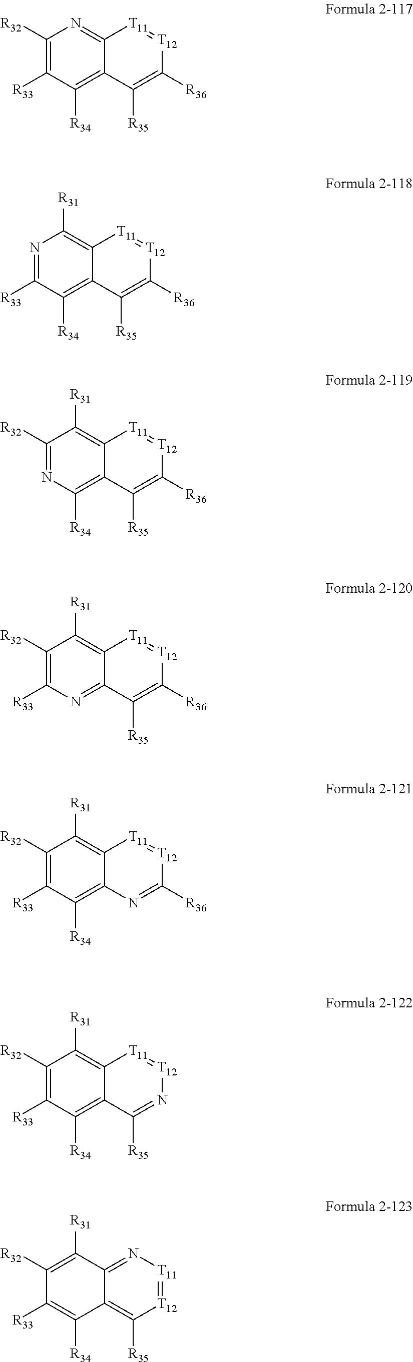

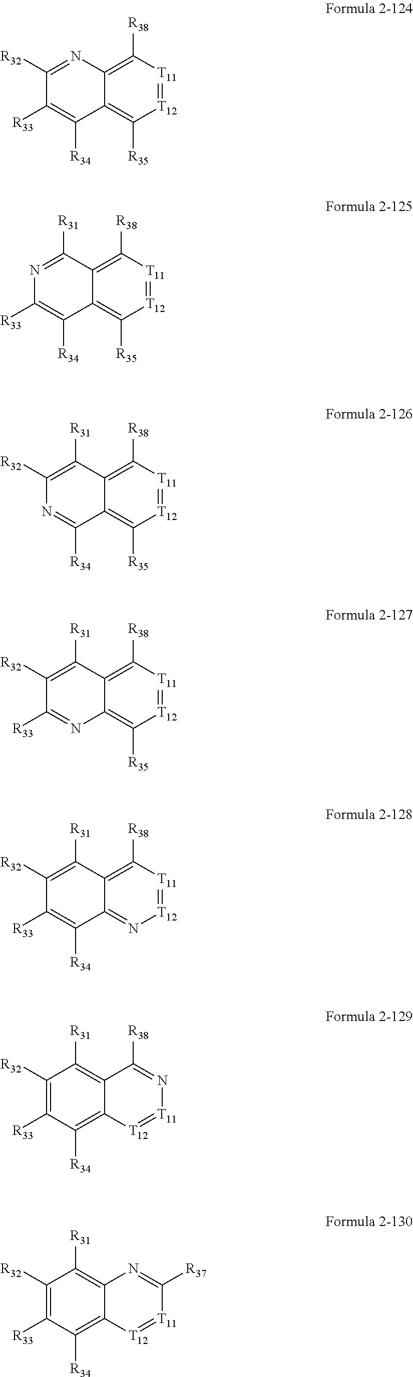

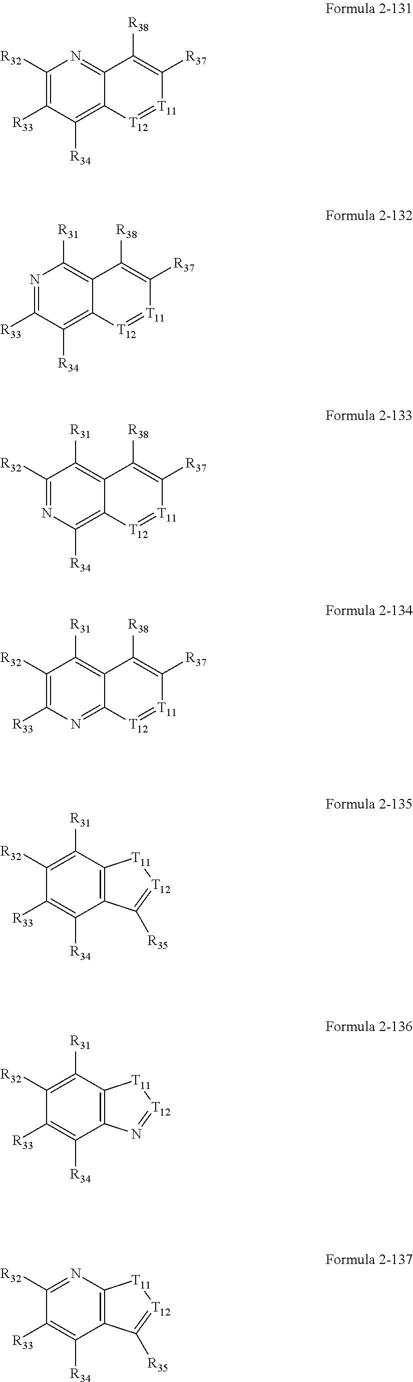

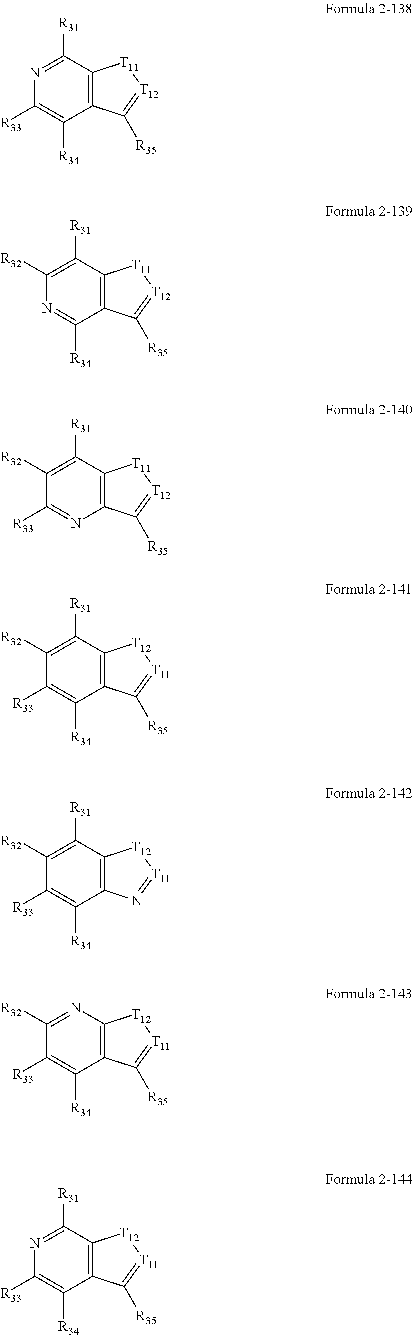

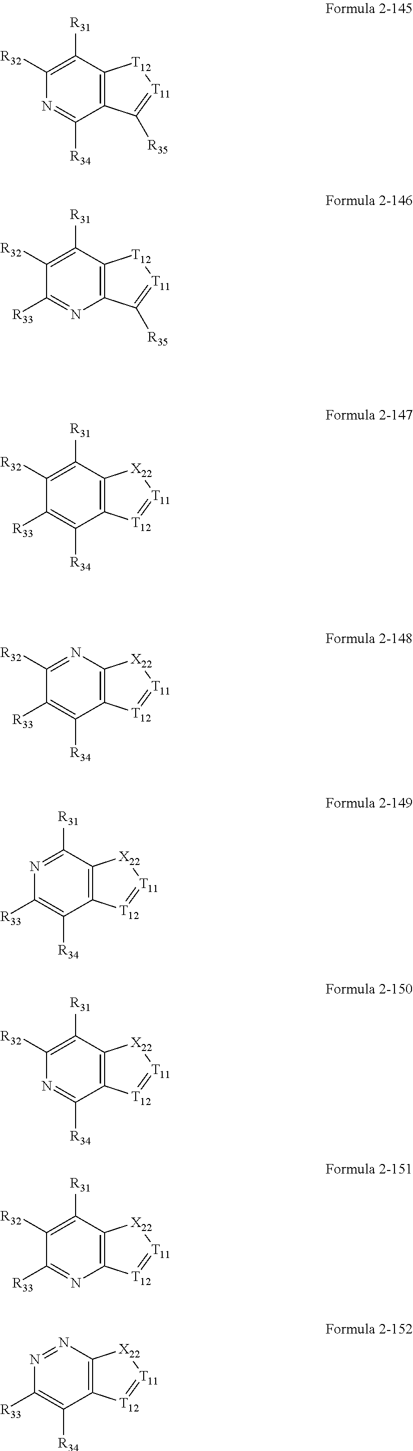

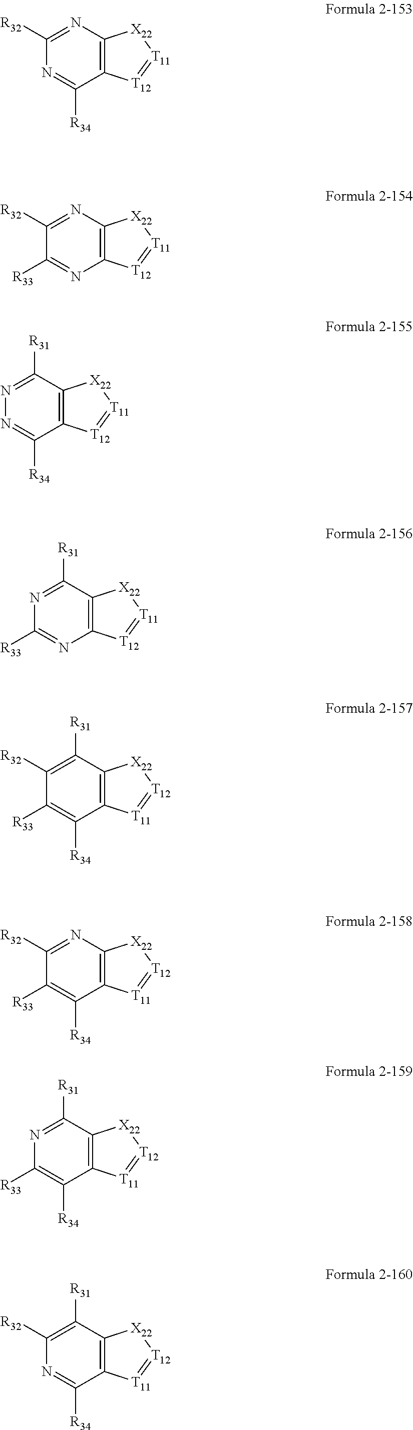

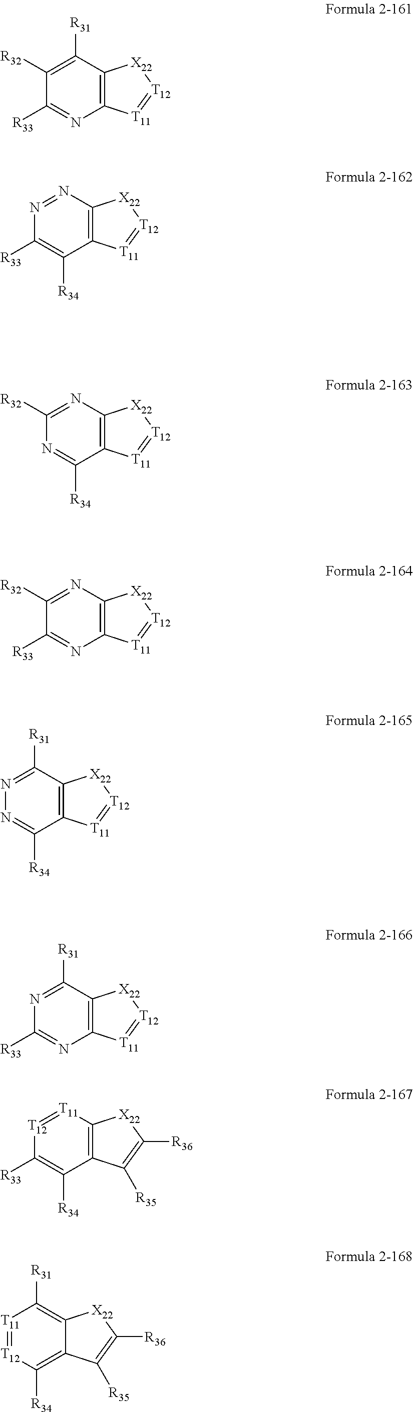

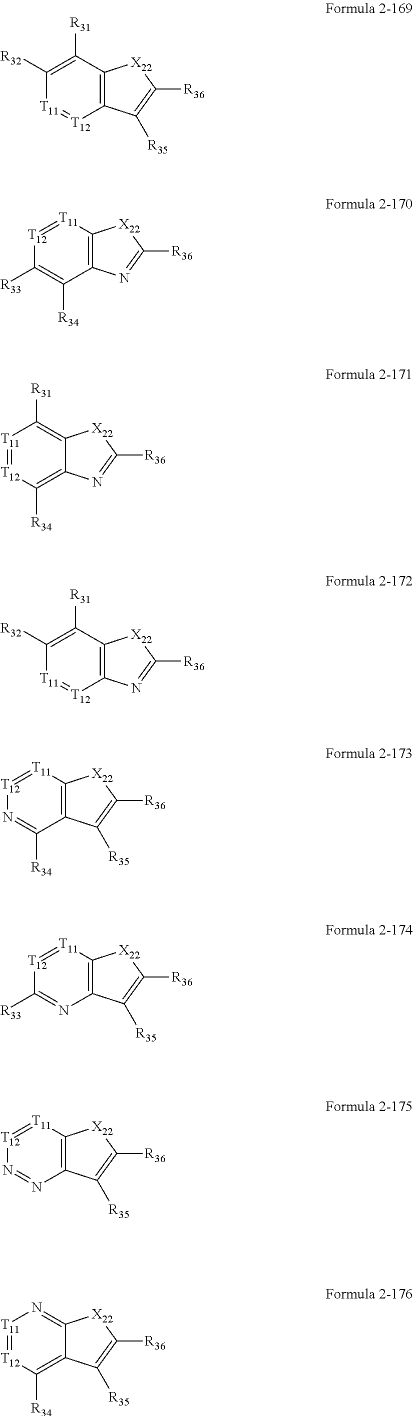

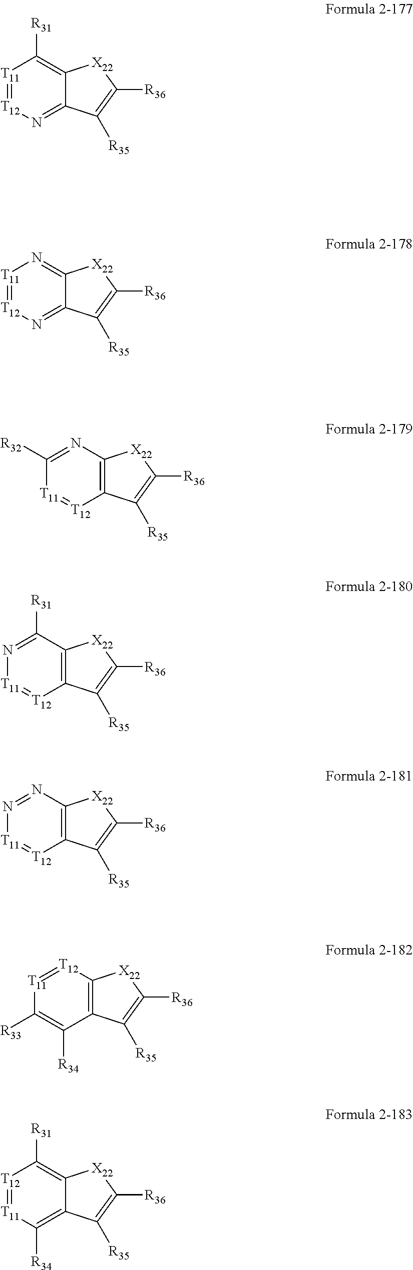

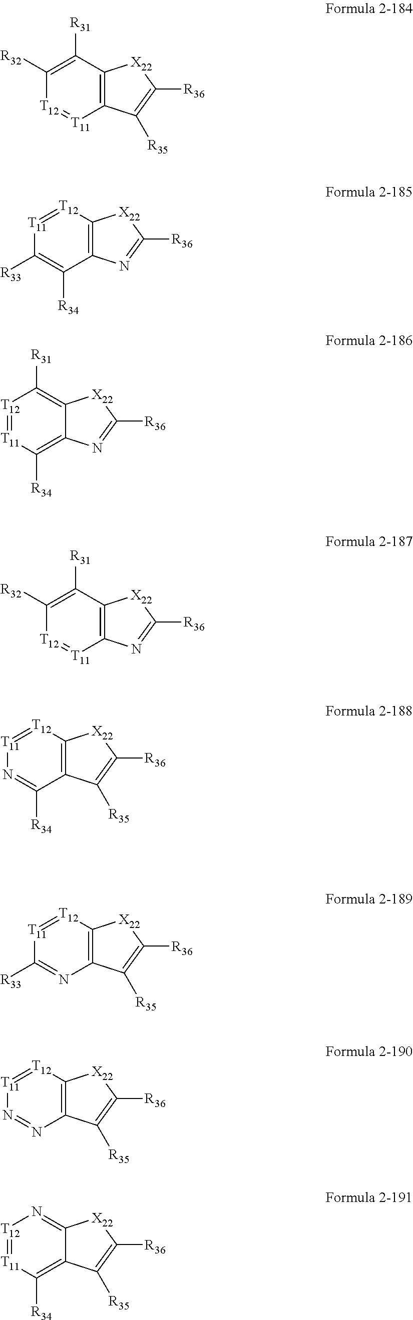

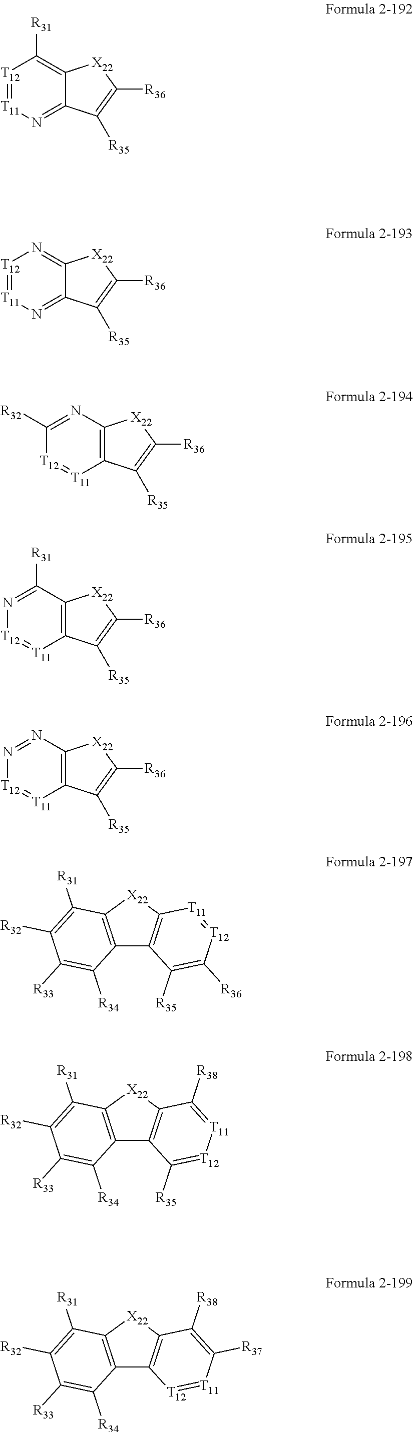

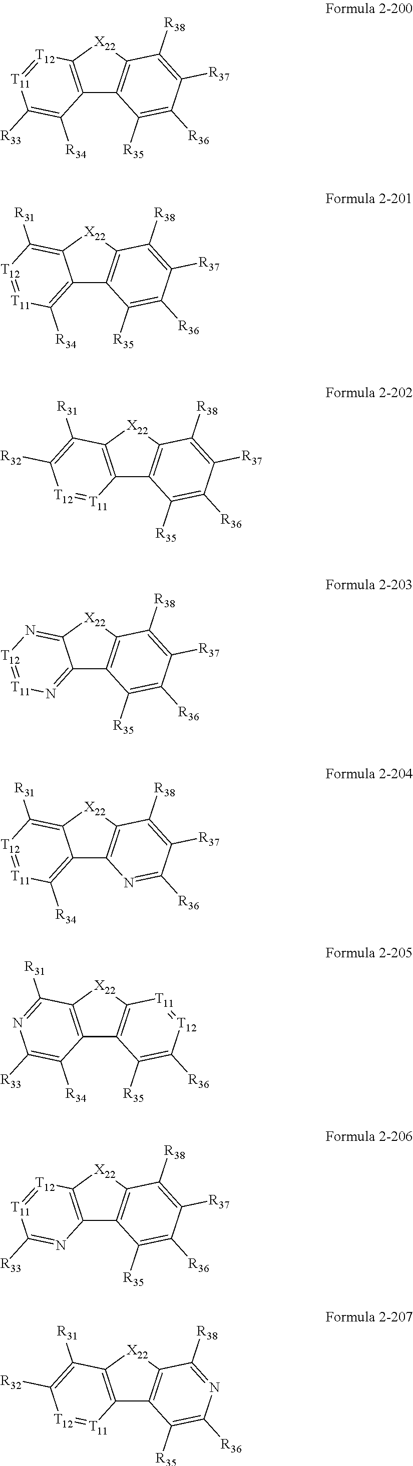

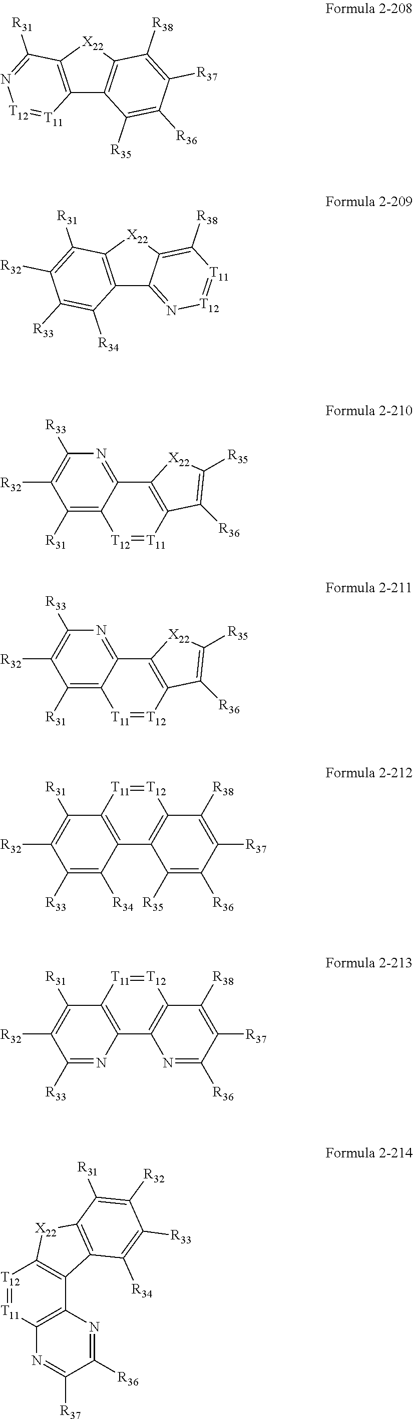

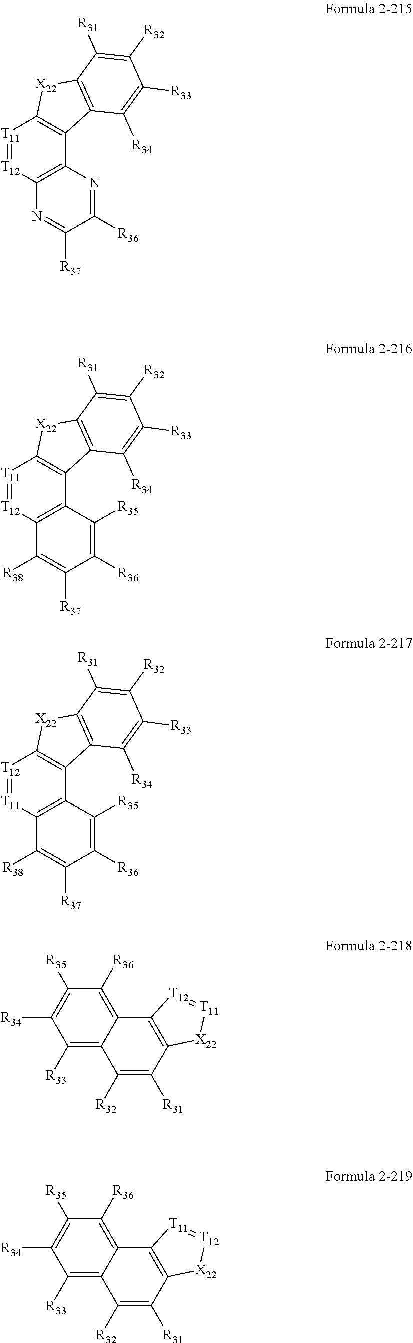

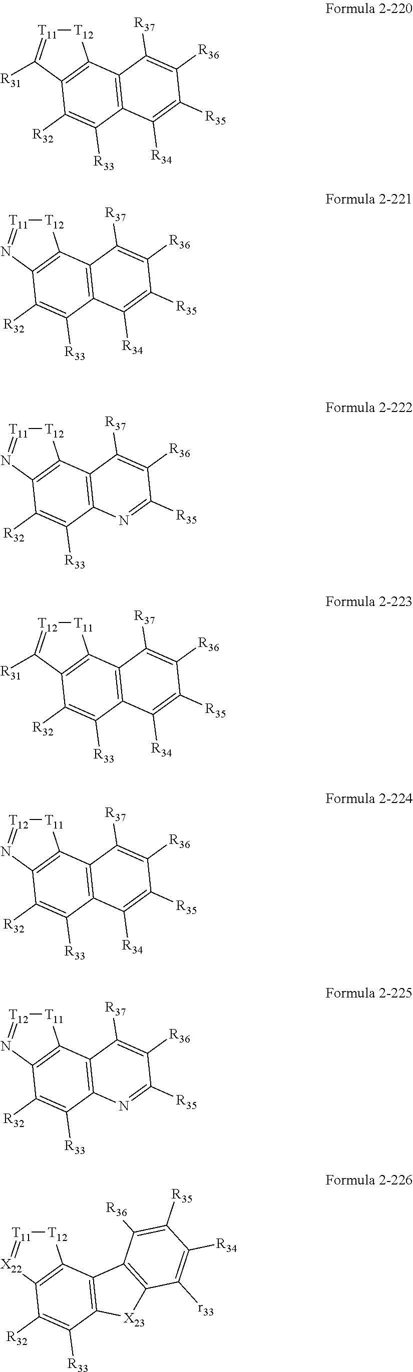

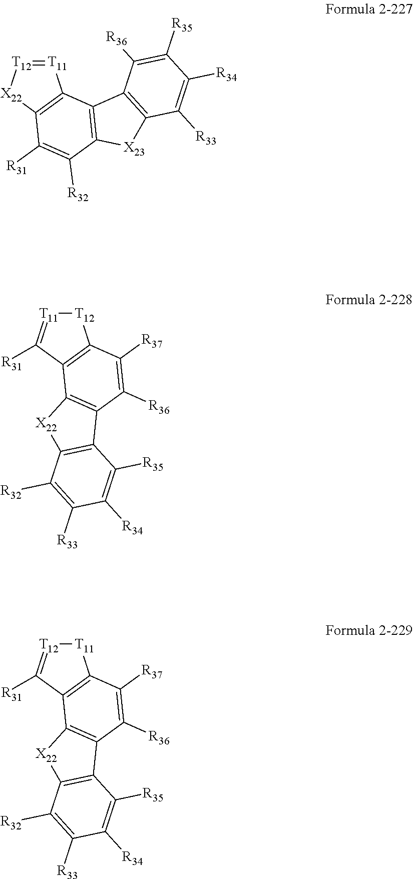

In Formulae 2-101 to 2-229,

T₁₁ and T₁₂ are the same as described above,

X₂₂ and X₂₃ are the same as described above, and

R₃₁ to R₃₈ may each independently be selected from substituents represented by *-[(L₂₂)ₐ₂₂-(R₂₂)_{b22}] as described herein.

In Formulae 2-101 to 2-229, when the number of *-[(L₂₂)ₐ₂₂-(R₂₂)_{b22}](s) is two or more, two or more *-[(L₂₂)ₐ₂₂-(R₂₂)_{b22}](s) (e.g., in the respective Formula) may be identical to or different from each other.

For example, in Formulae 2A to 2B, a case where rings A₂₁, A₂₂, and A₂₃ are all represented by Formula 2-104 may be excluded.

In various embodiments, the second compound represented by Formula 2A or 2B may be represented by one selected from Formulae 2-201A to 2-269A, and rings A₂₁, A₂₂, and A₂₃ in Formulae 2-201A to 2-269A may each be selected from the Formulae shown in Table 1.

TABLE 1

| | Formula No. for | Formula No. for | Formula No. for |
|---|---|---|---|
| Formula No. | ring A₂₁ | ring A₂₂ | ring A₂₃ |
| 2-201A | 2-2 | 2-4 | 2-4 |
| 2-202A | 2-4 | 2-4 | 2-1 |
| 2-203A | 2-4 | 2-4 | 2-2 |
| 2-204A | 2-4 | 2-4 | 2-3 |
| 2-205A | 2-4 | 2-1 | 2-4 |
| 2-206A | 2-4 | 2-2 | 2-4 |
| 2-207A | 2-4 | 2-4 | 2-10 |
| 2-208A | 2-11 | 2-4 | 2-4 |
| 2-209A | 2-4 | 2-4 | 2-11 |
| 2-210A | 2-4 | 2-10 | 2-4 |
| 2-211A | 2-4 | 2-4 | 2-8 |
| 2-212A | 2-4 | 2-9 | 2-4 |
| 2-213A | 2-4 | 2-4 | 2-14 |
| 2-214A | 2-17 | 2-4 | 2-4 |
| 2-215A | 2-4 | 2-4 | 2-15 |
| 2-216A | 2-13 | 2-4 | 2-4 |
| 2-217A | 2-4 | 2-4 | 2-16 |
| 2-218A | 2-4 | 2-4 | 2-13 |
| 2-219A | 2-16 | 2-4 | 2-4 |
| 2-220A | 2-4 | 2-4 | 2-12 |
| 2-221A | 2-4 | 2-4 | 2-17 |
| 2-222A | 2-4 | 2-16 | 2-4 |
| 2-223A | 2-4 | 2-15 | 2-4 |
| 2-224A | 2-4 | 2-14 | 2-4 |
| 2-225A | 2-4 | 2-17 | 2-4 |
| 2-226A | 2-19 | 2-4 | 2-4 |
| 2-227A | 2-22 | 2-4 | 2-4 |
| 2-228A | 2-18 | 2-4 | 2-4 |
| 2-229A | 2-23 | 2-4 | 2-4 |
| 2-230A | 2-21 | 2-4 | 2-4 |
| 2-231A | 2-20 | 2-4 | 2-4 |
| 2-232A | 2-4 | 2-23 | 2-4 |
| 2-233A | 2-4 | 2-18 | 2-4 |
| 2-234A | 2-4 | 2-21 | 2-4 |
| 2-235A | 2-4 | 2-19 | 2-4 |
| 2-236A | 2-5 | 2-2 | 2-4 |
| 2-237A | 2-5 | 2-1 | 2-4 |
| 2-238A | 2-2 | 2-2 | 2-4 |
| 2-239A | 2-4 | 2-23 | 2-1 |
| 2-240A | 2-6 | 2-10 | 2-4 |
| 2-241A | 2-4 | 2-4 | 2-29 |
| 2-242A | 2-7 | 2-4 | 2-10 |
| 2-243A | 2-11 | 2-4 | 2-10 |
| 2-244A | 2-4 | 2-10 | 2-6 |
| 2-245A | 2-11 | 2-11 | 2-4 |
| 2-246A | 2-11 | 2-11 | 2-5 |
| 2-247A | 2-11 | 2-11 | 2-10 |
| 2-248A | 2-7 | 2-9 | 2-4 |
| 2-249A | 2-4 | 2-4 | 2-25 |
| 2-250A | 2-11 | 2-15 | 2-4 |
| 2-251A | 2-18 | 2-28 | 2-4 |
| 2-252A | 2-23 | 2-10 | 2-4 |
| 2-253A | 2-4 | 2-27 | 2-4 |
| 2-254A | 2-6 | 2-18 | 2-4 |
| 2-255A | 2-4 | 2-23 | 2-5 |
| 2-256A | 2-23 | 2-4 | 2-14 |
| 2-257A | 2-17 | 2-4 | 2-14 |
| 2-258A | 2-14 | 2-4 | 2-12 |
| 2-259A | 2-17 | 2-4 | 2-12 |
| 2-260A | 2-14 | 2-16 | 2-2 |
| 2-261A | 2-17 | 2-5 | 2-14 |
| 2-262A | 2-17 | 2-13 | 2-17 |
| 2-263A | 2-17 | 2-14 | 2-12 |
| 2-264A | 2-17 | 2-12 | 2-12 |
| 2-265A | 2-5 | 2-1 | 2-18 |
| 2-266A | 2-4 | 2-29 | 2-4 |
| 2-267A | 2-4 | 2-31 | 2-4 |
| 2-268A | 2-4 | 2-33 | 2-4 |
| 2-269A | 2-4 | 2-35 | 2-4 |

In various embodiments, the second compound represented by Formula 2A or 2B may be represented by one selected from Formulae 2-201B to 2-215B, and rings A₂₁ and A₂₃ in Formulae 2-201B to 2-215B (e.g., each representing a compound represented by Formula 2B) may each be selected from the Formulae shown in Table 2.

TABLE 2

| | Formula No. for | Formula No. for | Formula No. for |
|---|---|---|---|
| Formula No. | ring A₂₁ | ring A₂₂ | ring A₂₃ |
| 2-201B | 2-4 | — | 2-19 |
| 2-202B | 2-4 | — | 2-22 |
| 2-203B | 2-4 | — | 2-18 |
| 2-204B | 2-4 | — | 2-23 |
| 2-205B | 2-4 | — | 2-21 |
| 2-206B | 2-4 | — | 2-20 |
| 2-207B | 2-5 | — | 2-23 |
| 2-208B | 2-7 | — | 2-23 |
| 2-209B | 2-4 | — | 2-26 |
| 2-210B | 2-7 | — | 2-22 |
| 2-211B | 2-13 | — | 2-16 |
| 2-212B | 2-5 | — | 2-19 |
| 2-213B | 2-7 | — | 2-20 |
| 2-214B | 2-19 | — | 2-18 |
| 2-215B | 2-18 | — | 2-18 |

In various embodiments, the second compound represented by Formula 2A or 2B may be represented by one selected from Formulae 2-301A to 2-421A, and rings A₂₁, A₂₂, and A₂₃ in Formulae 2-301A to 2-419A and 2-421A to 2-431A may each be selected from the Formulae shown in Table 3.

TABLE 3

| | Formula No. for | Formula No. for | Formula No. for |
|---|---|---|---|
| Formula No. | ring A₂₁ | ring A₂₂ | ring A₂₃ |
| 2-301A | 2-104 | 2-147 | 2-104 |
| 2-302A | 2-102 | 2-104 | 2-104 |
| 2-303A | 2-104 | 2-104 | 2-101 |
| 2-304A | 2-104 | 2-104 | 2-102 |
| 2-305A | 2-104 | 2-104 | 2-103 |
| 2-306A | 2-104 | 2-101 | 2-104 |
| 2-307A | 2-104 | 2-102 | 2-104 |
| 2-308A | 2-104 | 2-104 | 2-147 |
| 2-309A | 2-157 | 2-104 | 2-104 |
| 2-310A | 2-104 | 2-104 | 2-157 |
| 2-311A | 2-104 | 2-147 | 2-107 |
| 2-312A | 2-104 | 2-149 | 2-104 |
| 2-313A | 2-104 | 2-156 | 2-104 |
| 2-314A | 2-107 | 2-147 | 2-106 |
| 2-315A | 2-104 | 2-151 | 2-104 |
| 2-316A | 2-104 | 2-147 | 2-106 |
| 2-317A | 2-104 | 2-148 | 2-104 |
| 2-318A | 2-104 | 2-150 | 2-104 |
| 2-319A | 2-106 | 2-147 | 2-104 |
| 2-320A | 2-104 | 2-106 | 2-147 |
| 2-321A | 2-157 | 2-107 | 2-104 |
| 2-322A | 2-106 | 2-104 | 2-147 |
| 2-323A | 2-104 | 2-107 | 2-147 |
| 2-324A | 2-107 | 2-104 | 2-147 |
| 2-325A | 2-104 | 2-104 | 2-160 |
| 2-326A | 2-104 | 2-111 | 2-157 |
| 2-327A | 2-108 | 2-104 | 2-158 |
| 2-328A | 2-111 | 2-104 | 2-157 |
| 2-329A | 2-107 | 2-147 | 2-104 |
| 2-330A | 2-104 | 2-104 | 2-135 |
| 2-331A | 2-104 | 2-141 | 2-104 |
| 2-332A | 2-104 | 2-142 | 2-104 |
| 2-333A | 2-107 | 2-104 | 2-135 |
| 2-334A | 2-104 | 2-111 | 2-135 |
| 2-335A | 2-104 | 2-143 | 2-104 |
| 2-336A | 2-106 | 2-142 | 2-104 |
| 2-337A | 2-107 | 2-142 | 2-106 |
| 2-338A | 2-104 | 2-104 | 2-169 |
| 2-339A | 2-184 | 2-104 | 2-104 |
| 2-340A | 2-104 | 2-104 | 2-182 |
| 2-341A | 2-168 | 2-104 | 2-104 |
| 2-342A | 2-104 | 2-104 | 2-183 |
| 2-343A | 2-104 | 2-104 | 2-168 |
| 2-344A | 2-183 | 2-104 | 2-104 |
| 2-345A | 2-104 | 2-104 | 2-167 |
| 2-346A | 2-104 | 2-104 | 2-184 |
| 2-347A | 2-104 | 2-183 | 2-104 |
| 2-348A | 2-104 | 2-182 | 2-104 |
| 2-349A | 2-104 | 2-169 | 2-104 |
| 2-350A | 2-104 | 2-184 | 2-104 |
| 2-351A | 2-107 | 2-104 | 2-179 |
| 2-352A | 2-111 | 2-104 | 2-169 |
| 2-353A | 2-104 | 2-111 | 2-182 |
| 2-354A | 2-106 | 2-104 | 2-185 |
| 2-355A | 2-171 | 2-104 | 2-104 |
| 2-356A | 2-104 | 2-104 | 2-115 |
| 2-357A | 2-104 | 2-104 | 2-178 |
| 2-358A | 2-104 | 2-106 | 2-167 |
| 2-359A | 2-108 | 2-105 | 2-167 |
| 2-360A | 2-105 | 2-104 | 2-167 |
| 2-361A | 2-112 | 2-104 | 2-184 |
| 2-362A | 2-104 | 2-192 | 2-104 |
| 2-363A | 2-107 | 2-182 | 2-106 |
| 2-364A | 2-104 | 2-169 | 2-105 |
| 2-365A | 2-105 | 2-184 | 2-104 |
| 2-366A | 2-105 | 2-169 | 2-105 |
| 2-367A | 2-198 | 2-104 | 2-104 |
| 2-368A | 2-201 | 2-104 | 2-104 |
| 2-369A | 2-197 | 2-104 | 2-104 |
| 2-370A | 2-202 | 2-104 | 2-104 |
| 2-371A | 2-200 | 2-104 | 2-104 |
| 2-372A | 2-199 | 2-104 | 2-104 |
| 2-373A | 2-104 | 2-202 | 2-104 |
| 2-374A | 2-104 | 2-197 | 2-104 |
| 2-375A | 2-104 | 2-200 | 2-104 |
| 2-376A | 2-104 | 2-198 | 2-104 |
| 2-377A | 2-209 | 2-104 | 2-104 |
| 2-378A | 2-207 | 2-104 | 2-104 |
| 2-379A | 2-200 | 2-106 | 2-104 |
| 2-380A | 2-104 | 2-208 | 2-104 |
| 2-381A | 2-105 | 2-198 | 2-108 |
| 2-382A | 2-202 | 2-102 | 2-104 |
| 2-383A | 2-202 | 2-101 | 2-106 |
| 2-384A | 2-102 | 2-102 | 2-107 |
| 2-385A | 2-104 | 2-202 | 2-101 |
| 2-386A | 2-123 | 2-147 | 2-104 |
| 2-387A | 2-104 | 2-104 | 2-218 |
| 2-388A | 2-116 | 2-104 | 2-147 |
| 2-389A | 2-157 | 2-104 | 2-147 |
| 2-390A | 2-107 | 2-147 | 2-115 |
| 2-391A | 2-157 | 2-157 | 2-104 |
| 2-392A | 2-157 | 2-157 | 2-114 |
| 2-393A | 2-157 | 2-157 | 2-147 |
| 2-394A | 2-116 | 2-147 | 2-104 |
| 2-395A | 2-104 | 2-104 | 2-210 |
| 2-396A | 2-157 | 2-182 | 2-104 |
| 2-397A | 2-197 | 2-213 | 2-104 |
| 2-398A | 2-202 | 2-167 | 2-104 |
| 2-399A | 2-104 | 2-216 | 2-104 |
| 2-400A | 2-124 | 2-197 | 2-104 |
| 2-401A | 2-104 | 2-202 | 2-114 |
| 2-402A | 2-168 | 2-104 | 2-169 |
| 2-403A | 2-184 | 2-104 | 2-169 |
| 2-404A | 2-169 | 2-104 | 2-167 |
| 2-405A | 2-184 | 2-106 | 2-167 |
| 2-406A | 2-169 | 2-183 | 2-102 |
| 2-407A | 2-184 | 2-114 | 2-169 |
| 2-408A | 2-184 | 2-168 | 2-184 |
| 2-409A | 2-184 | 2-104 | 2-167 |
| 2-410A | 2-184 | 2-167 | 2-167 |
| 2-411A | 2-114 | 2-101 | 2-197 |
| 2-412A | 2-104 | 2-149 | 2-104 |
| 2-413A | 2-106 | 2-104 | 2-147 |
| 2-414A | 2-104 | 2-104 | 2-168 |
| 2-415A | 2-200 | 2-106 | 2-104 |
| 2-416A | 2-104 | 2-104 | 2-183 |
| 2-417A | 2-104 | 2-104 | 2-101 |
| 2-418A | 2-105 | 2-169 | 2-105 |
| 2-419A | 2-104 | 2-147 | 2-107 |
| 2-421A | 2-104 | 2-218 | 2-104 |
| 2-422A | 2-104 | 2-226 | 2-104 |
| 2-423A | 2-104 | 2-222 | 2-104 |
| 2-424A | 2-104 | 2-228 | 2-104 |
| 2-425A | 2-104 | 2-151 | 2-104 |
| 2-426A | 2-106 | 2-147 | 2-107 |
| 2-427A | 2-104 | 2-147 | 2-106 |
| 2-428A | 2-107 | 2-150 | 2-104 |
| 2-429A | 2-104 | 2-143 | 2-104 |
| 2-430A | 2-107 | 2-142 | 2-106 |
| 2-431A | 2-104 | 2-142 | 2-104 |

In various embodiments, the second compound represented by Formula 2A or 2B may be represented by one selected from Formulae 2-301B to 2-320B, and rings A₂₁ and A₂₃ in Formulae 2-301B to 2-320B (e.g., each representing a compound represented by Formula 2B) may each be selected from the Formulae shown in Table 4.

TABLE 4

| | Formula No. for | Formula No. for | Formula No. for |
|---|---|---|---|
| Formula No. | ring A₂₁ | ring A₂₂ | ring A₂₃ |
| 2-301B | 2-104 | — | 2-198 |
| 2-302B | 2-104 | — | 2-201 |
| 2-303B | 2-104 | — | 2-197 |
| 2-304B | 2-104 | — | 2-202 |
| 2-305B | 2-104 | — | 2-200 |
| 2-306B | 2-104 | — | 2-199 |
| 2-307B | 2-104 | — | 2-203 |
| 2-308B | 2-104 | — | 2-204 |
| 2-309B | 2-106 | — | 2-205 |
| 2-310B | 2-104 | — | 2-206 |
| 2-311B | 2-112 | — | 2-199 |
| 2-312B | 2-114 | — | 2-202 |
| 2-313B | 2-116 | — | 2-202 |
| 2-314B | 2-104 | — | 2-214 |
| 2-315B | 2-130 | — | 2-201 |
| 2-316B | 2-168 | — | 2-183 |
| 2-317B | 2-114 | — | 2-198 |
| 2-318B | 2-116 | — | 2-199 |
| 2-319B | 2-198 | — | 2-197 |
| 2-320B | 2-197 | — | 2-197 |

X₁ in Formula 1 may be selected from N[(L₃)ₐ₃-(Ar₃)_{c3}], Si(R₃)(R₄), O, S, and Se.

For example, X₁ in Formula 1 may be selected from N[(L₃)ₐ₃-(Ar₃)_{c3}], O, and S.

X₂₁ in Formulae 2A and 2B may be selected from O, S, Se, C(R₂₃)(R₂₄), Si(R₂₃)(R₂₄), and N-[(L₂₁)ₐ₂₁-(R₂₁)_{b21}].

In various embodiments, X₂₁ in Formulae 2A and 2B may be N[(L₂₁)ₐ₂₁-(R₂₁)_{b21}].

In various embodiments, X₂₁ in Formulae 2A and 2B may be O, S, Se, C(R₂₃)(R₂₄), or Si(R₂₃)(R₂₄), and

at least one selected from A₂₁, A₂₂, and A₂₃ in Formula 2A and at least one selected from rings A₂₁ and A₂₃ in Formula 2B may each independently be selected from groups represented by Formulae 2-1 to 2-3, 2-10 to 2-27, and 2-33 to 2-36, and X₂₂ or X₂₃ in Formulae 2-1 to 2-3, 2-10 to 2-27, and 2-33 to 2-36 may be N-[(L₂₂)ₐ₂₂-(R₂₂)_{b22}].

In various embodiments, X₂₁ in Formulae 2A and 2B may be O, S, Se, C(R₂₃)(R₂₄), or Si(R₂₃)(R₂₄), and

at least one selected from rings A₂₁, A₂₂, and A₂₃ in Formula 2A and at least one selected from rings A₂₁ and A₂₃ in Formula 2B may each independently be selected from groups represented by Formulae 2-101 to 2-103, 2-147 to 2-211, 2-214 to 2-219, and 2-226 to 2-229, and X₂₂ or X₂₃ in Formulae 2-101 to 2-103, 2-147 to 2-211, 2-214 to 2-219, and 2-226 to 2-229 may be N-[(L₂₂)ₐ₂₂-(R₂₂)_{b22}], but embodiments of the present disclosure are not limited thereto.

X₂₁ in Formulae 2A and 2B may be O, S, Se, C(R₂₃)(R₂₄), Si(R₂₃)(R₂₄), or N-[(L₂₁)ₐ₂₁-(R₂₁)_{b21}], and X₂₂ and X₂₃ may each independently be O, S, Se, C(R₂₅)(R₂₆), Si(R₂₅)(R₂₆), or N-[(L₂₂)ₐ₂₂-(R₂₂)_{b22}]. L₂₁, L₂₂, a21, a22, R₂₁ to R₂₆, b21, and b22 are the same as described below.

L₁ to L₃, L₂₁, and L₂₂ in Formulae 1, 2A, and 2B may each independently be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group.

L₁ to L₃, L₂₁, and L₂₂ in Formulae 1, 2A, and 2B may each independently be selected from the group consisting of:

a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a spiro-benzofluorene-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, a silolylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an indolylene group, an isoindolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzoimidazolylene group, a benzofuranylene group, a benzothiophenylene group, a benzosilolylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a dibenzosilolylene group, a carbazolylene group, a benzocarbazolylene group, a dibenzocarbazolylene group, a thiadiazolylene group, an imidazopyridinylene group, an imidazopyrimidinylene group, an oxazolopyridinylene group, a thiazolopyridinylene group, a benzonaphthyridinylene group, an azafluorenylene group, an azaspiro-bifluorenylene group, an azacarbazolylene group, an azadibenzofuranylene group, an azadibenzothiophenylene group, and an azadibenzosilolylene group; and

a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a spiro-benzofluorene-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, a silolylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an indolylene group, an isoindolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzoimidazolylene group, a benzofuranylene group, a benzothiophenylene group, a benzosilolylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a dibenzosilolylene group, a carbazolylene group, a benzocarbazolylene group, a dibenzocarbazolylene group, a thiadiazolylene group, an imidazopyridinylene group, an imidazopyrimidinylene group, an oxazolopyridinylene group, a thiazolopyridinylene group, a benzonaphthyridinylene group, an azafluorenylene group, an azaspiro-bifluorenylene group, an azacarbazolylene group, an azadibenzofuranylene group, an azadibenzothiophenylene group, and an azadibenzosilolylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

wherein Q₃₁ to Q₃₃ may each independently be selected from the group consisting of:

a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and

a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group,

but embodiments of the present disclosure are not limited thereto.

In various embodiments, L₁ to L₃, L₂₁, and L₂₂ in Formulae 1, 2A, and 2B may each independently be selected from groups represented by Formulae 3-1 to 3-100, but embodiments of the present disclosure are not limited thereto:

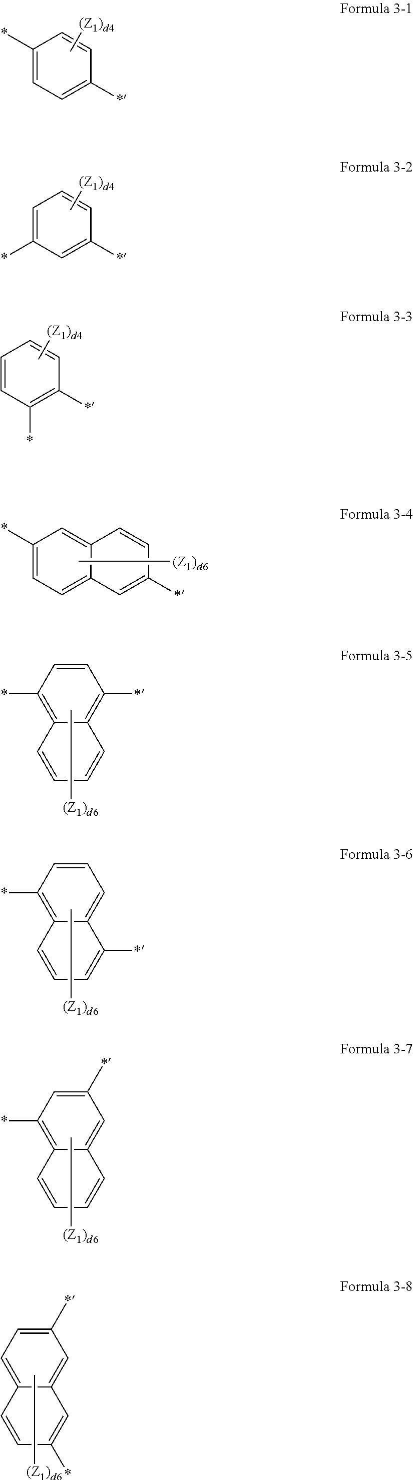

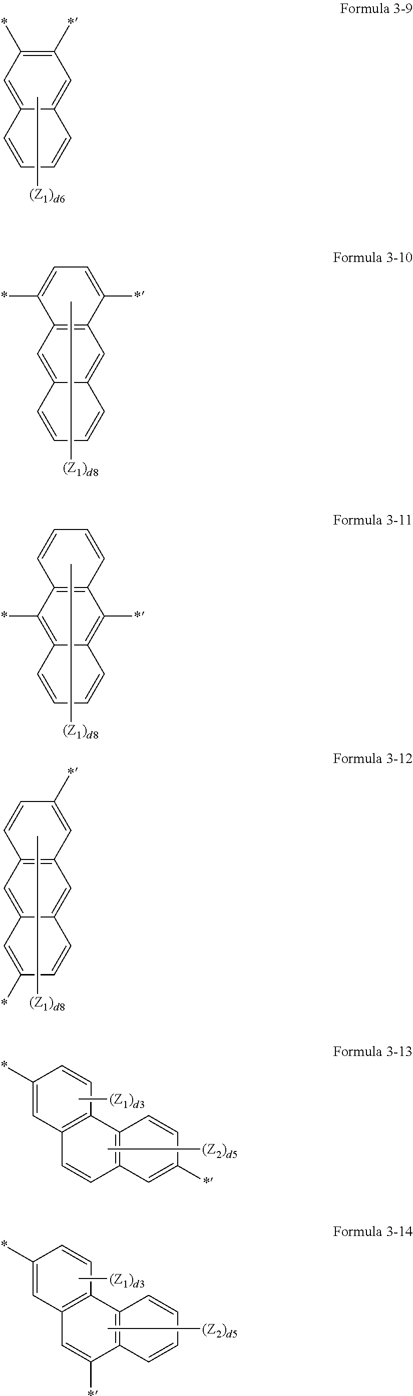

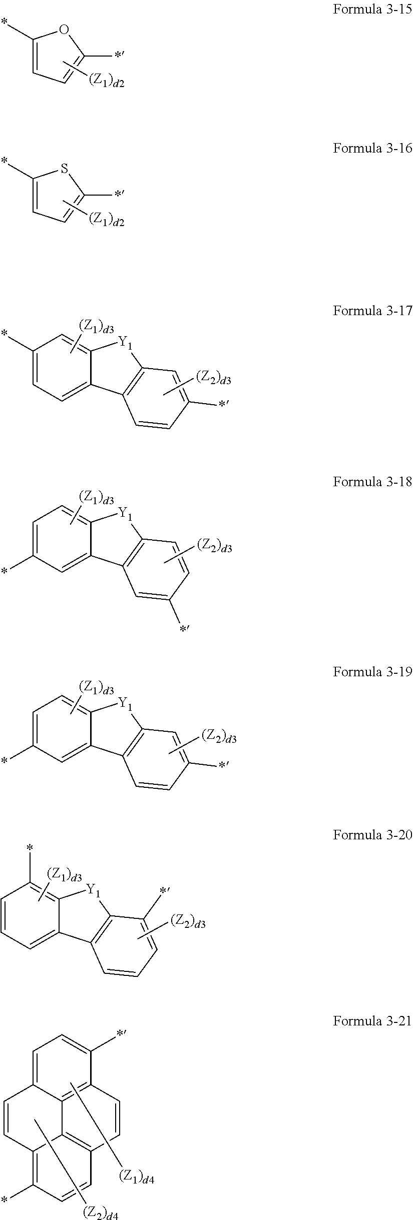

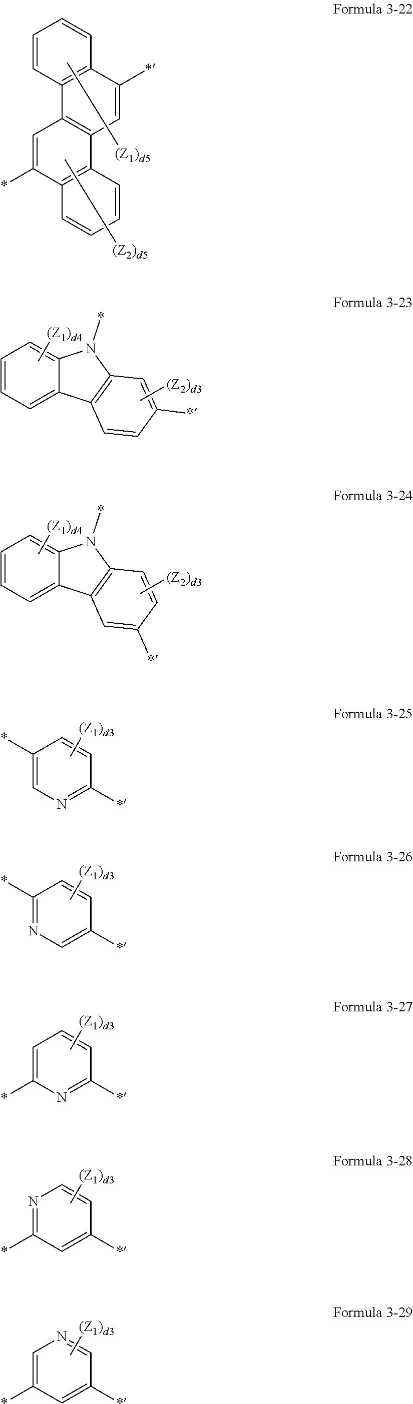

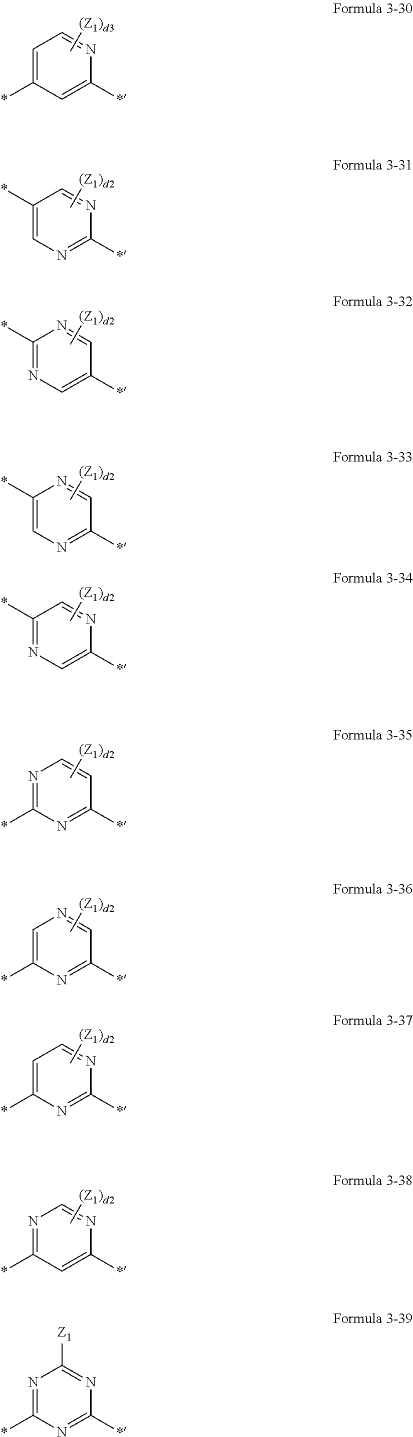

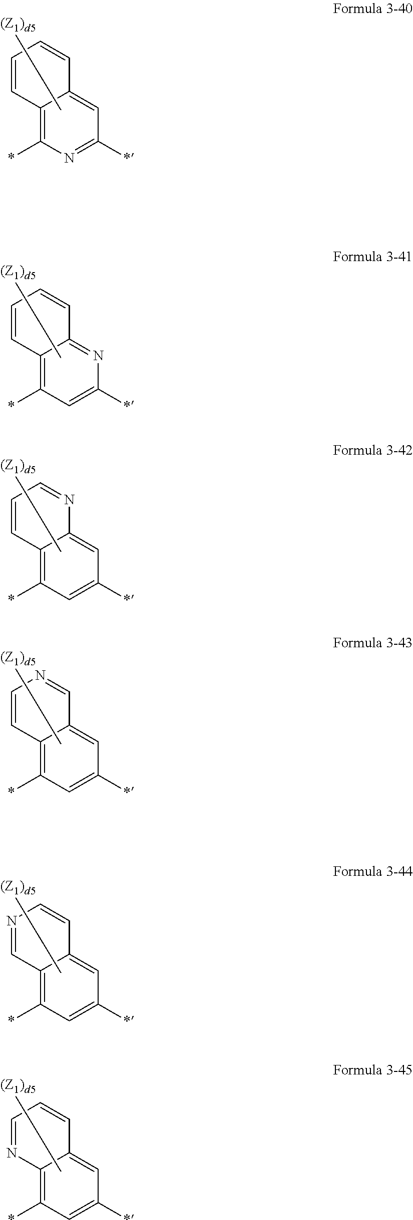

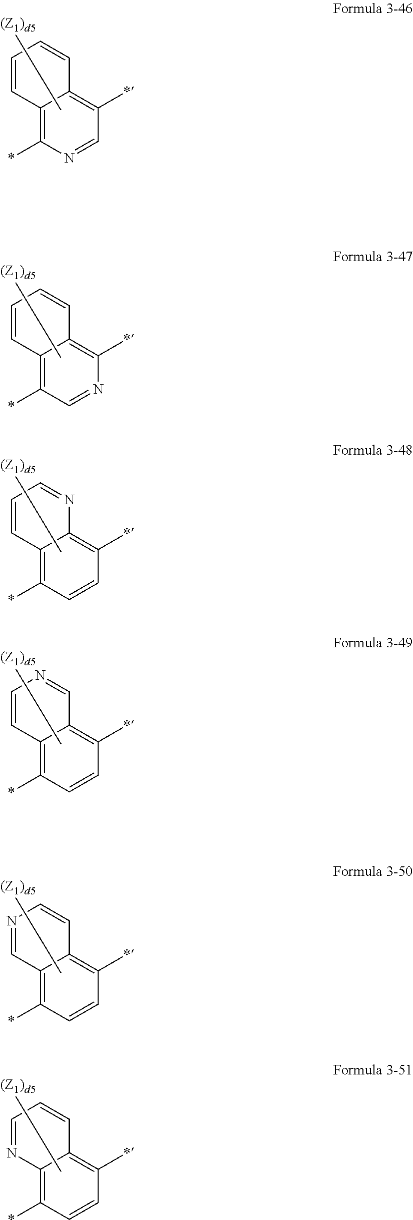

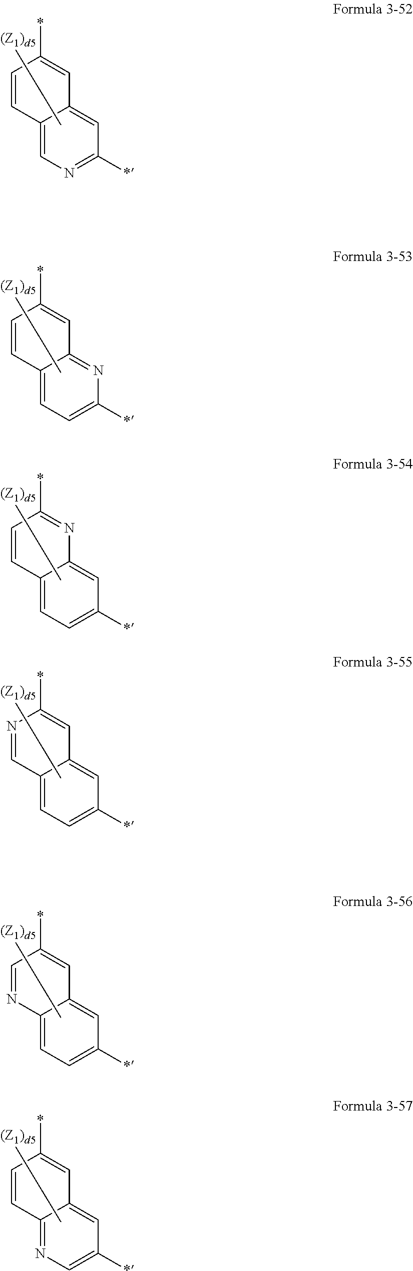

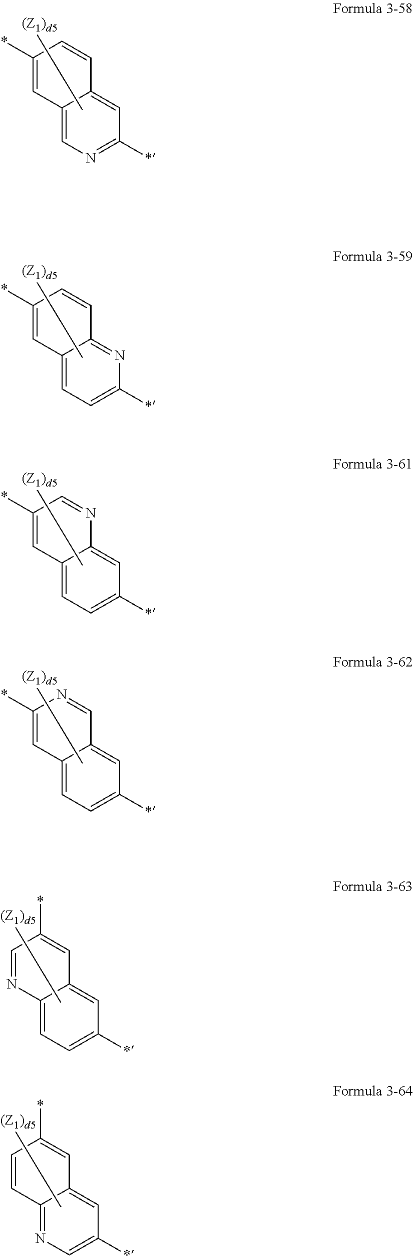

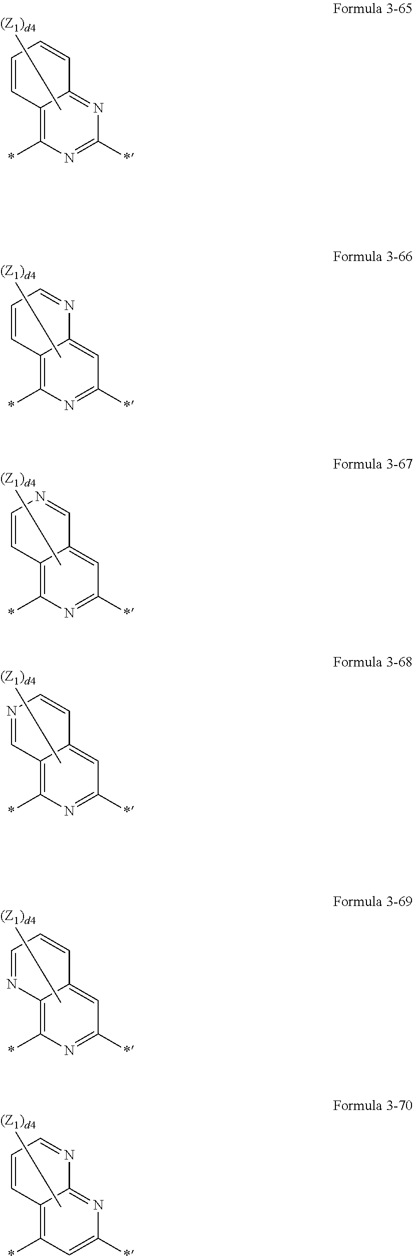

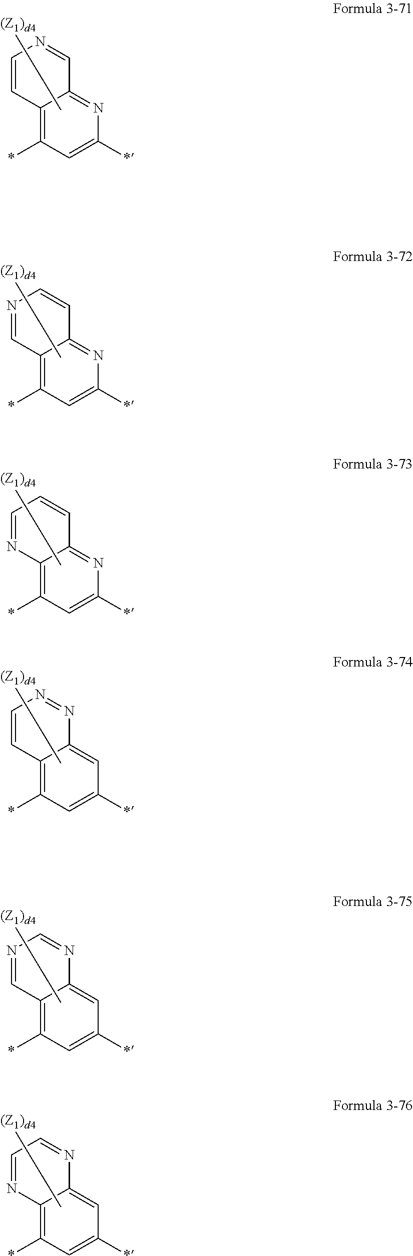

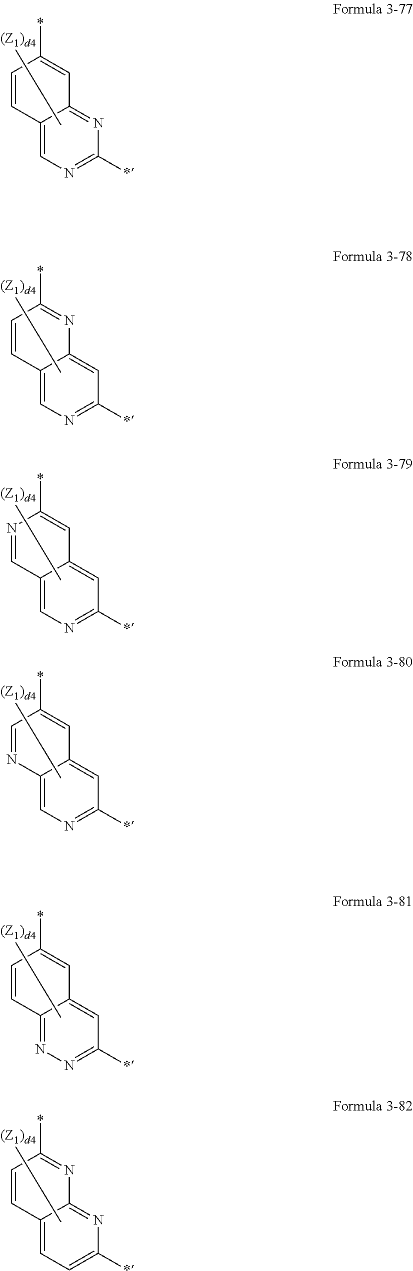

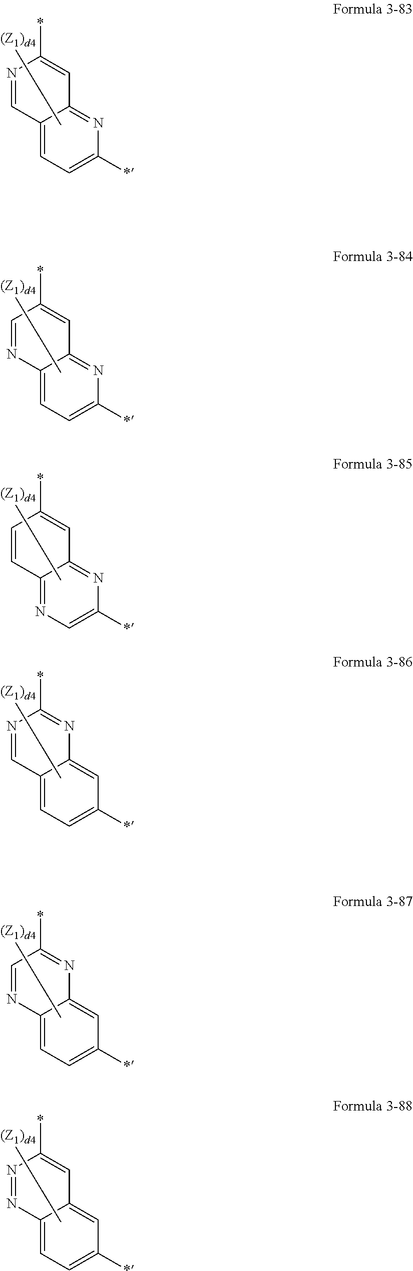

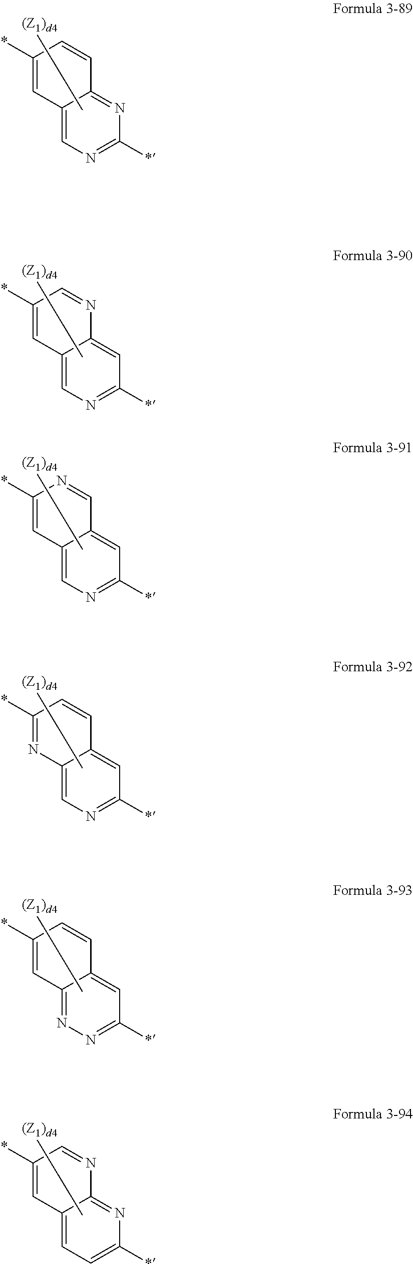

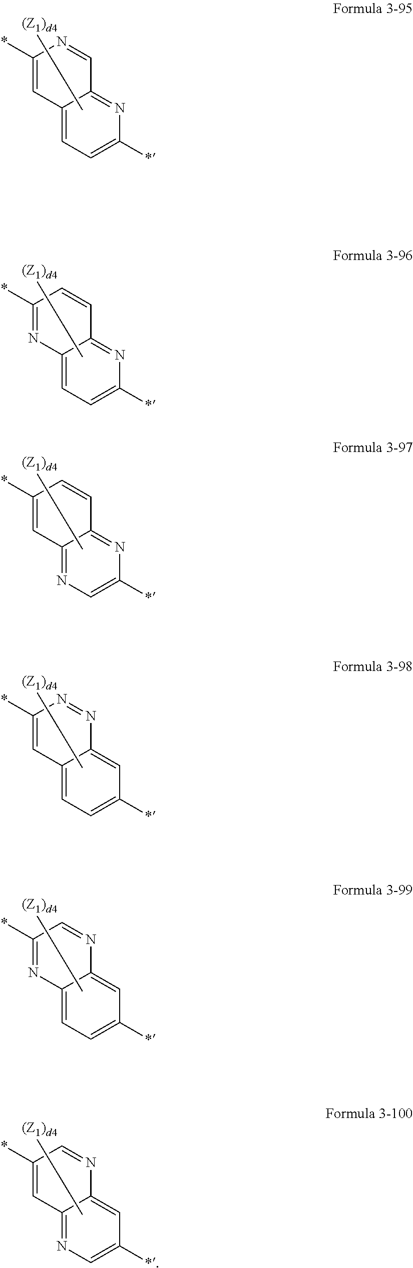

In Formula 3-1 to 3-100, Y₁ may be O, S, C(Z₃)(Z₄), N(Z₅), or Si(Z₆)(Z₇),

Z₁ to Z₇ may each independently be selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzoimidazolyl group, a benzofuranyl group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a carbazolyl group, a benzocarbazolyl group, a dibenzocarbazolyl group, a thiadiazolyl group, an imidazopyridinyl group, an imidazopyrimidinyl group, a benzonaphthyridinyl group, an azafluorenyl group, an azaspiro-bifluorenyl group, an azacarbazolyl group, an azadibenzofuranyl group, an azadibenzothiophenyl group, an azadibenzosilolyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

wherein Q₃₁ to Q₃₃ may each independently be selected from the group consisting of:

a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and

a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group,

d2 may be an integer selected from 0 to 2,

d3 may be an integer selected from 0 to 3,

d4 may be an integer selected from 0 to 4,

d5 may be an integer selected from 0 to 5,

d6 may be an integer selected from 0 to 6,

d8 may be an integer selected from 0 to 8, and

* and *′ each indicate a binding site to a neighboring atom.

In Formulae 1, 2A, and 2B, a1, a2, a3, a21, and a22 indicate the number of L₁(s), the number of L₂(s), the number of L₃(s), the number of L₂₁(s), and the number of L₂₂(s), respectively. In Formulae 1, 2A, and 2B, a1 to a3, a21, and a22 may each independently be an integer selected from 0 to 5. When a1 is two or more, two or more L₁(s) may be identical to or different from each other. When a2 is two or more, two or more L₂(s) may be identical to or different from each other. When a3 is two or more, two or more L₃(s) may be identical to or different from each other. When a21 is two or more, two or more L₂₁(s) may be identical to or different from each other. When a22 is two or more, two or more L₂₂(s) may be identical to or different from each other. When a1 is zero, *-(L₁)ₐ₁-*′ may be a single bond. When a2 is zero, *-(L₂)ₐ₂-*′ may be a single bond. When a3 is zero, *-(L₃)ₐ₃-*′ may be a single bond. When a21 is zero, *-(L₂₁)ₐ₂₁-*′ may be a single bond. When a22 is zero, *-(L₂₂)ₐ₂₂-*′ may be a single bond.

In various embodiments, a1 to a3, a21, and a22 in Formulae 1 and 2 may each independently be an integer selected from 0 to 3, but embodiments of the present disclosure are not limited thereto.

Ar₁ to Ar₃ in Formula 1 may each independently be selected from a substituted or unsubstituted C₁-C₆₀ alkyl group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂).

In Formula 1, Ar₁ to Ar₃ may each independently be selected from the group consisting of:

a group represented by any of Formulae 1-1 and 1-2, a C₁-C₂₀ alkyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a dibenzosilolyl group, a thiadiazolyl group, an imidazopyridinyl group, an imidazopyrimidinyl group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂); and

a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a dibenzosilolyl group, a thiadiazolyl group, an imidazopyridinyl group, and an imidazopyrimidinyl group, each substituted with at least one selected from deuterium, —F, —Cl, —Br, —I, a hydroxyl group, a cyano group, a nitro group, an amidino group, a hydrazino group, a hydrazono group, a C₁-C₁₀ alkyl group, a C₁-C₁₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂), and

R₁ to R₄, R₂₁ to R₂₄, R₂₇, and R₂₈ may each independently be selected from the group consisting of:

hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;

a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a dibenzosilolyl group, a thiadiazolyl group, an imidazopyridinyl group, an imidazopyrimidinyl group, —Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅); and

a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a dibenzosilolyl group, a thiadiazolyl group, an imidazopyridinyl group, and an imidazopyrimidinyl group, each substituted with at least one selected from deuterium, —F, —Cl, —Br, —I, a hydroxyl group, a cyano group, a nitro group, an amidino group, a hydrazino group, a hydrazono group, a C₁-C₁₀ alkyl group, a C₁-C₁₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

wherein Q₁ to Q₆ and Q₃₁ to Q₃₃ may each independently be selected from the group consisting of:

a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and

a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group:

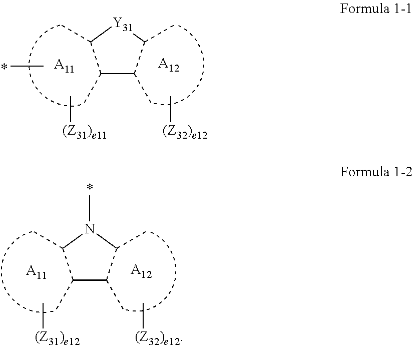

In Formulae 1-1 and 1-2,

A₁₁ and A₁₂ may each independently be selected from a cyclohexene group, a benzene group, a naphthalene group, a phenanthrene group, an anthracene group, a triphenylene group, a pyrene group, a carbazole group, a fluorene group, a spiro-bifluorene group, a pyridine group, a pyrazine group, a pyrimidine group, a pyridazine group, a quinoline group, an isoquinoline group, a quinoxaline group, a quinazoline group, a triazine group, an indene group, a benzofuran group, a benzothiophene group, a dibenzofuran group, and a dibenzothiophene group,

Y₃₁ may be selected from N[(L₁₁)ₐ₁₁-(Z₃₃)ₑ₁₃], C(Z₃₄)(Z₃₅), Si(Z₃₄)(Z₃₅), O, S, and Se,

L₁₁ may be the same as described above in connection with L₁ in Formula 1,

a11 may be the same as described above in connection with a1,

Z₃₁ to Z₃₅ may each independently be selected from the group consisting of:

hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, a quinolinyl group, an isoquinolinyl group, a benzoquinolinyl group, a quinoxalinyl group, a quinazolinyl group, a benzoimidazolyl group, an isobenzothiazolyl group, a benzoxazolyl group, an isobenzoxazolyl group, an oxadiazolyl group, and a triazinyl group; and

—Si(Q₃₁)(Q₃₂)(Q₃₃),

e11 and e12 may each independently be an integer selected from 1 to 10,

e13 may be an integer selected from 1 to 3,

Q₃₁ to Q₃₃ are the same as described above, and

* indicates a binding site to a neighboring atom.

For example, rings A₁₁ and A₁₂ in Formulae 1-1 and 1-2 may each independently be selected from a benzene group, a naphthalene group, and a pyridine group.

X₁ may be N[(L₃)ₐ₃-(Ar₃)_{c3}], and at least one selected from Ar₁ to Ar₃ may be a group represented by Formula 1-1 or 1-2.

In various embodiments, in Formula 1, X₁ may be O, S, or Se, and at least one selected from Ar₁ and Ar₂ may be a group represented by Formula 1-1 or 1-2.

In various embodiments, Ar₁ to Ar₃ in Formula 1 may each independently be selected from groups represented by Formulae 1-1 and 1-2, a C₁-C₂₀ alkyl group, groups represented by Formulae 5-1 to 5-45 and 6-1 to 6-124, and —Si(Q₁)(Q₂)(Q₃):

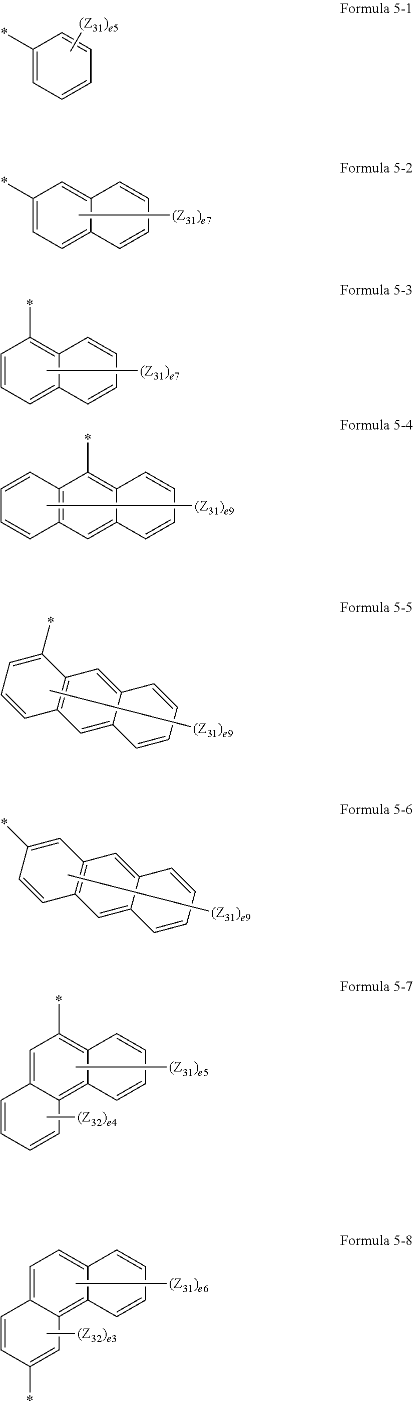

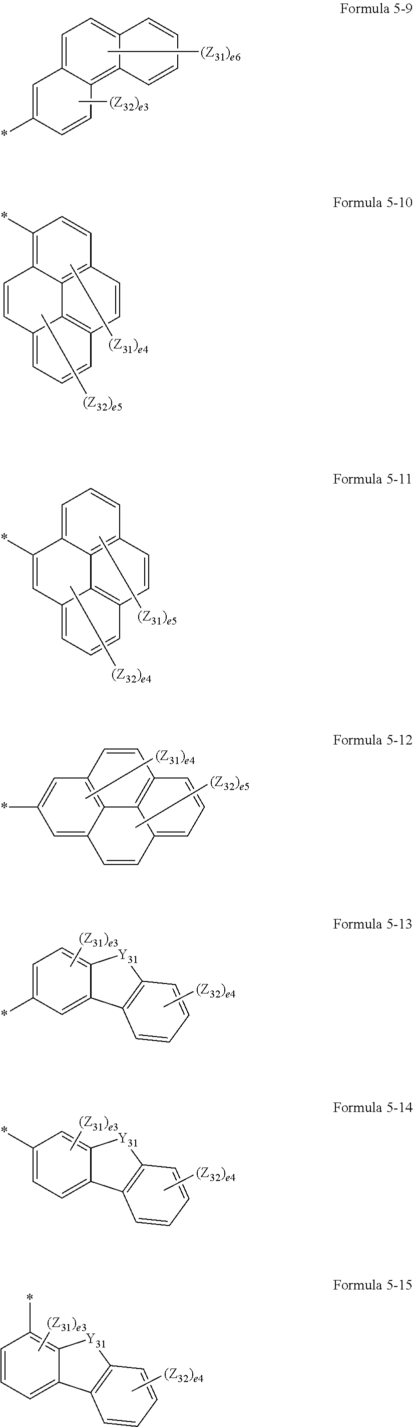

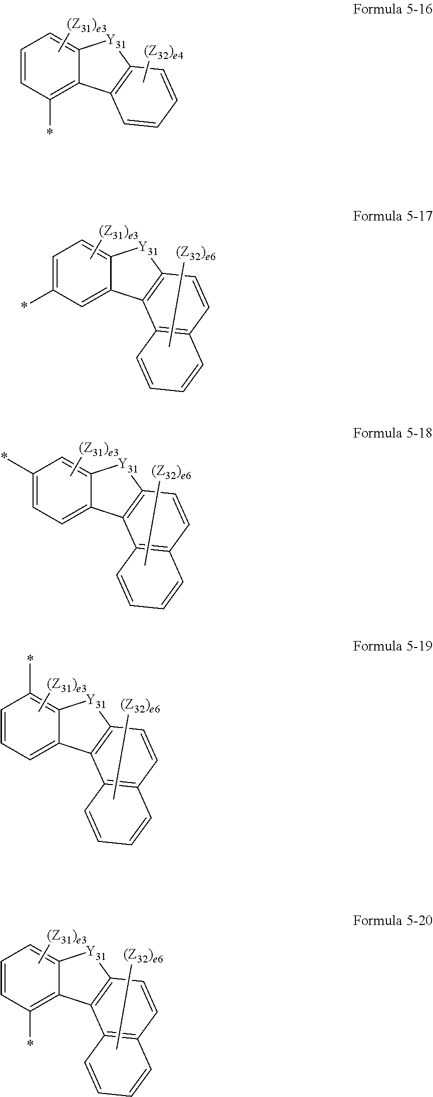

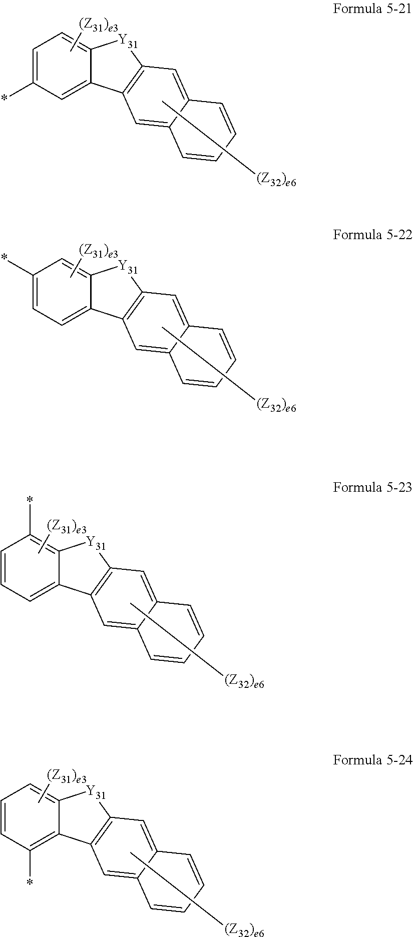

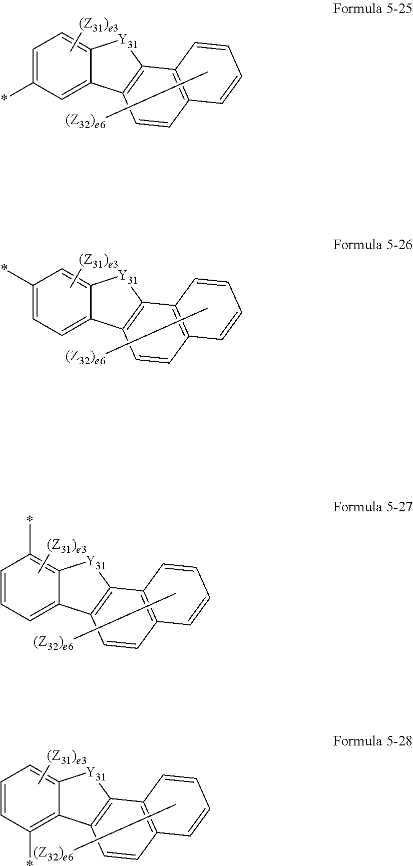

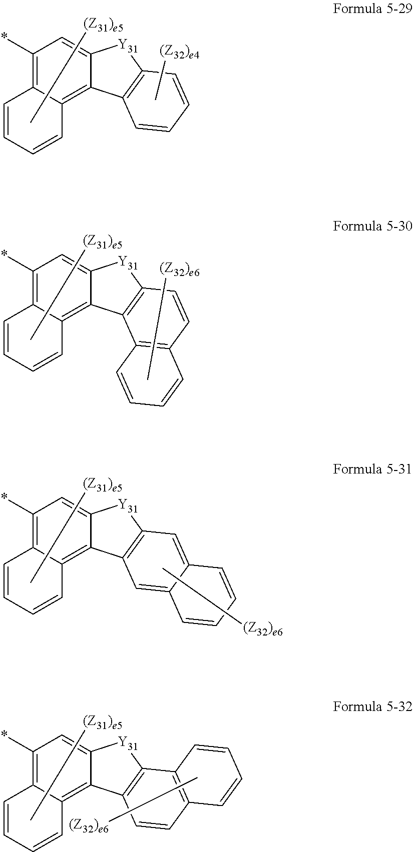

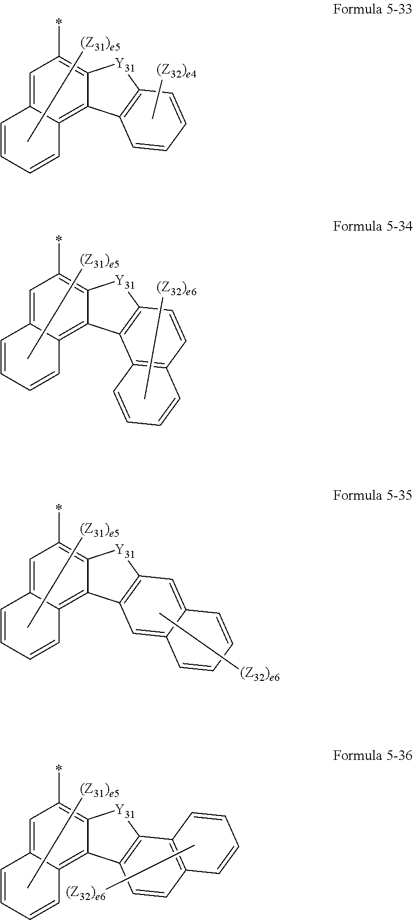

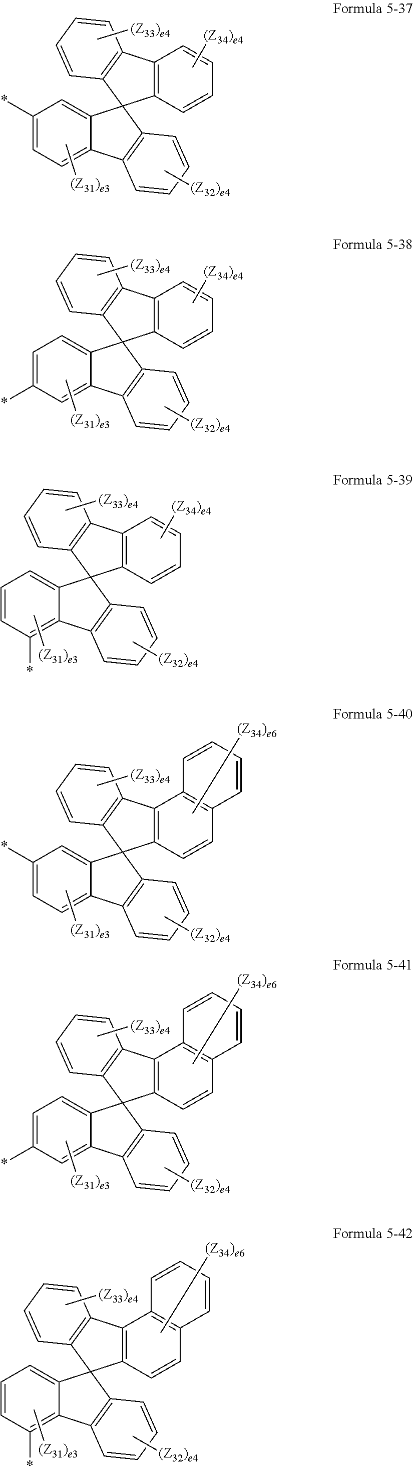

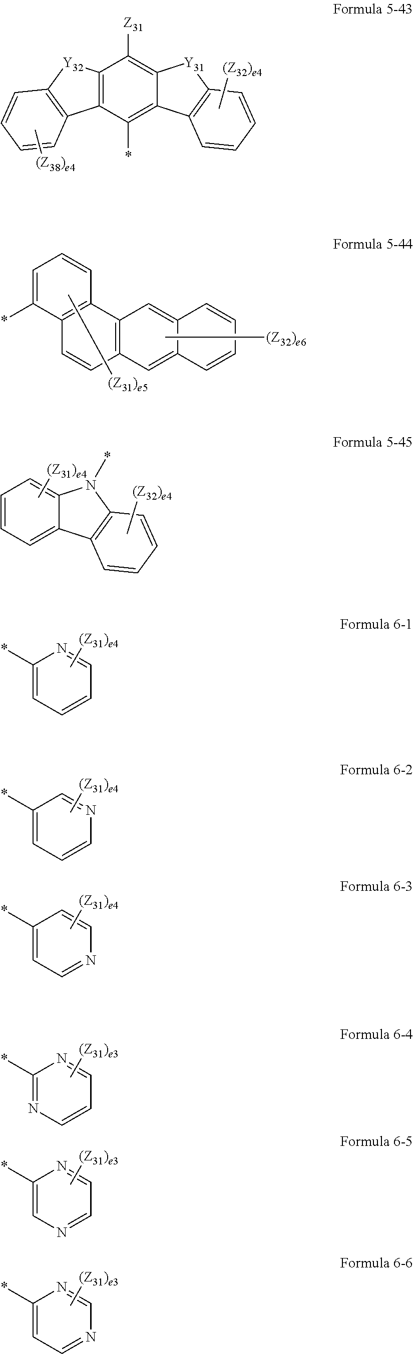

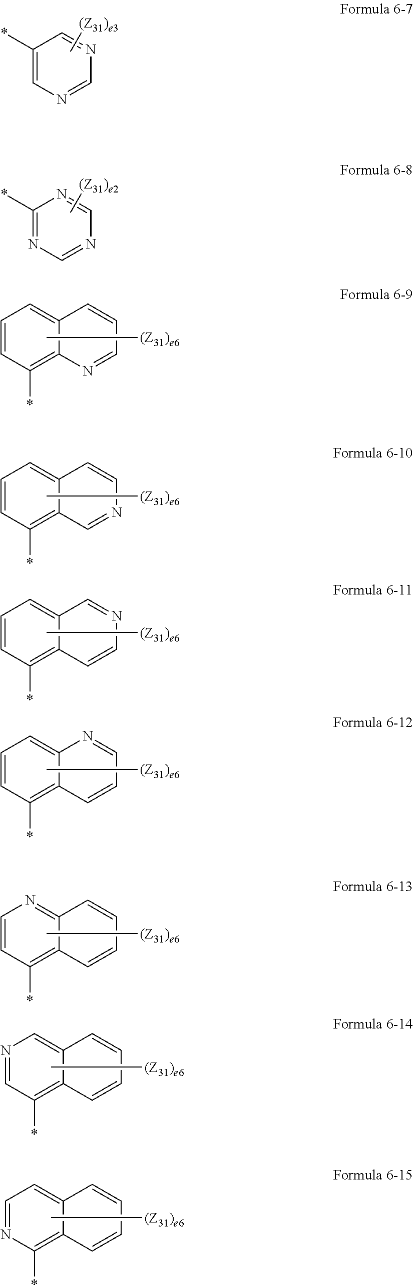

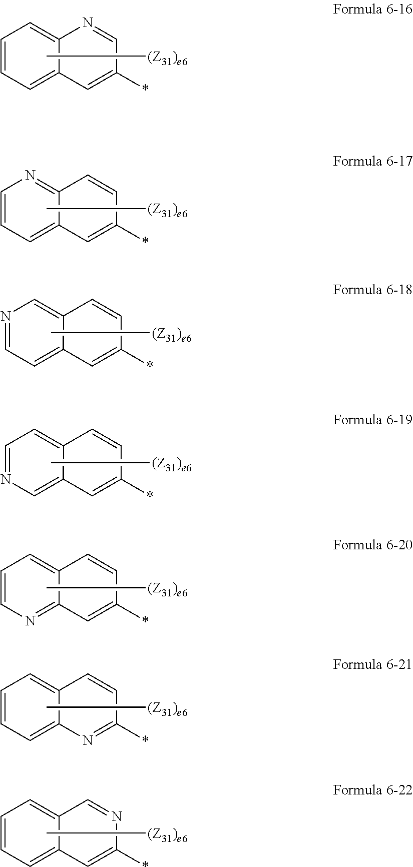

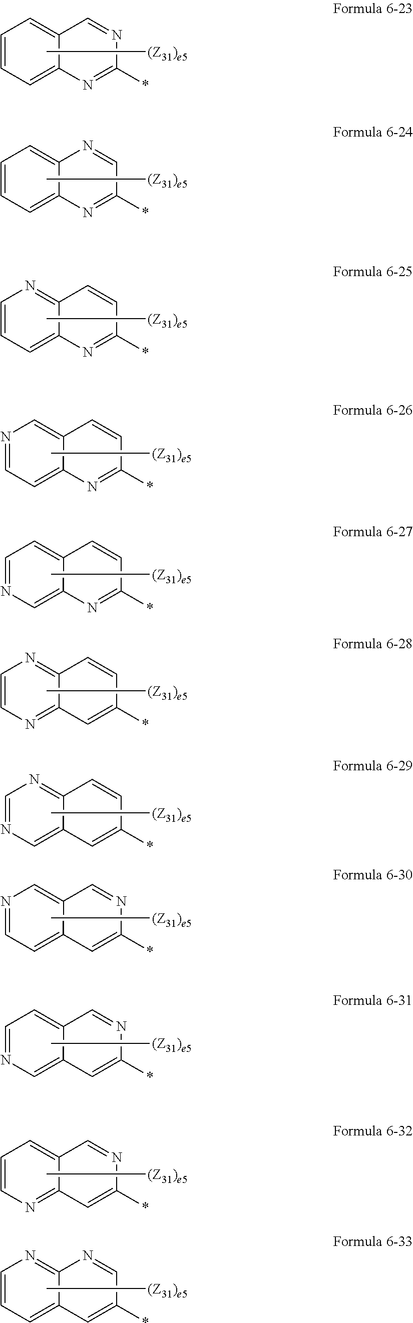

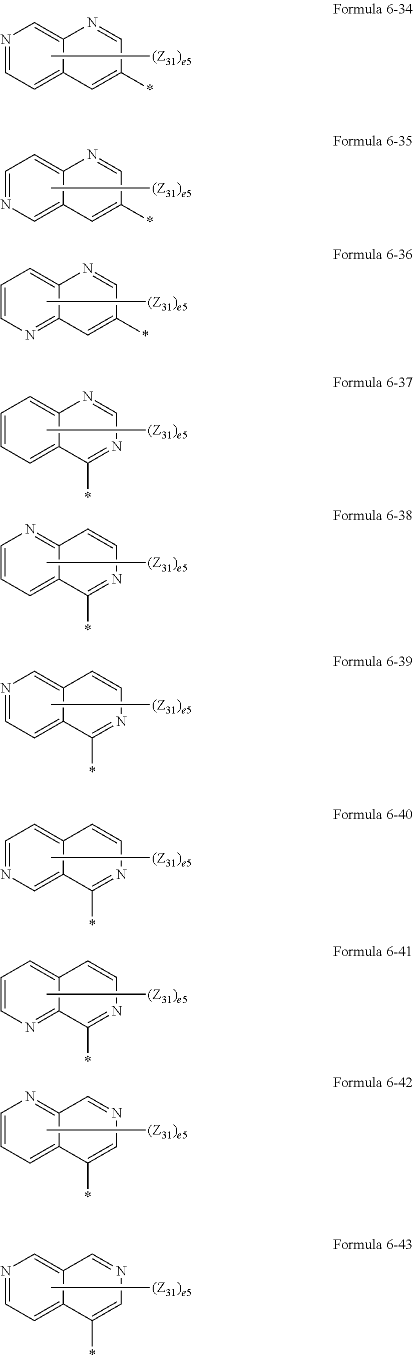

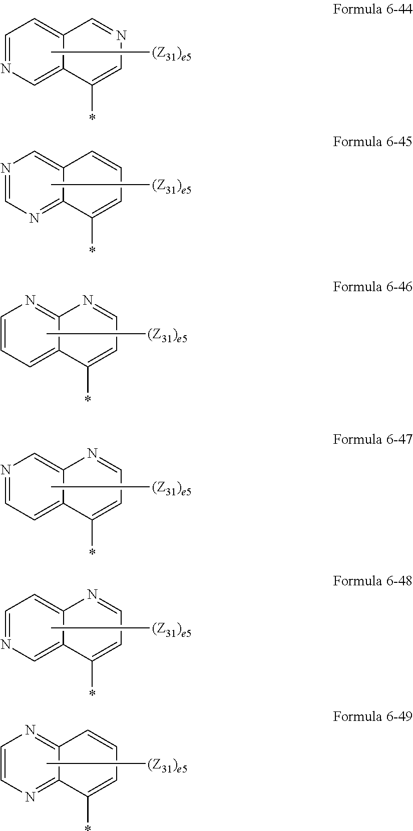

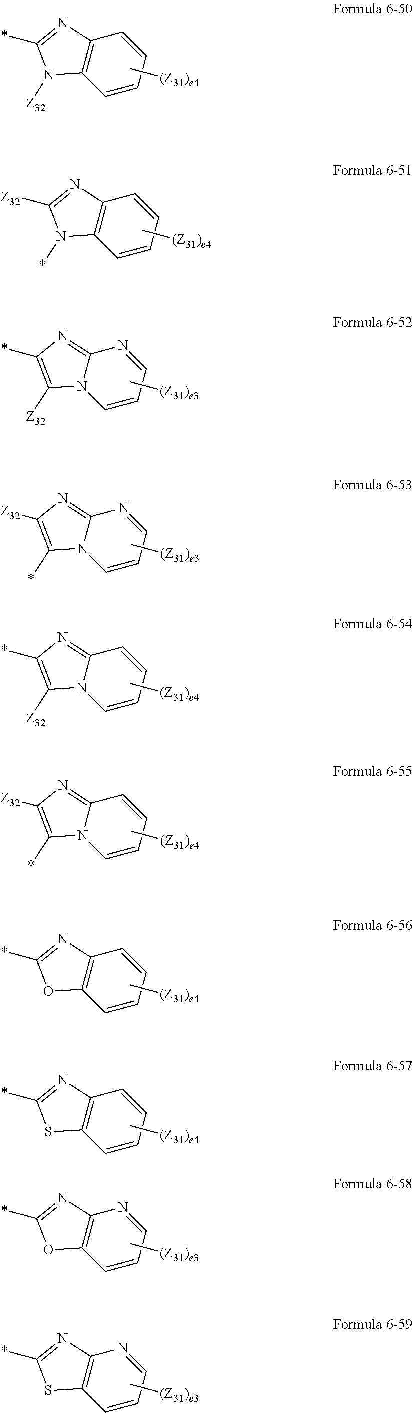

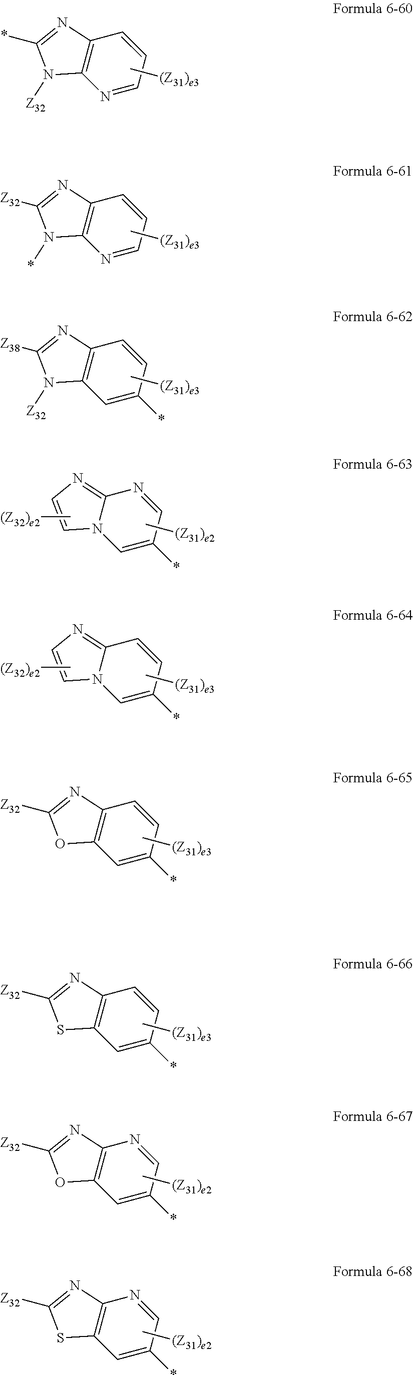

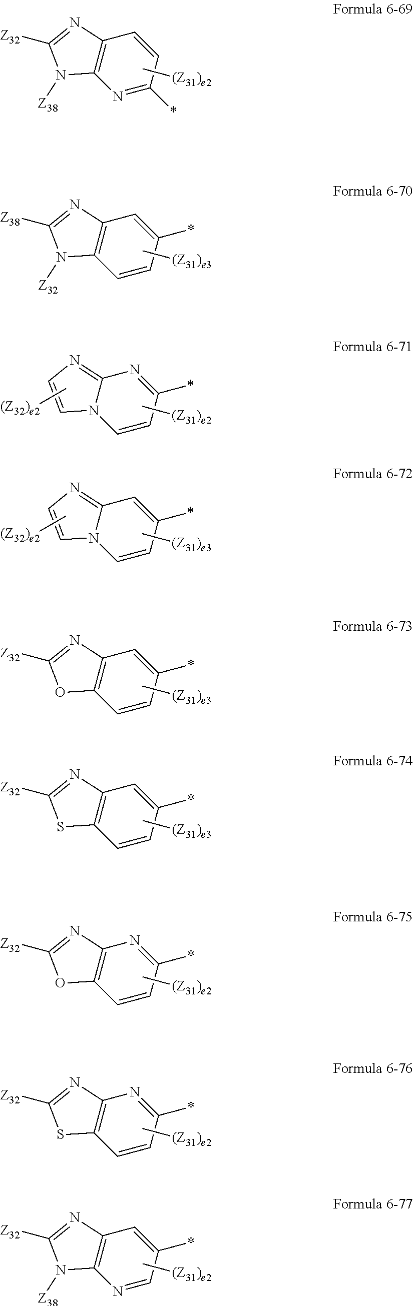

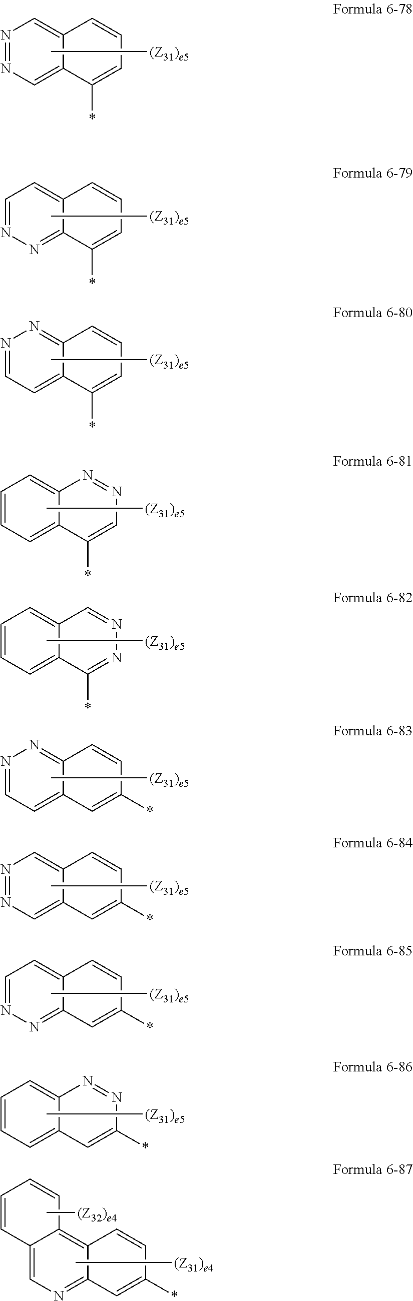

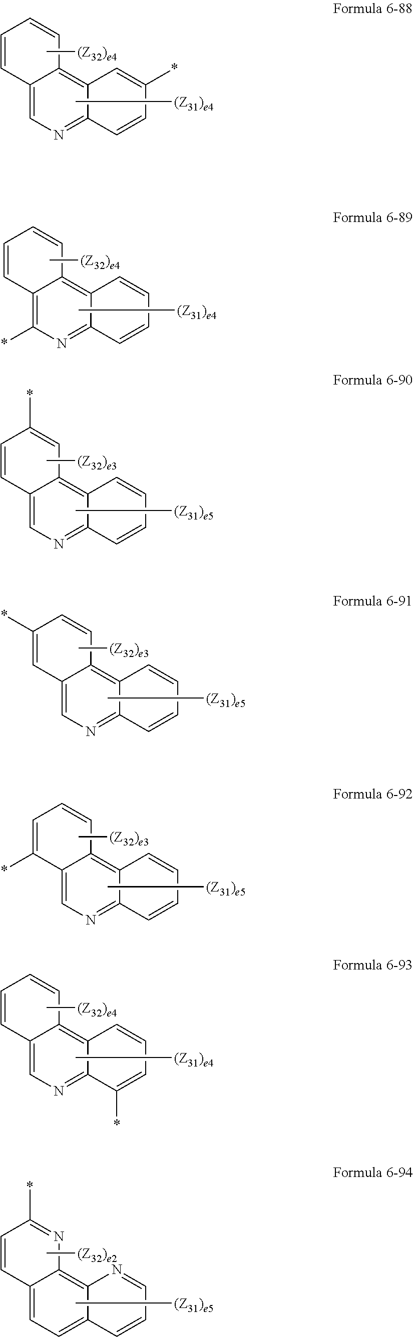

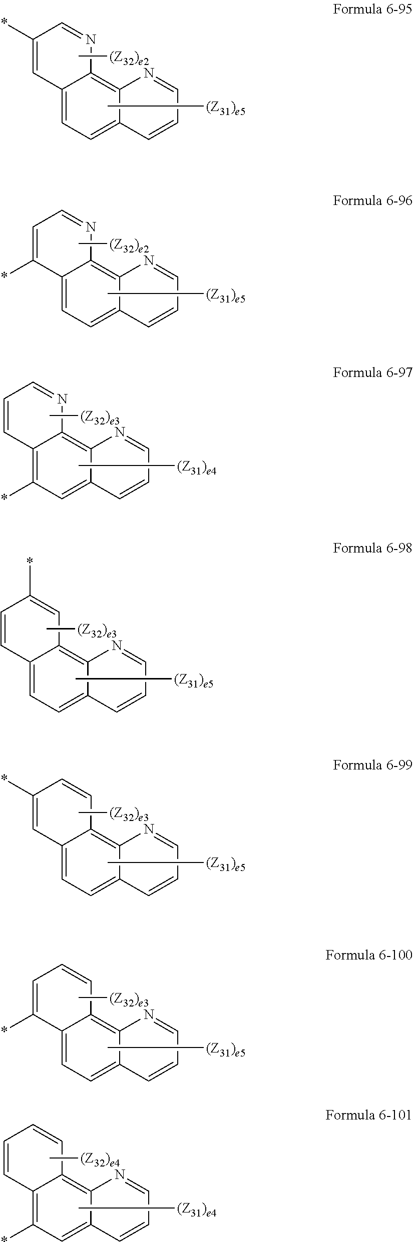

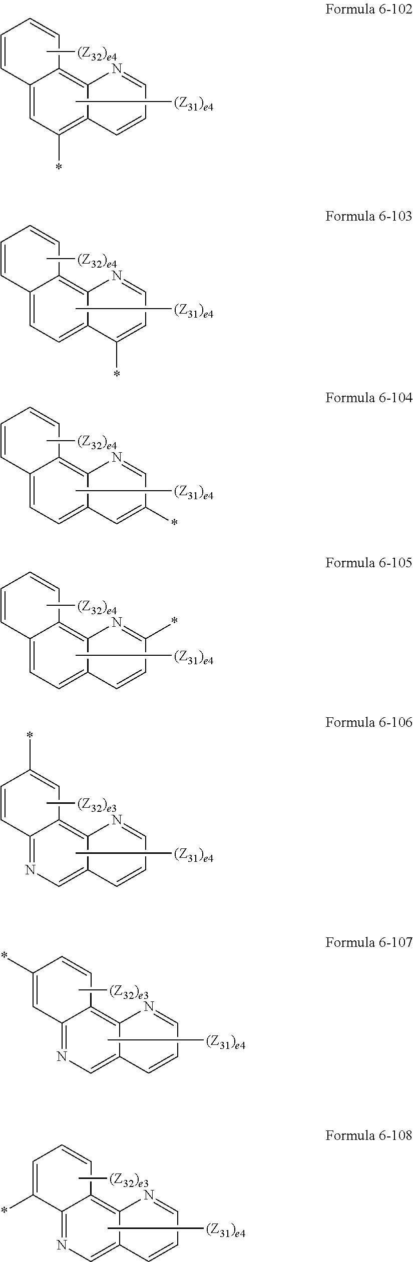

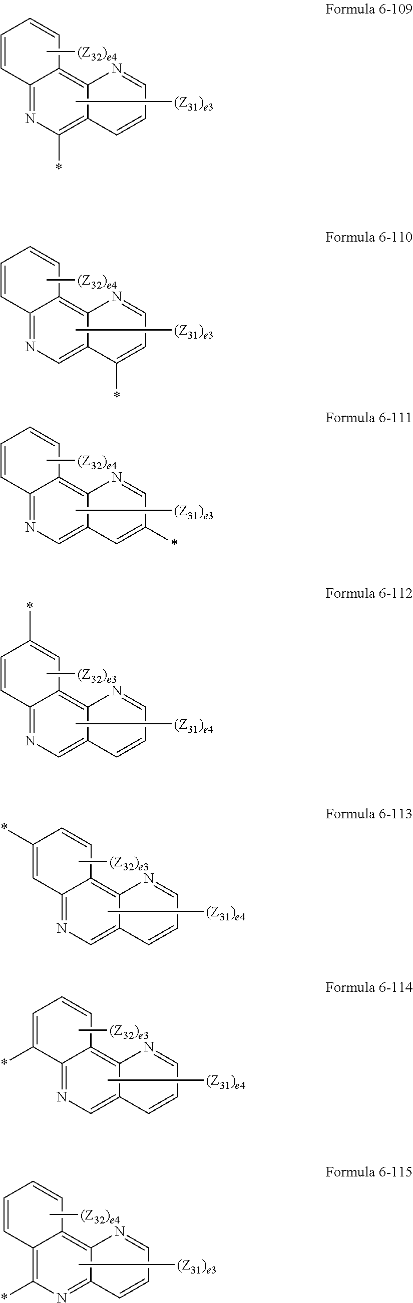

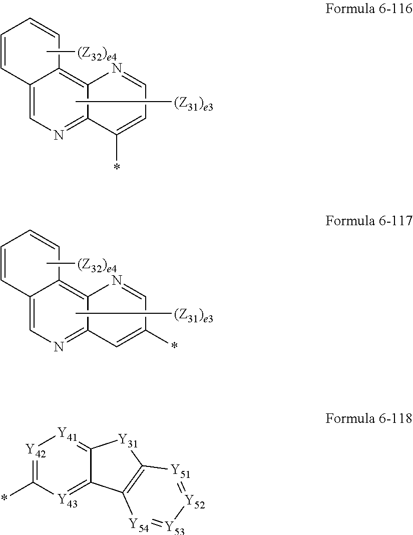

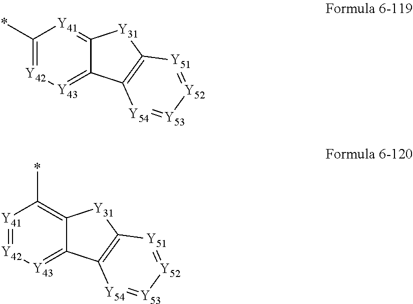

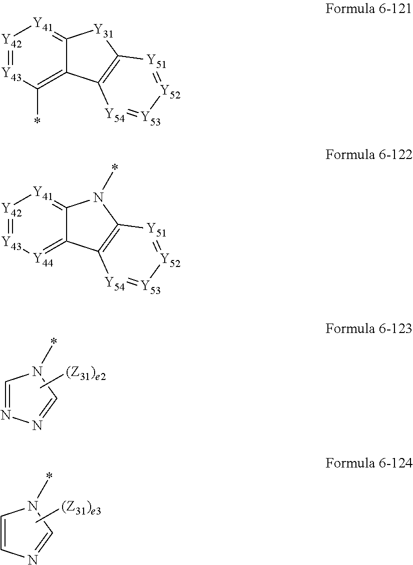

In Formulae 5-1 to 5-45 and 6-1 to 6-124,

Y₃₁ and Y₃₂ may each independently be O, S, C(Z₃₃)(Z₃₄), N(Z₃₅), or Si(Z₃₆)(Z₃₇),

Y₄₁ may be N or C(Z₄₁), Y₄₂ may be N or C(Z₄₂), Y₄₃ may be N or C(Z₄₃), Y₄₄ may be N or C(Z₄₄), Y₅₁ may be N or C(Z₅₁), Y₅₂ may be N or C(Z₅₂), Y₅₃ may be N or C(Z₅₃), Y₅₄ may be N or C(Z₅₄), at least one selected from Y₄₁ to Y₄₃ and Y₅₁ to Y₅₄ in Formulae 6-118 to 6-121 may be N, and at least one selected from Y₄₁ to Y₄₄ and Y₅₁ to Y₅₄ in Formula 6-122 may be N,

Z₃₁ to Z₃₇, Z₄₁ to Z₄₄, and Z₅₁ to Z₅₄ may each independently be selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzoimidazolyl group, a benzofuranyl group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a carbazolyl group, a benzocarbazolyl group, a dibenzocarbazolyl group, a thiadiazolyl group, an imidazopyridinyl group, an imidazopyrimidinyl group, a benzonaphthyridinyl group, an azafluorenyl group, an azaspiro-bifluorenyl group, an azacarbazolyl group, an azadibenzofuranyl group, an azadibenzothiophenyl group, an azadibenzosilolyl group, and —Si(Q₃₁)(Q₃₂)(Q₃₃),

wherein Q₁ to Q₃ and Q₃₁ to Q₃₃ may each independently be selected from the group consisting of:

a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and

a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group,

e3 may be an integer selected from 0 to 3,

e2 may be an integer selected from 0 to 2,

e4 may be an integer selected from 0 to 4,

e5 may be an integer selected from 0 to 5,

e6 may be an integer selected from 0 to 6,

e7 may be an integer selected from 0 to 7,

e9 may be an integer selected from 0 to 9, and

* indicates a binding site to a neighboring atom.

In various embodiments, Ar₁ to Arₐ in Formula 1 may each independently be selected from —Si(Q₁)(Q₂)(Q₃) and a group represented by any of Formulae 9-1 to 9-100 and 10-1 to 10-121, but embodiments of the present disclosure are not limited thereto:

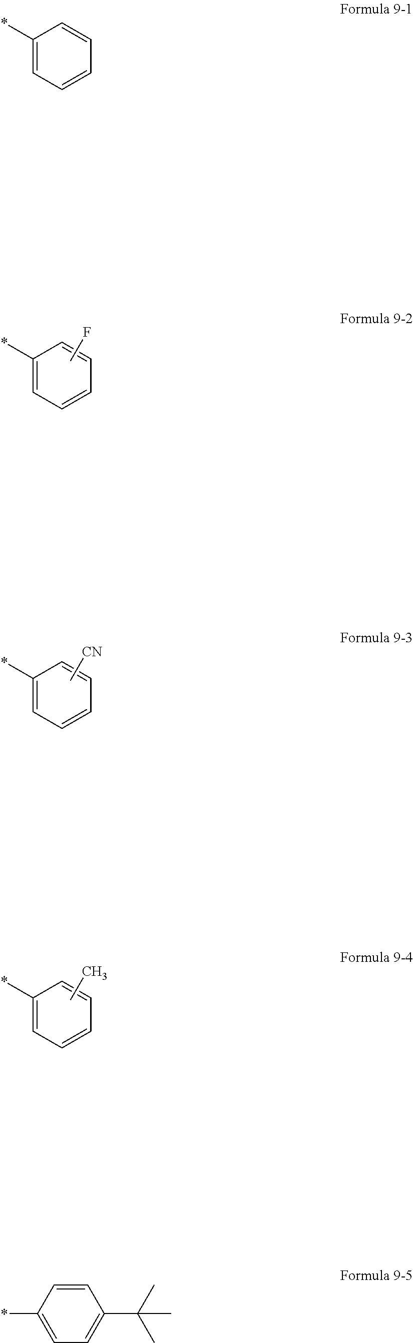

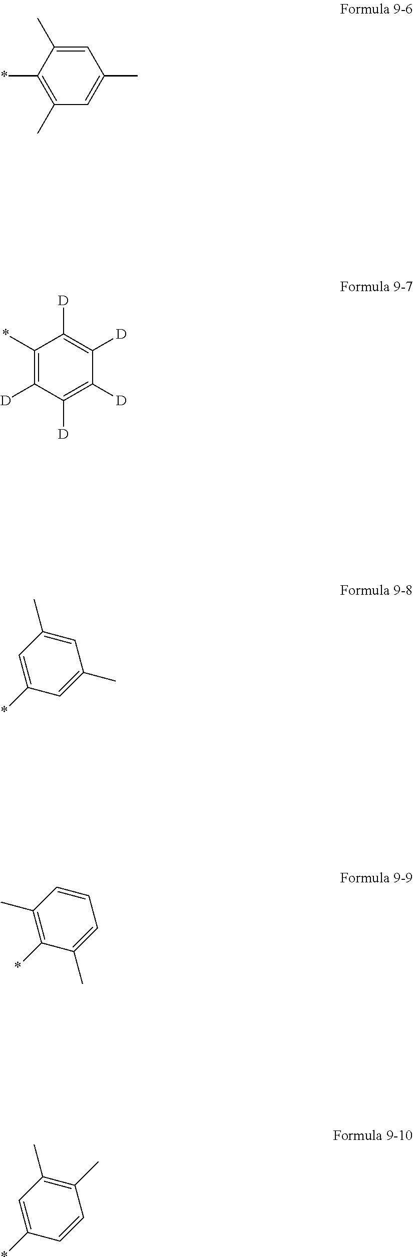

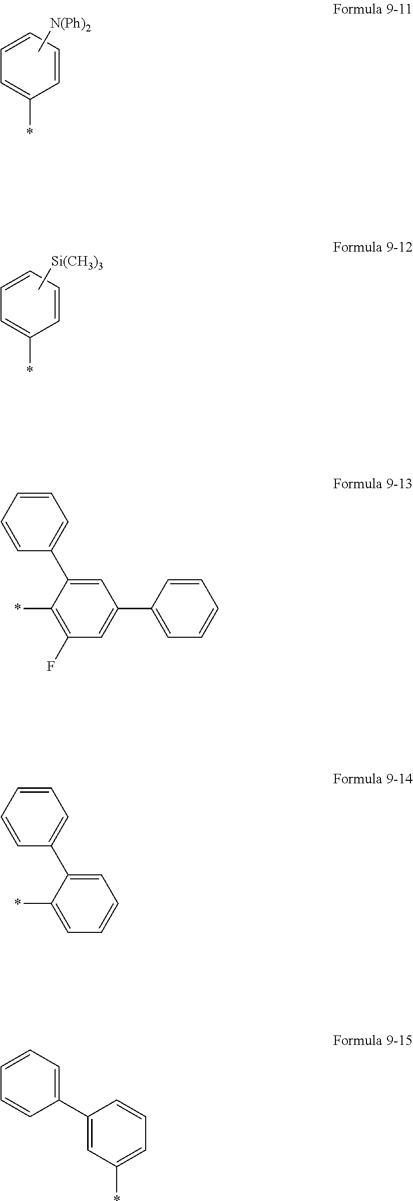

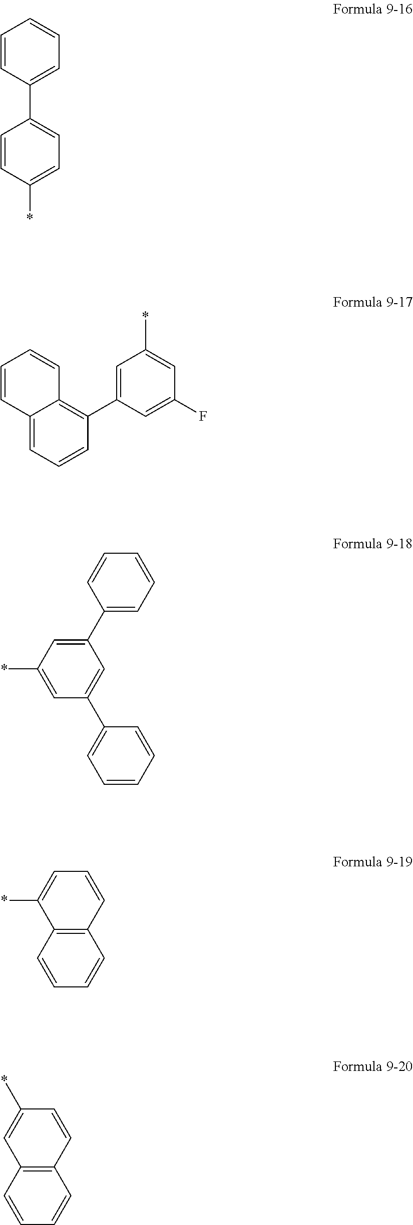 [SMILES: *c1ccc(-c2ccccc2)cc1 ; *c1cc(F)cc(-c2cccc3ccccc23)c1 ; *c1cc(-c2ccccc2)cc(-c2ccccc2)c1 ; *c1cccc2ccccc12 ; *c1ccc2ccccc2c1]

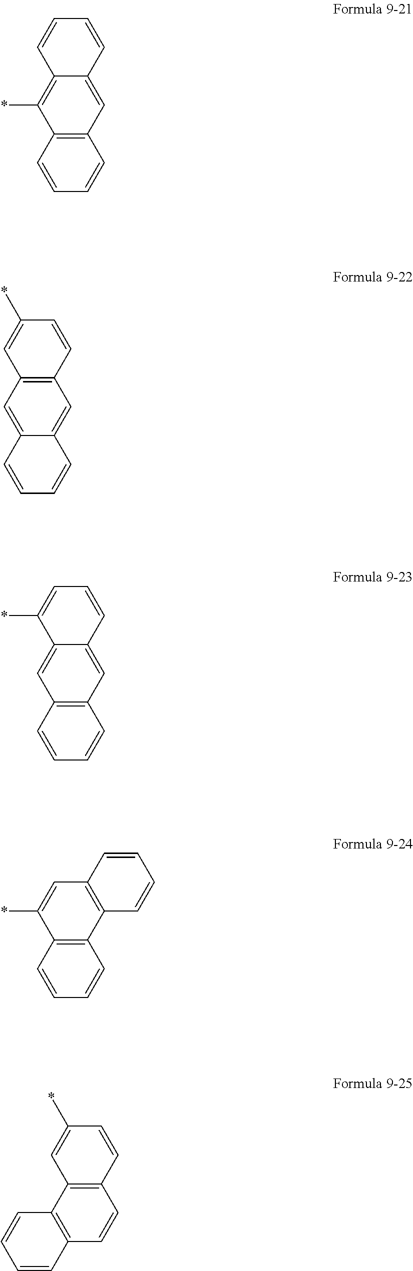 [SMILES: *c1c2ccccc2cc2ccccc12 ; *c1ccc2cc3ccccc3cc2c1 ; *c1cccc2cc3ccccc3cc12 ; *c1cc2ccccc2c2ccccc12 ; *c1ccc2ccc3ccccc3c2c1]

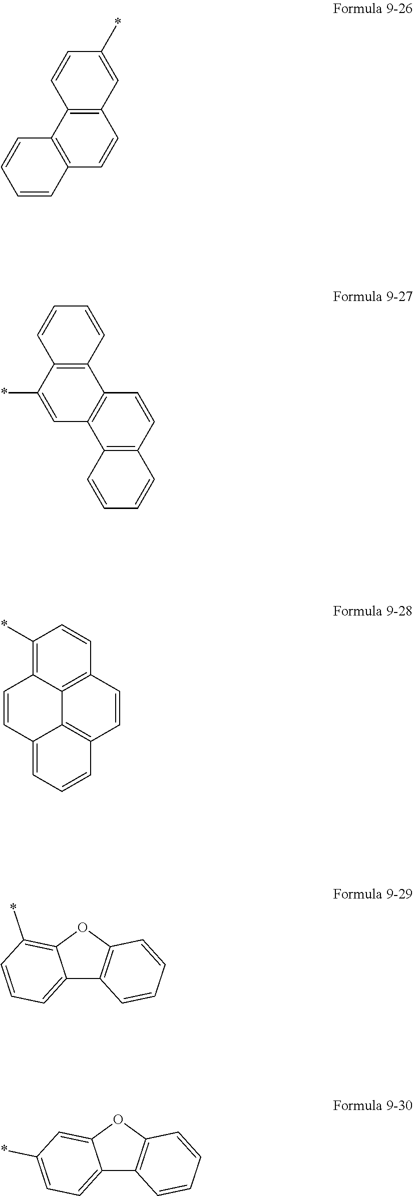 [SMILES: *c1ccc2c(ccc3ccccc32)c1 ; *c1cc2c3ccccc3ccc2c2ccccc12 ; *c1ccc2ccc3cccc4ccc1c2c34 ; *c1cccc2c1oc1ccccc12 ; *c1ccc2c(c1)oc1ccccc12]

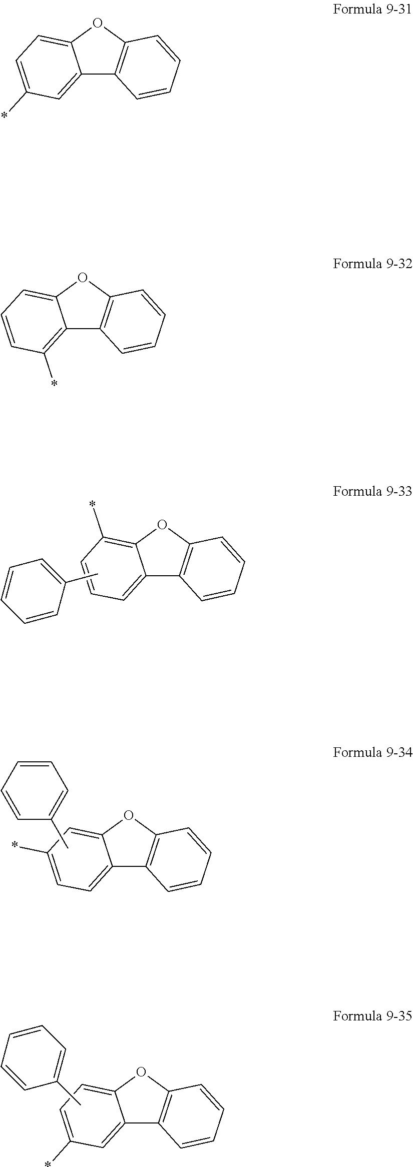

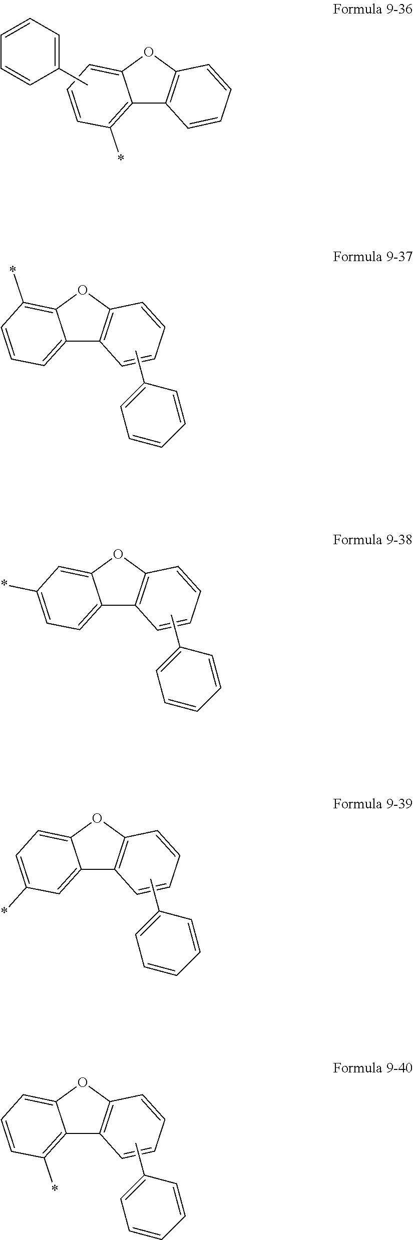

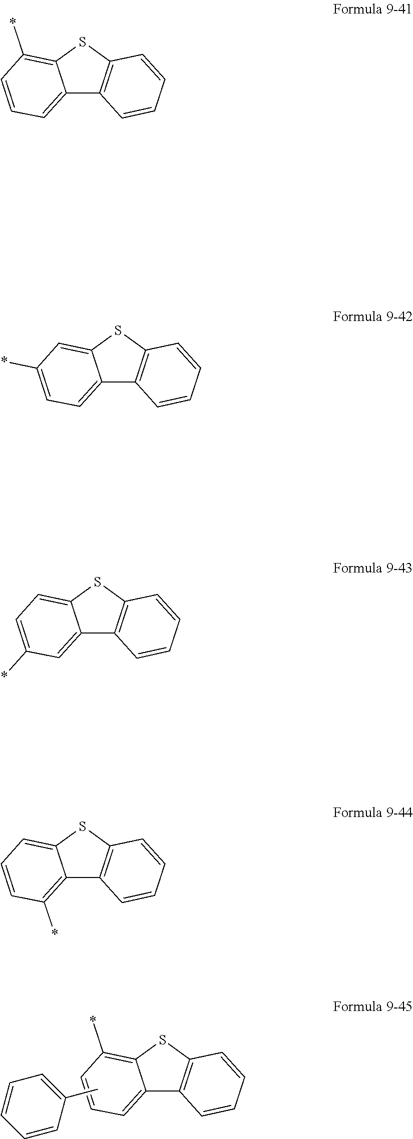

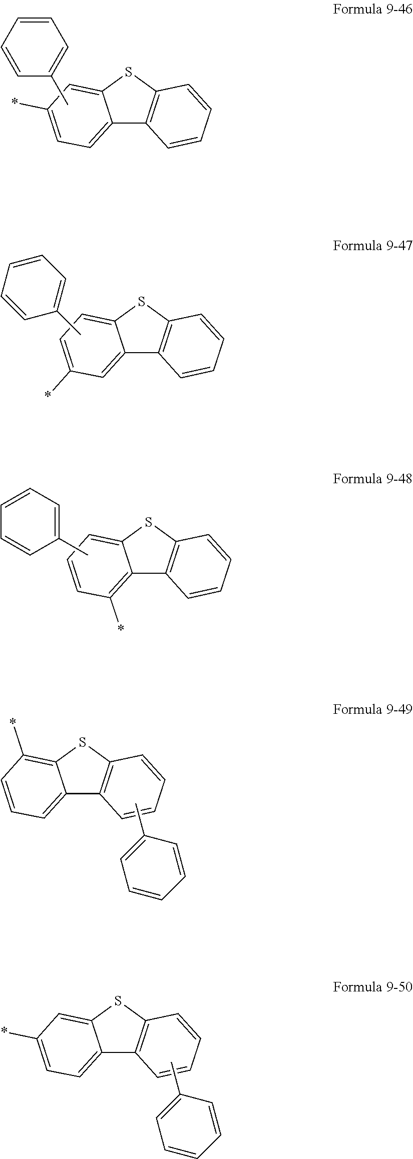

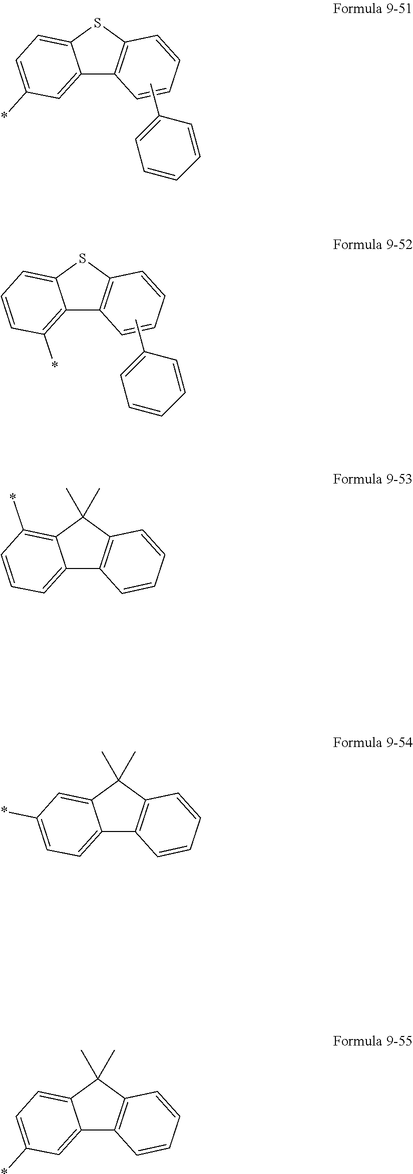

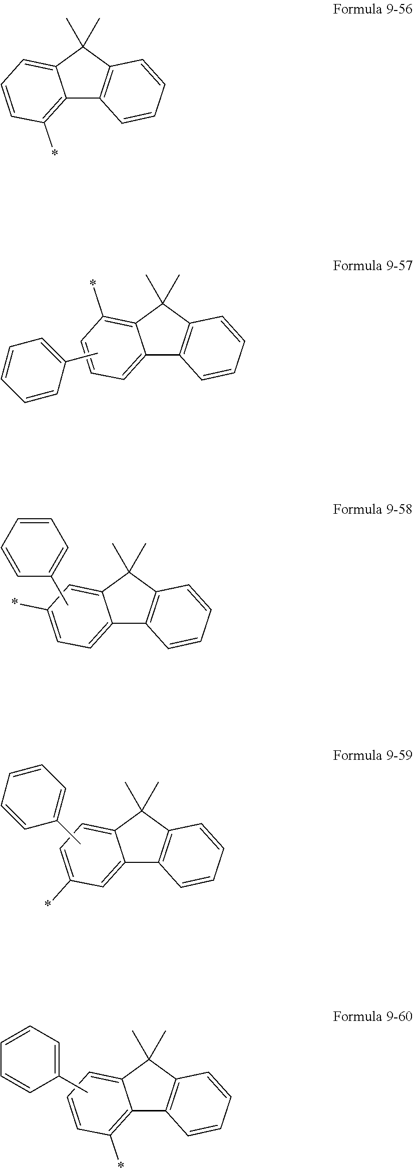

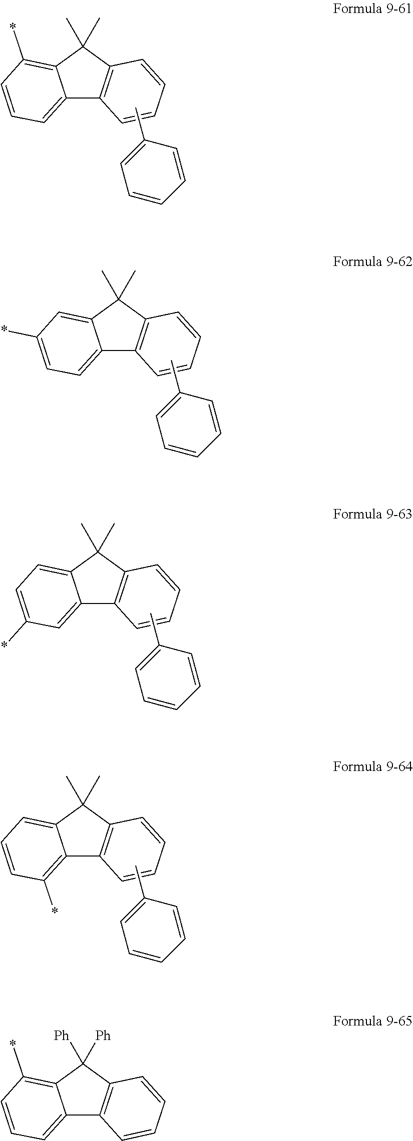

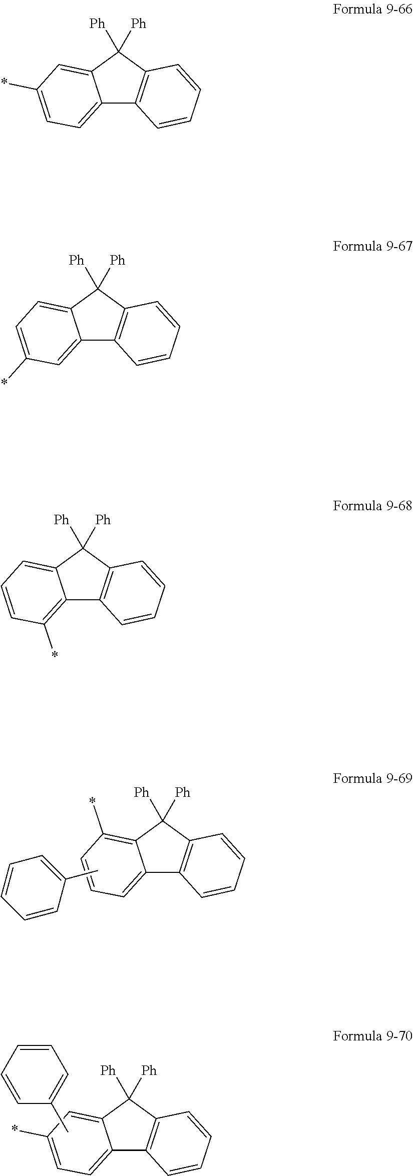

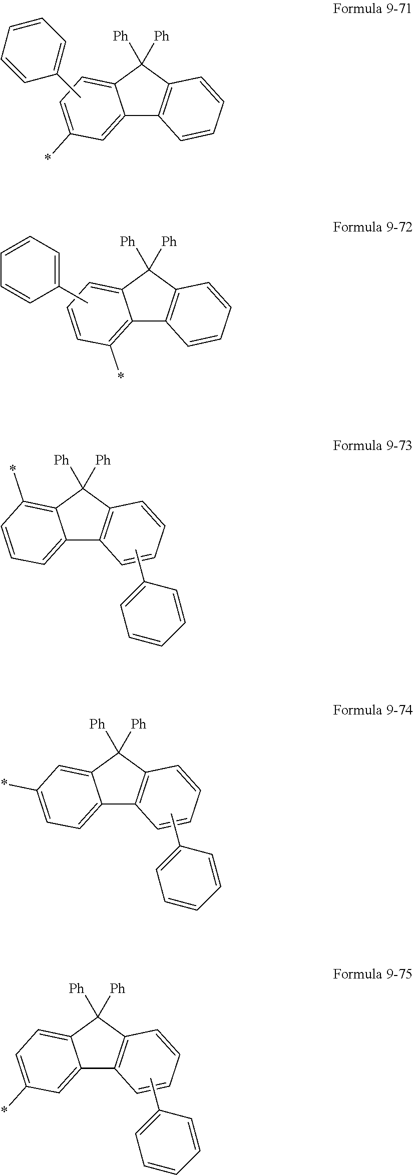

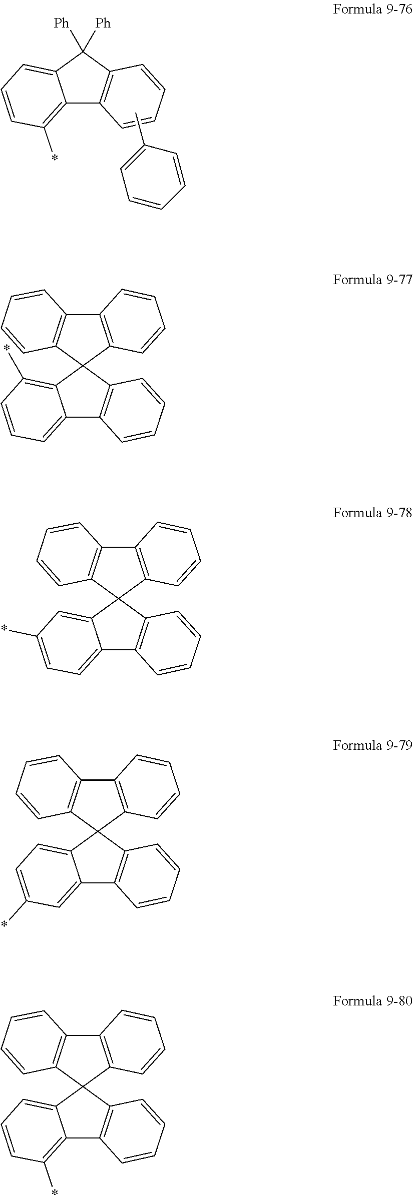

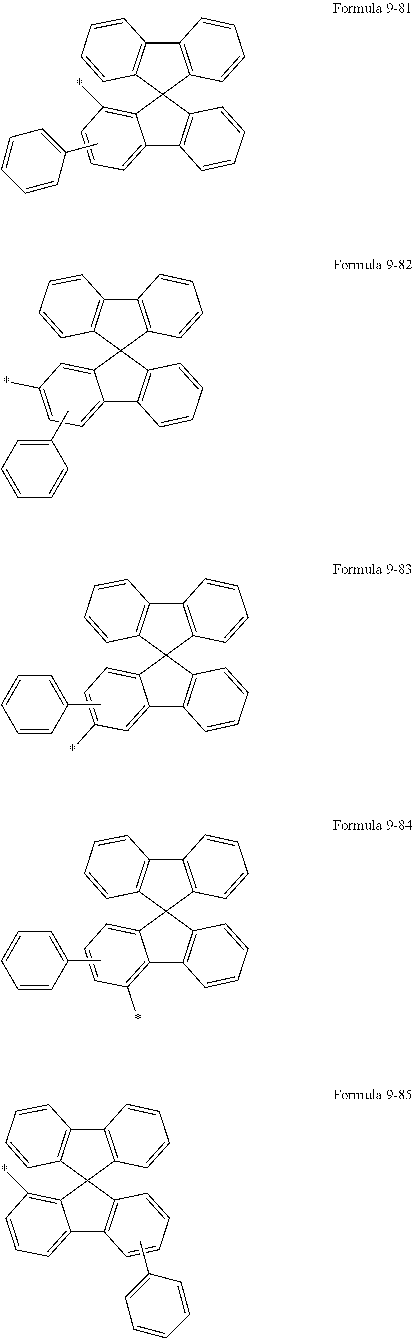

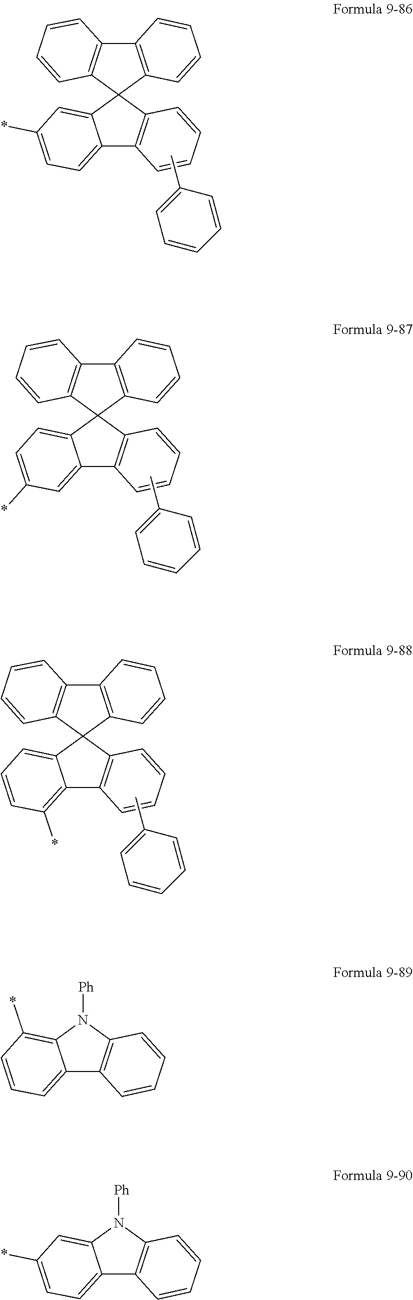

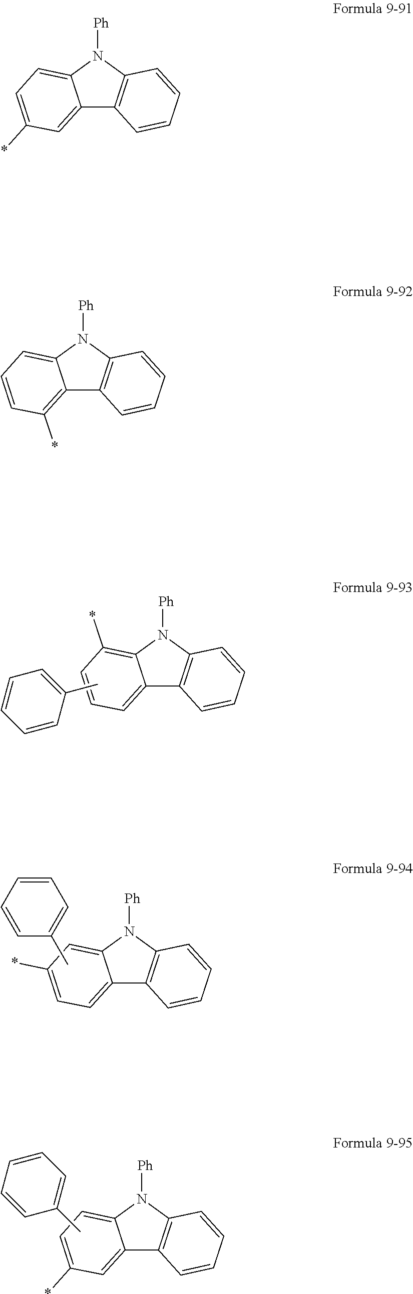

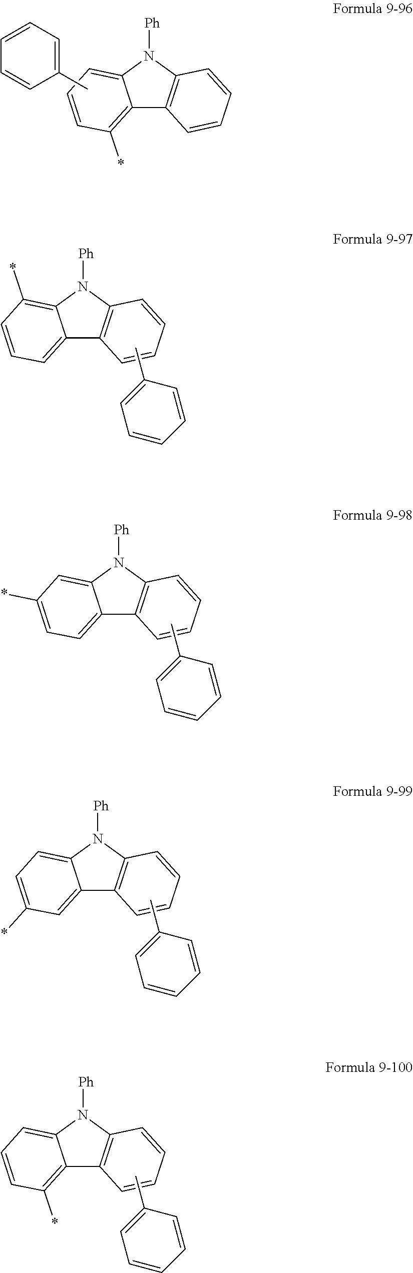

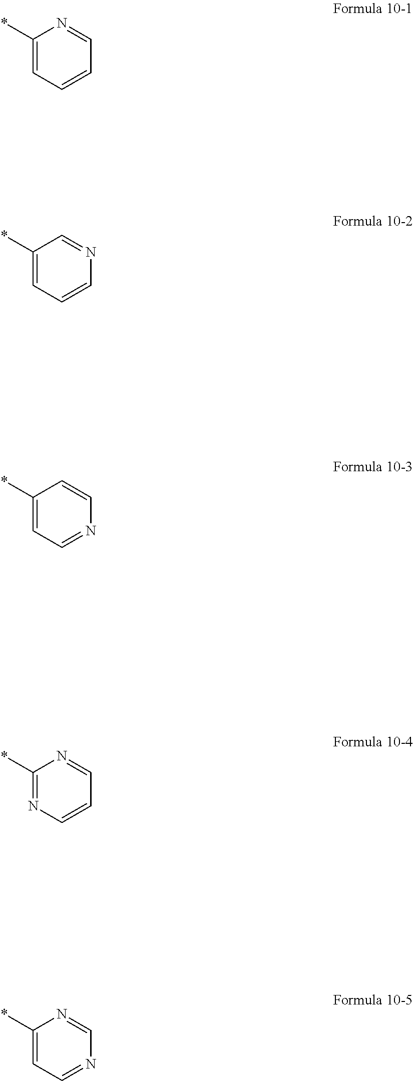 [SMILES: *c1ccccn1 ; *c1cccnc1 ; *c1ccncc1 ; *c1ncccn1 ; *c1ccncn1]

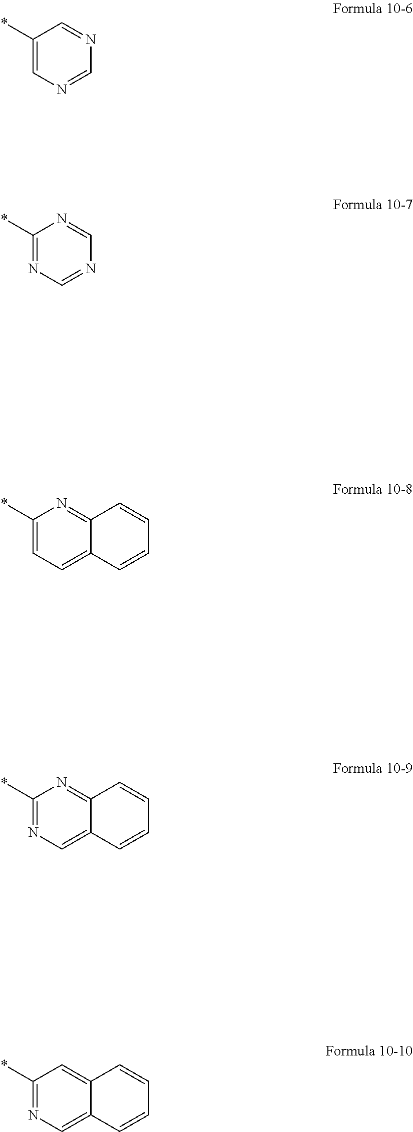 [SMILES: *c1cncnc1 ; *c1ncncn1 ; *c1ccc2ccccc2n1 ; *c1ncc2ccccc2n1 ; *c1cc2ccccc2cn1]

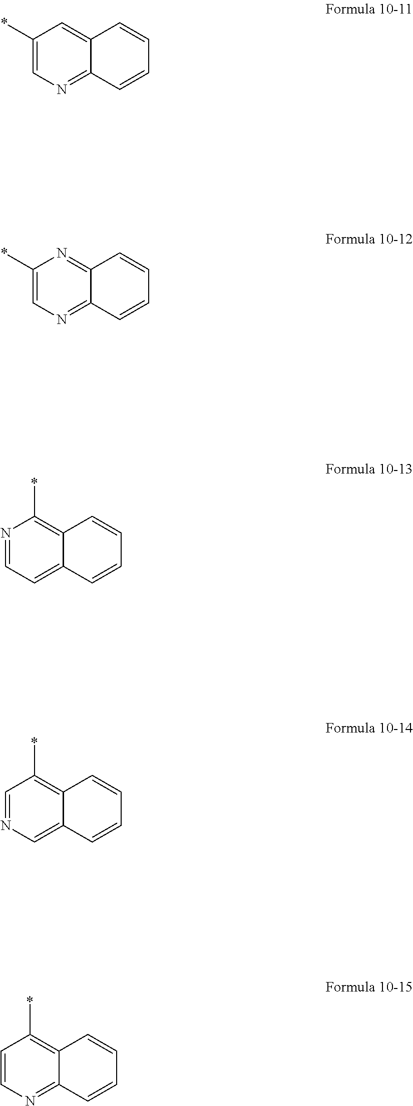 [SMILES: *c1cnc2ccccc2c1 ; *c1cnc2ccccc2n1 ; *c1nccc2ccccc12 ; *c1cncc2ccccc12 ; *c1ccnc2ccccc12]

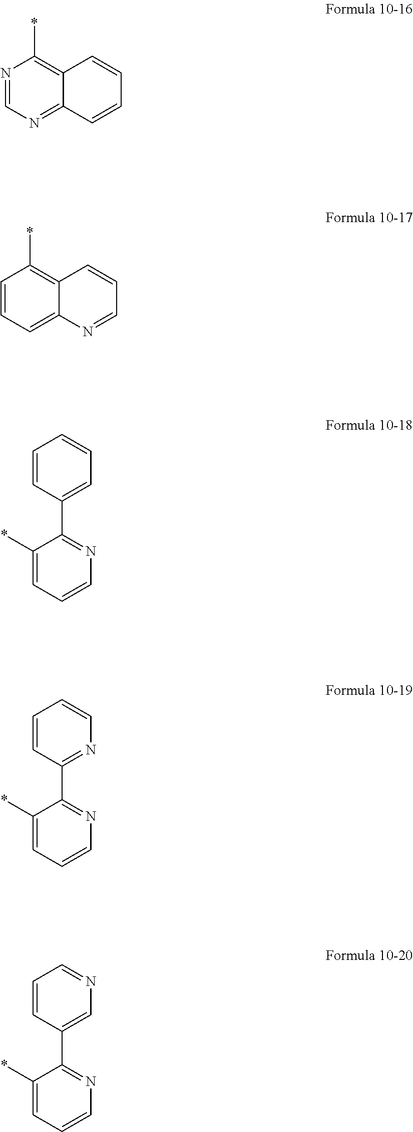 [SMILES: *c1ncnc2ccccc12 ; *c1cccc2ncccc12 ; *c1cccnc1-c1ccccc1 ; *c1cccnc1-c1ccccn1 ; *c1cccnc1-c1cccnc1]

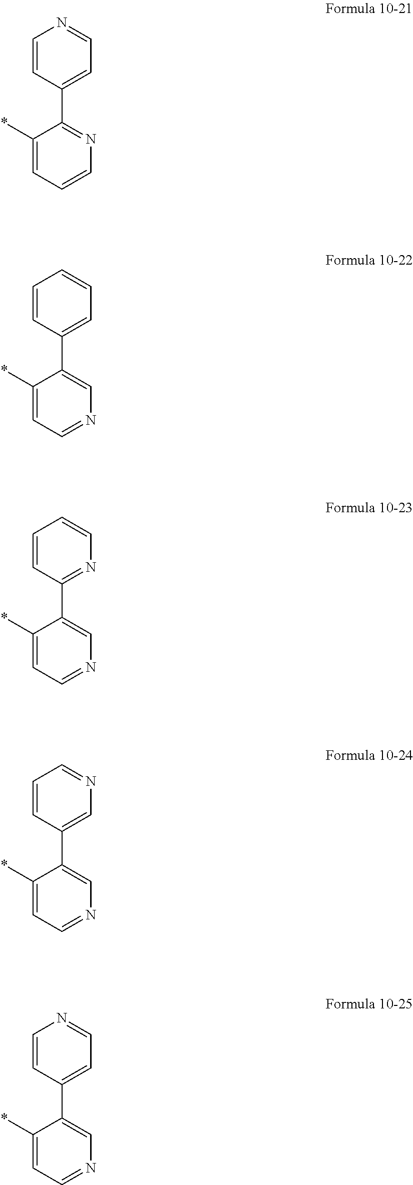 [SMILES: *c1cccnc1-c1ccncc1 ; *c1ccncc1-c1ccccc1 ; *c1ccncc1-c1ccccn1 ; *c1ccncc1-c1cccnc1 ; *c1ccncc1-c1ccncc1]

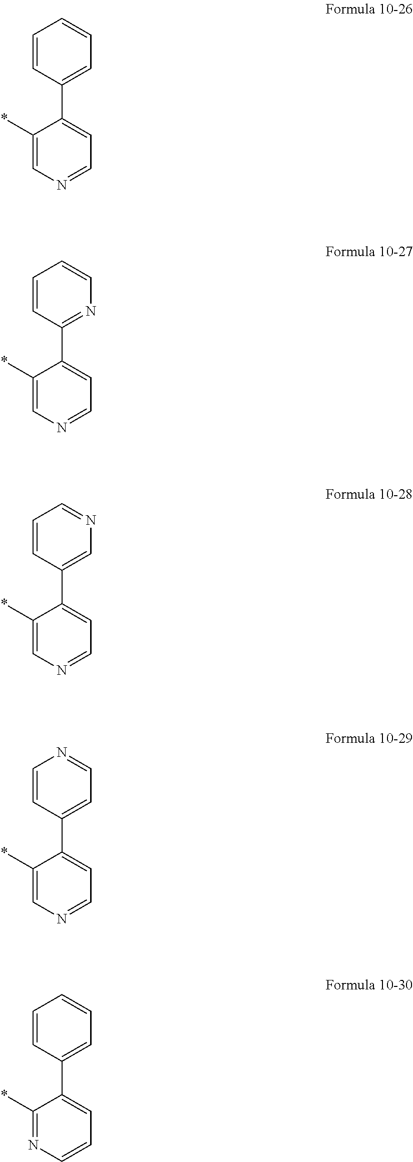 [SMILES: *c1cnccc1-c1ccccc1 ; *c1cnccc1-c1ccccn1 ; *c1cnccc1-c1cccnc1 ; *c1cnccc1-c1ccncc1 ; *c1ncccc1-c1ccccc1]

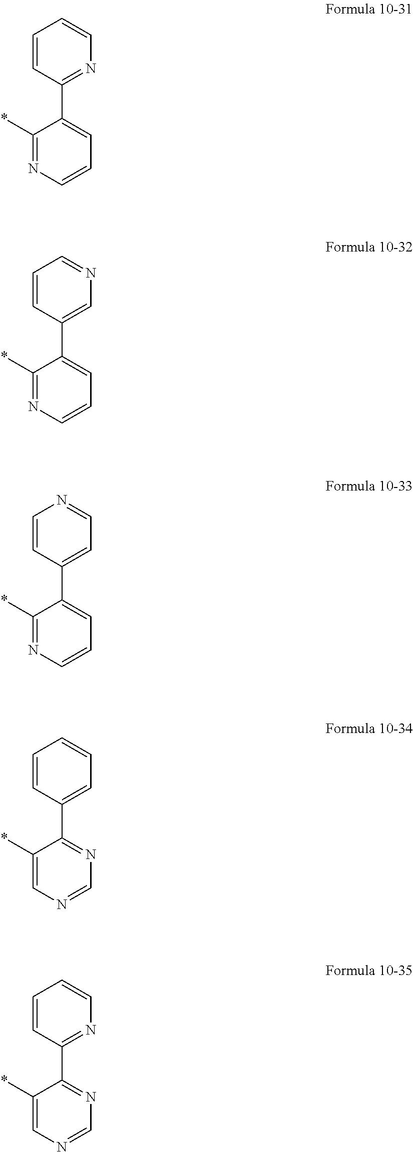 [SMILES: *c1ncccc1-c1ccccn1 ; *c1ncccc1-c1cccnc1 ; *c1ncccc1-c1ccncc1 ; *c1cncnc1-c1ccccc1 ; *c1cncnc1-c1ccccn1]

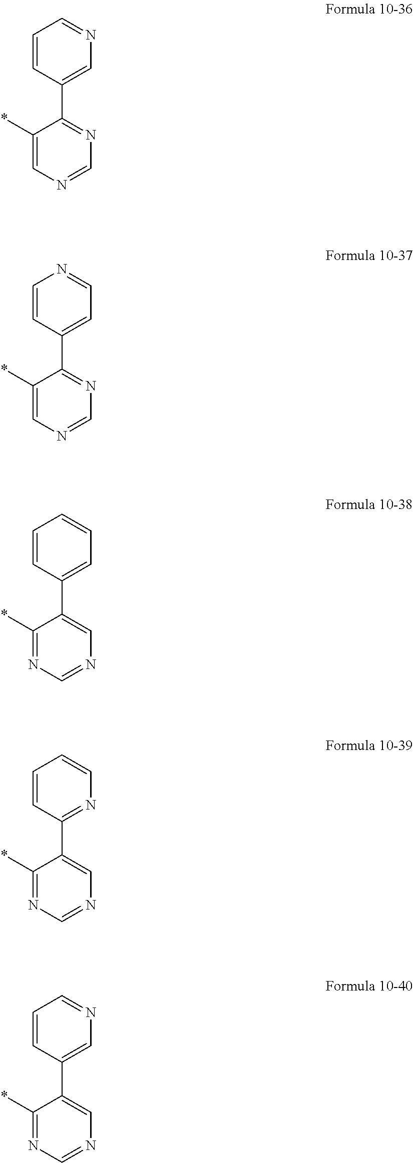 [SMILES: *c1cncnc1-c1cccnc1 ; *c1cncnc1-c1ccncc1 ; *c1ncncc1-c1ccccc1 ; *c1ncncc1-c1ccccn1 ; *c1ncncc1-c1cccnc1]

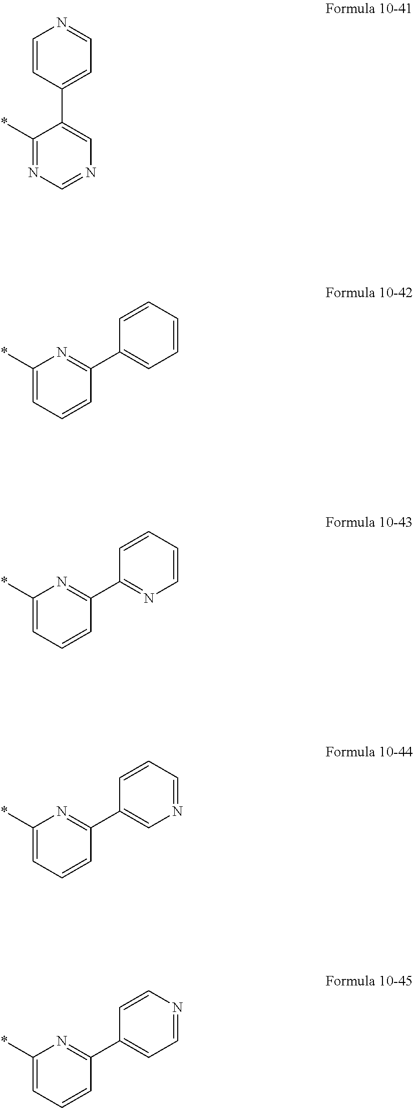 [SMILES: *c1ncncc1-c1ccncc1 ; *c1cccc(-c2ccccc2)n1 ; *c1cccc(-c2ccccn2)n1 ; *c1cccc(-c2cccnc2)n1 ; *c1cccc(-c2ccncc2)n1]

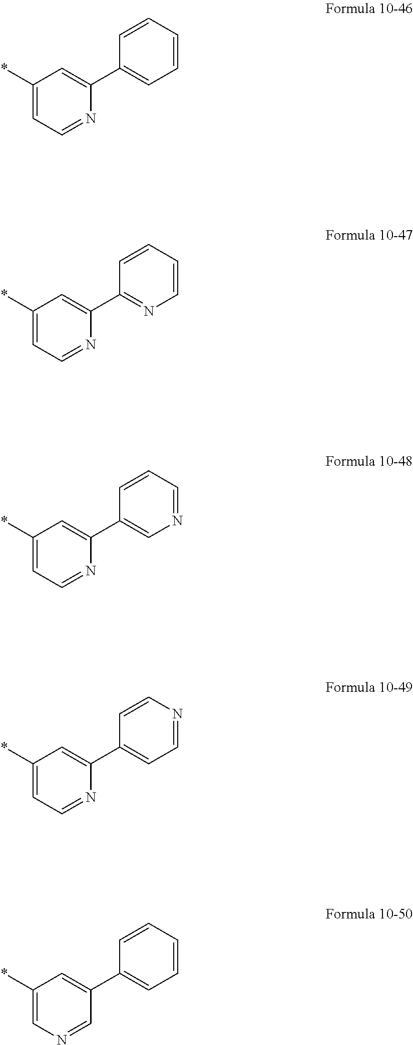 [SMILES: *c1ccnc(-c2ccccc2)c1 ; *c1ccnc(-c2ccccn2)c1 ; *c1ccnc(-c2cccnc2)c1 ; *c1ccnc(-c2ccncc2)c1 ; *c1cncc(-c2ccccc2)c1]

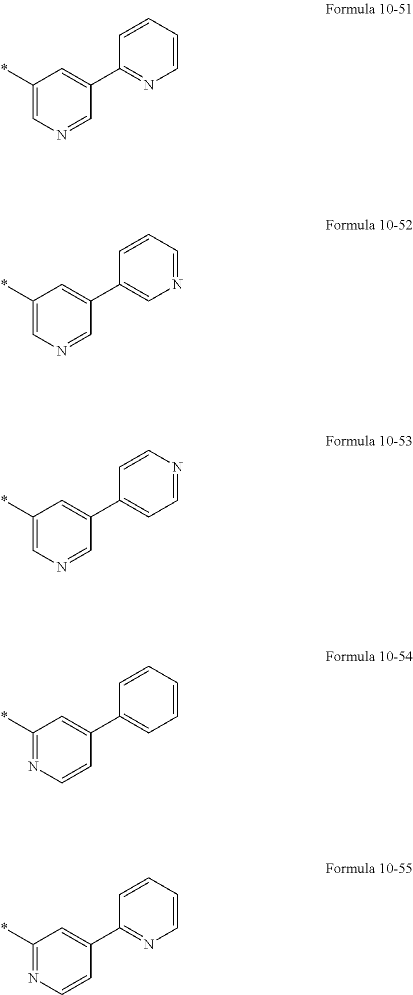 [SMILES: *c1cncc(-c2ccccn2)c1 ; *c1cncc(-c2cccnc2)c1 ; *c1cncc(-c2ccncc2)c1 ; *c1cc(-c2ccccc2)ccn1 ; *c1cc(-c2ccccn2)ccn1]

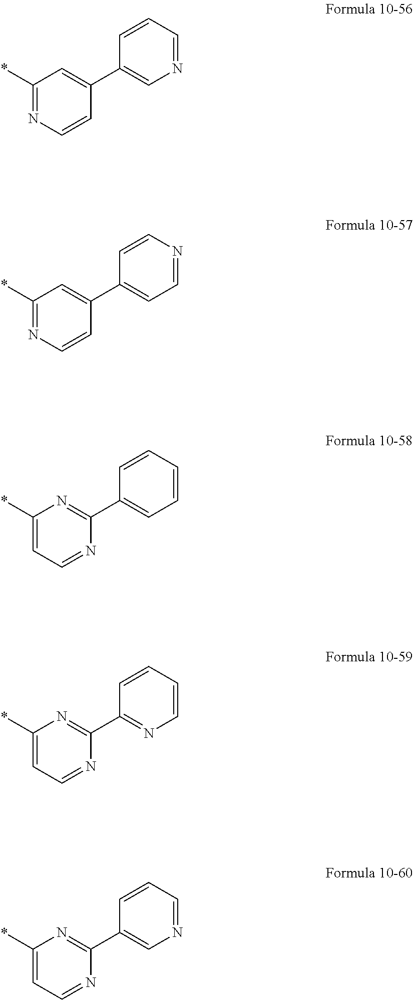 [SMILES: *c1cc(-c2cccnc2)ccn1 ; *c1cc(-c2ccncc2)ccn1 ; *c1ccnc(-c2ccccc2)n1 ; *c1ccnc(-c2ccccn2)n1 ; *c1ccnc(-c2cccnc2)n1]

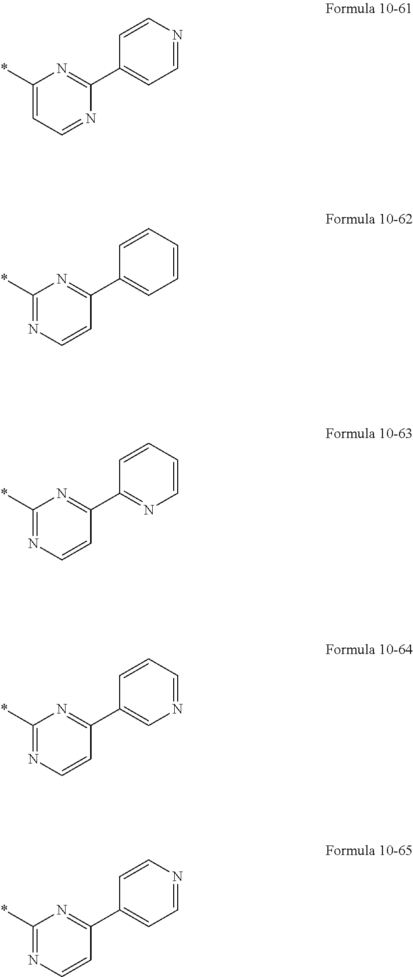 [SMILES: *c1ccnc(-c2ccncc2)n1 ; *c1nccc(-c2ccccc2)n1 ; *c1nccc(-c2ccccn2)n1 ; *c1nccc(-c2cccnc2)n1 ; *c1nccc(-c2ccncc2)n1]

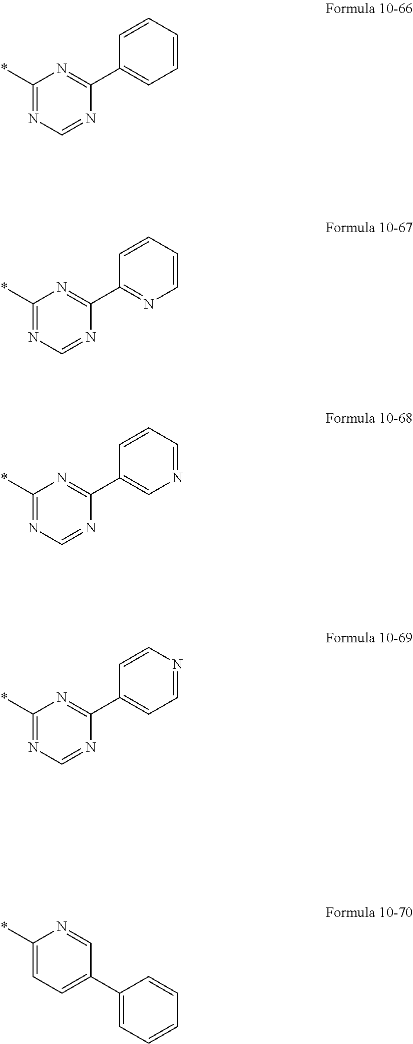 [SMILES: *c1ncnc(-c2ccccc2)n1 ; *c1ncnc(-c2ccccn2)n1 ; *c1ncnc(-c2cccnc2)n1 ; *c1ncnc(-c2ccncc2)n1 ; *c1ccc(-c2ccccc2)cn1]

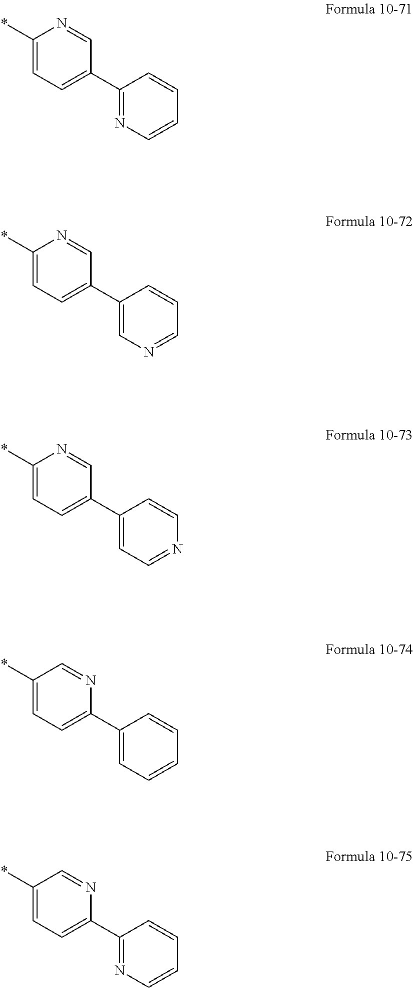 [SMILES: *c1ccc(-c2ccccn2)cn1 ; *c1ccc(-c2cccnc2)cn1 ; *c1ccc(-c2ccncc2)cn1 ; *c1ccc(-c2ccccc2)nc1 ; *c1ccc(-c2ccccn2)nc1]

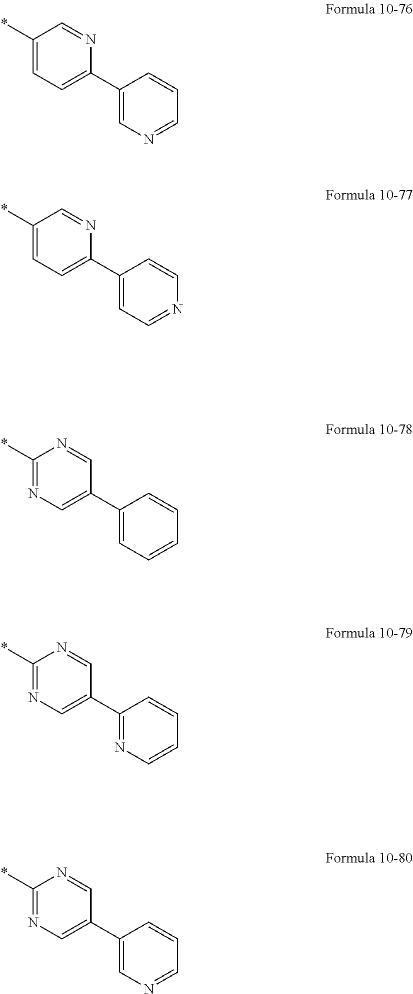 [SMILES: *c1ccc(-c2cccnc2)nc1 ; *c1ccc(-c2ccncc2)nc1 ; *c1ncc(-c2ccccc2)cn1 ; *c1ncc(-c2ccccn2)cn1 ; *c1ncc(-c2cccnc2)cn1]

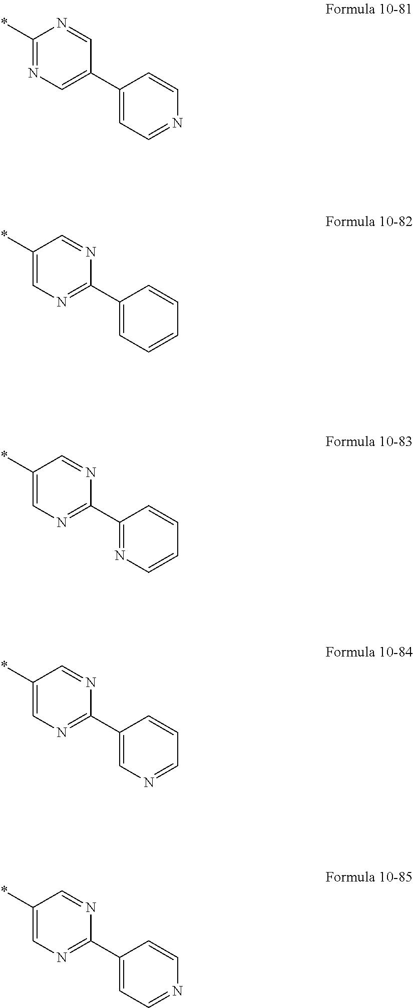 [SMILES: *c1ncc(-c2ccncc2)cn1 ; *c1cnc(-c2ccccc2)nc1 ; *c1cnc(-c2ccccn2)nc1 ; *c1cnc(-c2cccnc2)nc1 ; *c1cnc(-c2ccncc2)nc1]

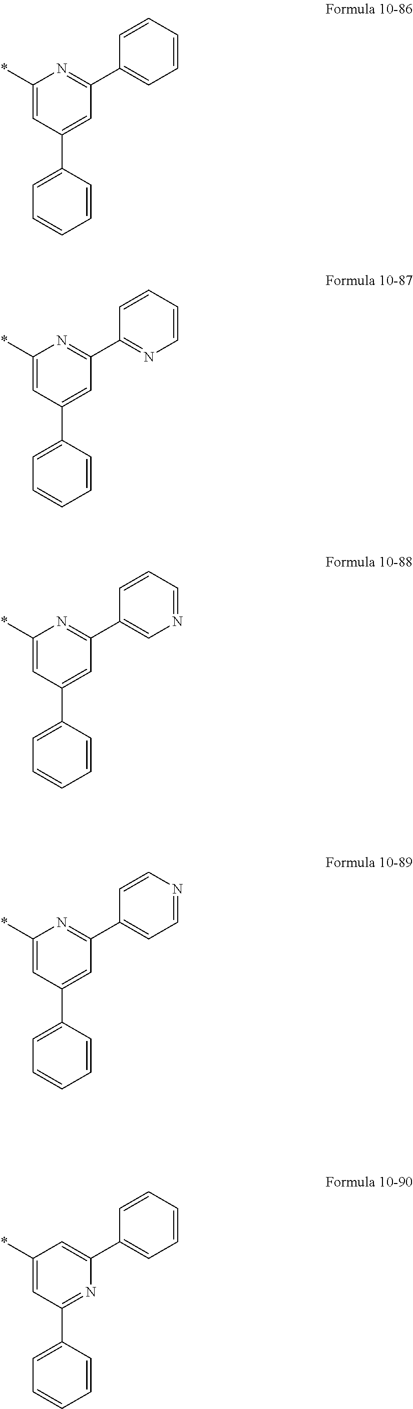 [SMILES: *c1cc(-c2ccccc2)cc(-c2ccccc2)n1 ; *c1cc(-c2ccccc2)cc(-c2ccccn2)n1 ; *c1cc(-c2ccccc2)cc(-c2cccnc2)n1 ; *c1cc(-c2ccccc2)cc(-c2ccncc2)n1 ; *c1cc(-c2ccccc2)nc(-c2ccccc2)c1]

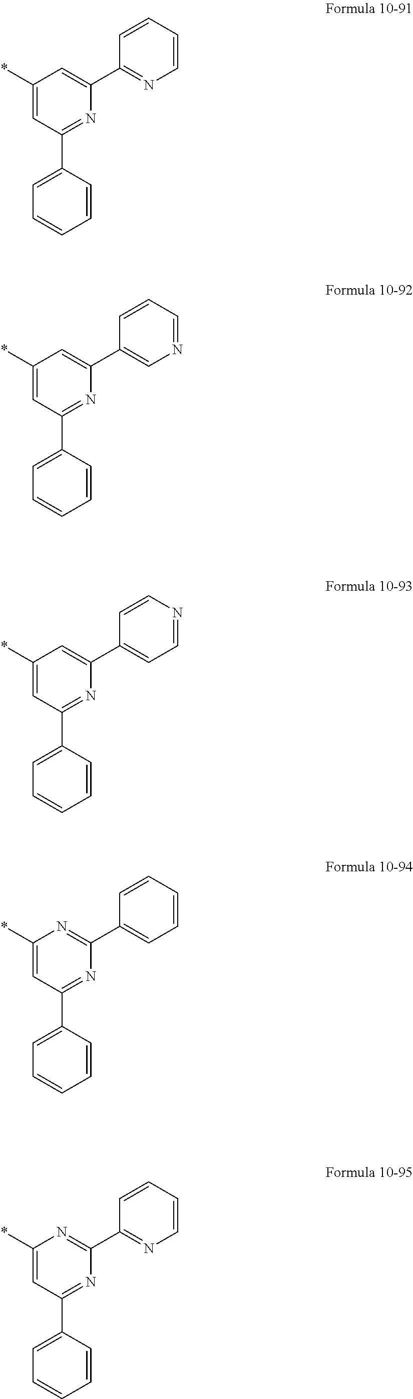 [SMILES: *c1cc(-c2ccccc2)nc(-c2ccccn2)c1 ; *c1cc(-c2ccccc2)nc(-c2cccnc2)c1 ; *c1cc(-c2ccccc2)nc(-c2ccncc2)c1 ; *c1cc(-c2ccccc2)nc(-c2ccccc2)n1 ; *c1cc(-c2ccccc2)nc(-c2ccccn2)n1]

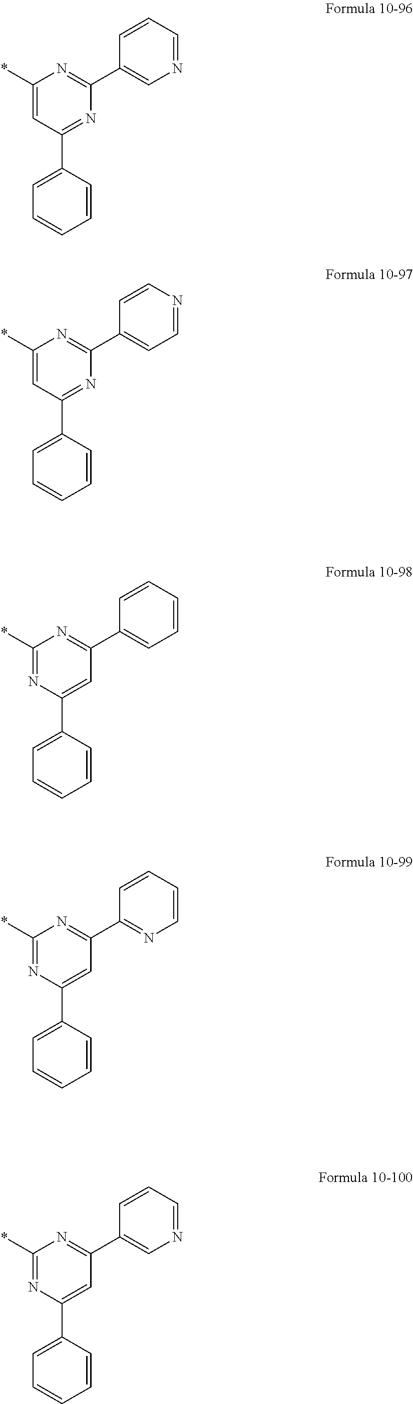 [SMILES: *c1cc(-c2ccccc2)nc(-c2cccnc2)n1 ; *c1cc(-c2ccccc2)nc(-c2ccncc2)n1 ; *c1nc(-c2ccccc2)cc(-c2ccccc2)n1 ; *c1nc(-c2ccccc2)cc(-c2ccccn2)n1 ; *c1nc(-c2ccccc2)cc(-c2cccnc2)n1]

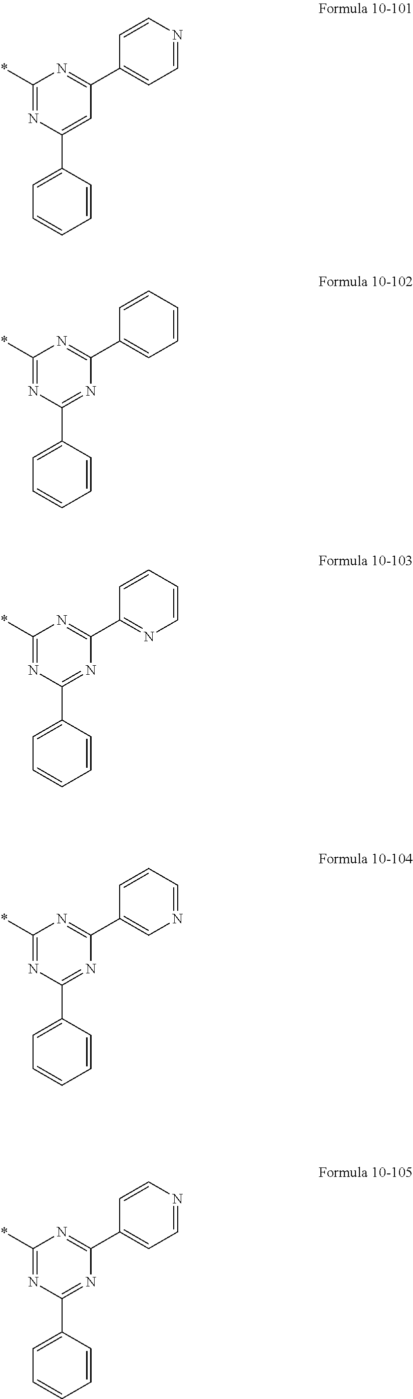 [SMILES: *c1nc(-c2ccccc2)cc(-c2ccncc2)n1 ; *c1nc(-c2ccccc2)nc(-c2ccccc2)n1 ; *c1nc(-c2ccccc2)nc(-c2ccccn2)n1 ; *c1nc(-c2ccccc2)nc(-c2cccnc2)n1 ; *c1nc(-c2ccccc2)nc(-c2ccncc2)n1]

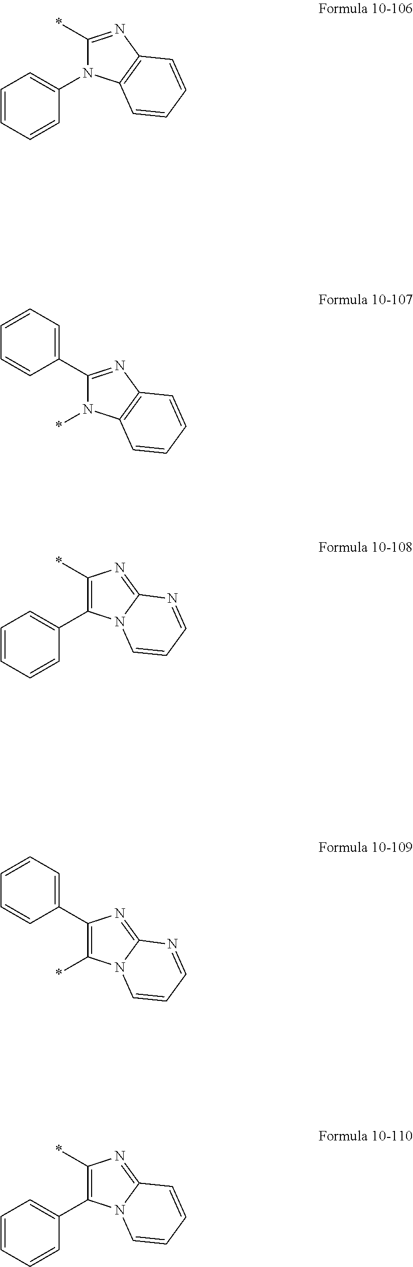 [SMILES: *c1nc2ccccc2n1-c1ccccc1 ; *n1c(-c2ccccc2)nc2ccccc21 ; *c1nc2ncccn2c1-c1ccccc1 ; *c1c(-c2ccccc2)nc2ncccn12 ; *c1nc2ccccn2c1-c1ccccc1]

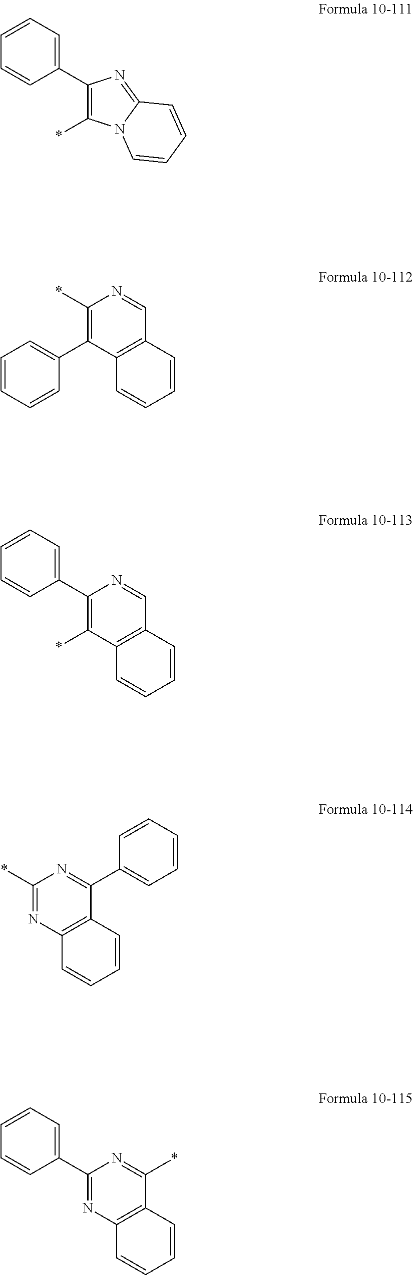 [SMILES: *c1c(-c2ccccc2)nc2ccccn12 ; *c1ncc2ccccc2c1-c1ccccc1 ; *c1c(-c2ccccc2)ncc2ccccc12 ; *c1nc(-c2ccccc2)c2ccccc2n1 ; *c1nc(-c2ccccc2)nc2ccccc12]

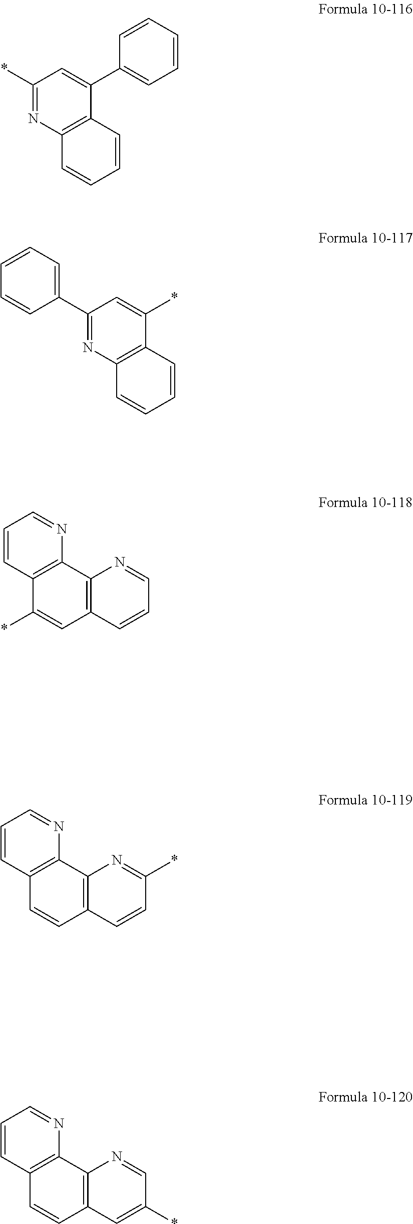 [SMILES: *c1cc(-c2ccccc2)c2ccccc2n1 ; *c1cc(-c2ccccc2)nc2ccccc12 ; *c1cc2cccnc2c2ncccc12 ; *c1ccc2ccc3cccnc3c2n1 ; *c1cnc2c(ccc3cccnc32)c1]

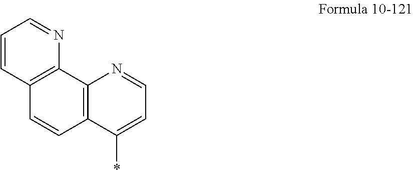 [SMILES: *c1ccnc2c1ccc1cccnc12]

In Formulae 9-1 to 9-100 and 10-1 to 10-121, Ph may refer to a phenyl group, * indicates a binding site to a neighboring atom, and Q₁ to Q₃ are the same as described above.

In Formula 1, c1 indicates the number of Ar₁(s), c2 indicates the number of Ar₂(s), and c3 indicates the number of Ar₃(s). c1 to c3 may each independently be an integer selected from 1 to 3. When c1 is two or more, two or more Ar₁(s) may be identical to or different from each other, when c2 is two or more, two or more Ar₂(s) may be identical to or different from each other, and when c3 is two or more, two or more Ar₃(s) may be identical to or different from each other.

For example, c1 to c3 in Formula 1 may each independently be 1 or 2.

R₁ to R₄, R₂₁ to R₂₄, R₂₇, and R₂₈ in Formulae 1, 2A, and 2B may each independently be selected from hydrogen, deuterium (-D), —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅).

For example, R₁ to R₄ in Formula 1 may each independently be selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a phenanthrenyl group, an anthracenyl group, a fluorenyl group, a dimethyl-fluorenyl group, a diphenyl-fluorenyl group, and —Si(Q₄)(Q₅)(Q₆), wherein Q₄ to Q₆ are the same as described above.

R₂₁ to R₂₄, R₂₇, and R₂₈ in Formulae 2A and 2B may each independently be selected from the group consisting of:

hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;

a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a picenyl group, a perylenyl group, a pentaphenyl group, a hexacenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a dibenzosilolyl group, a thiadiazolyl group, an imidazopyridinyl group, an imidazopyrimidinyl group, —Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅); and

a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a pentacenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a dibenzosilolyl group, a thiadiazolyl group, an imidazopyridinyl group, and an imidazopyrimidinyl group, each substituted with at least one selected from deuterium, —F, —Cl, —Br, —I, a hydroxyl group, a cyano group, a nitro group, an amidino group, a hydrazino group, a hydrazono group, a C₁-C₁₀ alkyl group, a C₁-C₁₀ alkoxy group, a C₃-C₂₀ cycloalkyl group, a C₆-C₂₀ aryl group, a C₃-C₂₀ heteroaryl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

wherein Q₄ to Q₆ and Q₃₁ to Q₃₃ may each independently be selected from the group consisting of:

a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and

a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group.

In various embodiments, in Formulae 1, 2A, and 2B,

R₁ to R₄, R₂₁ to R₂₄, R₂₇, and R₂₈ may each independently be selected from the group consisting of:

hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;

groups represented by Formulae 5-1 to 5-45 and 6-1 to 6-124; and

—Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅),

wherein Q₄ to Q₆ may each independently be selected from the group consisting of:

a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and

a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group.

In various embodiments, in Formulae 1, 2A, and 2B,

R₁ to R₄, R₂₁ to R₂₄, R₂₇, and R₂₈ may each independently be selected from the group consisting of:

hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;

groups represented by Formulae 9-1 to 9-100 and 10-1 to 10-121; and

—Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅),

wherein Q₄ to Q₆ may each independently be selected from the group consisting of:

a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and

a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group.

In Formulae 1 and 2, b1, b2, b21, and b22 indicate the number of R₁(s), the number of R₂(s), the number of R₂₁(s), and the number of R₂₂(s), respectively. b1 and b2 may each independently be an integer selected from 1 to 6, and b21 and b22 may each independently be an integer selected from 1 to 3. When b1 is two or more, two or more R₁(s) may be identical to or different from each other. When b2 is two or more, two or more R₂(s) may be identical to or different from each other. When b21 is two or more, two or more R₂₁(s) may be identical to or different from each other. When b22 is two or more, two or more R₂₂(s) may be identical to or different from each other.

For example, b1 and b2 may each independently be an integer selected from 1 to 4, and b21 to b22 may each independently be 1 or 2.

In Formula 1, d11 and d12 indicate the number of *-[(L₁)ₐ₁-(Ar₁)_{c1}](s) and the number of *-[(L₂)ₐ₂-(Ar₂)_{c2}](s) respectively. d11 and d12 may each independently be an integer selected from 0 to 4.

When d11 is two or more, two or more *-[(L₁)ₐ₁-(Ar₁)_{c1}](s) may be identical to or different from each other, and when d12 is two or more, two or more *-[(L₂)ₐ₂-(Ar₂)_{c2}](s) may be identical to or different from each other.

For example, d11 and d12 in Formula 1 may each independently be an integer selected from 0, 1, and 2, but embodiments of the present disclosure are not limited thereto.

In various embodiments, the first compound may be represented by one selected from Formulae 1A to 1F:

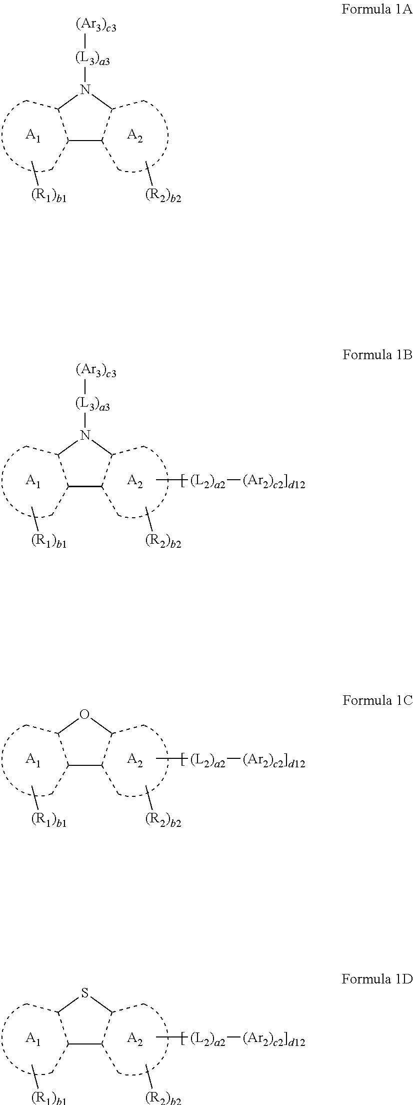

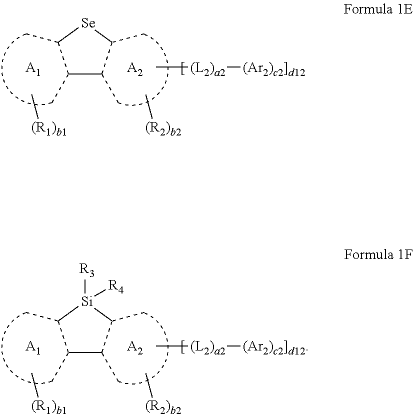

In Formulae 1A to 1F,

ring A₁, ring A₂, L₂, L₃, a2, a3, Ar₂, Arₐ, c2, c3, R₁ to R₄, b1, b2, and d12 are the same as respectively described above.

For example, in Formulae 1A to 1F,

ring A₁ may be selected from a benzene group, a naphthalene group, a pyridine group, and a pyrimidine group,

ring A₂ may be selected from a benzene group, a naphthalene group, a phenanthrene group, an anthracene group, a phenanthroline group, an indenopyridine group, a benzofuropyrimidine group, a benzofuropyridine group, an indenofluorene group, an indenoindole group, a benzoindole group, a naphthofuran group, a benzonaphthofuran group, a pyridobenzothiophene group, a benzonaphthothiophene group, a benzocarbazole group, a quinoline group, a quinoxaline group, a pyridine group, a pyrimidine group, an indole group, a carbazole, a fluorene, a benzofluorene, a benzofuran, a benzoxazole, an indene, a dibenzofuran, a dibenzothiophene, a pyridoindole, a group represented by Formula

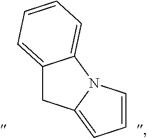 [SMILES: c1ccc2c(c1)Cc1cccn1-2]

a group represented by Formula

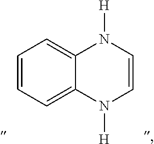

a group represented by Formula

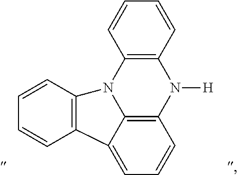 [SMILES: c1ccc2c(c1)Nc1cccc3c4ccccc4n-2c13]

and a group represented by Formula

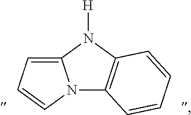 [SMILES: c1ccc2c(c1)[nH]c1cccn12]

and

R₁ and R₂ may each independently be selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a C₆-C₃₀ aryl group, a C₁-C₃₀ heteroaryl group, —Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅).

In various embodiments, the first compound may be selected from Compounds 1-1 to 1-194:

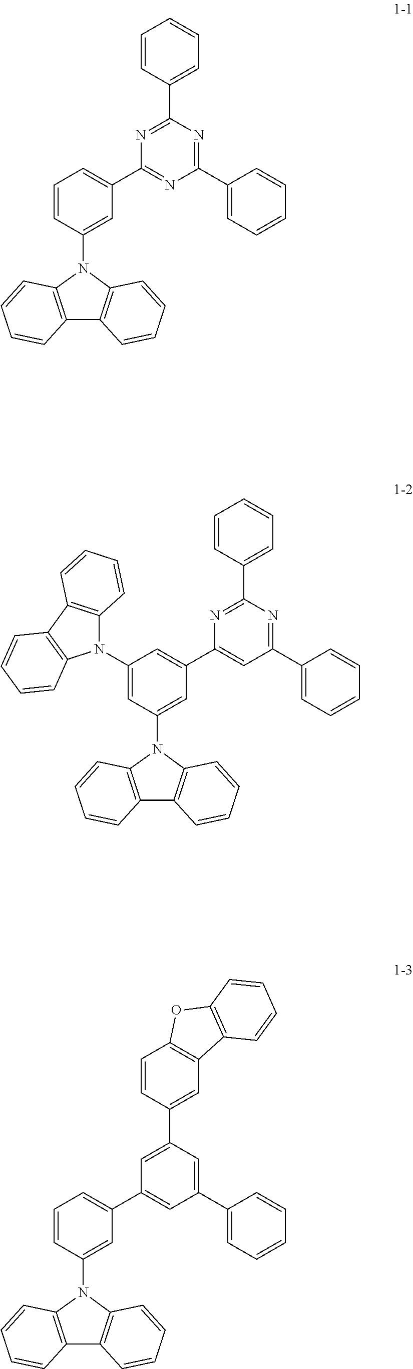 [SMILES: c1ccc(-c2nc(-c3ccccc3)nc(-c3cccc(-n4c5ccccc5c5ccccc54)c3)n2)cc1 ; c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2cc(-c3cccc(-n4c5ccccc5c5ccccc54)c3)cc(-c3ccc4oc5ccccc5c4c3)c2)cc1]

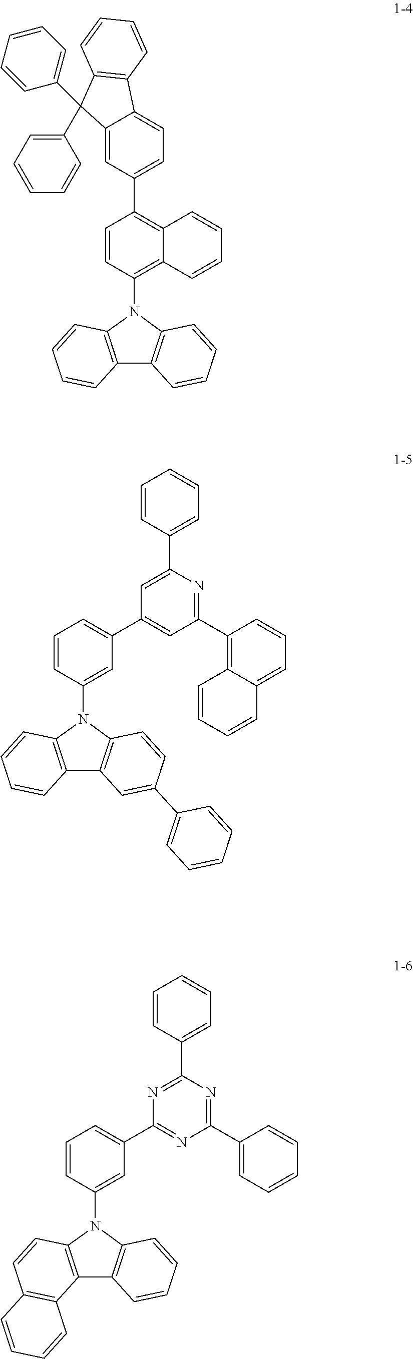 [SMILES: c1ccc(C2(c3ccccc3)c3ccccc3-c3ccc(-c4ccc(-n5c6ccccc6c6ccccc65)c5ccccc45)cc32)cc1 ; c1ccc(-c2ccc3c(c2)c2ccccc2n3-c2cccc(-c3cc(-c4ccccc4)nc(-c4cccc5ccccc45)c3)c2)cc1 ; c1ccc(-c2nc(-c3ccccc3)nc(-c3cccc(-n4c5ccccc5c5c6ccccc6ccc54)c3)n2)cc1]

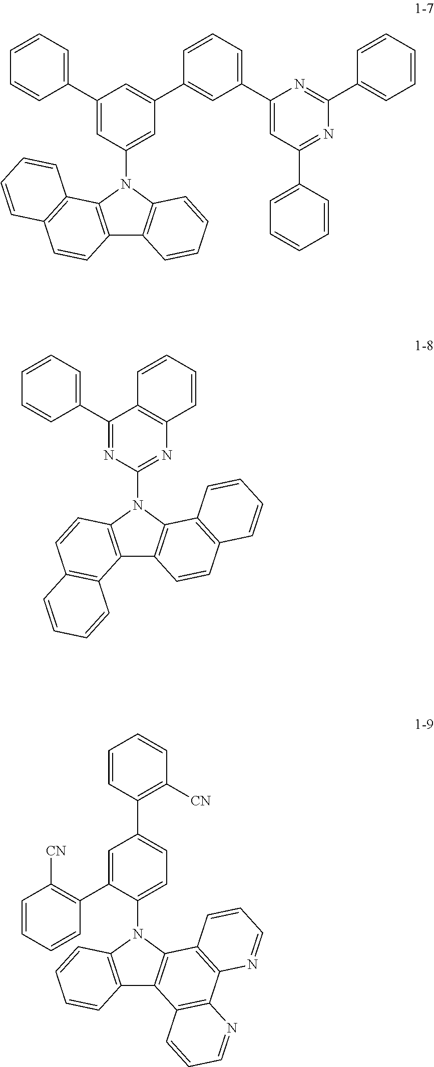 [SMILES: c1ccc(-c2cc(-c3cccc(-c4cc(-c5ccccc5)nc(-c5ccccc5)n4)c3)cc(-n3c4ccccc4c4ccc5ccccc5c43)c2)cc1 ; c1ccc(-c2nc(-n3c4ccc5ccccc5c4c4ccc5ccccc5c43)nc3ccccc23)cc1 ; N#Cc1ccccc1-c1ccc(-n2c3ccccc3c3c4cccnc4c4ncccc4c32)c(-c2ccccc2C#N)c1]

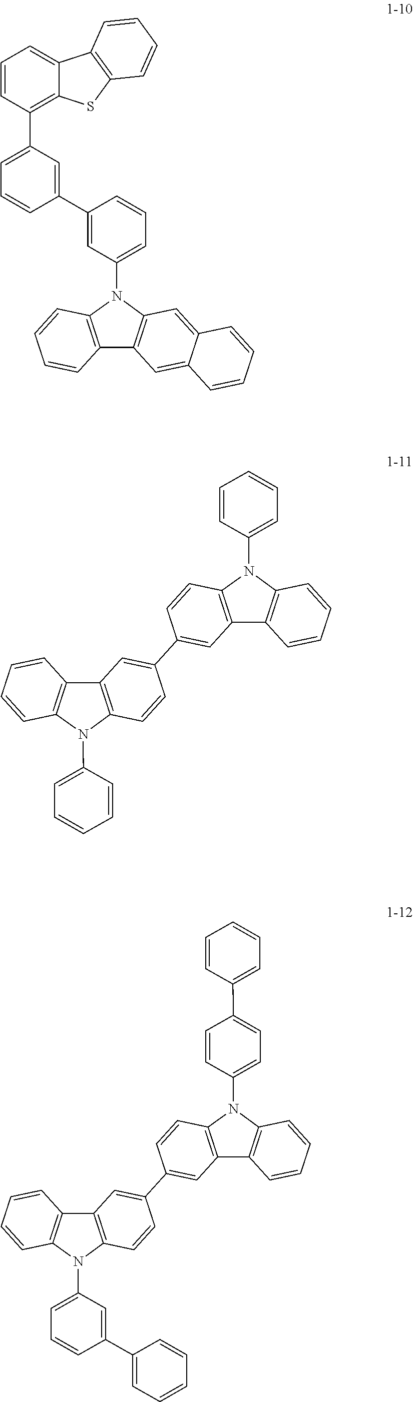 [SMILES: c1cc(-c2cccc(-n3c4ccccc4c4cc5ccccc5cc43)c2)cc(-c2cccc3c2sc2ccccc23)c1 ; c1ccc(-n2c3ccccc3c3cc(-c4ccc5c(c4)c4ccccc4n5-c4ccccc4)ccc32)cc1 ; c1ccc(-c2ccc(-n3c4ccccc4c4cc(-c5ccc6c(c5)c5ccccc5n6-c5cccc(-c6ccccc6)c5)ccc43)cc2)cc1]

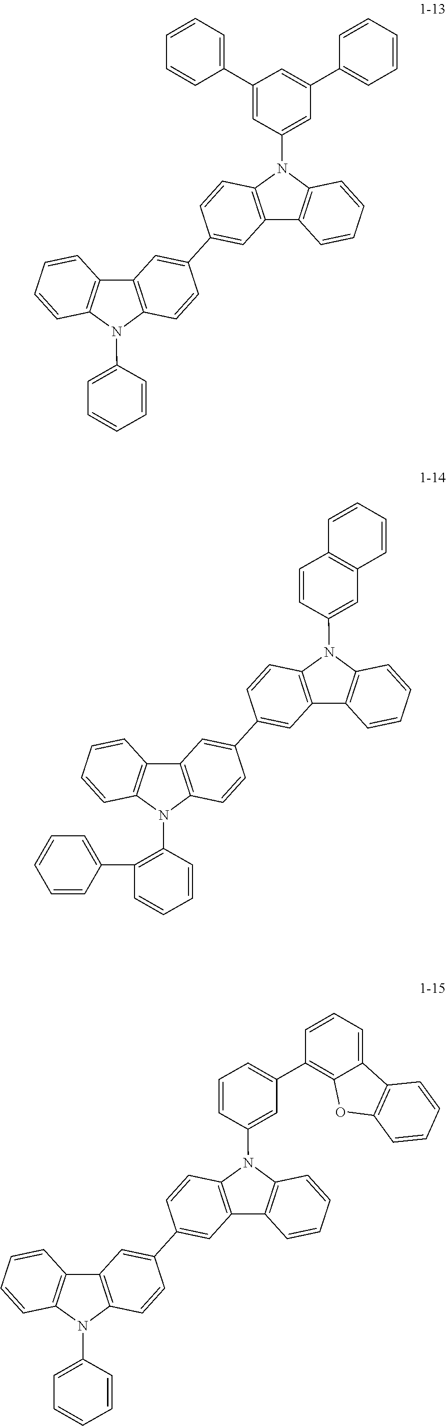 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2ccccc2-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cccc(-c5cccc6c5oc5ccccc56)c4)ccc32)cc1]

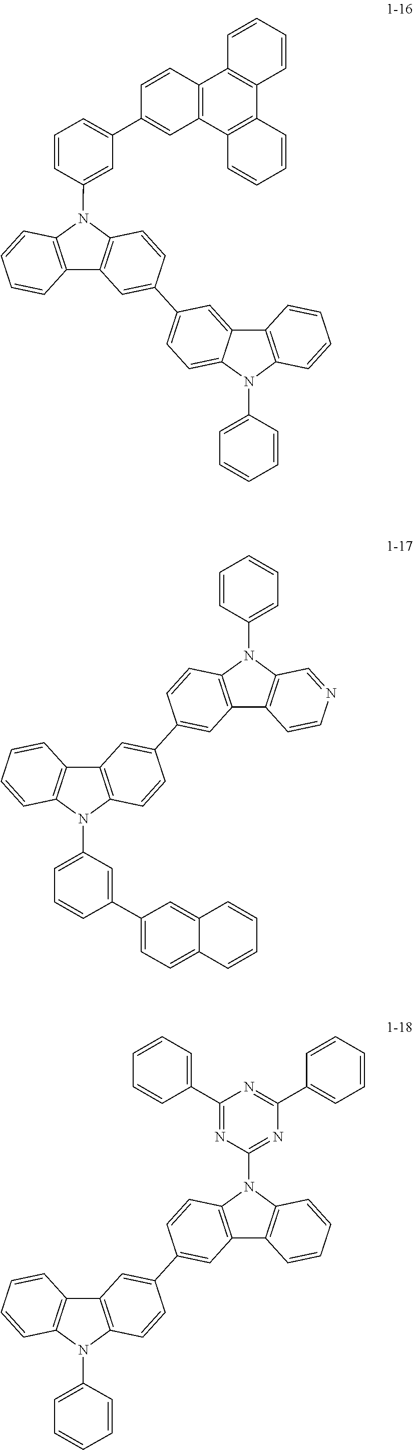 [SMILES: c1ccc(-n2c3ccccc3c3cc(-c4ccc5c(c4)c4ccccc4n5-c4cccc(-c5ccc6c7ccccc7c7ccccc7c6c5)c4)ccc32)cc1 ; c1ccc(-n2c3ccc(-c4ccc5c(c4)c4ccccc4n5-c4cccc(-c5ccc6ccccc6c5)c4)cc3c3ccncc32)cc1 ; c1ccc(-c2nc(-c3ccccc3)nc(-n3c4ccccc4c4cc(-c5ccc6c(c5)c5ccccc5n6-c5ccccc5)ccc43)n2)cc1]

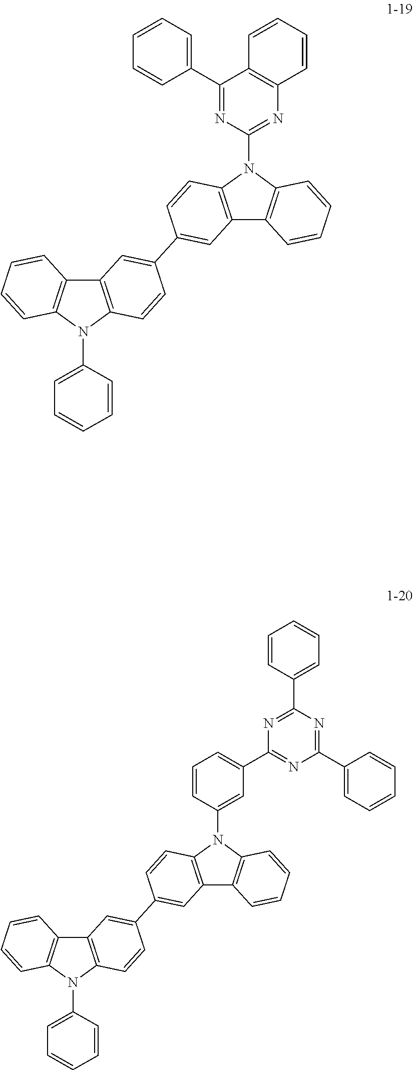 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

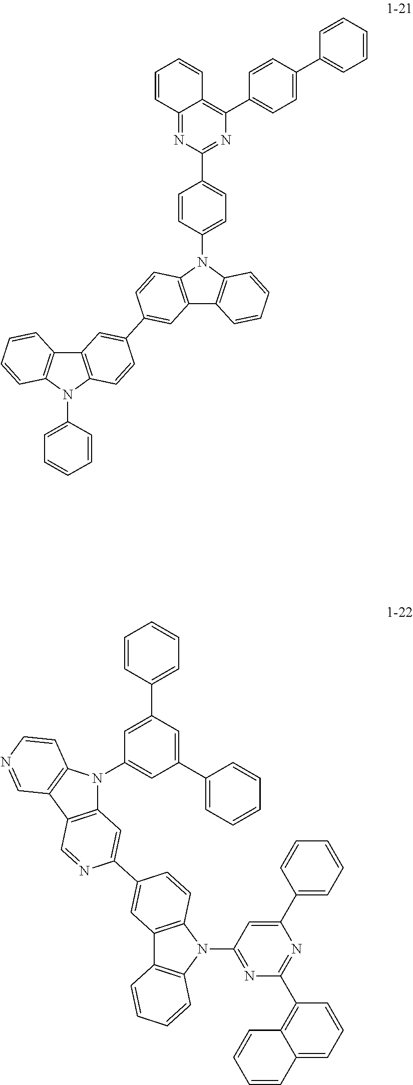 [SMILES: c1ccc(-c2ccc(-c3nc(-c4ccc(-n5c6ccccc6c6cc(-c7ccc8c(c7)c7ccccc7n8-c7ccccc7)ccc65)cc4)nc4ccccc34)cc2)cc1 ; c1ccc(-c2cc(-c3ccccc3)cc(-n3c4ccncc4c4cnc(-c5ccc6c(c5)c5ccccc5n6-c5cc(-c6ccccc6)nc(-c6cccc7ccccc67)n5)cc43)c2)cc1]

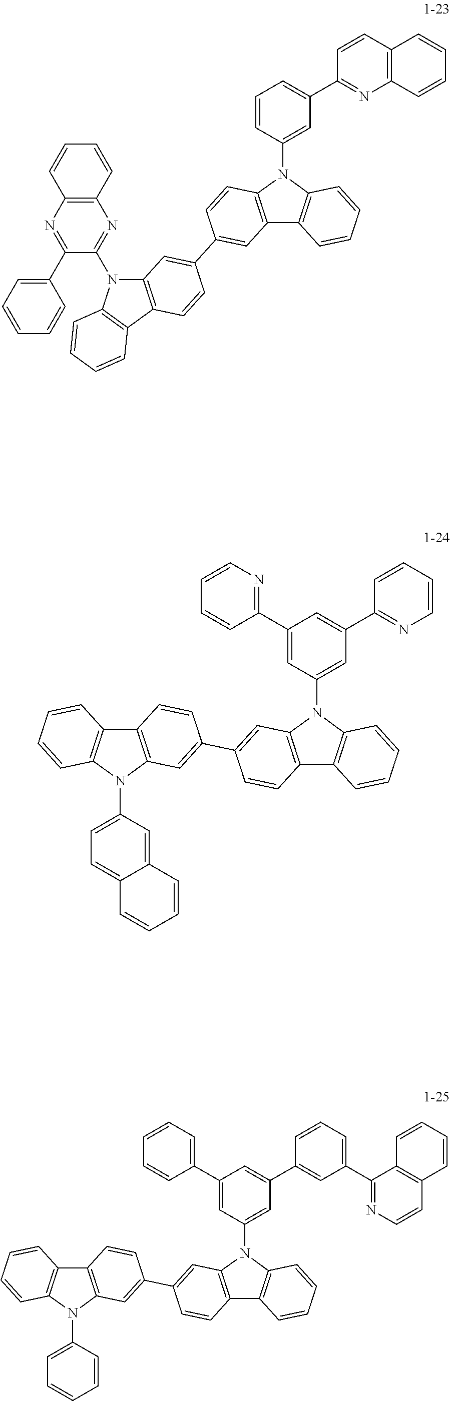 [SMILES: c1ccc(-c2nc3ccccc3nc2-n2c3ccccc3c3ccc(-c4ccc5c(c4)c4ccccc4n5-c4cccc(-c5ccc6ccccc6n5)c4)cc32)cc1 ; c1ccc(-c2cc(-c3ccccn3)cc(-n3c4ccccc4c4ccc(-c5ccc6c7ccccc7n(-c7ccc8ccccc8c7)c6c5)cc43)c2)nc1 ; c1ccc(-c2cc(-c3cccc(-c4nccc5ccccc45)c3)cc(-n3c4ccccc4c4ccc(-c5ccc6c7ccccc7n(-c7ccccc7)c6c5)cc43)c2)cc1]

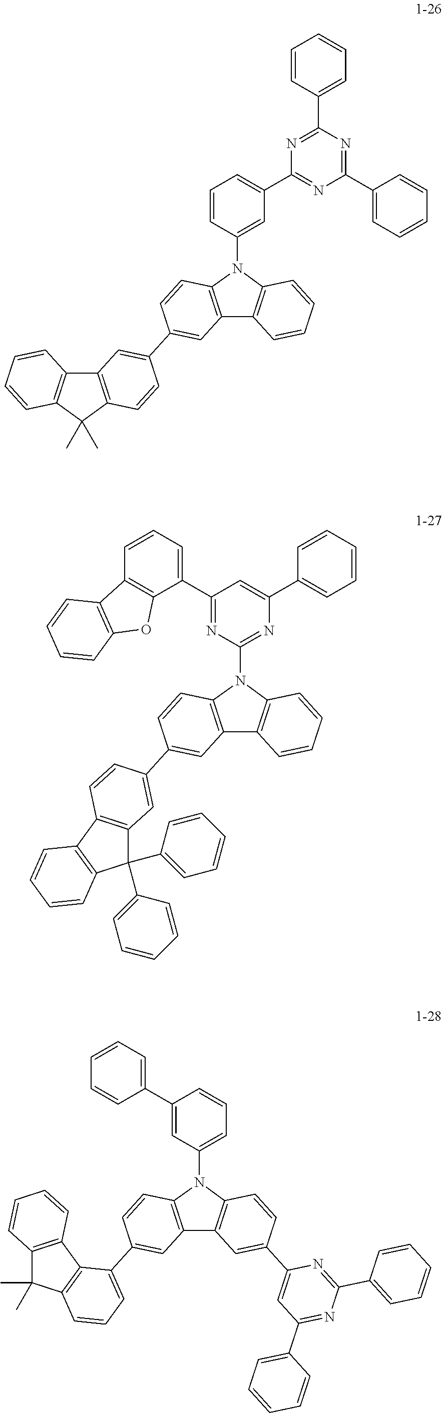 [SMILES: CC1(C)c2ccccc2-c2cc(-c3ccc4c(c3)c3ccccc3n4-c3cccc(-c4nc(-c5ccccc5)nc(-c5ccccc5)n4)c3)ccc21 ; c1ccc(-c2cc(-c3cccc4c3oc3ccccc34)nc(-n3c4ccccc4c4cc(-c5ccc6c(c5)C(c5ccccc5)(c5ccccc5)c5ccccc5-6)ccc43)n2)cc1 ; CC1(C)c2ccccc2-c2c(-c3ccc4c(c3)c3cc(-c5cc(-c6ccccc6)nc(-c6ccccc6)n5)ccc3n4-c3cccc(-c4ccccc4)c3)cccc21]

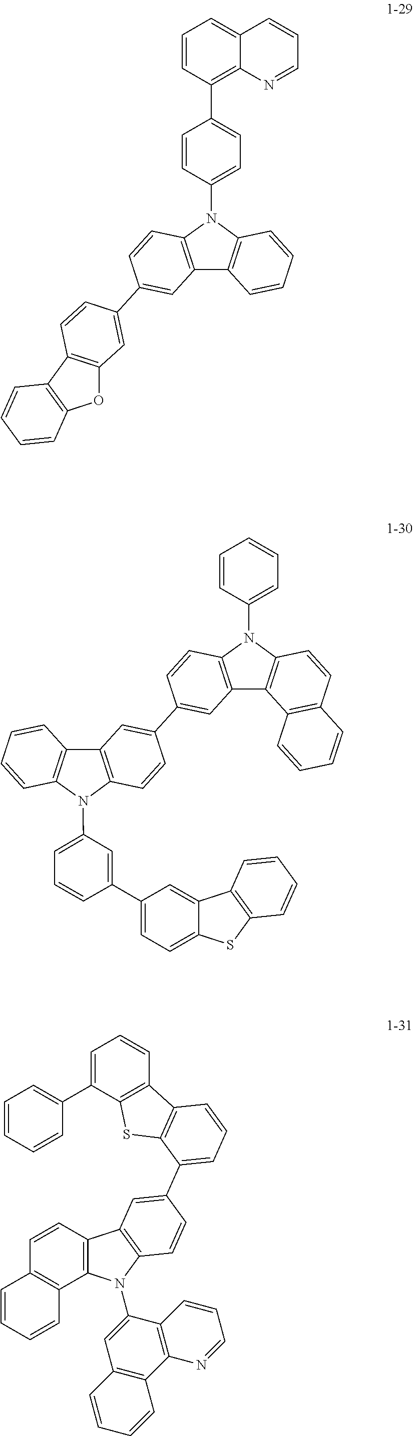 [SMILES: c1cnc2c(-c3ccc(-n4c5ccccc5c5cc(-c6ccc7c(c6)oc6ccccc67)ccc54)cc3)cccc2c1 ; c1ccc(-n2c3ccc(-c4ccc5c(c4)c4ccccc4n5-c4cccc(-c5ccc6sc7ccccc7c6c5)c4)cc3c3c4ccccc4ccc32)cc1 ; c1ccc(-c2cccc3c2sc2c(-c4ccc5c(c4)c4ccc6ccccc6c4n5-c4cc5ccccc5c5ncccc45)cccc23)cc1]

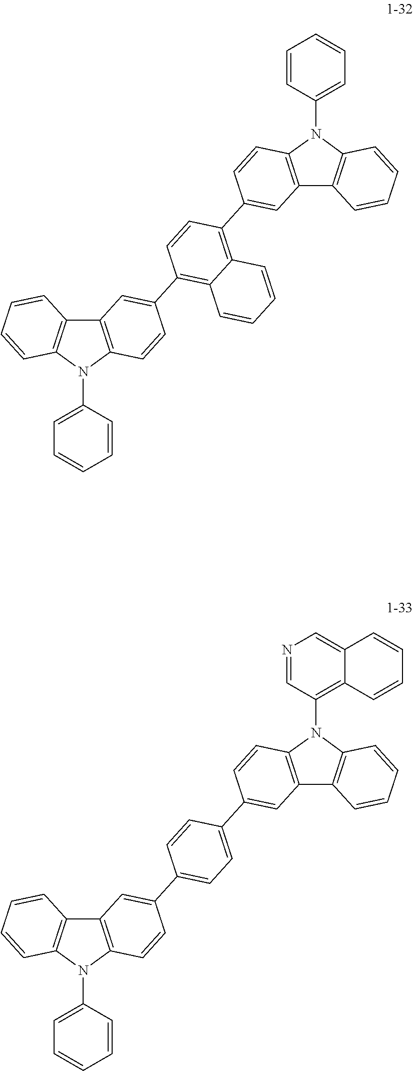 [SMILES: c1ccc(-n2c3ccccc3c3cc(-c4ccc(-c5ccc6c(c5)c5ccccc5n6-c5ccccc5)c5ccccc45)ccc32)cc1 ; c1ccc(-n2c3ccccc3c3cc(-c4ccc(-c5ccc6c(c5)c5ccccc5n6-c5cncc6ccccc56)cc4)ccc32)cc1]

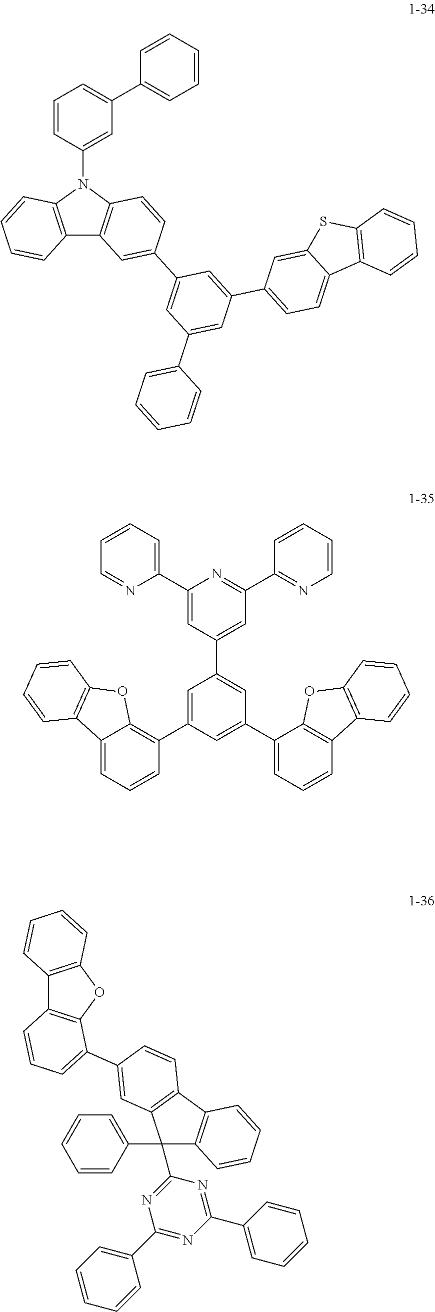 [SMILES: c1ccc(-c2cc(-c3ccc4c(c3)sc3ccccc34)cc(-c3ccc4c(c3)c3ccccc3n4-c3cccc(-c4ccccc4)c3)c2)cc1 ; c1ccc(-c2cc(-c3cc(-c4cccc5c4oc4ccccc45)cc(-c4cccc5c4oc4ccccc45)c3)cc(-c3ccccn3)n2)nc1 ; c1ccc(-c2nc(-c3ccccc3)nc(C3(c4ccccc4)c4ccccc4-c4ccc(-c5cccc6c5oc5ccccc56)cc43)n2)cc1]

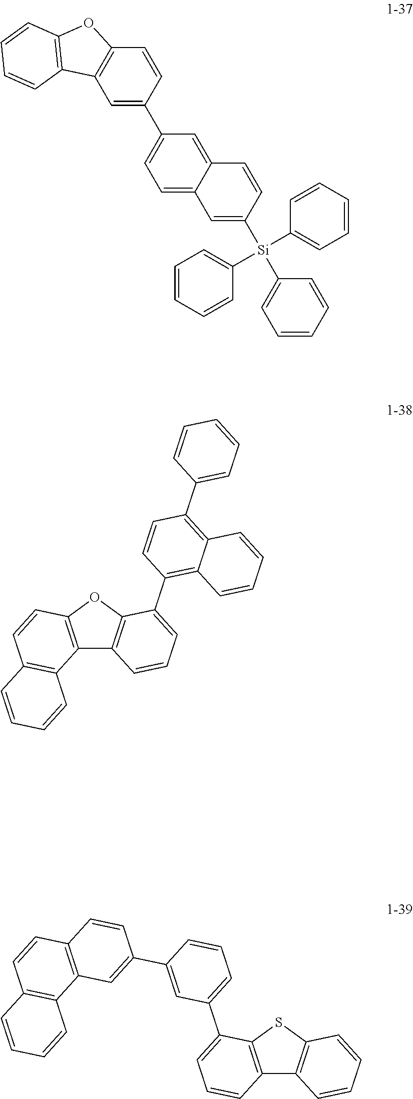 [SMILES: c1ccc([Si](c2ccccc2)(c2ccccc2)c2ccc3cc(-c4ccc5oc6ccccc6c5c4)ccc3c2)cc1 ; c1ccc(-c2ccc(-c3cccc4c3oc3ccc5ccccc5c34)c3ccccc23)cc1 ; c1cc(-c2ccc3ccc4ccccc4c3c2)cc(-c2cccc3c2sc2ccccc23)c1]

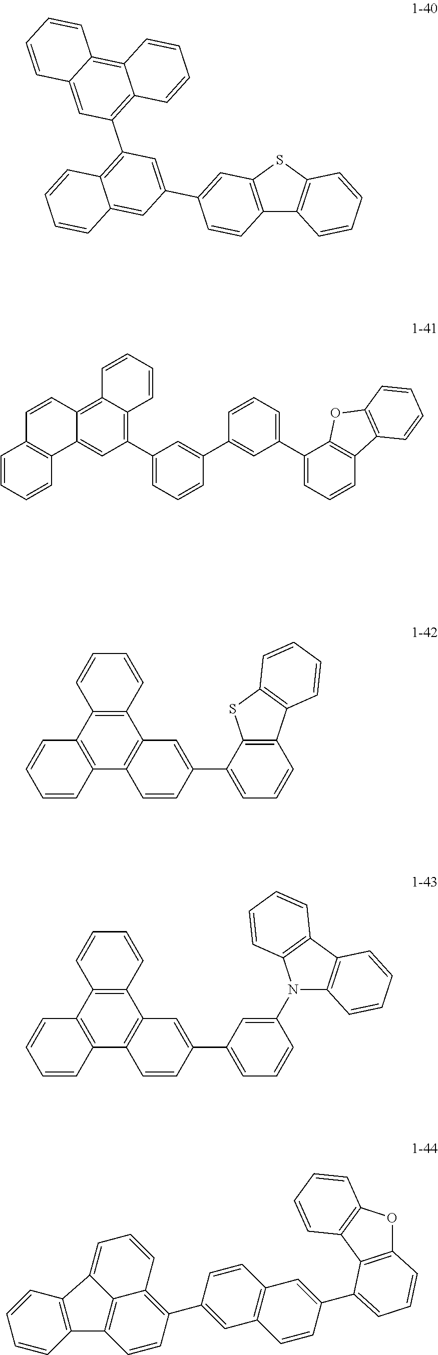 [SMILES: c1ccc2c(-c3cc4ccccc4c4ccccc34)cc(-c3ccc4c(c3)sc3ccccc34)cc2c1 ; c1cc(-c2cccc(-c3cccc4c3oc3ccccc34)c2)cc(-c2cc3c4ccccc4ccc3c3ccccc23)c1 ; c1ccc2c(c1)sc1c(-c3ccc4c5ccccc5c5ccccc5c4c3)cccc12 ; c1cc(-c2ccc3c4ccccc4c4ccccc4c3c2)cc(-n2c3ccccc3c3ccccc32)c1 ; c1ccc2c(c1)-c1cccc3c(-c4ccc5cc(-c6cccc7oc8ccccc8c67)ccc5c4)ccc-2c13]

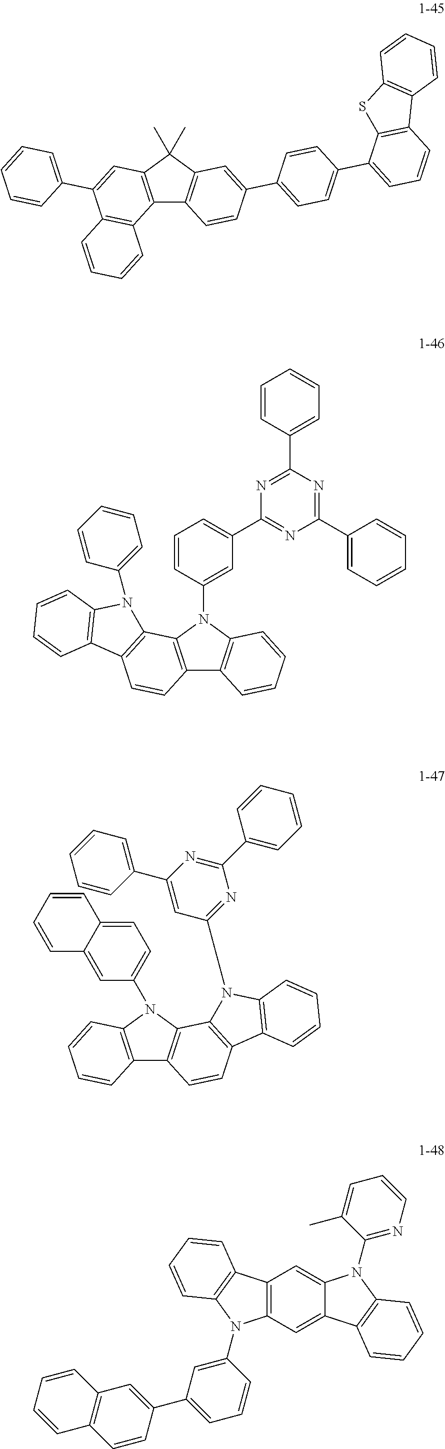 [SMILES: CC1(C)c2cc(-c3ccc(-c4cccc5c4sc4ccccc45)cc3)ccc2-c2c1cc(-c1ccccc1)c1ccccc21 ; c1ccc(-c2nc(-c3ccccc3)nc(-c3cccc(-n4c5ccccc5c5ccc6c7ccccc7n(-c7ccccc7)c6c54)c3)n2)cc1 ; c1ccc(-c2cc(-n3c4ccccc4c4ccc5c6ccccc6n(-c6ccc7ccccc7c6)c5c43)nc(-c3ccccc3)n2)cc1 ; Cc1cccnc1-n1c2ccccc2c2cc3c(cc21)c1ccccc1n3-c1cccc(-c2ccc3ccccc3c2)c1]

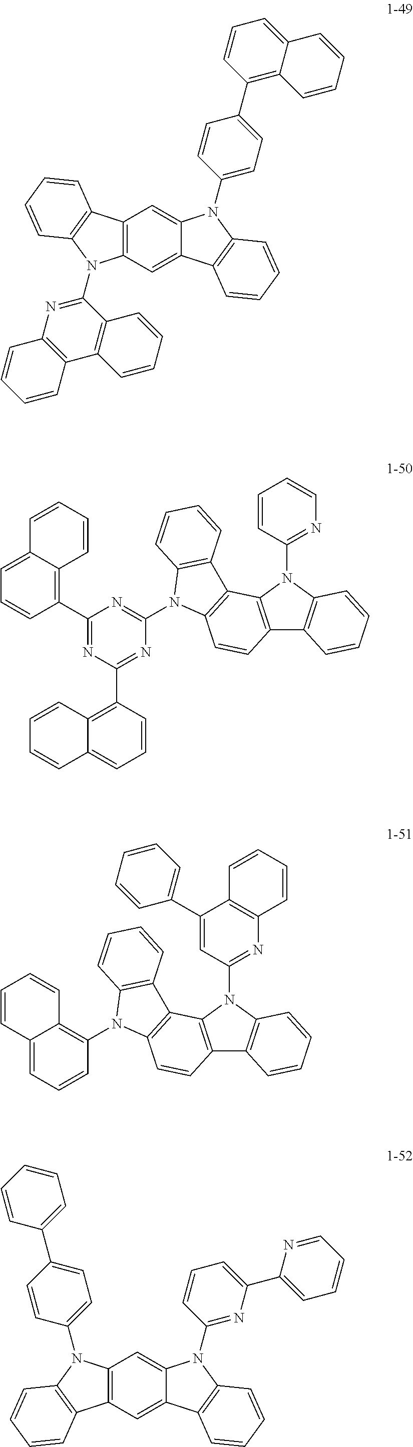 [SMILES: c1ccc2c(-c3ccc(-n4c5ccccc5c5cc6c(cc54)c4ccccc4n6-c4nc5ccccc5c5ccccc45)cc3)cccc2c1 ; c1ccc(-n2c3ccccc3c3ccc4c(c5ccccc5n4-c4nc(-c5cccc6ccccc56)nc(-c5cccc6ccccc56)n4)c32)nc1 ; c1ccc(-c2cc(-n3c4ccccc4c4ccc5c(c6ccccc6n5-c5cccc6ccccc56)c43)nc3ccccc23)cc1 ; c1ccc(-c2ccc(-n3c4ccccc4c4cc5c6ccccc6n(-c6cccc(-c7ccccn7)n6)c5cc43)cc2)cc1]

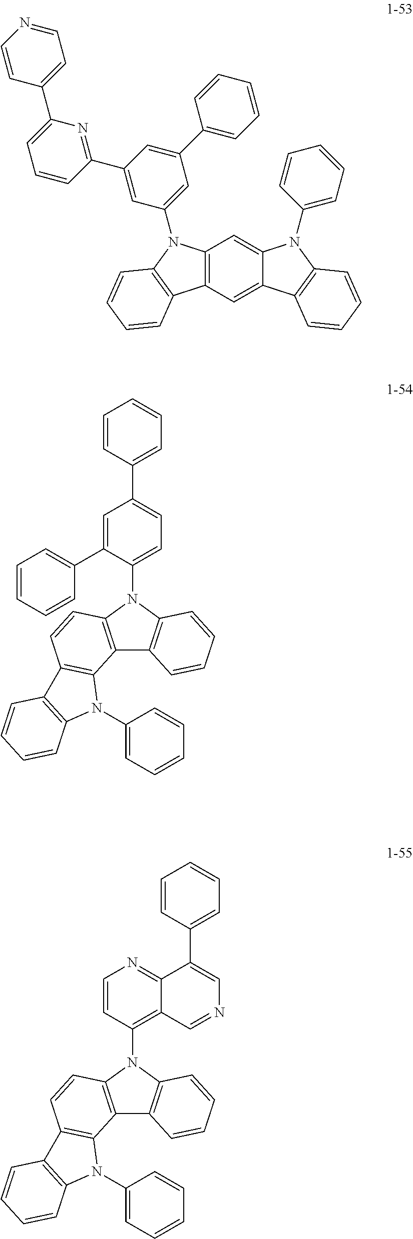 [SMILES: c1ccc(-c2cc(-c3cccc(-c4ccncc4)n3)cc(-n3c4ccccc4c4cc5c6ccccc6n(-c6ccccc6)c5cc43)c2)cc1 ; c1ccc(-c2ccc(-n3c4ccccc4c4c3ccc3c5ccccc5n(-c5ccccc5)c34)c(-c3ccccc3)c2)cc1 ; c1ccc(-c2cncc3c(-n4c5ccccc5c5c4ccc4c6ccccc6n(-c6ccccc6)c45)ccnc23)cc1]

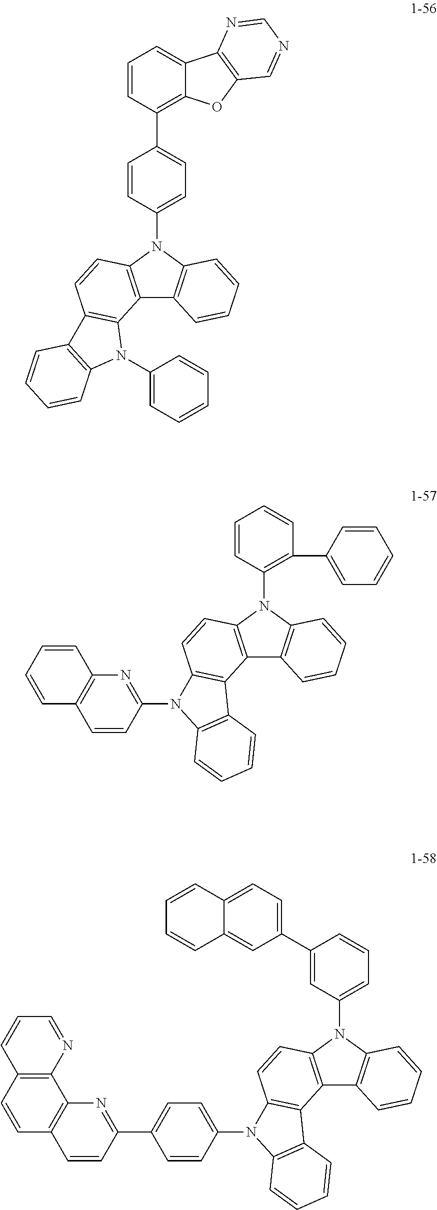 [SMILES: c1ccc(-n2c3ccccc3c3ccc4c(c5ccccc5n4-c4ccc(-c5cccc6c5oc5cncnc56)cc4)c32)cc1 ; c1ccc(-c2ccccc2-n2c3ccccc3c3c4c5ccccc5n(-c5ccc6ccccc6n5)c4ccc32)cc1 ; c1cc(-c2ccc3ccccc3c2)cc(-n2c3ccccc3c3c4c5ccccc5n(-c5ccc(-c6ccc7ccc8cccnc8c7n6)cc5)c4ccc32)c1]

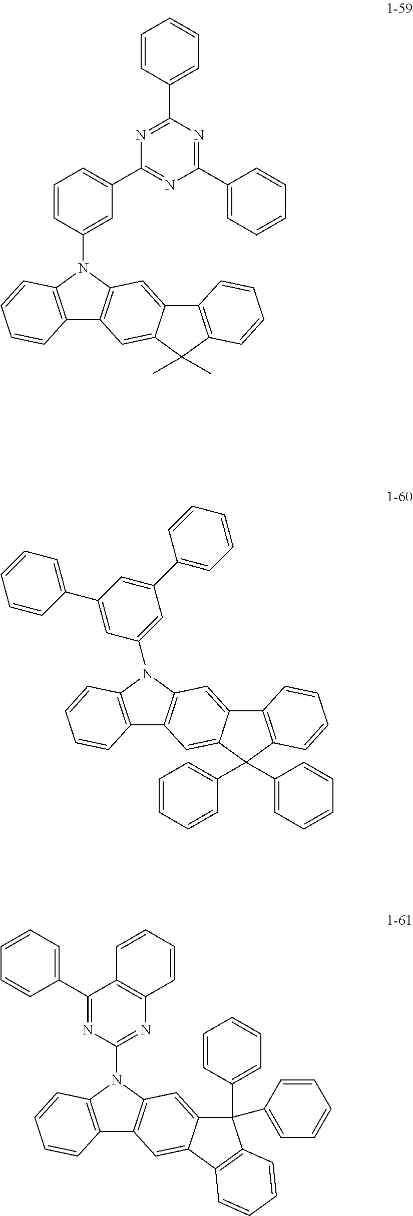 [SMILES: CC1(C)c2ccccc2-c2cc3c(cc21)c1ccccc1n3-c1cccc(-c2nc(-c3ccccc3)nc(-c3ccccc3)n2)c1 ; c1ccc(-c2cc(-c3ccccc3)cc(-n3c4ccccc4c4cc5c(cc43)-c3ccccc3C5(c3ccccc3)c3ccccc3)c2)cc1 ; c1ccc(-c2nc(-n3c4ccccc4c4cc5c(cc43)C(c3ccccc3)(c3ccccc3)c3ccccc3-5)nc3ccccc23)cc1]

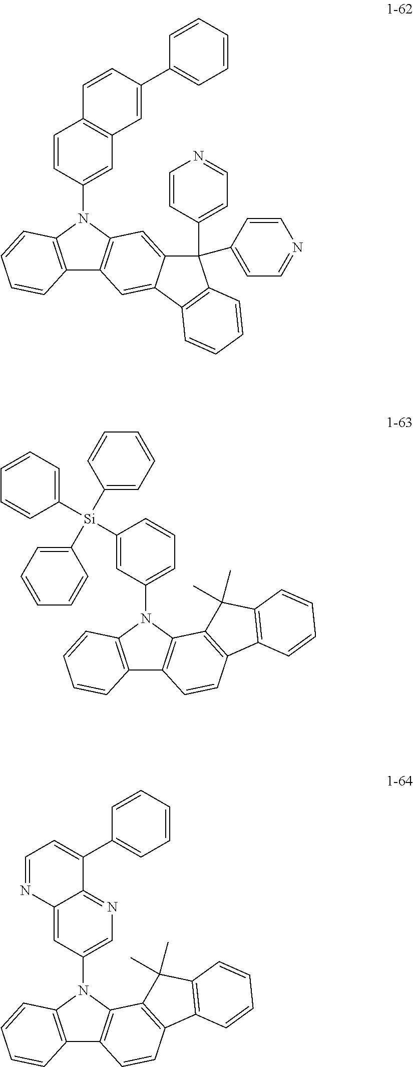 [SMILES: c1ccc(-c2ccc3ccc(-n4c5ccccc5c5cc6c(cc54)C(c4ccncc4)(c4ccncc4)c4ccccc4-6)cc3c2)cc1 ; CC1(C)c2ccccc2-c2ccc3c4ccccc4n(-c4cccc([Si](c5ccccc5)(c5ccccc5)c5ccccc5)c4)c3c21 ; CC1(C)c2ccccc2-c2ccc3c4ccccc4n(-c4cnc5c(-c6ccccc6)ccnc5c4)c3c21]

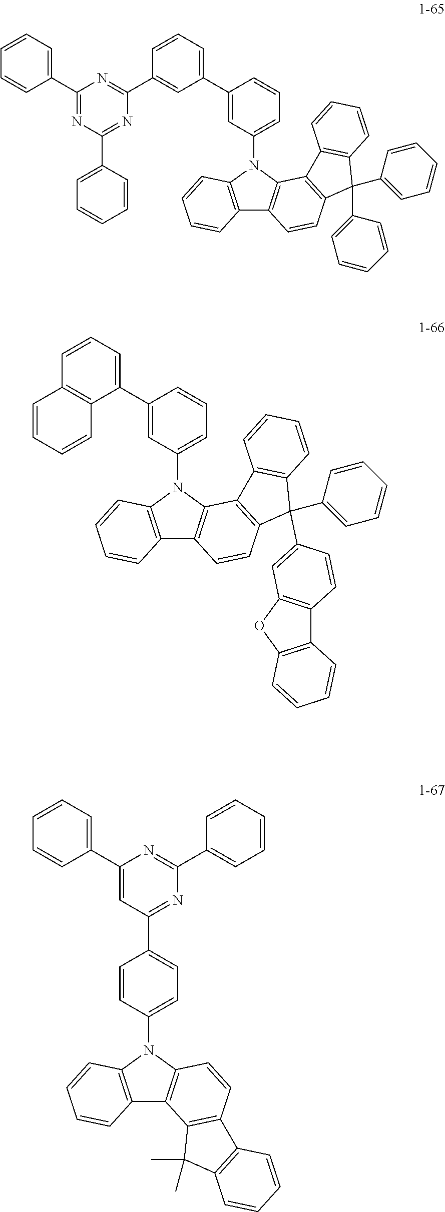 [SMILES: c1ccc(-c2nc(-c3ccccc3)nc(-c3cccc(-c4cccc(-n5c6ccccc6c6ccc7c(c65)-c5ccccc5C7(c5ccccc5)c5ccccc5)c4)c3)n2)cc1 ; c1ccc(C2(c3ccc4c(c3)oc3ccccc34)c3ccccc3-c3c2ccc2c4ccccc4n(-c4cccc(-c5cccc6ccccc56)c4)c32)cc1 ; CC1(C)c2ccccc2-c2ccc3c(c21)c1ccccc1n3-c1ccc(-c2cc(-c3ccccc3)nc(-c3ccccc3)n2)cc1]

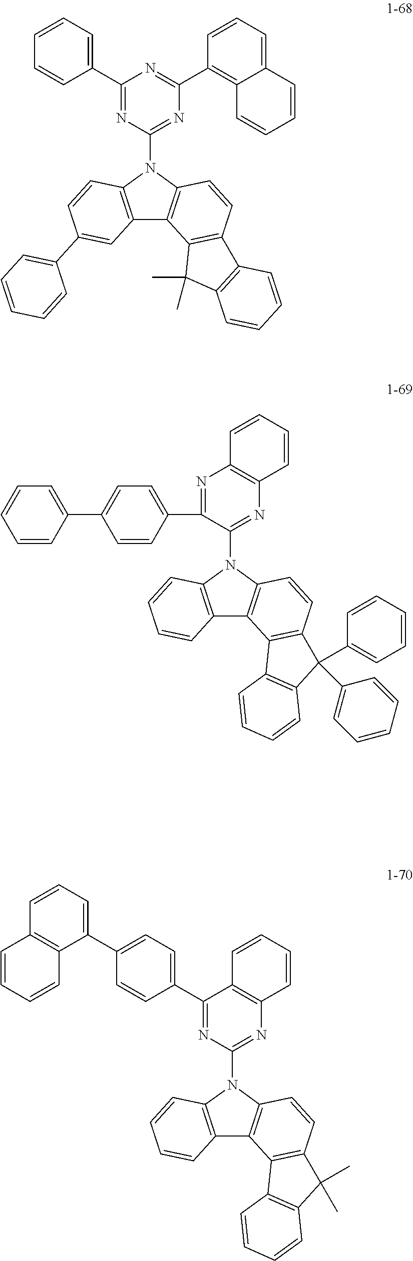 [SMILES: CC1(C)c2ccccc2-c2ccc3c(c21)c1cc(-c2ccccc2)ccc1n3-c1nc(-c2ccccc2)nc(-c2cccc3ccccc23)n1 ; c1ccc(-c2ccc(-c3nc4ccccc4nc3-n3c4ccccc4c4c5c(ccc43)C(c3ccccc3)(c3ccccc3)c3ccccc3-5)cc2)cc1 ; CC1(C)c2ccccc2-c2c1ccc1c2c2ccccc2n1-c1nc(-c2ccc(-c3cccc4ccccc34)cc2)c2ccccc2n1]

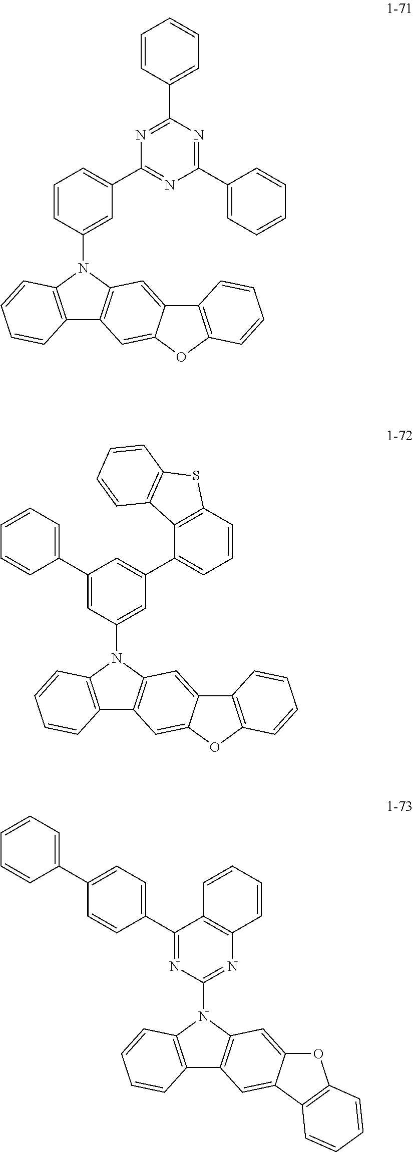 [SMILES: c1ccc(-c2nc(-c3ccccc3)nc(-c3cccc(-n4c5ccccc5c5cc6oc7ccccc7c6cc54)c3)n2)cc1 ; c1ccc(-c2cc(-c3cccc4sc5ccccc5c34)cc(-n3c4ccccc4c4cc5oc6ccccc6c5cc43)c2)cc1 ; c1ccc(-c2ccc(-c3nc(-n4c5ccccc5c5cc6c(cc54)oc4ccccc46)nc4ccccc34)cc2)cc1]

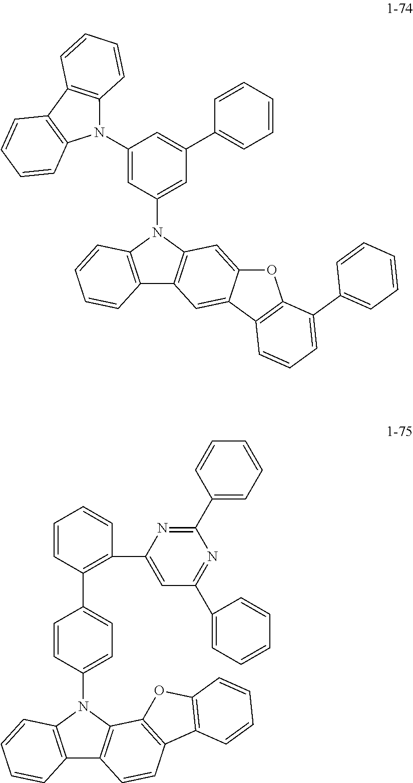 [SMILES: c1ccc(-c2cc(-n3c4ccccc4c4ccccc43)cc(-n3c4ccccc4c4cc5c(cc43)oc3c(-c4ccccc4)cccc35)c2)cc1 ; c1ccc(-c2cc(-c3ccccc3-c3ccc(-n4c5ccccc5c5ccc6c7ccccc7oc6c54)cc3)nc(-c3ccccc3)n2)cc1]

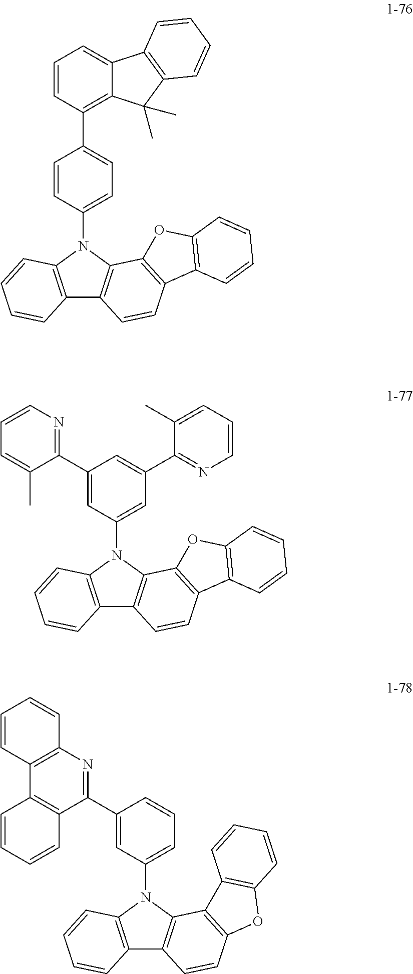 [SMILES: CC1(C)c2ccccc2-c2cccc(-c3ccc(-n4c5ccccc5c5ccc6c7ccccc7oc6c54)cc3)c21 ; Cc1cccnc1-c1cc(-c2ncccc2C)cc(-n2c3ccccc3c3ccc4c5ccccc5oc4c32)c1 ; c1cc(-c2nc3ccccc3c3ccccc23)cc(-n2c3ccccc3c3ccc4oc5ccccc5c4c32)c1]

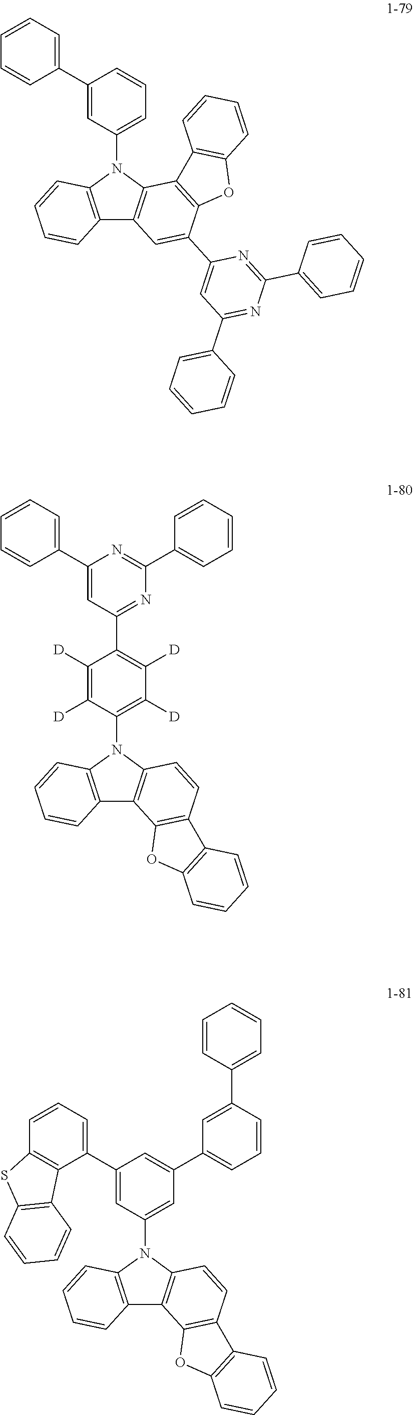 [SMILES: c1ccc(-c2cccc(-n3c4ccccc4c4cc(-c5cc(-c6ccccc6)nc(-c6ccccc6)n5)c5oc6ccccc6c5c43)c2)cc1 ; [2H]c1c([2H])c(-n2c3ccccc3c3c4oc5ccccc5c4ccc32)c([2H])c([2H])c1-c1cc(-c2ccccc2)nc(-c2ccccc2)n1 ; c1ccc(-c2cccc(-c3cc(-c4cccc5sc6ccccc6c45)cc(-n4c5ccccc5c5c6oc7ccccc7c6ccc54)c3)c2)cc1]

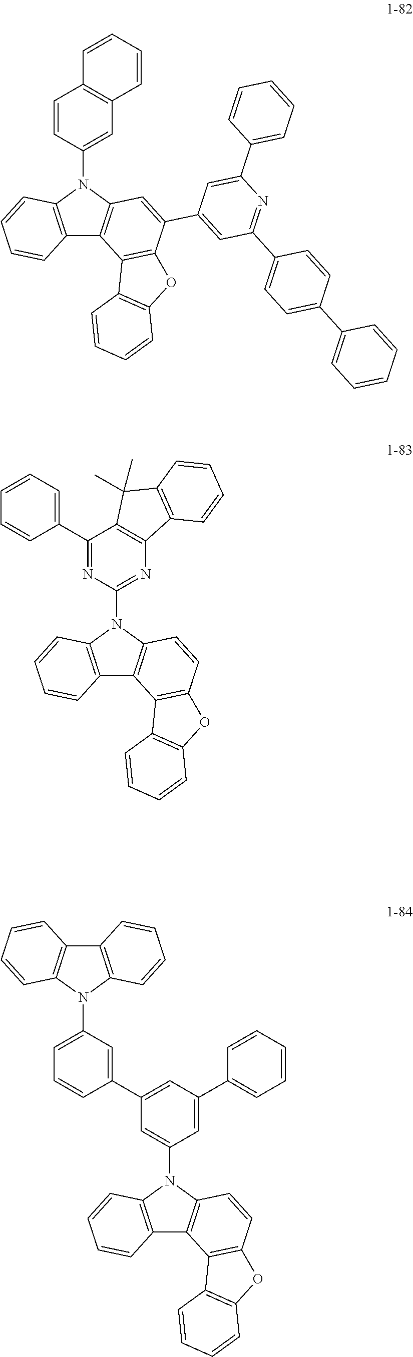 [SMILES: c1ccc(-c2ccc(-c3cc(-c4cc5c(c6ccccc6n5-c5ccc6ccccc6c5)c5c4oc4ccccc45)cc(-c4ccccc4)n3)cc2)cc1 ; CC1(C)c2ccccc2-c2nc(-n3c4ccccc4c4c5c(ccc43)oc3ccccc35)nc(-c3ccccc3)c21 ; c1ccc(-c2cc(-c3cccc(-n4c5ccccc5c5ccccc54)c3)cc(-n3c4ccccc4c4c5c(ccc43)oc3ccccc35)c2)cc1]

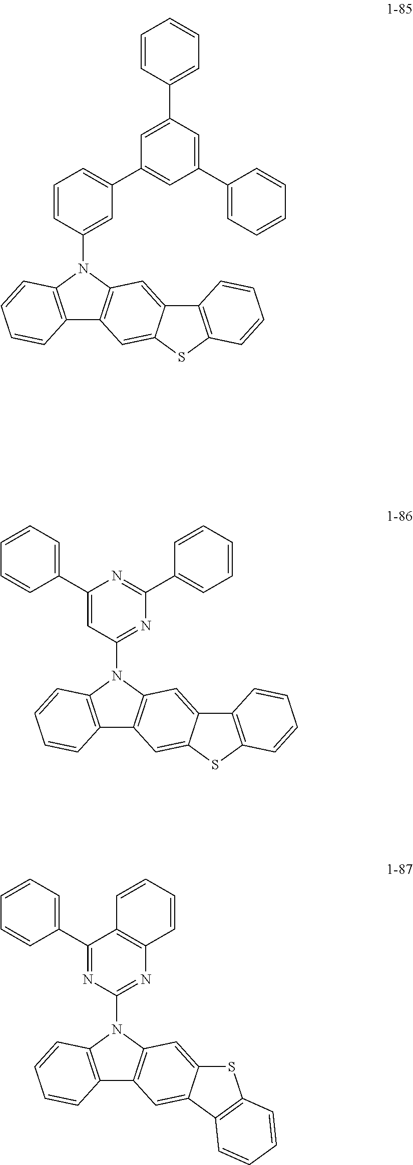 [SMILES: c1ccc(-c2cc(-c3ccccc3)cc(-c3cccc(-n4c5ccccc5c5cc6sc7ccccc7c6cc54)c3)c2)cc1 ; c1ccc(-c2cc(-n3c4ccccc4c4cc5sc6ccccc6c5cc43)nc(-c3ccccc3)n2)cc1 ; c1ccc(-c2nc(-n3c4ccccc4c4cc5c(cc43)sc3ccccc35)nc3ccccc23)cc1]

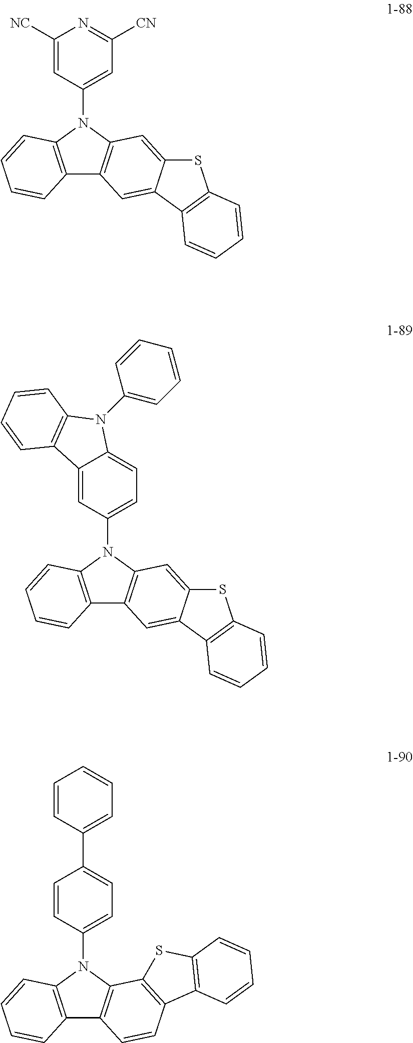 [SMILES: N#Cc1cc(-n2c3ccccc3c3cc4c(cc32)sc2ccccc24)cc(C#N)n1 ; c1ccc(-n2c3ccccc3c3cc(-n4c5ccccc5c5cc6c(cc54)sc4ccccc46)ccc32)cc1 ; c1ccc(-c2ccc(-n3c4ccccc4c4ccc5c6ccccc6sc5c43)cc2)cc1]

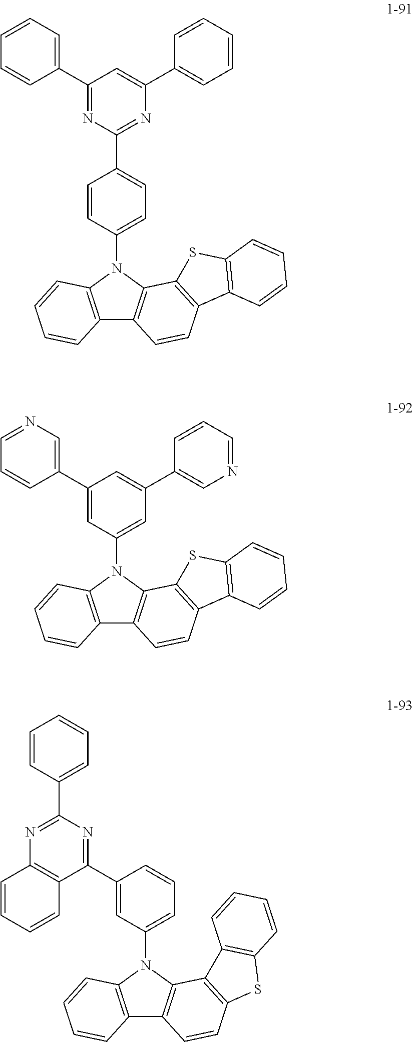 [SMILES: c1ccc(-c2cc(-c3ccccc3)nc(-c3ccc(-n4c5ccccc5c5ccc6c7ccccc7sc6c54)cc3)n2)cc1 ; c1cncc(-c2cc(-c3cccnc3)cc(-n3c4ccccc4c4ccc5c6ccccc6sc5c43)c2)c1 ; c1ccc(-c2nc(-c3cccc(-n4c5ccccc5c5ccc6sc7ccccc7c6c54)c3)c3ccccc3n2)cc1]

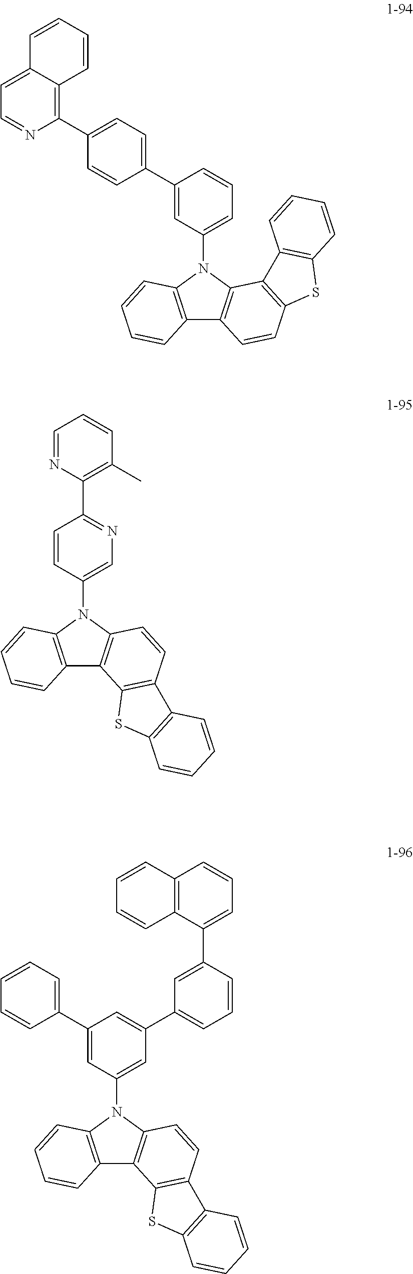 [SMILES: c1cc(-c2ccc(-c3nccc4ccccc34)cc2)cc(-n2c3ccccc3c3ccc4sc5ccccc5c4c32)c1 ; Cc1cccnc1-c1ccc(-n2c3ccccc3c3c4sc5ccccc5c4ccc32)cn1 ; c1ccc(-c2cc(-c3cccc(-c4cccc5ccccc45)c3)cc(-n3c4ccccc4c4c5sc6ccccc6c5ccc43)c2)cc1]

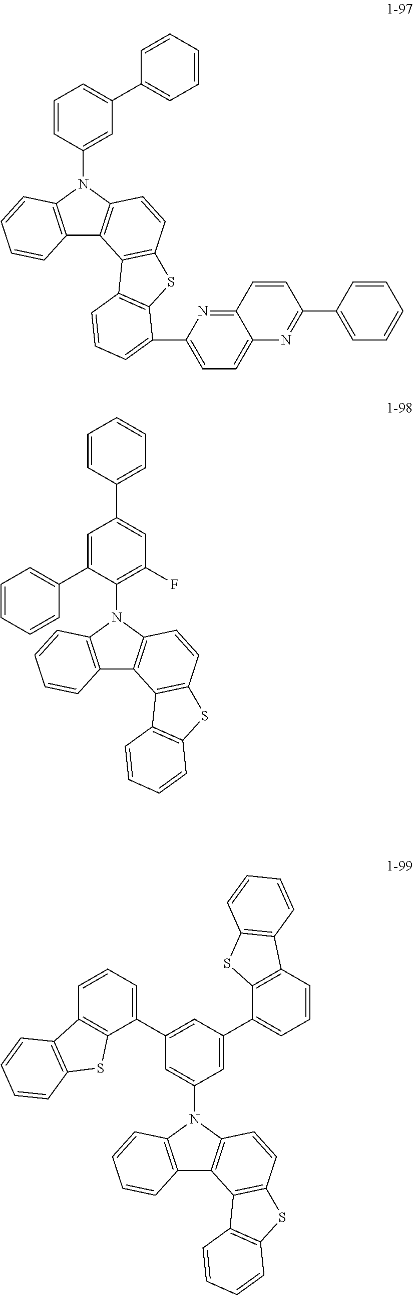 [SMILES: c1ccc(-c2cccc(-n3c4ccccc4c4c5c(ccc43)sc3c(-c4ccc6nc(-c7ccccc7)ccc6n4)cccc35)c2)cc1 ; Fc1cc(-c2ccccc2)cc(-c2ccccc2)c1-n1c2ccccc2c2c3c(ccc21)sc1ccccc13 ; c1ccc2c(c1)sc1c(-c3cc(-c4cccc5c4sc4ccccc45)cc(-n4c5ccccc5c5c6c(ccc54)sc4ccccc46)c3)cccc12]

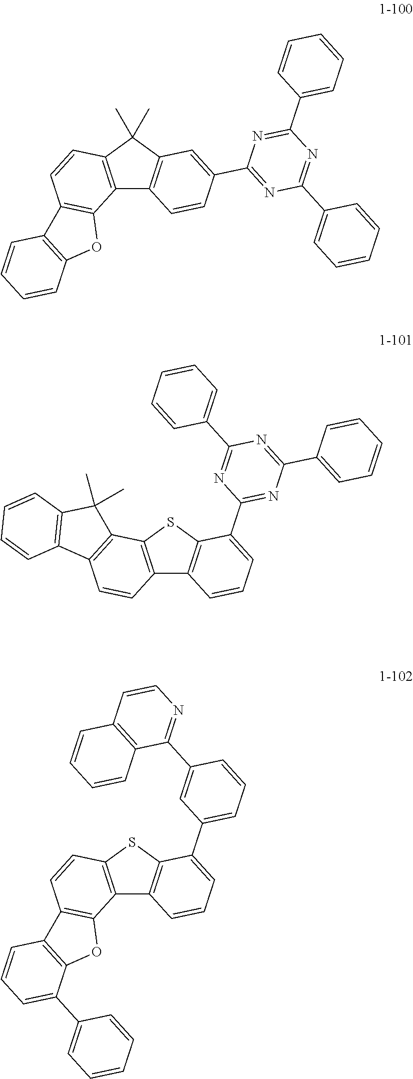 [SMILES: CC1(C)c2cc(-c3nc(-c4ccccc4)nc(-c4ccccc4)n3)ccc2-c2c1ccc1c2oc2ccccc21 ; CC1(C)c2ccccc2-c2ccc3c(sc4c(-c5nc(-c6ccccc6)nc(-c6ccccc6)n5)cccc43)c21 ; c1ccc(-c2cccc3c2oc2c3ccc3sc4c(-c5cccc(-c6nccc7ccccc67)c5)cccc4c32)cc1]

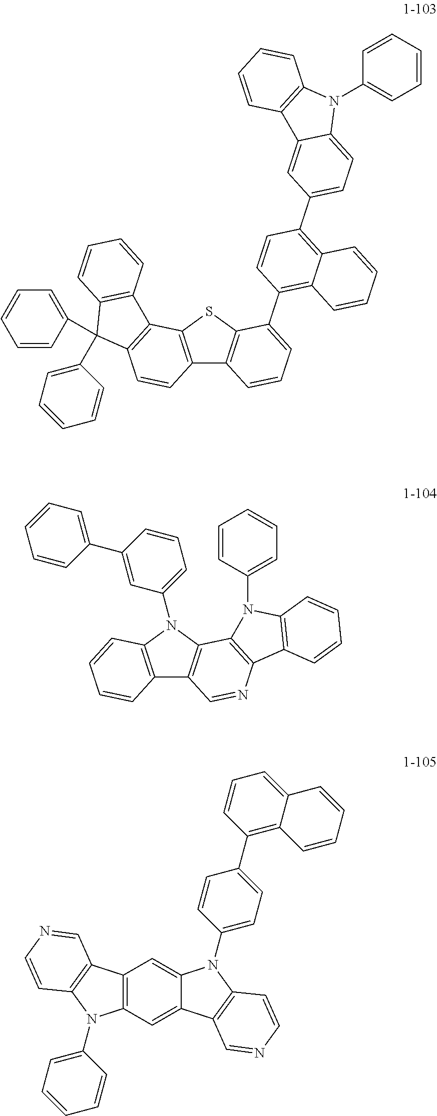 [SMILES: c1ccc(-n2c3ccccc3c3cc(-c4ccc(-c5cccc6c5sc5c7c(ccc56)C(c5ccccc5)(c5ccccc5)c5ccccc5-7)c5ccccc45)ccc32)cc1 ; c1ccc(-c2cccc(-n3c4ccccc4c4cnc5c6ccccc6n(-c6ccccc6)c5c43)c2)cc1 ; c1ccc(-n2c3ccncc3c3cc4c(cc32)c2cnccc2n4-c2ccc(-c3cccc4ccccc34)cc2)cc1]

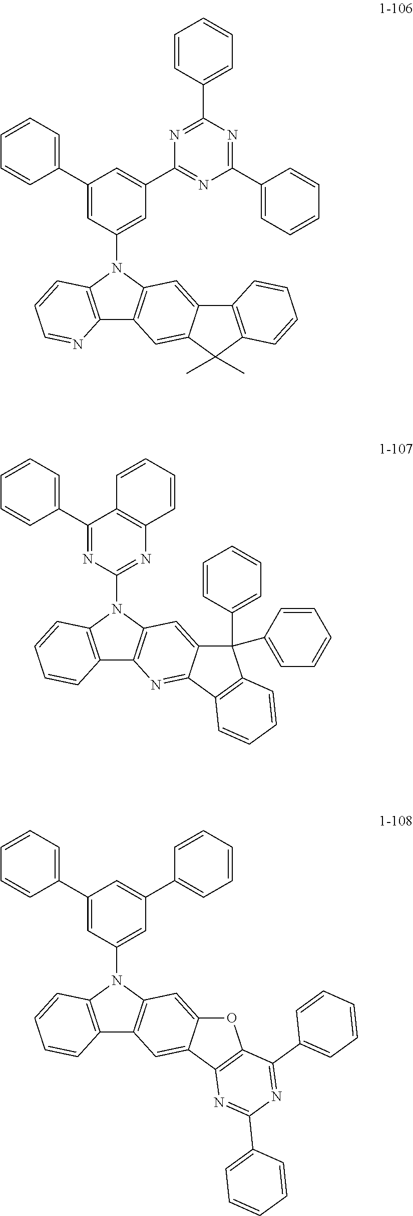 [SMILES: CC1(C)c2ccccc2-c2cc3c(cc21)c1ncccc1n3-c1cc(-c2ccccc2)cc(-c2nc(-c3ccccc3)nc(-c3ccccc3)n2)c1 ; c1ccc(-c2nc(-n3c4ccccc4c4nc5c(cc43)C(c3ccccc3)(c3ccccc3)c3ccccc3-5)nc3ccccc23)cc1 ; c1ccc(-c2cc(-c3ccccc3)cc(-n3c4ccccc4c4cc5c(cc43)oc3c(-c4ccccc4)nc(-c4ccccc4)nc35)c2)cc1]

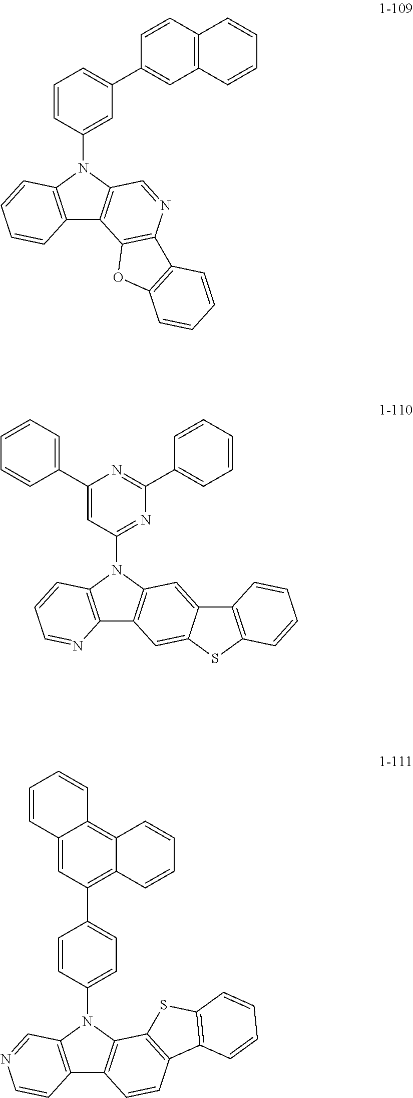 [SMILES: c1cc(-c2ccc3ccccc3c2)cc(-n2c3ccccc3c3c4oc5ccccc5c4ncc32)c1 ; c1ccc(-c2cc(-n3c4cc5c(cc4c4ncccc43)sc3ccccc35)nc(-c3ccccc3)n2)cc1 ; c1ccc2c(c1)cc(-c1ccc(-n3c4cnccc4c4ccc5c6ccccc6sc5c43)cc1)c1ccccc12]

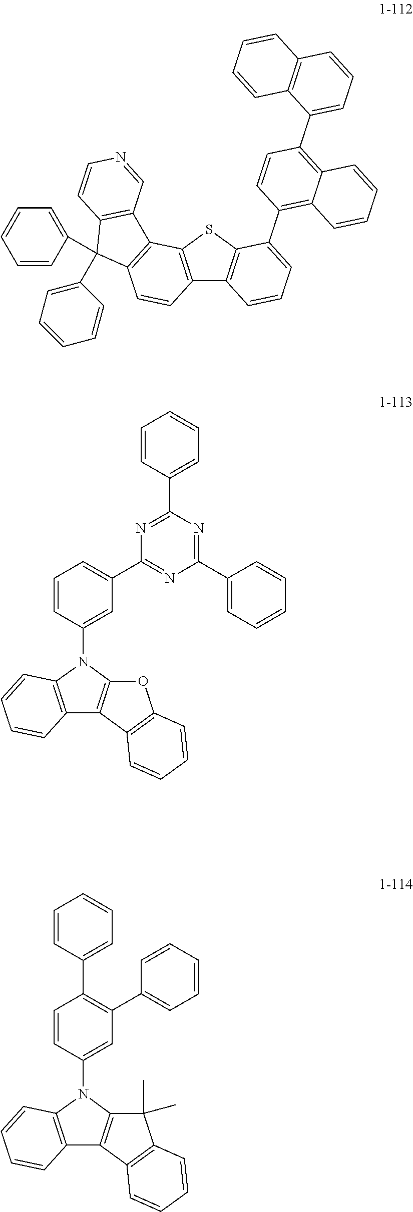 [SMILES: c1ccc(C2(c3ccccc3)c3ccncc3-c3c2ccc2c3sc3c(-c4ccc(-c5cccc6ccccc56)c5ccccc45)cccc32)cc1 ; c1ccc(-c2nc(-c3ccccc3)nc(-c3cccc(-n4c5ccccc5c5c6ccccc6oc54)c3)n2)cc1 ; CC1(C)c2ccccc2-c2c1n(-c1ccc(-c3ccccc3)c(-c3ccccc3)c1)c1ccccc21]

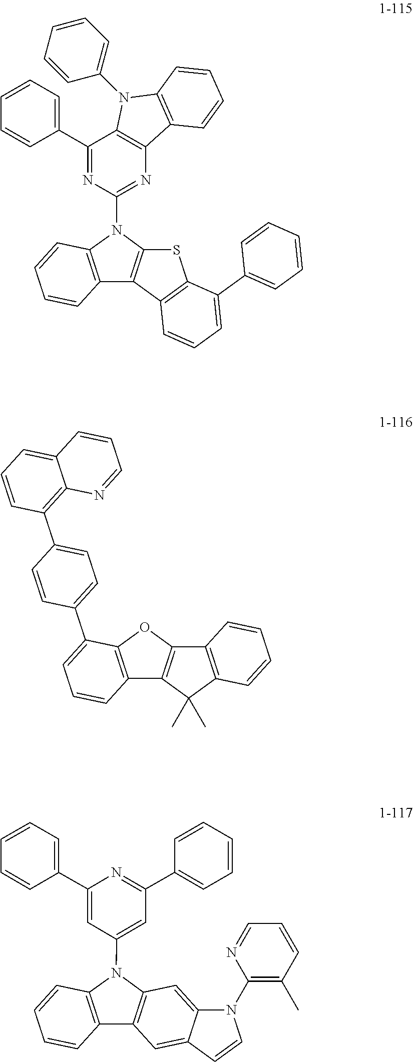 [SMILES: c1ccc(-c2cccc3c2sc2c3c3ccccc3n2-c2nc(-c3ccccc3)c3c(n2)c2ccccc2n3-c2ccccc2)cc1 ; CC1(C)c2ccccc2-c2oc3c(-c4ccc(-c5cccc6cccnc56)cc4)cccc3c21 ; Cc1cccnc1-n1ccc2cc3c4ccccc4n(-c4cc(-c5ccccc5)nc(-c5ccccc5)c4)c3cc21]

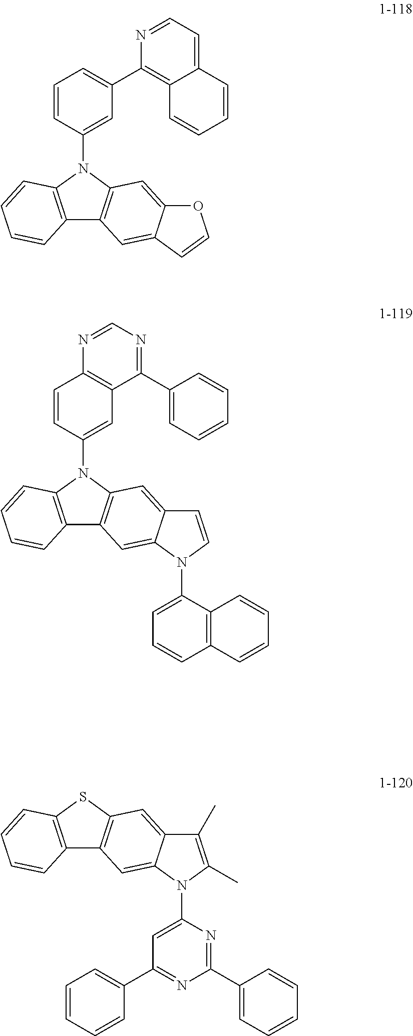 [SMILES: c1cc(-c2nccc3ccccc23)cc(-n2c3ccccc3c3cc4ccoc4cc32)c1 ; c1ccc(-c2ncnc3ccc(-n4c5ccccc5c5cc6c(ccn6-c6cccc7ccccc67)cc54)cc23)cc1 ; Cc1c(C)n(-c2cc(-c3ccccc3)nc(-c3ccccc3)n2)c2cc3c(cc12)sc1ccccc13]

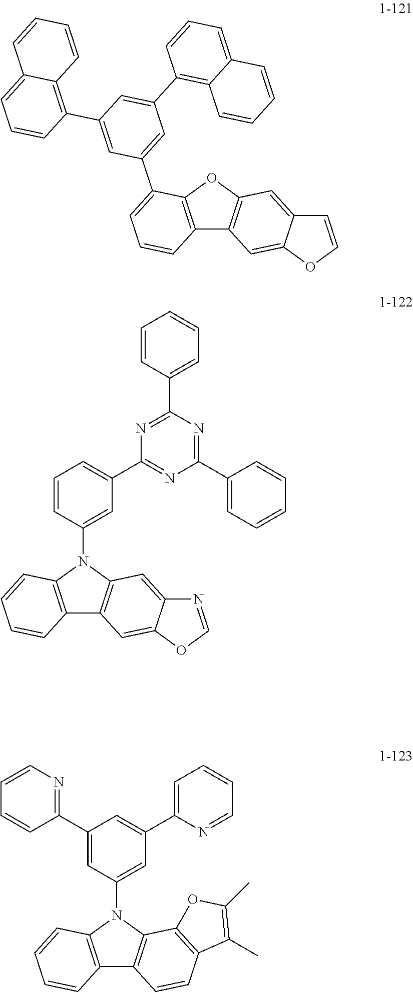 [SMILES: c1ccc2c(-c3cc(-c4cccc5ccccc45)cc(-c4cccc5c4oc4cc6ccoc6cc45)c3)cccc2c1 ; c1ccc(-c2nc(-c3ccccc3)nc(-c3cccc(-n4c5ccccc5c5cc6ocnc6cc54)c3)n2)cc1 ; Cc1oc2c(ccc3c4ccccc4n(-c4cc(-c5ccccn5)cc(-c5ccccn5)c4)c32)c1C]

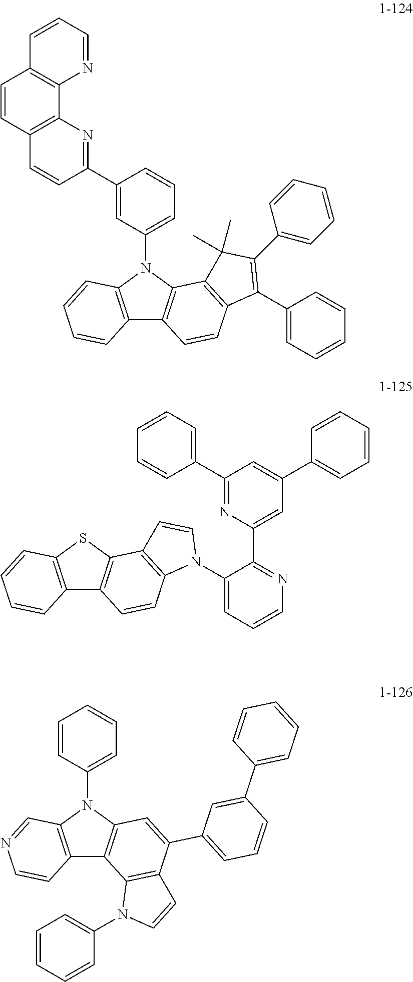 [SMILES: CC1(C)C(c2ccccc2)=C(c2ccccc2)c2ccc3c4ccccc4n(-c4cccc(-c5ccc6ccc7cccnc7c6n5)c4)c3c21 ; c1ccc(-c2cc(-c3ccccc3)nc(-c3ncccc3-n3ccc4c5sc6ccccc6c5ccc43)c2)cc1 ; c1ccc(-c2cccc(-c3cc4c(c5ccncc5n4-c4ccccc4)c4c3ccn4-c3ccccc3)c2)cc1]

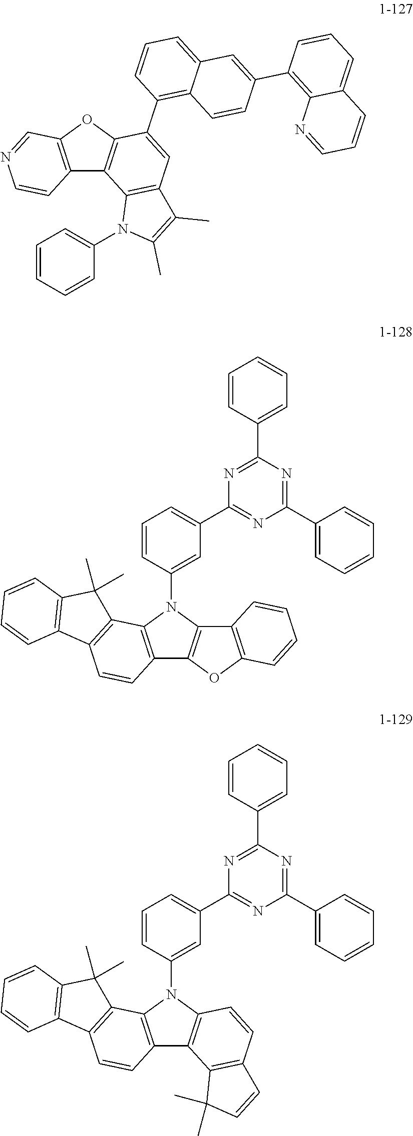 [SMILES: Cc1c(C)n(-c2ccccc2)c2c1cc(-c1cccc3cc(-c4cccc5cccnc45)ccc13)c1oc3cnccc3c12 ; CC1(C)c2ccccc2-c2ccc3c4oc5ccccc5c4n(-c4cccc(-c5nc(-c6ccccc6)nc(-c6ccccc6)n5)c4)c3c21 ; CC1(C)C=Cc2ccc3c(c21)c1ccc2c(c1n3-c1cccc(-c3nc(-c4ccccc4)nc(-c4ccccc4)n3)c1)C(C)(C)c1ccccc1-2]

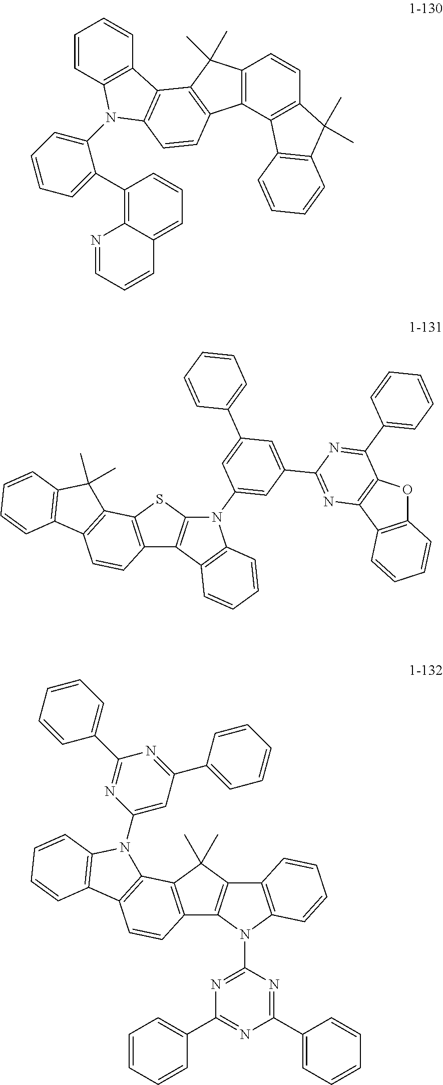 [SMILES: CC1(C)c2ccccc2-c2c1ccc1c2-c2ccc3c(c2C1(C)C)c1ccccc1n3-c1ccccc1-c1cccc2cccnc12 ; CC1(C)c2ccccc2-c2ccc3c(sc4c3c3ccccc3n4-c3cc(-c4ccccc4)cc(-c4nc(-c5ccccc5)c5oc6ccccc6c5n4)c3)c21 ; CC1(C)c2c(n(-c3nc(-c4ccccc4)nc(-c4ccccc4)n3)c3ccccc23)-c2ccc3c4ccccc4n(-c4cc(-c5ccccc5)nc(-c5ccccc5)n4)c3c21]

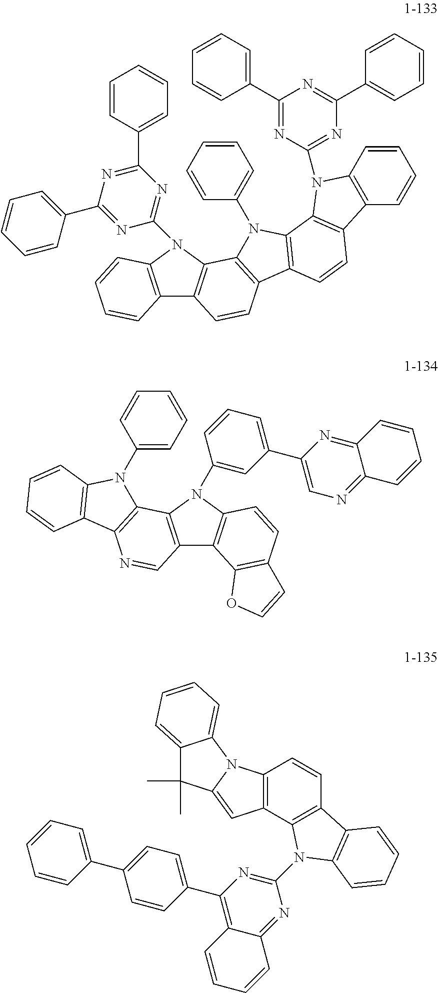 [SMILES: c1ccc(-c2nc(-c3ccccc3)nc(-n3c4ccccc4c4ccc5c6ccc7c8ccccc8n(-c8nc(-c9ccccc9)nc(-c9ccccc9)n8)c7c6n(-c6ccccc6)c5c43)n2)cc1 ; c1ccc(-n2c3ccccc3c3ncc4c5c6occc6ccc5n(-c5cccc(-c6cnc7ccccc7n6)c5)c4c32)cc1 ; CC1(C)c2ccccc2-n2c1cc1c2ccc2c3ccccc3n(-c3nc(-c4ccc(-c5ccccc5)cc4)c4ccccc4n3)c21]

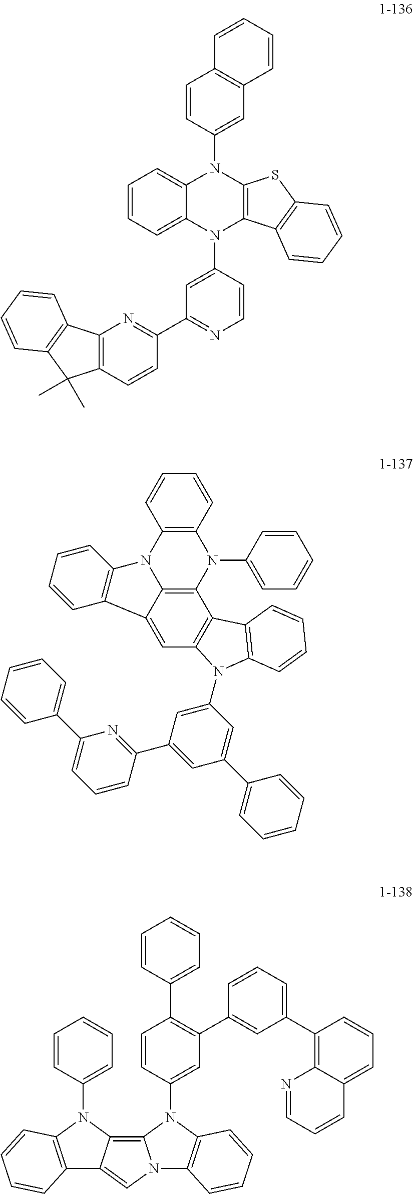 [SMILES: CC1(C)c2ccccc2-c2nc(-c3cc(N4c5ccccc5N(c5ccc6ccccc6c5)c5sc6ccccc6c54)ccn3)ccc21 ; c1ccc(-c2cc(-c3cccc(-c4ccccc4)n3)cc(-n3c4ccccc4c4c5c6c(cc43)c3ccccc3n6-c3ccccc3N5c3ccccc3)c2)cc1 ; c1ccc(-c2ccc(-n3c4ccccc4n4cc5c6ccccc6n(-c6ccccc6)c5c34)cc2-c2cccc(-c3cccc4cccnc34)c2)cc1]

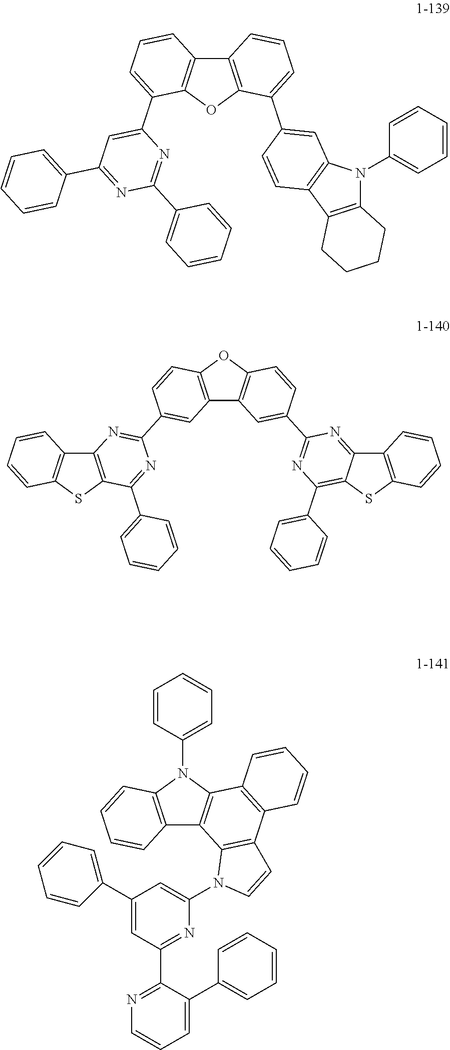 [SMILES: c1ccc(-c2cc(-c3cccc4c3oc3c(-c5ccc6c7c(n(-c8ccccc8)c6c5)CCCC7)cccc34)nc(-c3ccccc3)n2)cc1 ; c1ccc(-c2nc(-c3ccc4oc5ccc(-c6nc(-c7ccccc7)c7sc8ccccc8c7n6)cc5c4c3)nc3c2sc2ccccc23)cc1 ; c1ccc(-c2cc(-c3ncccc3-c3ccccc3)nc(-n3ccc4c5ccccc5c5c(c6ccccc6n5-c5ccccc5)c43)c2)cc1]

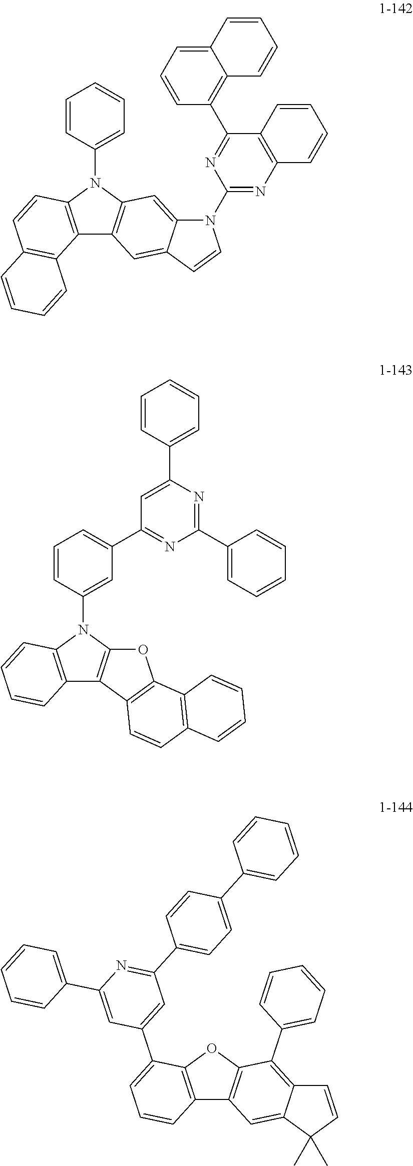 [SMILES: c1ccc(-n2c3cc4c(ccn4-c4nc(-c5cccc6ccccc56)c5ccccc5n4)cc3c3c4ccccc4ccc32)cc1 ; c1ccc(-c2cc(-c3cccc(-n4c5ccccc5c5c6ccc7ccccc7c6oc54)c3)nc(-c3ccccc3)n2)cc1 ; CC1(C)C=Cc2c1cc1c(oc3c(-c4cc(-c5ccccc5)nc(-c5ccc(-c6ccccc6)cc5)c4)cccc31)c2-c1ccccc1]

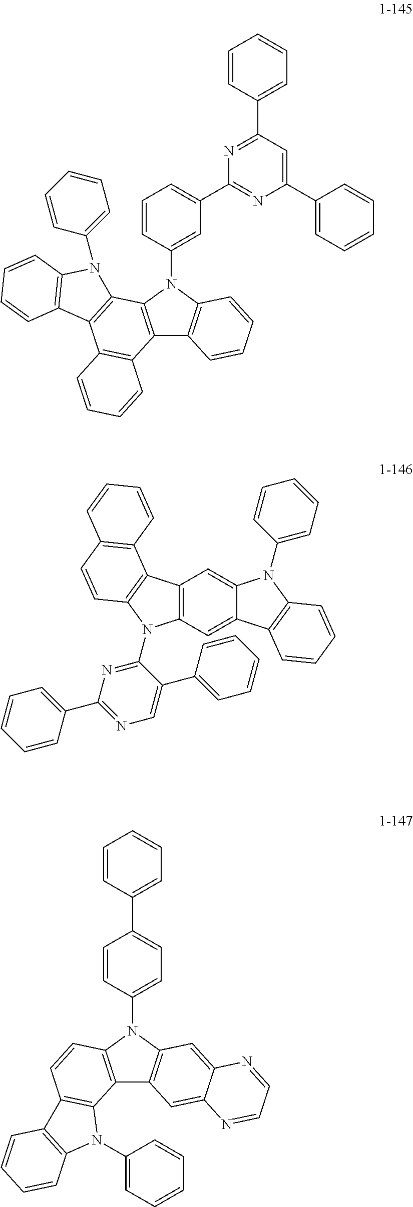 [SMILES: c1ccc(-c2cc(-c3ccccc3)nc(-c3cccc(-n4c5ccccc5c5c6ccccc6c6c7ccccc7n(-c7ccccc7)c6c54)c3)n2)cc1 ; c1ccc(-c2ncc(-c3ccccc3)c(-n3c4cc5c6ccccc6n(-c6ccccc6)c5cc4c4c5ccccc5ccc43)n2)cc1 ; c1ccc(-c2ccc(-n3c4cc5nccnc5cc4c4c3ccc3c5ccccc5n(-c5ccccc5)c34)cc2)cc1]

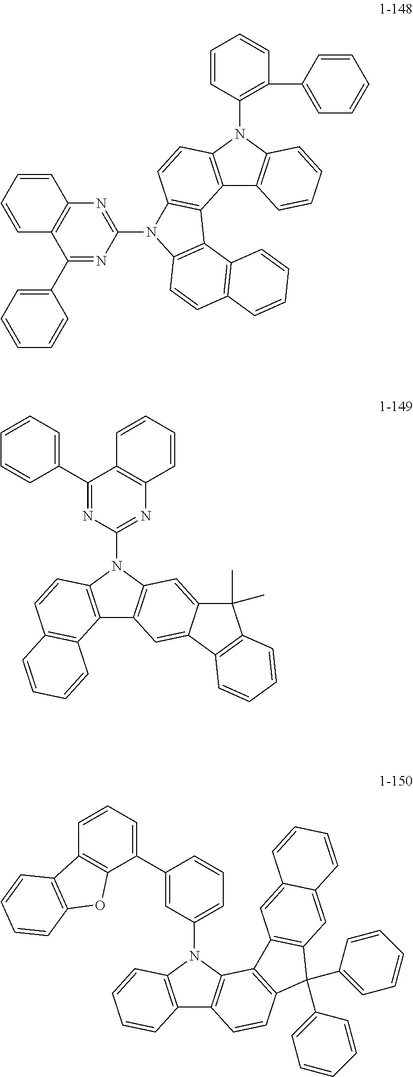 [SMILES: c1ccc(-c2ccccc2-n2c3ccccc3c3c4c5c6ccccc6ccc5n(-c5nc(-c6ccccc6)c6ccccc6n5)c4ccc32)cc1 ; CC1(C)c2ccccc2-c2cc3c4c5ccccc5ccc4n(-c4nc(-c5ccccc5)c5ccccc5n4)c3cc21 ; c1ccc(C2(c3ccccc3)c3cc4ccccc4cc3-c3c2ccc2c4ccccc4n(-c4cccc(-c5cccc6c5oc5ccccc56)c4)c32)cc1]

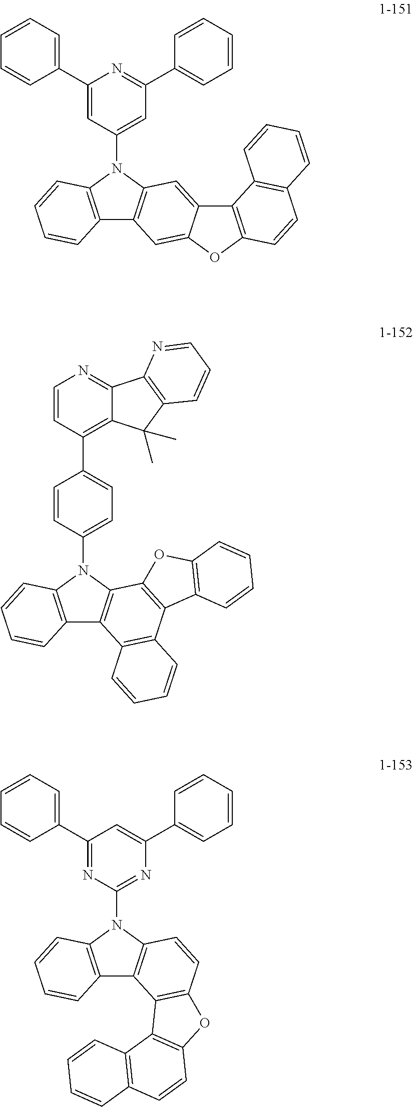 [SMILES: c1ccc(-c2cc(-n3c4ccccc4c4cc5oc6ccc7ccccc7c6c5cc43)cc(-c3ccccc3)n2)cc1 ; CC1(C)c2cccnc2-c2nccc(-c3ccc(-n4c5ccccc5c5c6ccccc6c6c7ccccc7oc6c54)cc3)c21 ; c1ccc(-c2cc(-c3ccccc3)nc(-n3c4ccccc4c4c5c(ccc43)oc3ccc4ccccc4c35)n2)cc1]

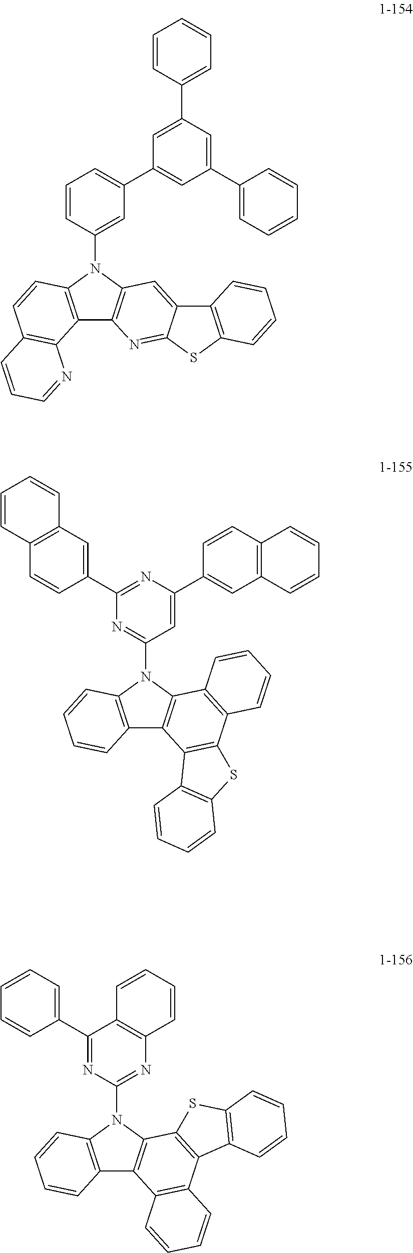 [SMILES: c1ccc(-c2cc(-c3ccccc3)cc(-c3cccc(-n4c5cc6c(nc5c5c7ncccc7ccc54)sc4ccccc46)c3)c2)cc1 ; c1ccc2cc(-c3cc(-n4c5ccccc5c5c6c7ccccc7sc6c6ccccc6c54)nc(-c4ccc5ccccc5c4)n3)ccc2c1 ; c1ccc(-c2nc(-n3c4ccccc4c4c5ccccc5c5c6ccccc6sc5c43)nc3ccccc23)cc1]

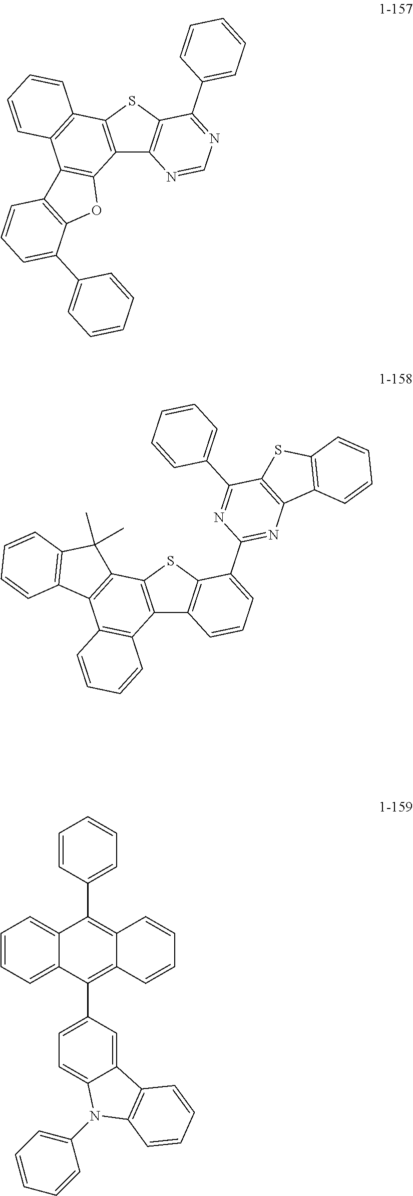 [SMILES: c1ccc(-c2cccc3c2oc2c3c3ccccc3c3sc4c(-c5ccccc5)ncnc4c23)cc1 ; CC1(C)c2ccccc2-c2c1c1sc3c(-c4nc(-c5ccccc5)c5sc6ccccc6c5n4)cccc3c1c1ccccc21 ; c1ccc(-c2c3ccccc3c(-c3ccc4c(c3)c3ccccc3n4-c3ccccc3)c3ccccc23)cc1]

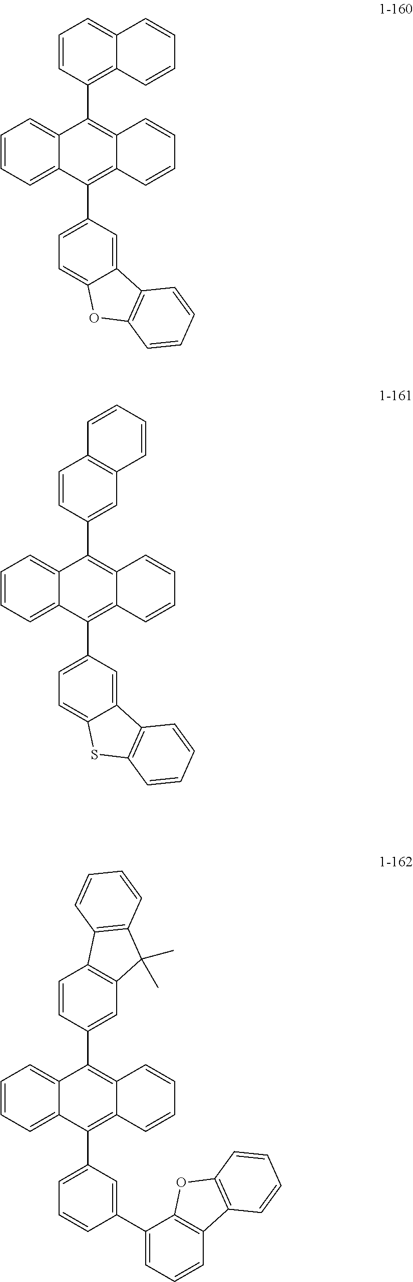 [SMILES: c1ccc2c(-c3c4ccccc4c(-c4ccc5oc6ccccc6c5c4)c4ccccc34)cccc2c1 ; c1ccc2cc(-c3c4ccccc4c(-c4ccc5sc6ccccc6c5c4)c4ccccc34)ccc2c1 ; CC1(C)c2ccccc2-c2ccc(-c3c4ccccc4c(-c4cccc(-c5cccc6c5oc5ccccc56)c4)c4ccccc34)cc21]

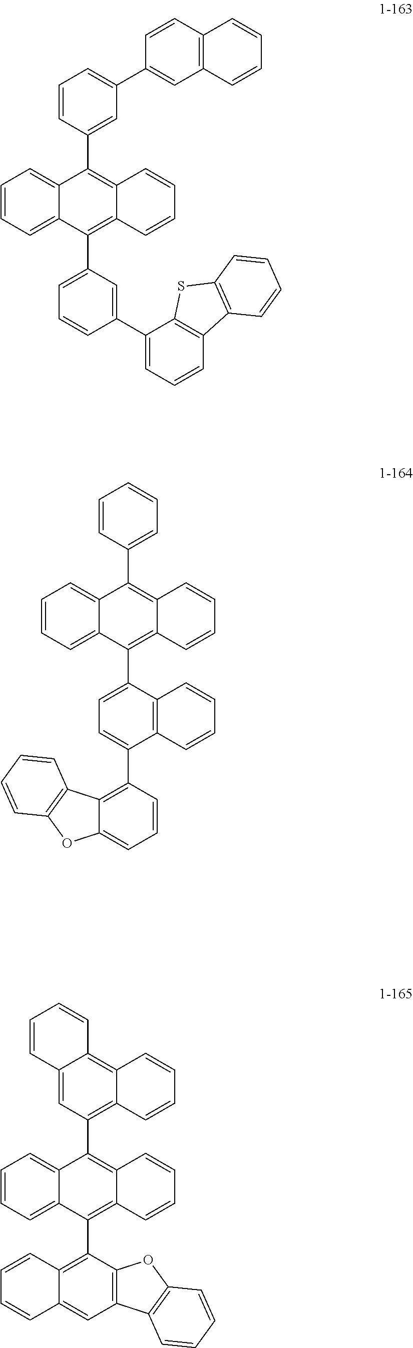 [SMILES: c1cc(-c2ccc3ccccc3c2)cc(-c2c3ccccc3c(-c3cccc(-c4cccc5c4sc4ccccc45)c3)c3ccccc23)c1 ; c1ccc(-c2c3ccccc3c(-c3ccc(-c4cccc5oc6ccccc6c45)c4ccccc34)c3ccccc23)cc1 ; c1ccc2c(-c3c4ccccc4c(-c4cc5ccccc5c5ccccc45)c4ccccc34)c3oc4ccccc4c3cc2c1]

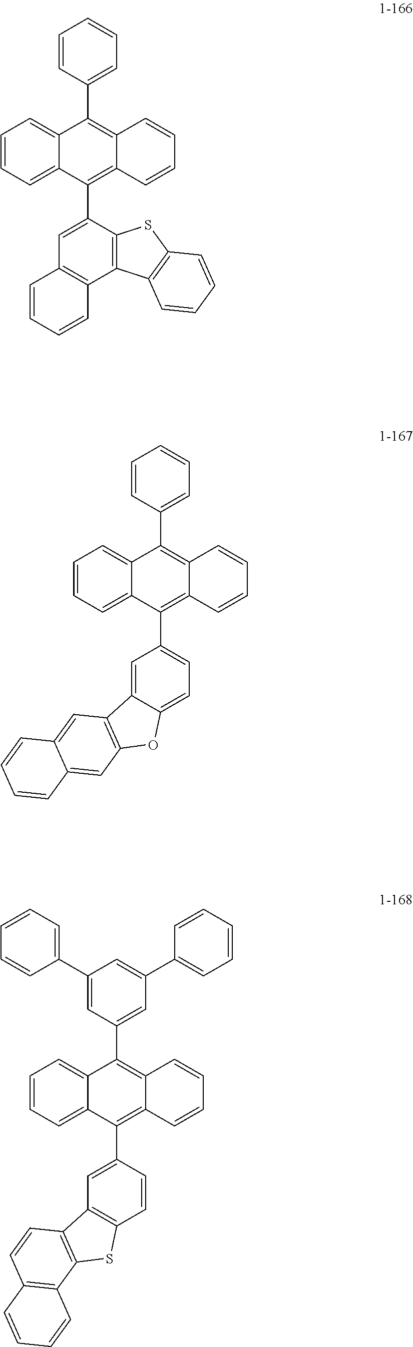 [SMILES: c1ccc(-c2c3ccccc3c(-c3cc4ccccc4c4c3sc3ccccc34)c3ccccc23)cc1 ; c1ccc(-c2c3ccccc3c(-c3ccc4oc5cc6ccccc6cc5c4c3)c3ccccc23)cc1 ; c1ccc(-c2cc(-c3ccccc3)cc(-c3c4ccccc4c(-c4ccc5sc6c7ccccc7ccc6c5c4)c4ccccc34)c2)cc1]

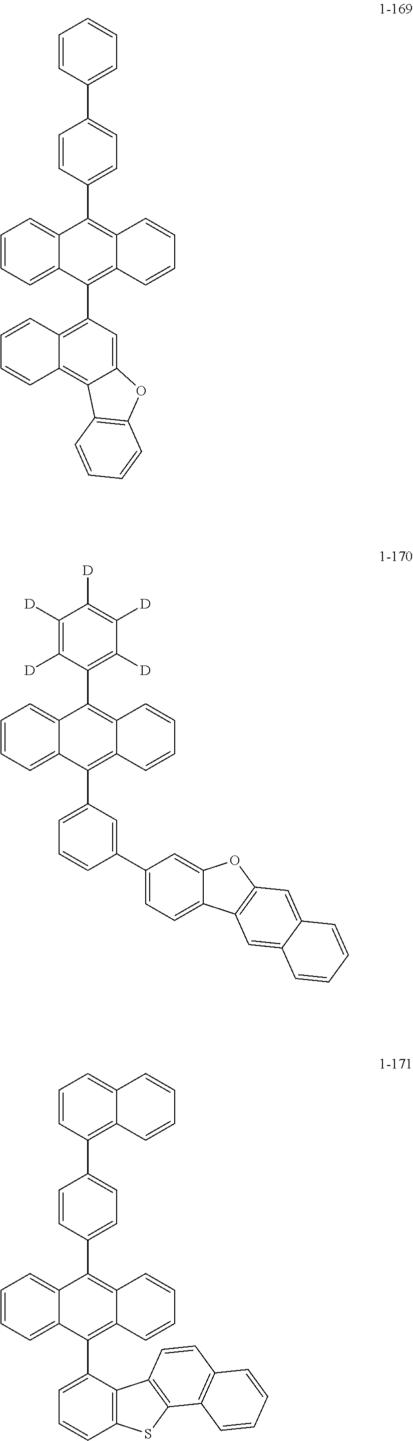 [SMILES: c1ccc(-c2ccc(-c3c4ccccc4c(-c4cc5oc6ccccc6c5c5ccccc45)c4ccccc34)cc2)cc1 ; [2H]c1c([2H])c([2H])c(-c2c3ccccc3c(-c3cccc(-c4ccc5c(c4)oc4cc6ccccc6cc45)c3)c3ccccc23)c([2H])c1[2H] ; c1ccc2c(-c3ccc(-c4c5ccccc5c(-c5cccc6sc7c8ccccc8ccc7c56)c5ccccc45)cc3)cccc2c1]

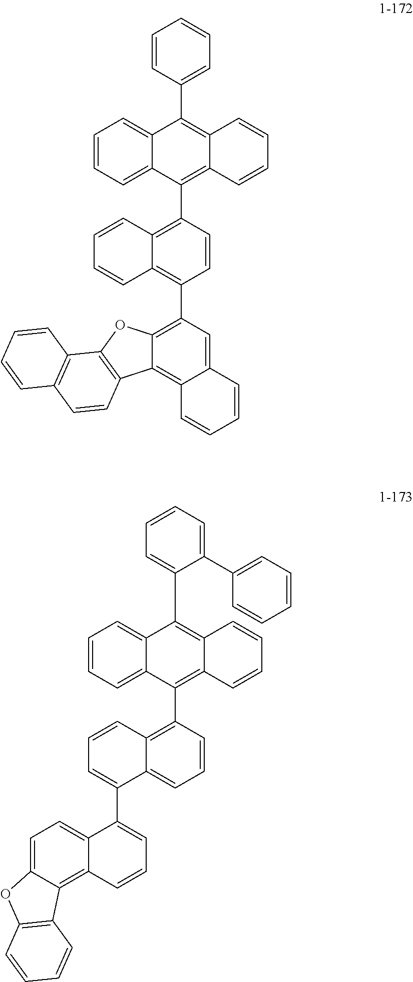 [SMILES: c1ccc(-c2c3ccccc3c(-c3ccc(-c4cc5ccccc5c5c4oc4c6ccccc6ccc45)c4ccccc34)c3ccccc23)cc1 ; c1ccc(-c2ccccc2-c2c3ccccc3c(-c3cccc4c(-c5cccc6c5ccc5oc7ccccc7c56)cccc34)c3ccccc23)cc1]

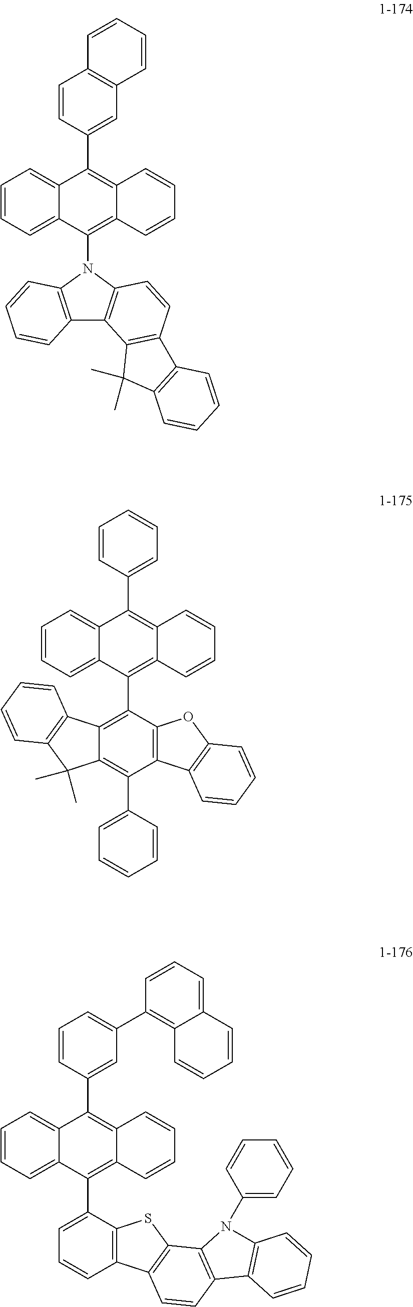 [SMILES: CC1(C)c2ccccc2-c2ccc3c(c21)c1ccccc1n3-c1c2ccccc2c(-c2ccc3ccccc3c2)c2ccccc12 ; CC1(C)c2ccccc2-c2c1c(-c1ccccc1)c1c(oc3ccccc31)c2-c1c2ccccc2c(-c2ccccc2)c2ccccc12 ; c1ccc(-n2c3ccccc3c3ccc4c5cccc(-c6c7ccccc7c(-c7cccc(-c8cccc9ccccc89)c7)c7ccccc67)c5sc4c32)cc1]

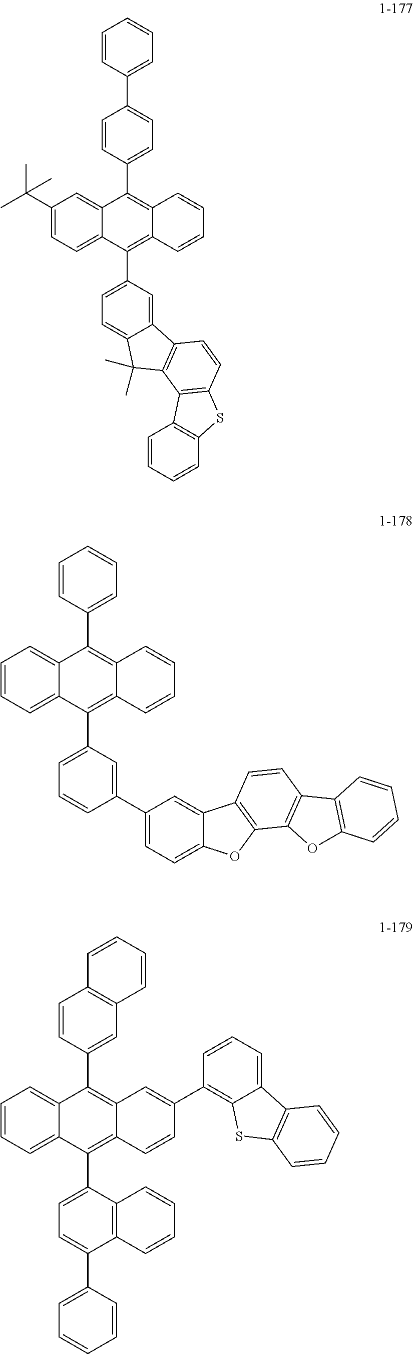 [SMILES: CC(C)(C)c1ccc2c(-c3ccc4c(c3)-c3ccc5sc6ccccc6c5c3C4(C)C)c3ccccc3c(-c3ccc(-c4ccccc4)cc3)c2c1 ; c1ccc(-c2c3ccccc3c(-c3cccc(-c4ccc5oc6c(ccc7c8ccccc8oc76)c5c4)c3)c3ccccc23)cc1 ; c1ccc(-c2ccc(-c3c4ccccc4c(-c4ccc5ccccc5c4)c4cc(-c5cccc6c5sc5ccccc56)ccc34)c3ccccc23)cc1]

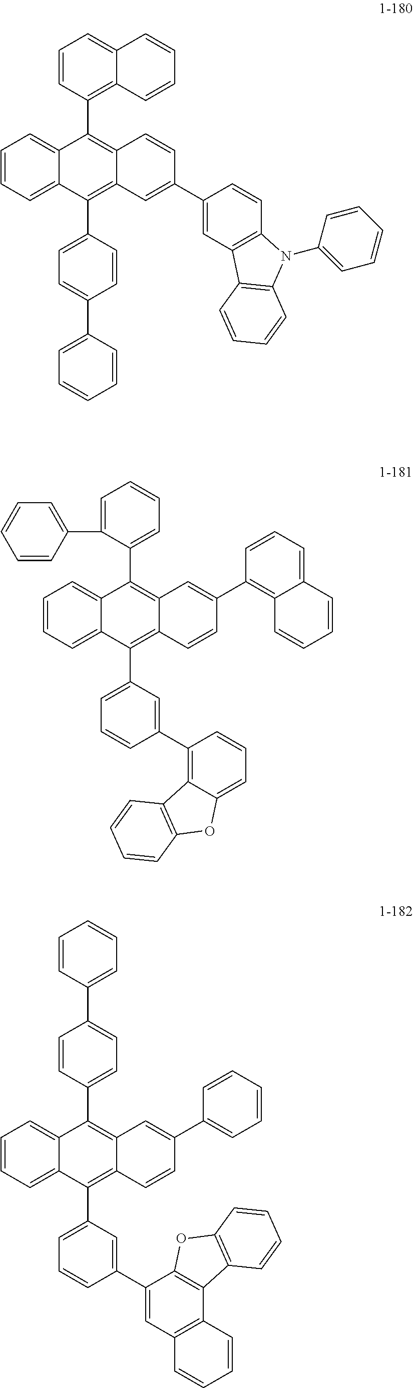 [SMILES: c1ccc(-c2ccc(-c3c4ccccc4c(-c4cccc5ccccc45)c4ccc(-c5ccc6c(c5)c5ccccc5n6-c5ccccc5)cc34)cc2)cc1 ; c1ccc(-c2ccccc2-c2c3ccccc3c(-c3cccc(-c4cccc5oc6ccccc6c45)c3)c3ccc(-c4cccc5ccccc45)cc23)cc1 ; c1ccc(-c2ccc(-c3c4ccccc4c(-c4cccc(-c5cc6ccccc6c6c5oc5ccccc56)c4)c4ccc(-c5ccccc5)cc34)cc2)cc1]

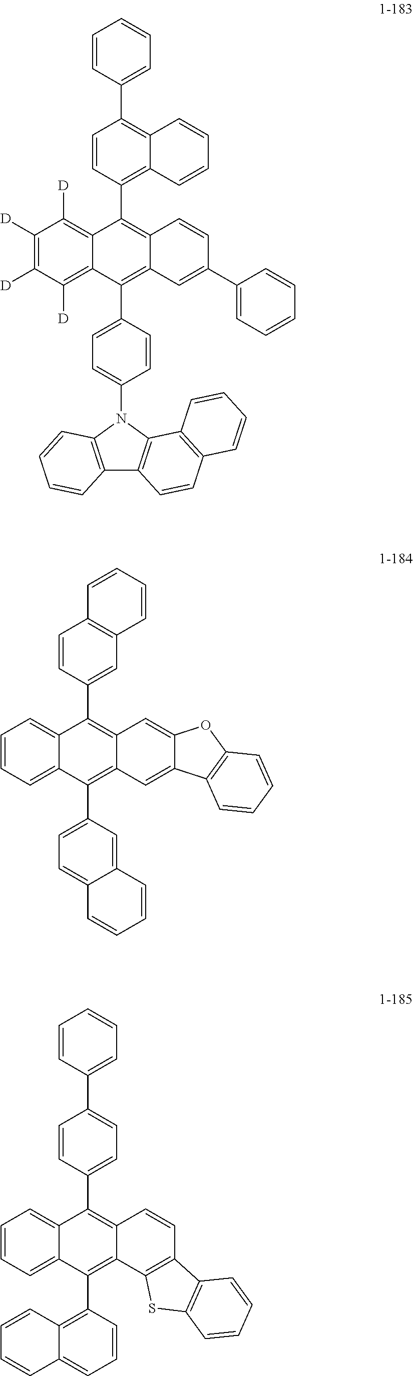 [SMILES: [2H]c1c([2H])c([2H])c2c(-c3ccc(-c4ccccc4)c4ccccc34)c3ccc(-c4ccccc4)cc3c(-c3ccc(-n4c5ccccc5c5ccc6ccccc6c54)cc3)c2c1[2H] ; c1ccc2cc(-c3c4ccccc4c(-c4ccc5ccccc5c4)c4cc5c(cc34)oc3ccccc35)ccc2c1 ; c1ccc(-c2ccc(-c3c4ccccc4c(-c4cccc5ccccc45)c4c3ccc3c5ccccc5sc34)cc2)cc1]

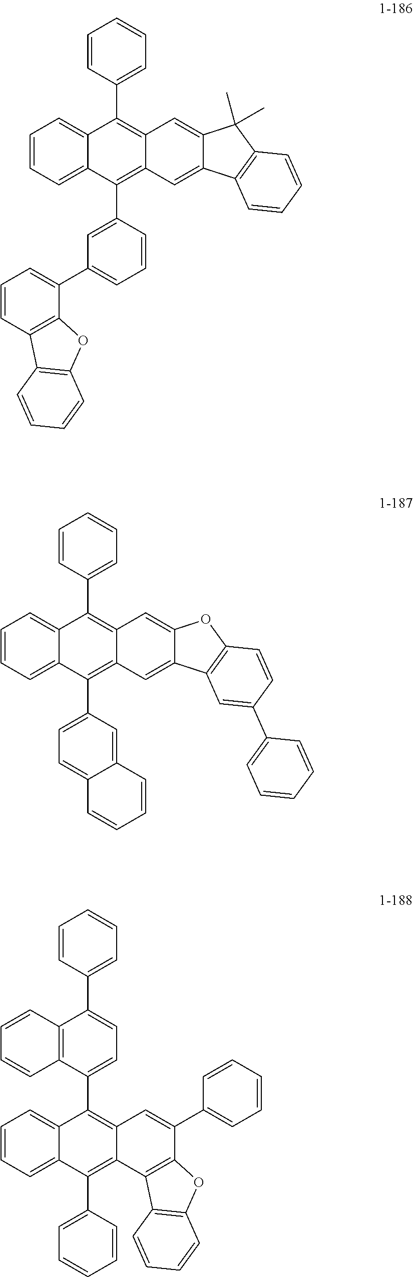 [SMILES: CC1(C)c2ccccc2-c2cc3c(-c4cccc(-c5cccc6c5oc5ccccc56)c4)c4ccccc4c(-c4ccccc4)c3cc21 ; c1ccc(-c2ccc3oc4cc5c(-c6ccccc6)c6ccccc6c(-c6ccc7ccccc7c6)c5cc4c3c2)cc1 ; c1ccc(-c2ccc(-c3c4ccccc4c(-c4ccccc4)c4c3cc(-c3ccccc3)c3oc5ccccc5c34)c3ccccc23)cc1]

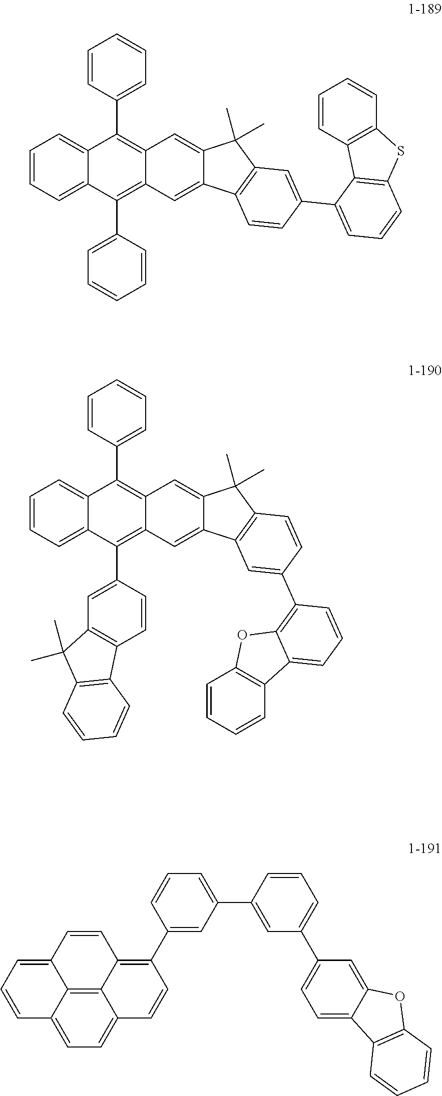 [SMILES: CC1(C)c2cc(-c3cccc4sc5ccccc5c34)ccc2-c2cc3c(-c4ccccc4)c4ccccc4c(-c4ccccc4)c3cc21 ; CC1(C)c2ccccc2-c2ccc(-c3c4ccccc4c(-c4ccccc4)c4cc5c(cc34)-c3cc(-c4cccc6c4oc4ccccc46)ccc3C5(C)C)cc21 ; c1cc(-c2cccc(-c3ccc4ccc5cccc6ccc3c4c56)c2)cc(-c2ccc3c(c2)oc2ccccc23)c1]

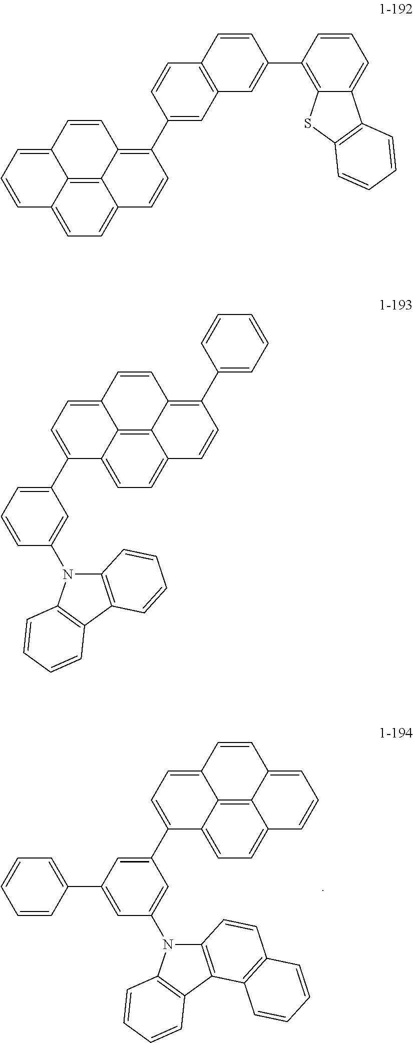 [SMILES: c1cc2ccc3ccc(-c4ccc5ccc(-c6cccc7c6sc6ccccc67)cc5c4)c4ccc(c1)c2c34 ; c1ccc(-c2ccc3ccc4c(-c5cccc(-n6c7ccccc7c7ccccc76)c5)ccc5ccc2c3c54)cc1 ; c1ccc(-c2cc(-c3ccc4ccc5cccc6ccc3c4c56)cc(-n3c4ccccc4c4c5ccccc5ccc43)c2)cc1]

In various embodiments, the second compound may be selected from Compounds 2-1a to 2-172a and 2-1 to 2-262, but embodiments of the present disclosure are not limited thereto:

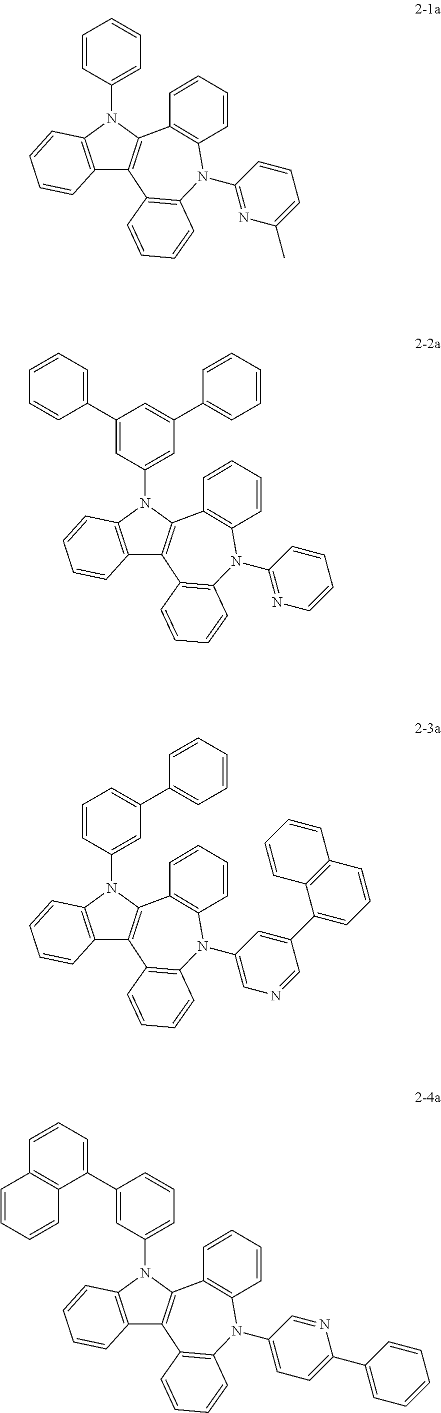 [SMILES: Cc1cccc(N2c3ccccc3-c3c(n(-c4ccccc4)c4ccccc34)-c3ccccc32)n1 ; c1ccc(-c2cc(-c3ccccc3)cc(-n3c4c(c5ccccc53)-c3ccccc3N(c3ccccn3)c3ccccc3-4)c2)cc1 ; c1ccc(-c2cccc(-n3c4c(c5ccccc53)-c3ccccc3N(c3cncc(-c5cccc6ccccc56)c3)c3ccccc3-4)c2)cc1 ; c1ccc(-c2ccc(N3c4ccccc4-c4c(n(-c5cccc(-c6cccc7ccccc67)c5)c5ccccc45)-c4ccccc43)cn2)cc1]

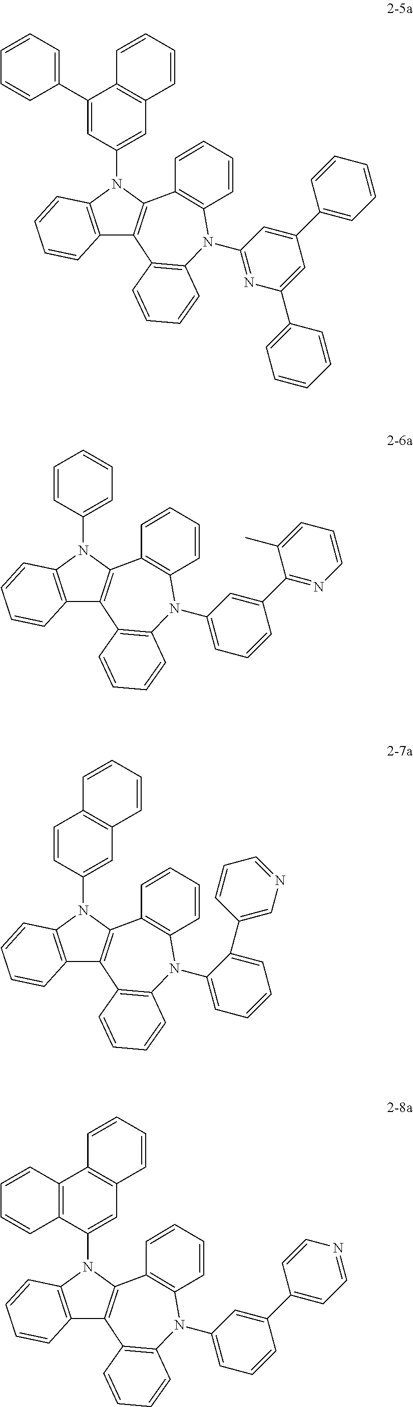 [SMILES: c1ccc(-c2cc(-c3ccccc3)nc(N3c4ccccc4-c4c(n(-c5cc(-c6ccccc6)c6ccccc6c5)c5ccccc45)-c4ccccc43)c2)cc1 ; Cc1cccnc1-c1cccc(N2c3ccccc3-c3c(n(-c4ccccc4)c4ccccc34)-c3ccccc32)c1 ; c1cncc(-c2ccccc2N2c3ccccc3-c3c(n(-c4ccc5ccccc5c4)c4ccccc34)-c3ccccc32)c1 ; c1cc(-c2ccncc2)cc(N2c3ccccc3-c3c(n(-c4cc5ccccc5c5ccccc45)c4ccccc34)-c3ccccc32)c1]

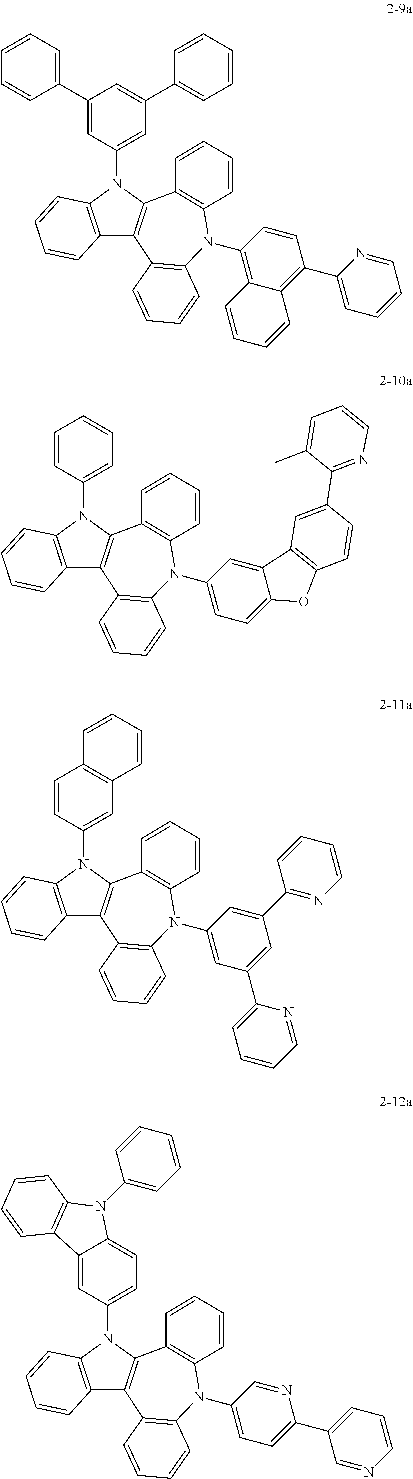 [SMILES: c1ccc(-c2cc(-c3ccccc3)cc(-n3c4c(c5ccccc53)-c3ccccc3N(c3ccc(-c5ccccn5)c5ccccc35)c3ccccc3-4)c2)cc1 ; Cc1cccnc1-c1ccc2oc3ccc(N4c5ccccc5-c5c(n(-c6ccccc6)c6ccccc56)-c5ccccc54)cc3c2c1 ; c1ccc(-c2cc(-c3ccccn3)cc(N3c4ccccc4-c4c(n(-c5ccc6ccccc6c5)c5ccccc45)-c4ccccc43)c2)nc1 ; c1ccc(-n2c3ccccc3c3cc(-n4c5c(c6ccccc64)-c4ccccc4N(c4ccc(-c6cccnc6)nc4)c4ccccc4-5)ccc32)cc1]

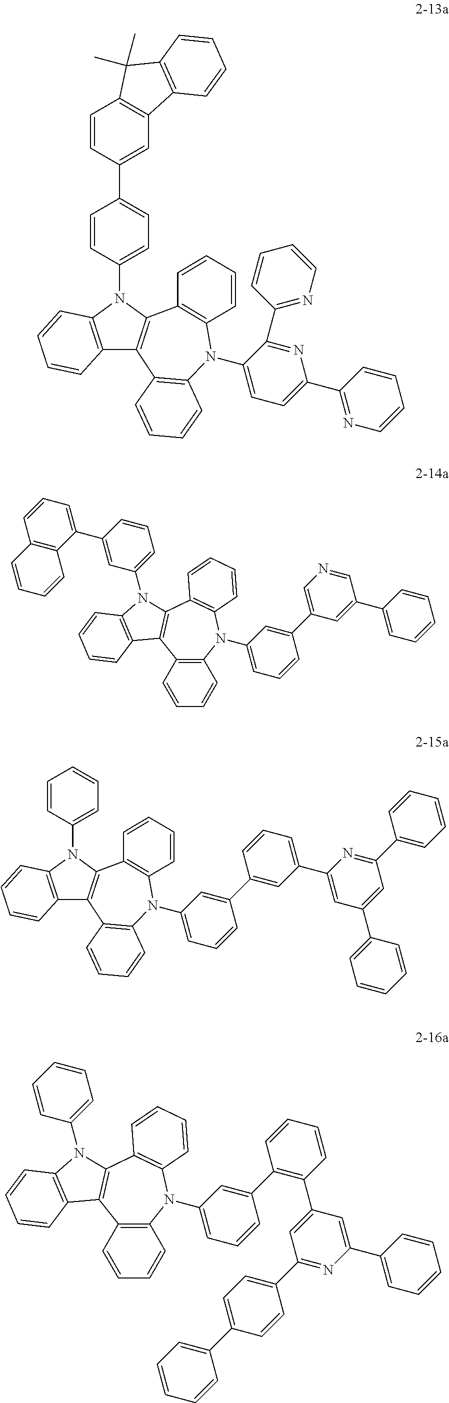 [SMILES: CC1(C)c2ccccc2-c2cc(-c3ccc(-n4c5c(c6ccccc64)-c4ccccc4N(c4ccc(-c6ccccn6)nc4-c4ccccn4)c4ccccc4-5)cc3)ccc21 ; c1ccc(-c2cncc(-c3cccc(N4c5ccccc5-c5c(n(-c6cccc(-c7cccc8ccccc78)c6)c6ccccc56)-c5ccccc54)c3)c2)cc1 ; c1ccc(-c2cc(-c3ccccc3)nc(-c3cccc(-c4cccc(N5c6ccccc6-c6c(n(-c7ccccc7)c7ccccc67)-c6ccccc65)c4)c3)c2)cc1 ; c1ccc(-c2ccc(-c3cc(-c4ccccc4-c4cccc(N5c6ccccc6-c6c(n(-c7ccccc7)c7ccccc67)-c6ccccc65)c4)cc(-c4ccccc4)n3)cc2)cc1]

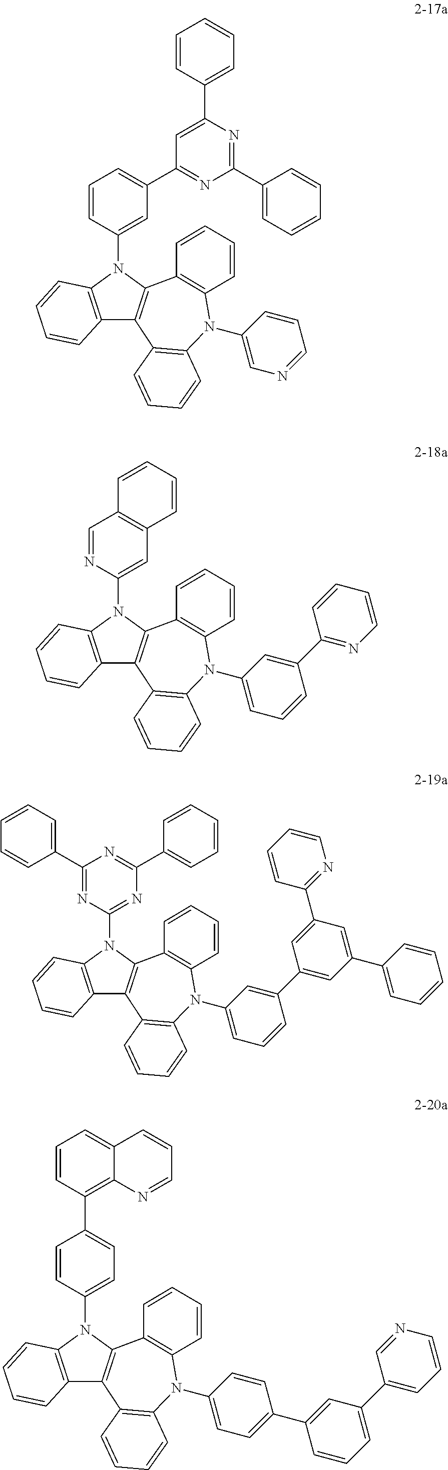 [SMILES: c1ccc(-c2cc(-c3cccc(-n4c5c(c6ccccc64)-c4ccccc4N(c4cccnc4)c4ccccc4-5)c3)nc(-c3ccccc3)n2)cc1 ; c1ccc(-c2cccc(N3c4ccccc4-c4c(n(-c5cc6ccccc6cn5)c5ccccc45)-c4ccccc43)c2)nc1 ; c1ccc(-c2cc(-c3cccc(N4c5ccccc5-c5c(n(-c6nc(-c7ccccc7)nc(-c7ccccc7)n6)c6ccccc56)-c5ccccc54)c3)cc(-c3ccccn3)c2)cc1 ; c1cncc(-c2cccc(-c3ccc(N4c5ccccc5-c5c(n(-c6ccc(-c7cccc8cccnc78)cc6)c6ccccc56)-c5ccccc54)cc3)c2)c1]

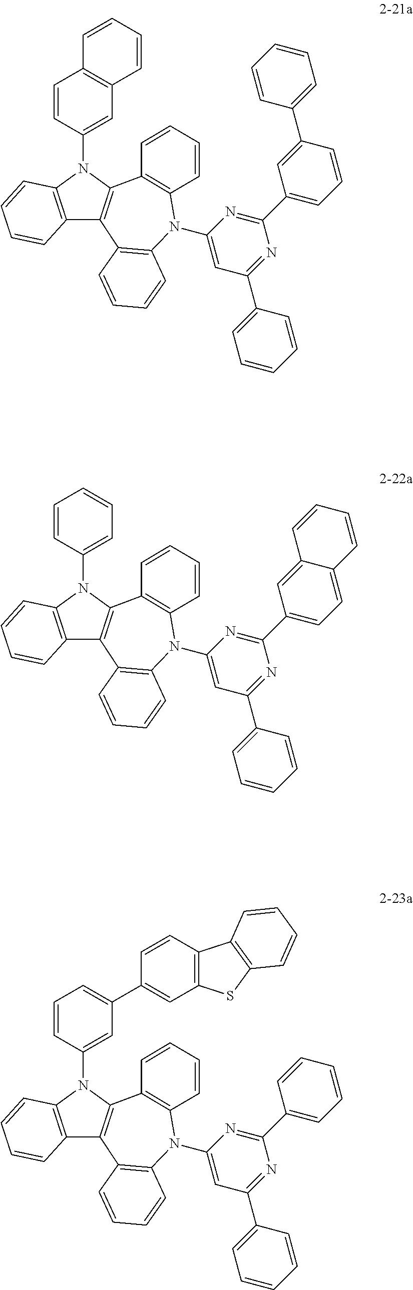 [SMILES: c1ccc(-c2cccc(-c3nc(-c4ccccc4)cc(N4c5ccccc5-c5c(n(-c6ccc7ccccc7c6)c6ccccc56)-c5ccccc54)n3)c2)cc1 ; c1ccc(-c2cc(N3c4ccccc4-c4c(n(-c5ccccc5)c5ccccc45)-c4ccccc43)nc(-c3ccc4ccccc4c3)n2)cc1 ; c1ccc(-c2cc(N3c4ccccc4-c4c(n(-c5cccc(-c6ccc7c(c6)sc6ccccc67)c5)c5ccccc45)-c4ccccc43)nc(-c3ccccc3)n2)cc1]

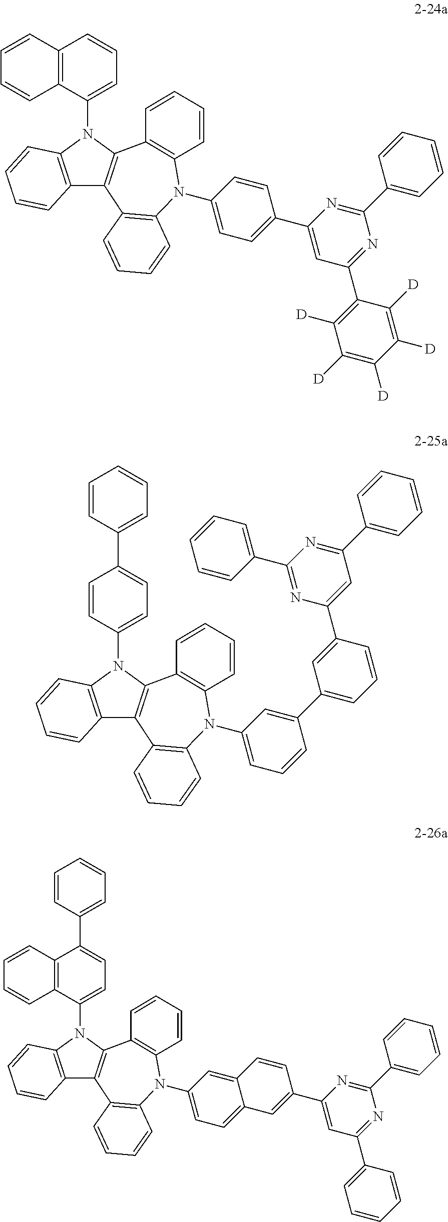 [SMILES: [2H]c1c([2H])c([2H])c(-c2cc(-c3ccc(N4c5ccccc5-c5c(n(-c6cccc7ccccc67)c6ccccc56)-c5ccccc54)cc3)nc(-c3ccccc3)n2)c([2H])c1[2H] ; c1ccc(-c2ccc(-n3c4c(c5ccccc53)-c3ccccc3N(c3cccc(-c5cccc(-c6cc(-c7ccccc7)nc(-c7ccccc7)n6)c5)c3)c3ccccc3-4)cc2)cc1 ; c1ccc(-c2cc(-c3ccc4cc(N5c6ccccc6-c6c(n(-c7ccc(-c8ccccc8)c8ccccc78)c7ccccc67)-c6ccccc65)ccc4c3)nc(-c3ccccc3)n2)cc1]

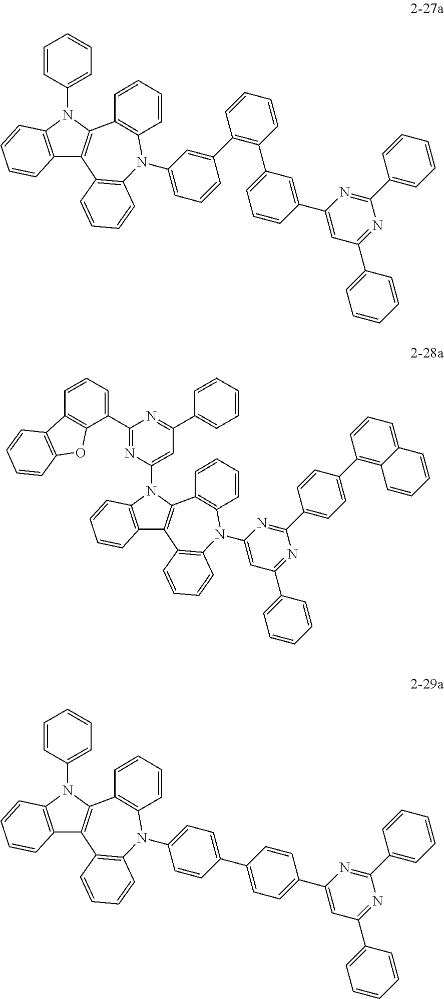 [SMILES: c1ccc(-c2cc(-c3cccc(-c4ccccc4-c4cccc(N5c6ccccc6-c6c(n(-c7ccccc7)c7ccccc67)-c6ccccc65)c4)c3)nc(-c3ccccc3)n2)cc1 ; c1ccc(-c2cc(N3c4ccccc4-c4c(n(-c5cc(-c6ccccc6)nc(-c6cccc7c6oc6ccccc67)n5)c5ccccc45)-c4ccccc43)nc(-c3ccc(-c4cccc5ccccc45)cc3)n2)cc1 ; c1ccc(-c2cc(-c3ccc(-c4ccc(N5c6ccccc6-c6c(n(-c7ccccc7)c7ccccc67)-c6ccccc65)cc4)cc3)nc(-c3ccccc3)n2)cc1]

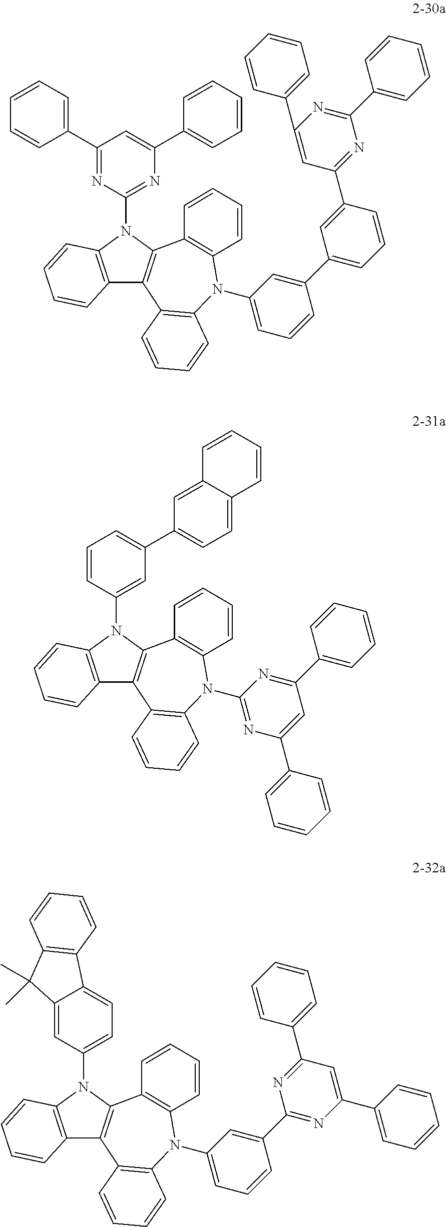 [SMILES: c1ccc(-c2cc(-c3cccc(-c4cccc(N5c6ccccc6-c6c(n(-c7nc(-c8ccccc8)cc(-c8ccccc8)n7)c7ccccc67)-c6ccccc65)c4)c3)nc(-c3ccccc3)n2)cc1 ; c1ccc(-c2cc(-c3ccccc3)nc(N3c4ccccc4-c4c(n(-c5cccc(-c6ccc7ccccc7c6)c5)c5ccccc45)-c4ccccc43)n2)cc1 ; CC1(C)c2ccccc2-c2ccc(-n3c4c(c5ccccc53)-c3ccccc3N(c3cccc(-c5nc(-c6ccccc6)cc(-c6ccccc6)n5)c3)c3ccccc3-4)cc21]

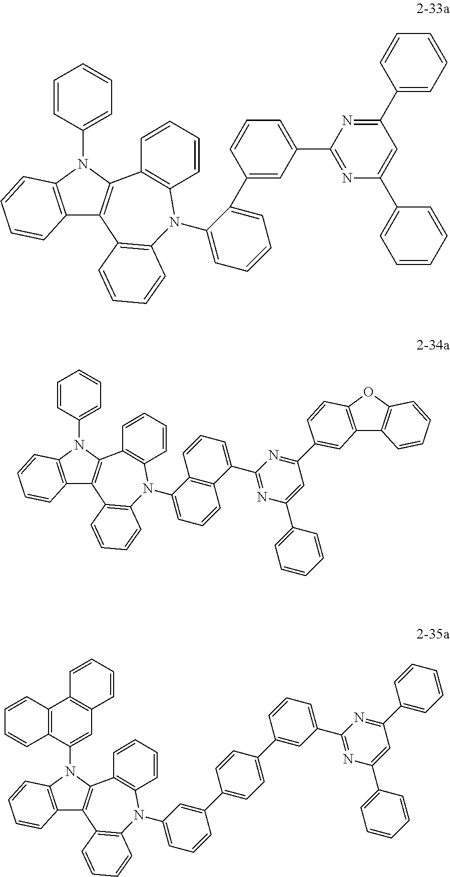 [SMILES: c1ccc(-c2cc(-c3ccccc3)nc(-c3cccc(-c4ccccc4N4c5ccccc5-c5c(n(-c6ccccc6)c6ccccc56)-c5ccccc54)c3)n2)cc1 ; c1ccc(-c2cc(-c3ccc4oc5ccccc5c4c3)nc(-c3cccc4c(N5c6ccccc6-c6c(n(-c7ccccc7)c7ccccc67)-c6ccccc65)cccc34)n2)cc1 ; c1ccc(-c2cc(-c3ccccc3)nc(-c3cccc(-c4ccc(-c5cccc(N6c7ccccc7-c7c(n(-c8cc9ccccc9c9ccccc89)c8ccccc78)-c7ccccc76)c5)cc4)c3)n2)cc1]

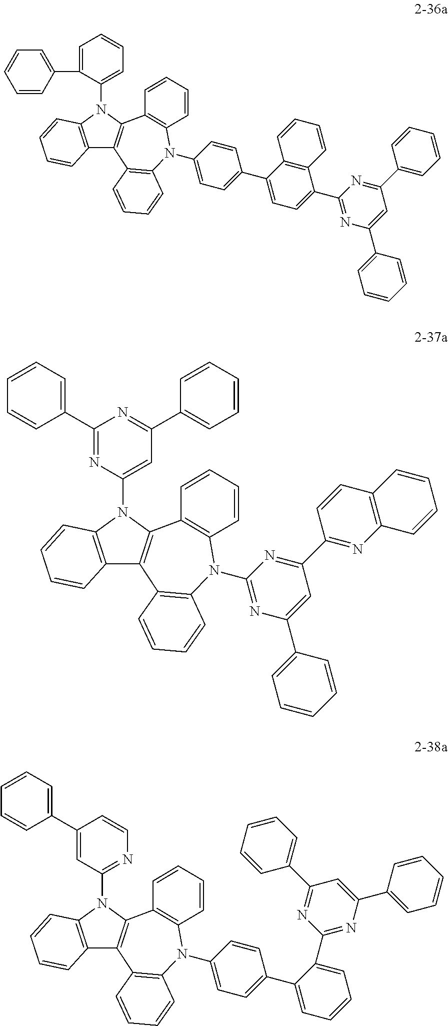 [SMILES: c1ccc(-c2cc(-c3ccccc3)nc(-c3ccc(-c4ccc(N5c6ccccc6-c6c(n(-c7ccccc7-c7ccccc7)c7ccccc67)-c6ccccc65)cc4)c4ccccc34)n2)cc1 ; c1ccc(-c2cc(-n3c4c(c5ccccc53)-c3ccccc3N(c3nc(-c5ccccc5)cc(-c5ccc6ccccc6n5)n3)c3ccccc3-4)nc(-c3ccccc3)n2)cc1 ; c1ccc(-c2ccnc(-n3c4c(c5ccccc53)-c3ccccc3N(c3ccc(-c5ccccc5-c5nc(-c6ccccc6)cc(-c6ccccc6)n5)cc3)c3ccccc3-4)c2)cc1]

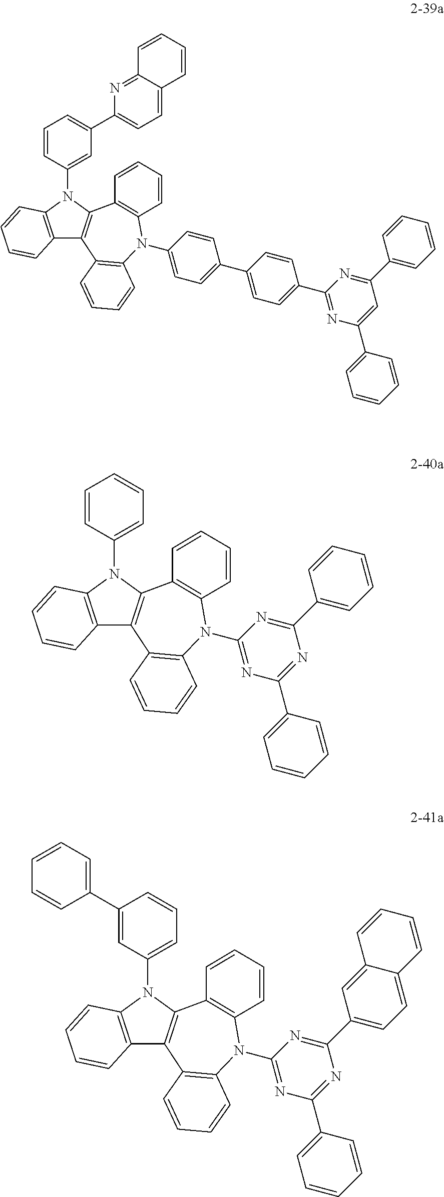 [SMILES: c1ccc(-c2cc(-c3ccccc3)nc(-c3ccc(-c4ccc(N5c6ccccc6-c6c(n(-c7cccc(-c8ccc9ccccc9n8)c7)c7ccccc67)-c6ccccc65)cc4)cc3)n2)cc1 ; c1ccc(-c2nc(-c3ccccc3)nc(N3c4ccccc4-c4c(n(-c5ccccc5)c5ccccc45)-c4ccccc43)n2)cc1 ; c1ccc(-c2cccc(-n3c4c(c5ccccc53)-c3ccccc3N(c3nc(-c5ccccc5)nc(-c5ccc6ccccc6c5)n3)c3ccccc3-4)c2)cc1]

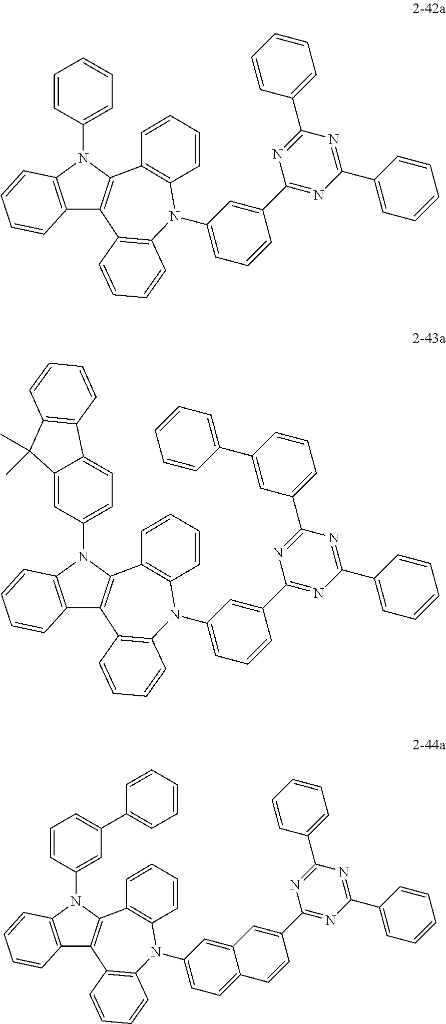 [SMILES: c1ccc(-c2nc(-c3ccccc3)nc(-c3cccc(N4c5ccccc5-c5c(n(-c6ccccc6)c6ccccc56)-c5ccccc54)c3)n2)cc1 ; CC1(C)c2ccccc2-c2ccc(-n3c4c(c5ccccc53)-c3ccccc3N(c3cccc(-c5nc(-c6ccccc6)nc(-c6cccc(-c7ccccc7)c6)n5)c3)c3ccccc3-4)cc21 ; c1ccc(-c2cccc(-n3c4c(c5ccccc53)-c3ccccc3N(c3ccc5ccc(-c6nc(-c7ccccc7)nc(-c7ccccc7)n6)cc5c3)c3ccccc3-4)c2)cc1]

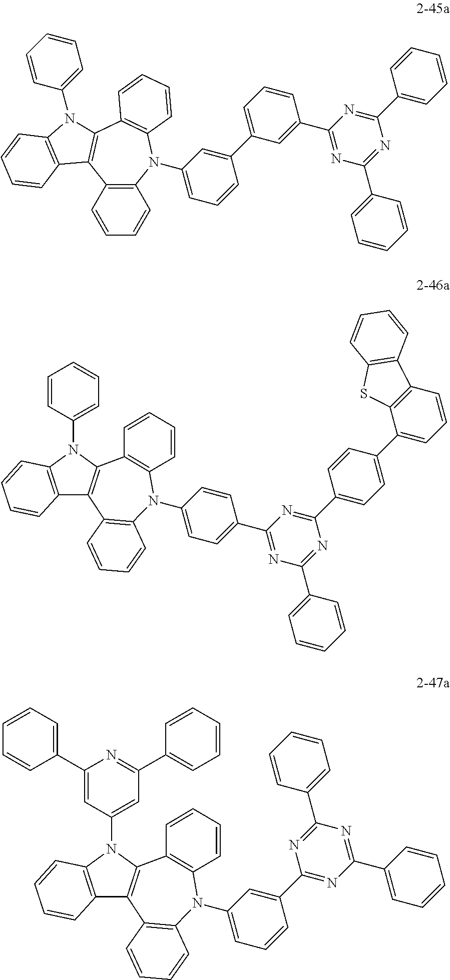 [SMILES: c1ccc(-c2nc(-c3ccccc3)nc(-c3cccc(-c4cccc(N5c6ccccc6-c6c(n(-c7ccccc7)c7ccccc67)-c6ccccc65)c4)c3)n2)cc1 ; c1ccc(-c2nc(-c3ccc(-c4cccc5c4sc4ccccc45)cc3)nc(-c3ccc(N4c5ccccc5-c5c(n(-c6ccccc6)c6ccccc56)-c5ccccc54)cc3)n2)cc1 ; c1ccc(-c2cc(-n3c4c(c5ccccc53)-c3ccccc3N(c3cccc(-c5nc(-c6ccccc6)nc(-c6ccccc6)n5)c3)c3ccccc3-4)cc(-c3ccccc3)n2)cc1]

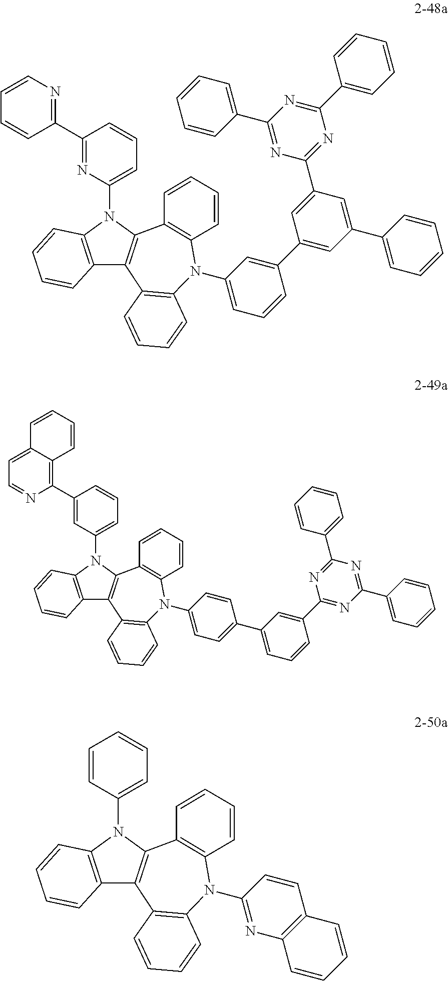 [SMILES: c1ccc(-c2cc(-c3cccc(N4c5ccccc5-c5c(n(-c6cccc(-c7ccccn7)n6)c6ccccc56)-c5ccccc54)c3)cc(-c3nc(-c4ccccc4)nc(-c4ccccc4)n3)c2)cc1 ; c1ccc(-c2nc(-c3ccccc3)nc(-c3cccc(-c4ccc(N5c6ccccc6-c6c(n(-c7cccc(-c8nccc9ccccc89)c7)c7ccccc67)-c6ccccc65)cc4)c3)n2)cc1 ; c1ccc(-n2c3c(c4ccccc42)-c2ccccc2N(c2ccc4ccccc4n2)c2ccccc2-3)cc1]

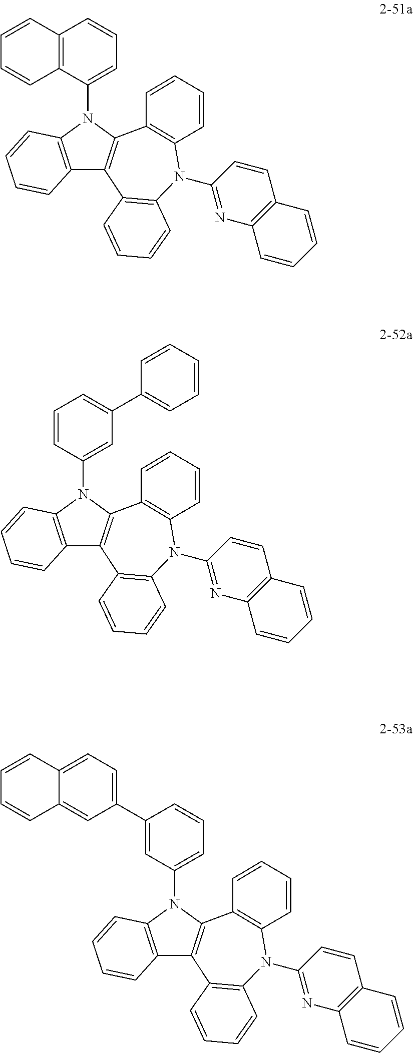 [SMILES: c1ccc2c(c1)-c1c(n(-c3cccc4ccccc34)c3ccccc13)-c1ccccc1N2c1ccc2ccccc2n1 ; c1ccc(-c2cccc(-n3c4c(c5ccccc53)-c3ccccc3N(c3ccc5ccccc5n3)c3ccccc3-4)c2)cc1 ; c1cc(-c2ccc3ccccc3c2)cc(-n2c3c(c4ccccc42)-c2ccccc2N(c2ccc4ccccc4n2)c2ccccc2-3)c1]

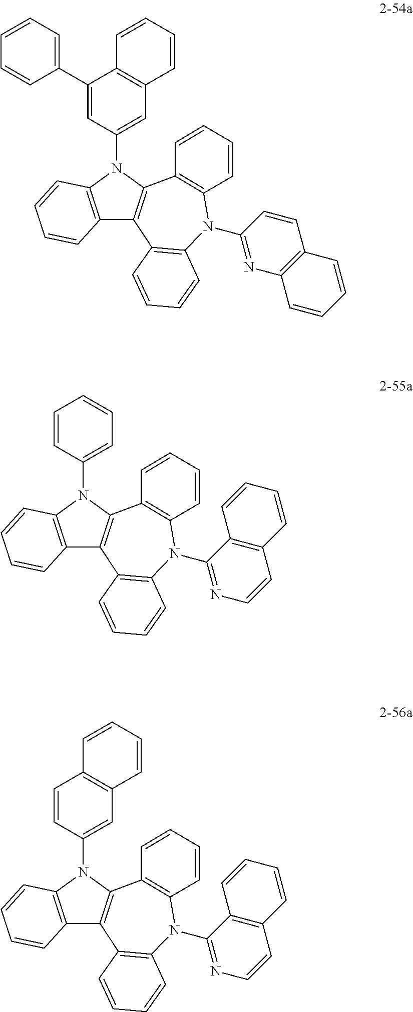 [SMILES: c1ccc(-c2cc(-n3c4c(c5ccccc53)-c3ccccc3N(c3ccc5ccccc5n3)c3ccccc3-4)cc3ccccc23)cc1 ; c1ccc(-n2c3c(c4ccccc42)-c2ccccc2N(c2nccc4ccccc24)c2ccccc2-3)cc1 ; c1ccc2c(c1)-c1c(n(-c3ccc4ccccc4c3)c3ccccc13)-c1ccccc1N2c1nccc2ccccc12]

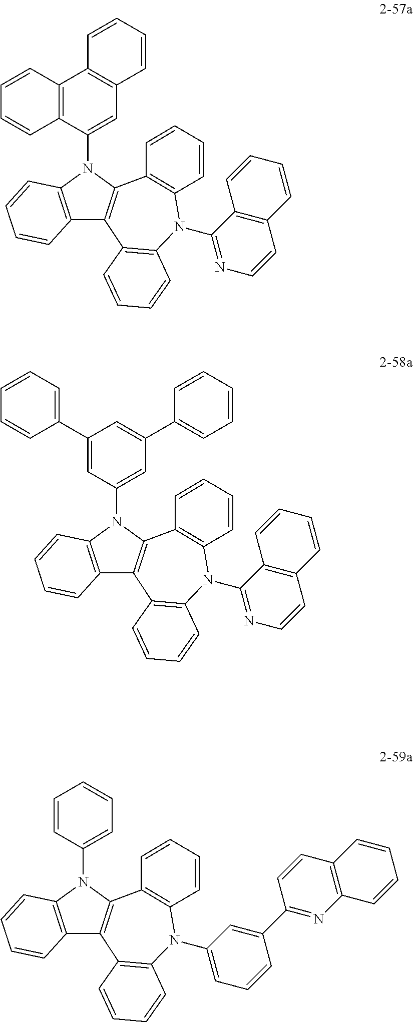 [SMILES: c1ccc2c(c1)-c1c(n(-c3cc4ccccc4c4ccccc34)c3ccccc13)-c1ccccc1N2c1nccc2ccccc12 ; c1ccc(-c2cc(-c3ccccc3)cc(-n3c4c(c5ccccc53)-c3ccccc3N(c3nccc5ccccc35)c3ccccc3-4)c2)cc1 ; c1ccc(-n2c3c(c4ccccc42)-c2ccccc2N(c2cccc(-c4ccc5ccccc5n4)c2)c2ccccc2-3)cc1]

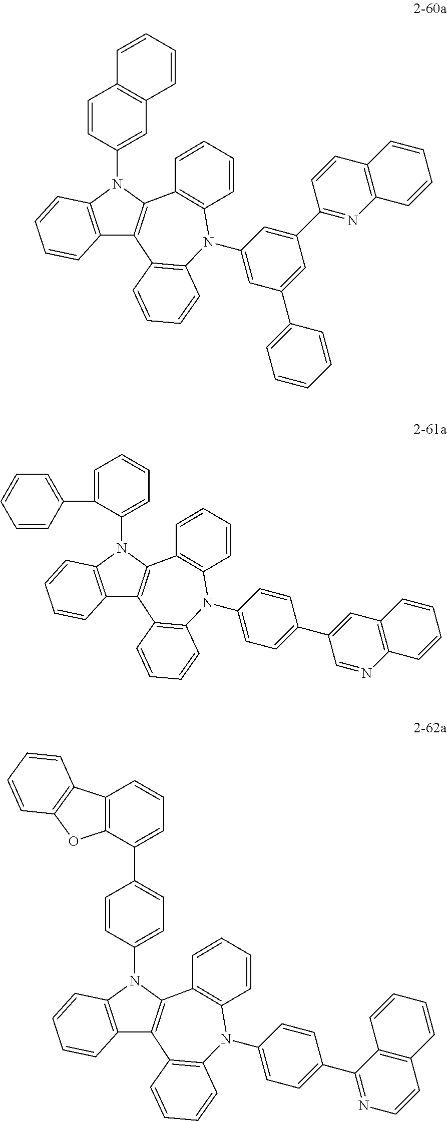 [SMILES: c1ccc(-c2cc(-c3ccc4ccccc4n3)cc(N3c4ccccc4-c4c(n(-c5ccc6ccccc6c5)c5ccccc45)-c4ccccc43)c2)cc1 ; c1ccc(-c2ccccc2-n2c3c(c4ccccc42)-c2ccccc2N(c2ccc(-c4cnc5ccccc5c4)cc2)c2ccccc2-3)cc1 ; c1ccc2c(c1)-c1c(n(-c3ccc(-c4cccc5c4oc4ccccc45)cc3)c3ccccc13)-c1ccccc1N2c1ccc(-c2nccc3ccccc23)cc1]

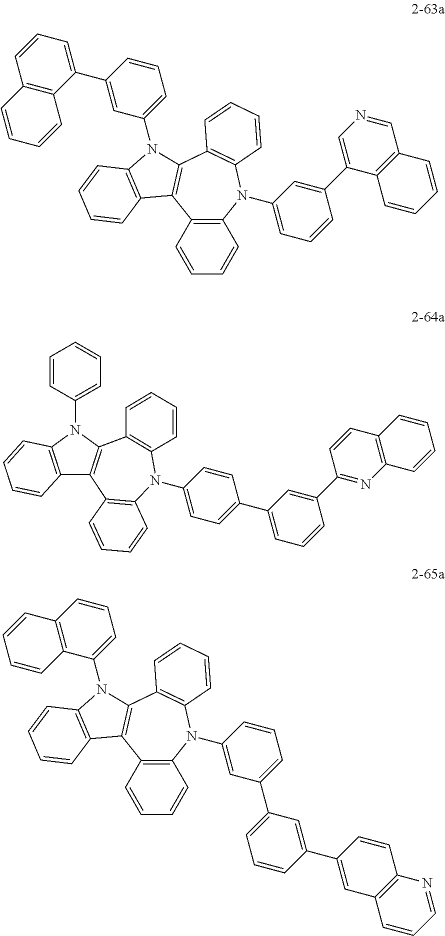 [SMILES: c1cc(-c2cncc3ccccc23)cc(N2c3ccccc3-c3c(n(-c4cccc(-c5cccc6ccccc56)c4)c4ccccc34)-c3ccccc32)c1 ; c1ccc(-n2c3c(c4ccccc42)-c2ccccc2N(c2ccc(-c4cccc(-c5ccc6ccccc6n5)c4)cc2)c2ccccc2-3)cc1 ; c1cc(-c2cccc(N3c4ccccc4-c4c(n(-c5cccc6ccccc56)c5ccccc45)-c4ccccc43)c2)cc(-c2ccc3ncccc3c2)c1]

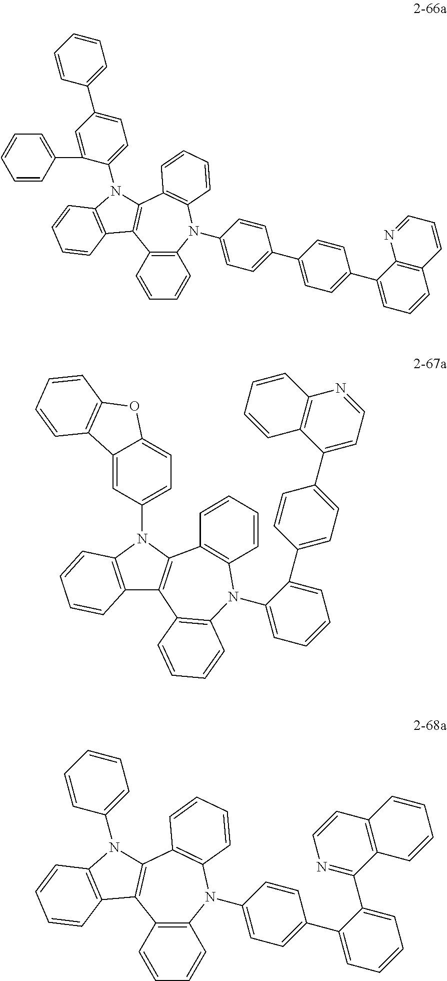 [SMILES: c1ccc(-c2ccc(-n3c4c(c5ccccc53)-c3ccccc3N(c3ccc(-c5ccc(-c6cccc7cccnc67)cc5)cc3)c3ccccc3-4)c(-c3ccccc3)c2)cc1 ; c1ccc(N2c3ccccc3-c3c(n(-c4ccc5oc6ccccc6c5c4)c4ccccc34)-c3ccccc32)c(-c2ccc(-c3ccnc4ccccc34)cc2)c1 ; c1ccc(-n2c3c(c4ccccc42)-c2ccccc2N(c2ccc(-c4ccccc4-c4nccc5ccccc45)cc2)c2ccccc2-3)cc1]

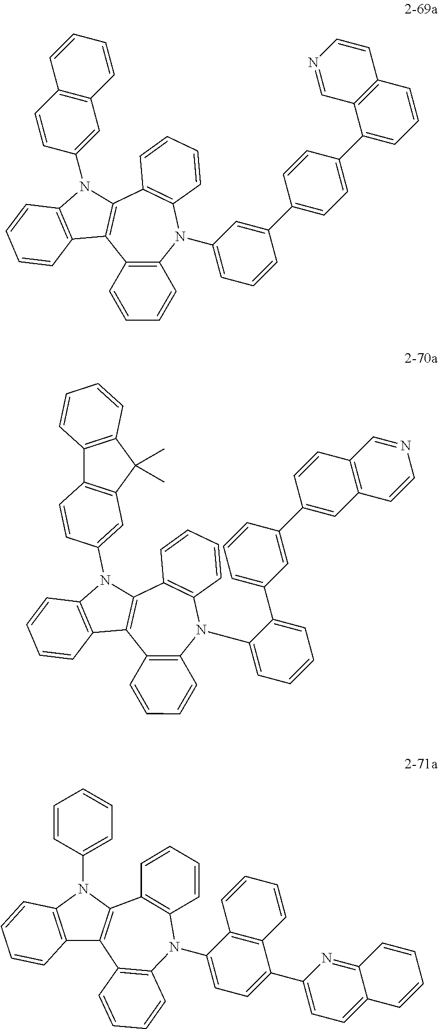 [SMILES: c1cc(-c2ccc(-c3cccc4ccncc34)cc2)cc(N2c3ccccc3-c3c(n(-c4ccc5ccccc5c4)c4ccccc34)-c3ccccc32)c1 ; CC1(C)c2ccccc2-c2ccc(-n3c4c(c5ccccc53)-c3ccccc3N(c3ccccc3-c3cccc(-c5ccc6cnccc6c5)c3)c3ccccc3-4)cc21 ; c1ccc(-n2c3c(c4ccccc42)-c2ccccc2N(c2ccc(-c4ccc5ccccc5n4)c4ccccc24)c2ccccc2-3)cc1]

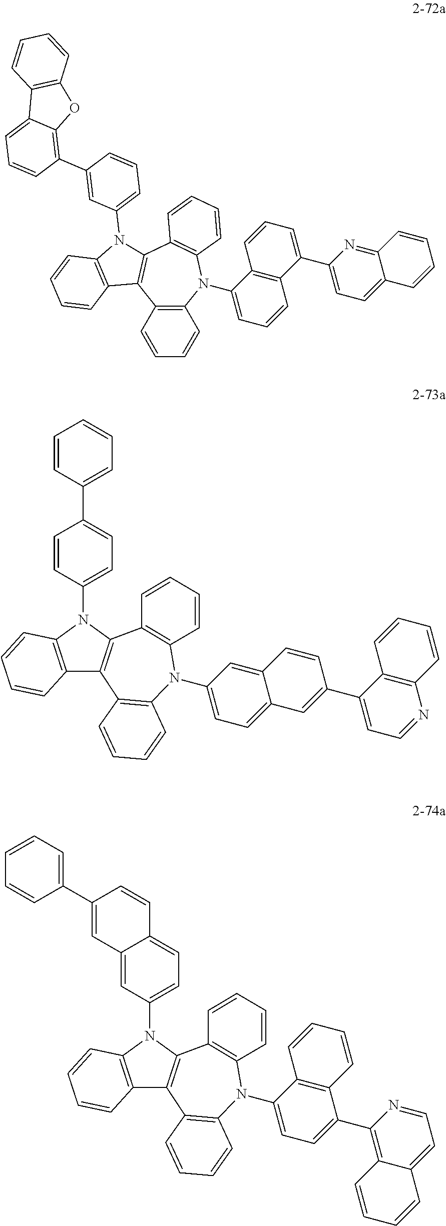 [SMILES: c1cc(-c2cccc3c2oc2ccccc23)cc(-n2c3c(c4ccccc42)-c2ccccc2N(c2cccc4c(-c5ccc6ccccc6n5)cccc24)c2ccccc2-3)c1 ; c1ccc(-c2ccc(-n3c4c(c5ccccc53)-c3ccccc3N(c3ccc5cc(-c6ccnc7ccccc67)ccc5c3)c3ccccc3-4)cc2)cc1 ; c1ccc(-c2ccc3ccc(-n4c5c(c6ccccc64)-c4ccccc4N(c4ccc(-c6nccc7ccccc67)c6ccccc46)c4ccccc4-5)cc3c2)cc1]

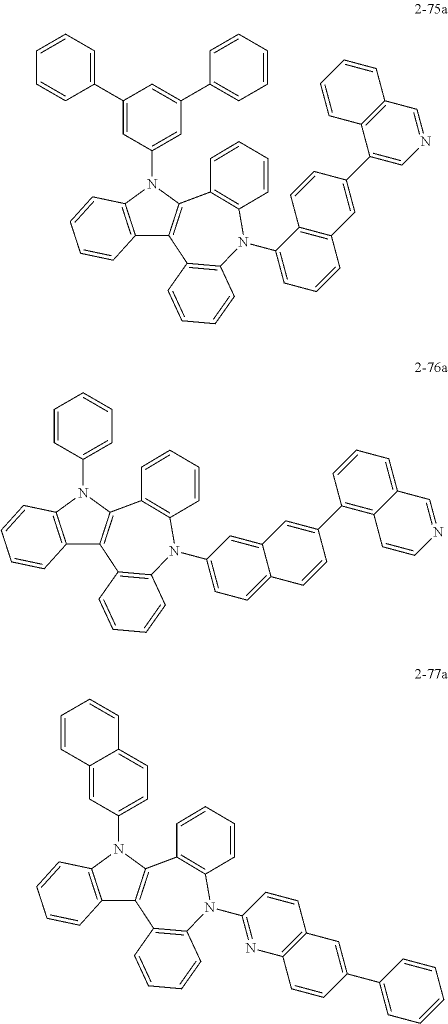 [SMILES: c1ccc(-c2cc(-c3ccccc3)cc(-n3c4c(c5ccccc53)-c3ccccc3N(c3cccc5cc(-c6cncc7ccccc67)ccc35)c3ccccc3-4)c2)cc1 ; c1ccc(-n2c3c(c4ccccc42)-c2ccccc2N(c2ccc4ccc(-c5cccc6cnccc56)cc4c2)c2ccccc2-3)cc1 ; c1ccc(-c2ccc3nc(N4c5ccccc5-c5c(n(-c6ccc7ccccc7c6)c6ccccc56)-c5ccccc54)ccc3c2)cc1]

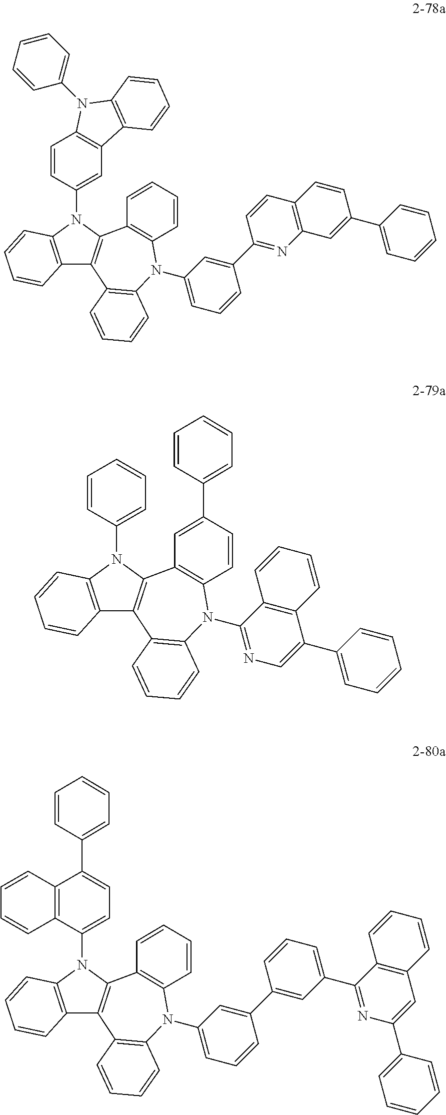 [SMILES: c1ccc(-c2ccc3ccc(-c4cccc(N5c6ccccc6-c6c(n(-c7ccc8c(c7)c7ccccc7n8-c7ccccc7)c7ccccc67)-c6ccccc65)c4)nc3c2)cc1 ; c1ccc(-c2ccc3c(c2)-c2c(c4ccccc4n2-c2ccccc2)-c2ccccc2N3c2ncc(-c3ccccc3)c3ccccc23)cc1 ; c1ccc(-c2cc3ccccc3c(-c3cccc(-c4cccc(N5c6ccccc6-c6c(n(-c7ccc(-c8ccccc8)c8ccccc78)c7ccccc67)-c6ccccc65)c4)c3)n2)cc1]

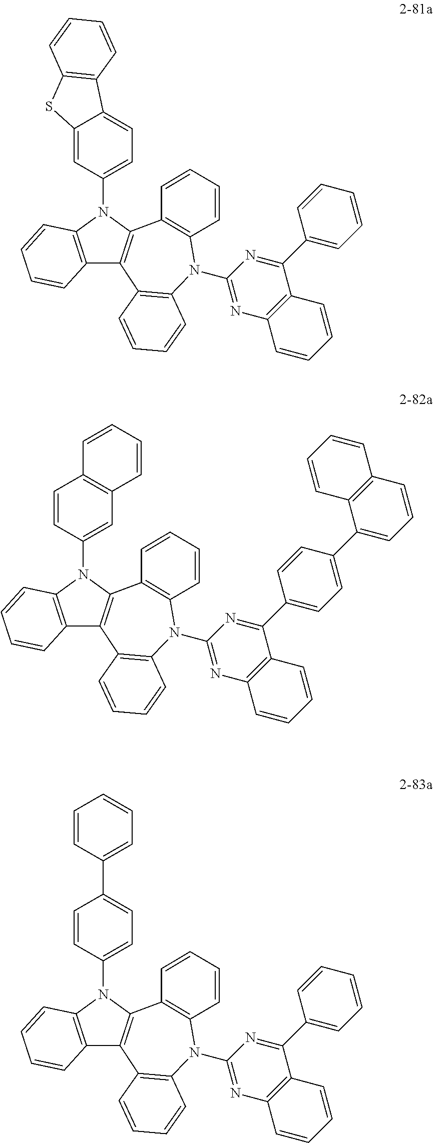 [SMILES: c1ccc(-c2nc(N3c4ccccc4-c4c(n(-c5ccc6c(c5)sc5ccccc56)c5ccccc45)-c4ccccc43)nc3ccccc23)cc1 ; c1ccc2c(c1)-c1c(n(-c3ccc4ccccc4c3)c3ccccc13)-c1ccccc1N2c1nc(-c2ccc(-c3cccc4ccccc34)cc2)c2ccccc2n1 ; c1ccc(-c2ccc(-n3c4c(c5ccccc53)-c3ccccc3N(c3nc(-c5ccccc5)c5ccccc5n3)c3ccccc3-4)cc2)cc1]

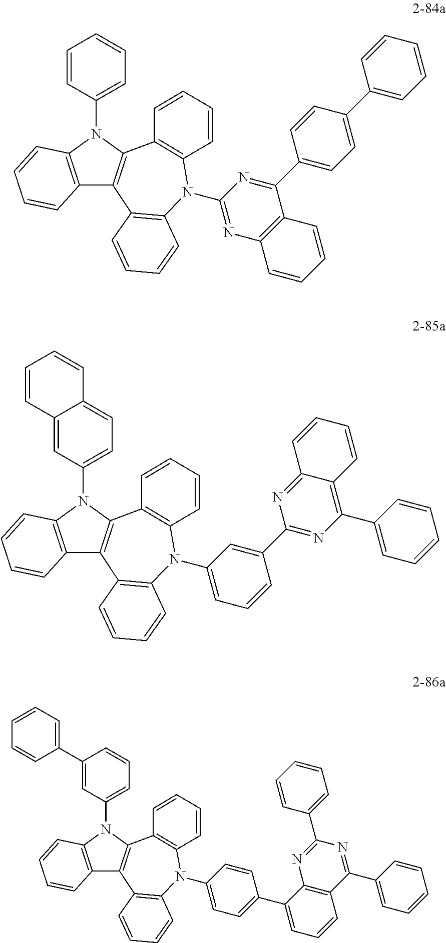 [SMILES: c1ccc(-c2ccc(-c3nc(N4c5ccccc5-c5c(n(-c6ccccc6)c6ccccc56)-c5ccccc54)nc4ccccc34)cc2)cc1 ; c1ccc(-c2nc(-c3cccc(N4c5ccccc5-c5c(n(-c6ccc7ccccc7c6)c6ccccc56)-c5ccccc54)c3)nc3ccccc23)cc1 ; c1ccc(-c2cccc(-n3c4c(c5ccccc53)-c3ccccc3N(c3ccc(-c5cccc6c(-c7ccccc7)nc(-c7ccccc7)nc56)cc3)c3ccccc3-4)c2)cc1]

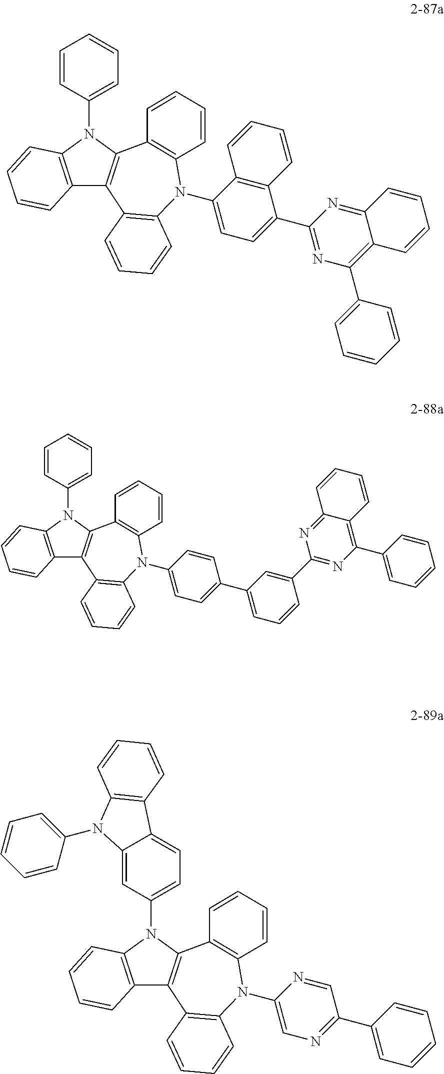 [SMILES: c1ccc(-c2nc(-c3ccc(N4c5ccccc5-c5c(n(-c6ccccc6)c6ccccc56)-c5ccccc54)c4ccccc34)nc3ccccc23)cc1 ; c1ccc(-c2nc(-c3cccc(-c4ccc(N5c6ccccc6-c6c(n(-c7ccccc7)c7ccccc67)-c6ccccc65)cc4)c3)nc3ccccc23)cc1 ; c1ccc(-c2cnc(N3c4ccccc4-c4c(n(-c5ccc6c7ccccc7n(-c7ccccc7)c6c5)c5ccccc45)-c4ccccc43)cn2)cc1]

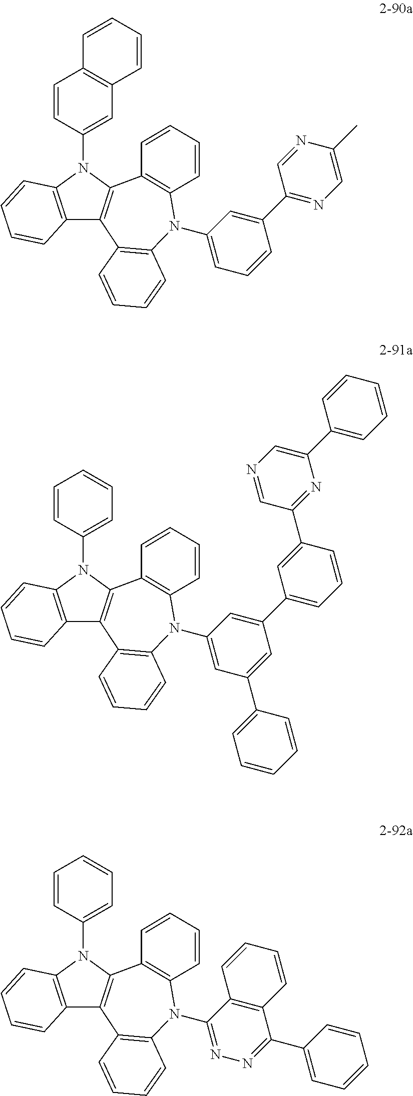 [SMILES: Cc1cnc(-c2cccc(N3c4ccccc4-c4c(n(-c5ccc6ccccc6c5)c5ccccc45)-c4ccccc43)c2)cn1 ; c1ccc(-c2cc(-c3cccc(-c4cncc(-c5ccccc5)n4)c3)cc(N3c4ccccc4-c4c(n(-c5ccccc5)c5ccccc45)-c4ccccc43)c2)cc1 ; c1ccc(-c2nnc(N3c4ccccc4-c4c(n(-c5ccccc5)c5ccccc45)-c4ccccc43)c3ccccc23)cc1]

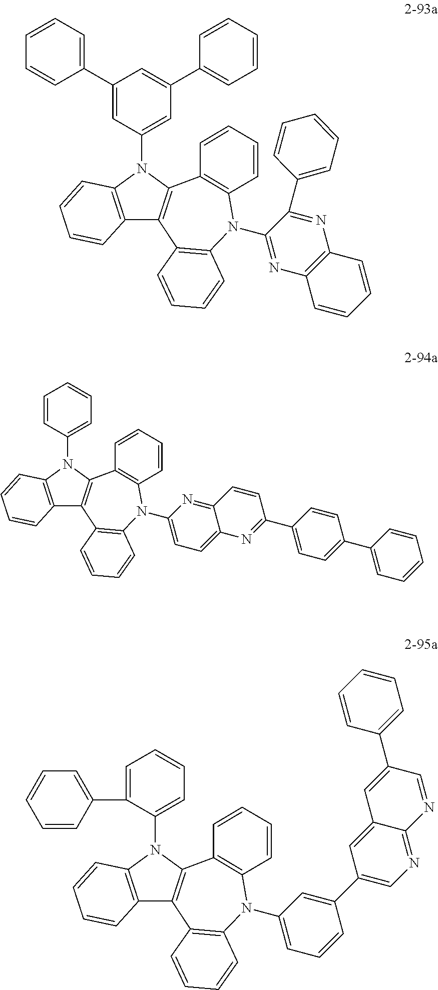 [SMILES: c1ccc(-c2cc(-c3ccccc3)cc(-n3c4c(c5ccccc53)-c3ccccc3N(c3nc5ccccc5nc3-c3ccccc3)c3ccccc3-4)c2)cc1 ; c1ccc(-c2ccc(-c3ccc4nc(N5c6ccccc6-c6c(n(-c7ccccc7)c7ccccc67)-c6ccccc65)ccc4n3)cc2)cc1 ; c1ccc(-c2cnc3ncc(-c4cccc(N5c6ccccc6-c6c(n(-c7ccccc7-c7ccccc7)c7ccccc67)-c6ccccc65)c4)cc3c2)cc1]

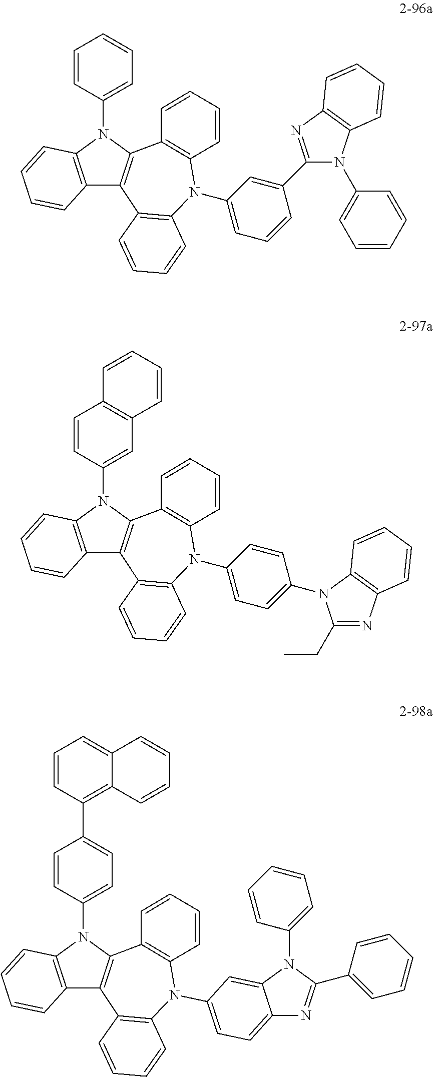 [SMILES: c1ccc(-n2c(-c3cccc(N4c5ccccc5-c5c(n(-c6ccccc6)c6ccccc56)-c5ccccc54)c3)nc3ccccc32)cc1 ; CCc1nc2ccccc2n1-c1ccc(N2c3ccccc3-c3c(n(-c4ccc5ccccc5c4)c4ccccc34)-c3ccccc32)cc1 ; c1ccc(-c2nc3ccc(N4c5ccccc5-c5c(n(-c6ccc(-c7cccc8ccccc78)cc6)c6ccccc56)-c5ccccc54)cc3n2-c2ccccc2)cc1]

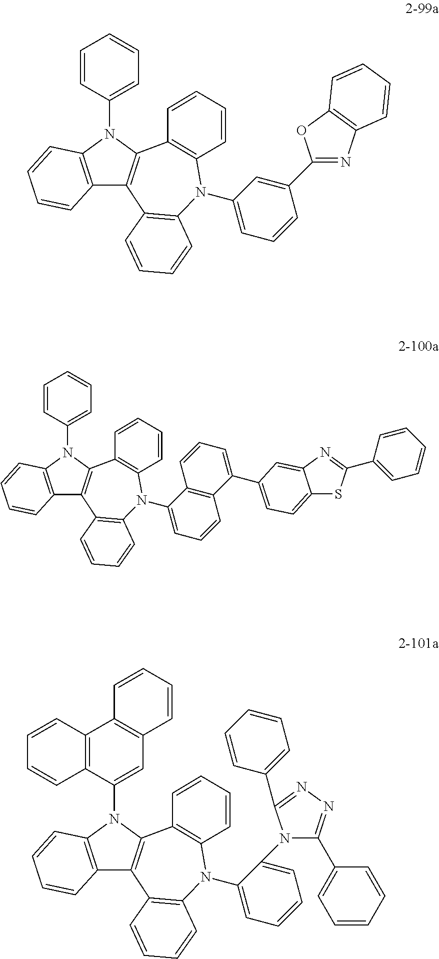 [SMILES: c1ccc(-n2c3c(c4ccccc42)-c2ccccc2N(c2cccc(-c4nc5ccccc5o4)c2)c2ccccc2-3)cc1 ; c1ccc(-c2nc3cc(-c4cccc5c(N6c7ccccc7-c7c(n(-c8ccccc8)c8ccccc78)-c7ccccc76)cccc45)ccc3s2)cc1 ; c1ccc(-c2nnc(-c3ccccc3)n2-c2ccccc2N2c3ccccc3-c3c(n(-c4cc5ccccc5c5ccccc45)c4ccccc34)-c3ccccc32)cc1]

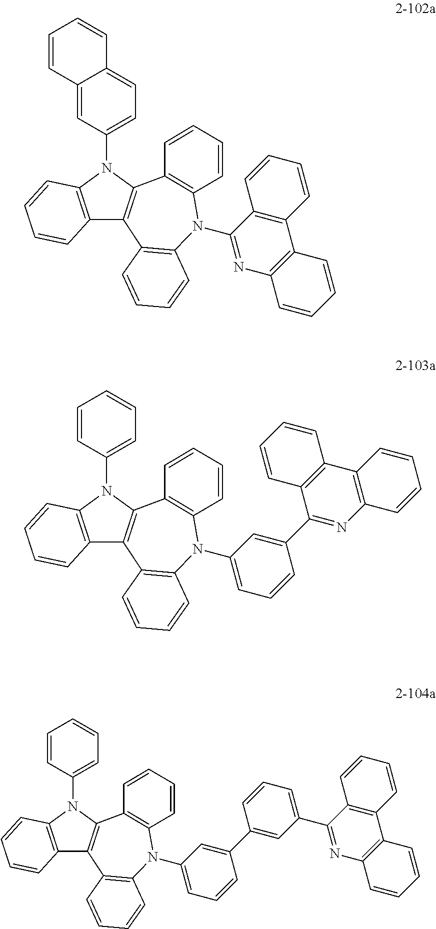 [SMILES: c1ccc2c(c1)-c1c(n(-c3ccc4ccccc4c3)c3ccccc13)-c1ccccc1N2c1nc2ccccc2c2ccccc12 ; c1ccc(-n2c3c(c4ccccc42)-c2ccccc2N(c2cccc(-c4nc5ccccc5c5ccccc45)c2)c2ccccc2-3)cc1 ; c1ccc(-n2c3c(c4ccccc42)-c2ccccc2N(c2cccc(-c4cccc(-c5nc6ccccc6c6ccccc56)c4)c2)c2ccccc2-3)cc1]

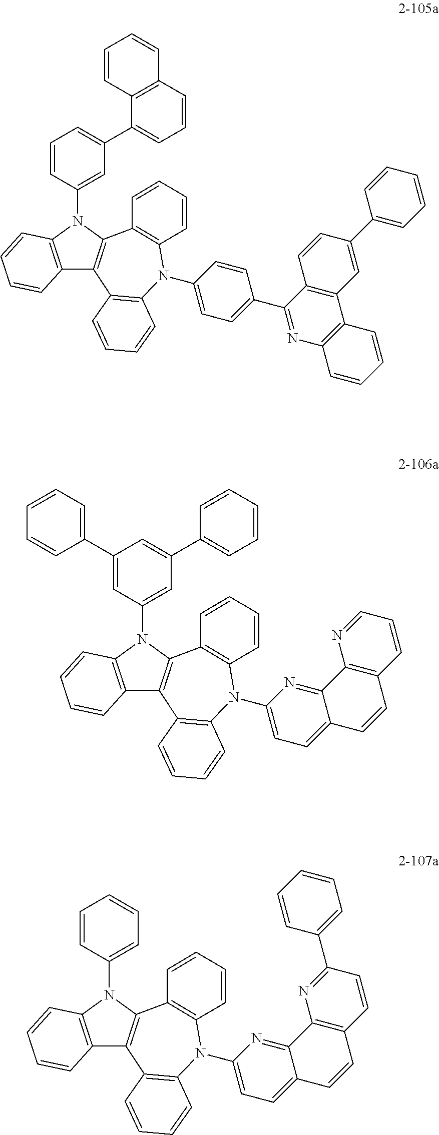 [SMILES: c1ccc(-c2ccc3c(-c4ccc(N5c6ccccc6-c6c(n(-c7cccc(-c8cccc9ccccc89)c7)c7ccccc67)-c6ccccc65)cc4)nc4ccccc4c3c2)cc1 ; c1ccc(-c2cc(-c3ccccc3)cc(-n3c4c(c5ccccc53)-c3ccccc3N(c3ccc5ccc6cccnc6c5n3)c3ccccc3-4)c2)cc1 ; c1ccc(-c2ccc3ccc4ccc(N5c6ccccc6-c6c(n(-c7ccccc7)c7ccccc67)-c6ccccc65)nc4c3n2)cc1]

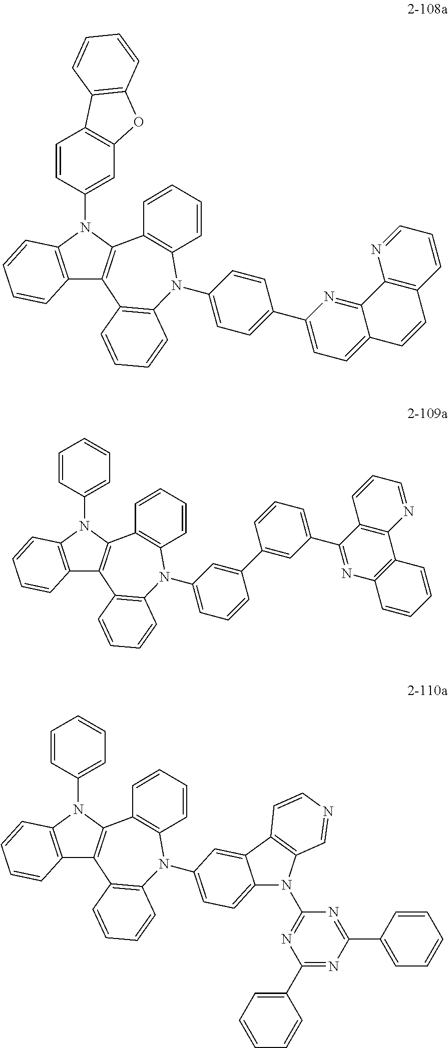 [SMILES: c1ccc2c(c1)-c1c(n(-c3ccc4c(c3)oc3ccccc34)c3ccccc13)-c1ccccc1N2c1ccc(-c2ccc3ccc4cccnc4c3n2)cc1 ; c1ccc(-n2c3c(c4ccccc42)-c2ccccc2N(c2cccc(-c4cccc(-c5nc6ccccc6c6ncccc56)c4)c2)c2ccccc2-3)cc1 ; c1ccc(-c2nc(-c3ccccc3)nc(-n3c4ccc(N5c6ccccc6-c6c(n(-c7ccccc7)c7ccccc67)-c6ccccc65)cc4c4ccncc43)n2)cc1]

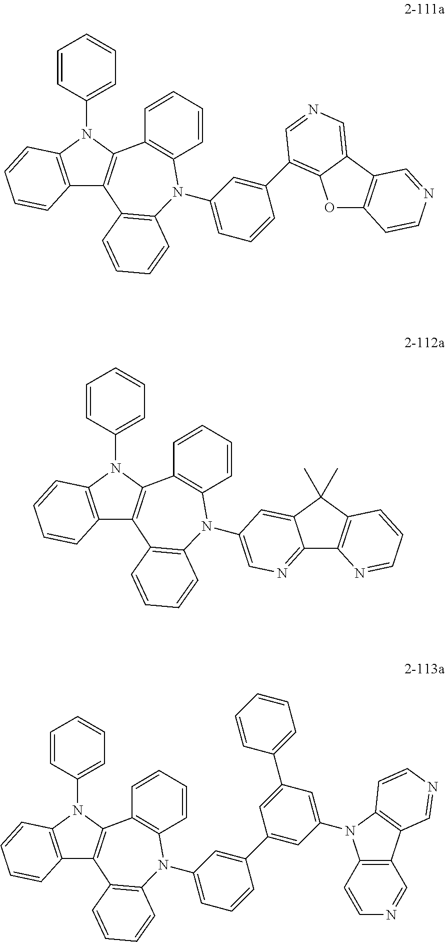 [SMILES: c1ccc(-n2c3c(c4ccccc42)-c2ccccc2N(c2cccc(-c4cncc5c4oc4ccncc45)c2)c2ccccc2-3)cc1 ; CC1(C)c2cccnc2-c2ncc(N3c4ccccc4-c4c(n(-c5ccccc5)c5ccccc45)-c4ccccc43)cc21 ; c1ccc(-c2cc(-c3cccc(N4c5ccccc5-c5c(n(-c6ccccc6)c6ccccc56)-c5ccccc54)c3)cc(-n3c4ccncc4c4cnccc43)c2)cc1]

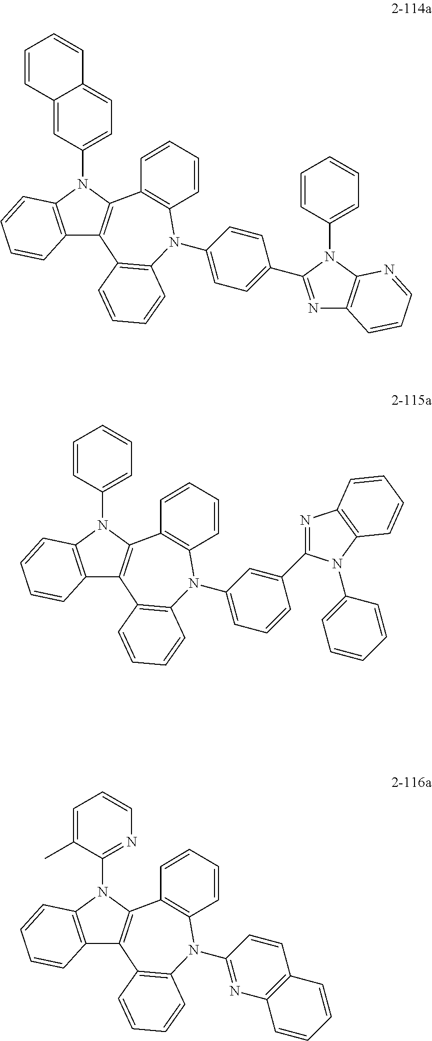 [SMILES: c1ccc(-n2c(-c3ccc(N4c5ccccc5-c5c(n(-c6ccc7ccccc7c6)c6ccccc56)-c5ccccc54)cc3)nc3cccnc32)cc1 ; c1ccc(-n2c(-c3cccc(N4c5ccccc5-c5c(n(-c6ccccc6)c6ccccc56)-c5ccccc54)c3)nc3ccccc32)cc1 ; Cc1cccnc1-n1c2c(c3ccccc31)-c1ccccc1N(c1ccc3ccccc3n1)c1ccccc1-2]

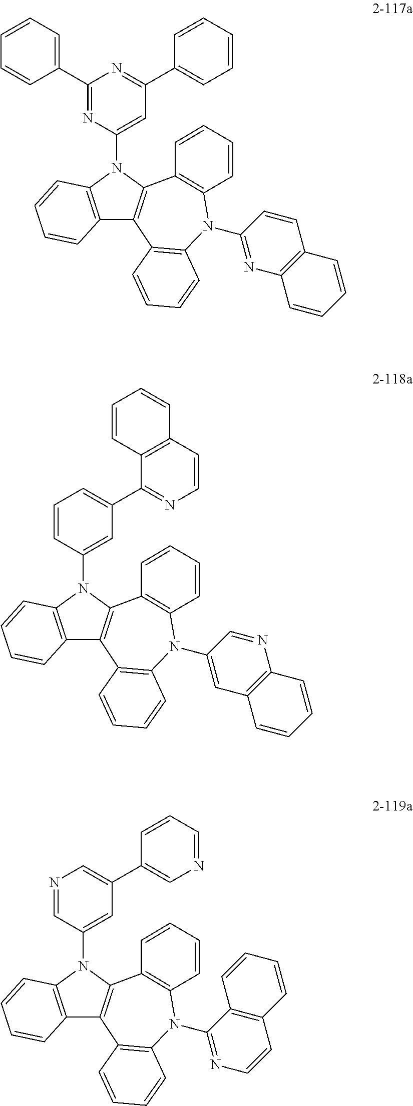 [SMILES: c1ccc(-c2cc(-n3c4c(c5ccccc53)-c3ccccc3N(c3ccc5ccccc5n3)c3ccccc3-4)nc(-c3ccccc3)n2)cc1 ; c1cc(-c2nccc3ccccc23)cc(-n2c3c(c4ccccc42)-c2ccccc2N(c2cnc4ccccc4c2)c2ccccc2-3)c1 ; c1cncc(-c2cncc(-n3c4c(c5ccccc53)-c3ccccc3N(c3nccc5ccccc35)c3ccccc3-4)c2)c1]

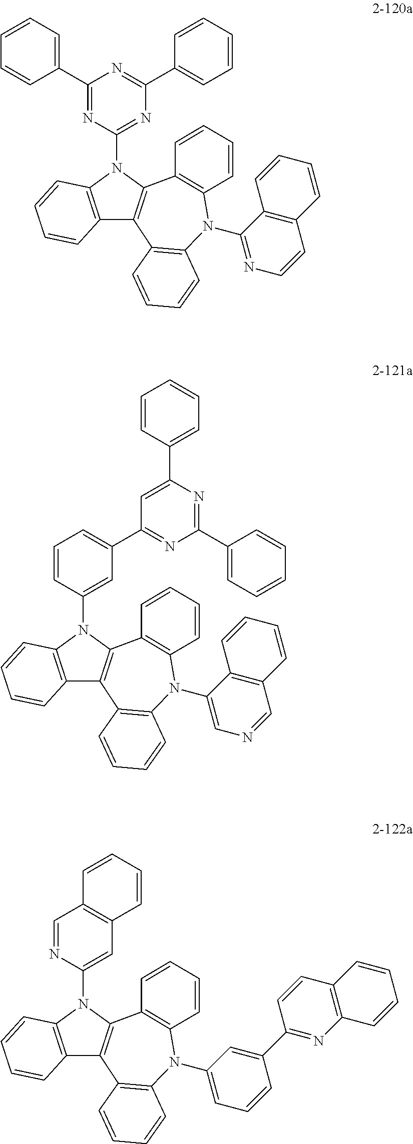 [SMILES: c1ccc(-c2nc(-c3ccccc3)nc(-n3c4c(c5ccccc53)-c3ccccc3N(c3nccc5ccccc35)c3ccccc3-4)n2)cc1 ; c1ccc(-c2cc(-c3cccc(-n4c5c(c6ccccc64)-c4ccccc4N(c4cncc6ccccc46)c4ccccc4-5)c3)nc(-c3ccccc3)n2)cc1 ; c1cc(-c2ccc3ccccc3n2)cc(N2c3ccccc3-c3c(n(-c4cc5ccccc5cn4)c4ccccc34)-c3ccccc32)c1]

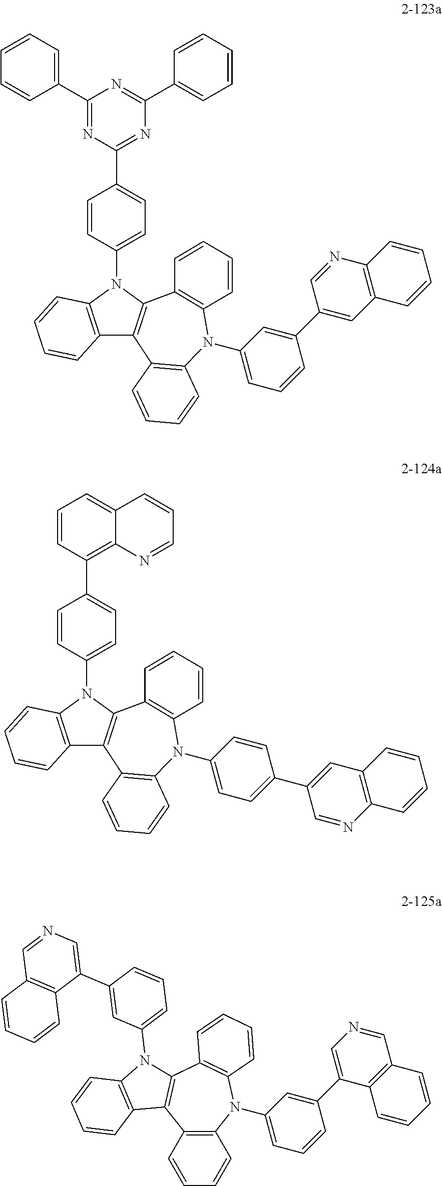 [SMILES: c1ccc(-c2nc(-c3ccccc3)nc(-c3ccc(-n4c5c(c6ccccc64)-c4ccccc4N(c4cccc(-c6cnc7ccccc7c6)c4)c4ccccc4-5)cc3)n2)cc1 ; c1ccc2c(c1)-c1c(n(-c3ccc(-c4cccc5cccnc45)cc3)c3ccccc13)-c1ccccc1N2c1ccc(-c2cnc3ccccc3c2)cc1 ; c1cc(-c2cncc3ccccc23)cc(N2c3ccccc3-c3c(n(-c4cccc(-c5cncc6ccccc56)c4)c4ccccc34)-c3ccccc32)c1]

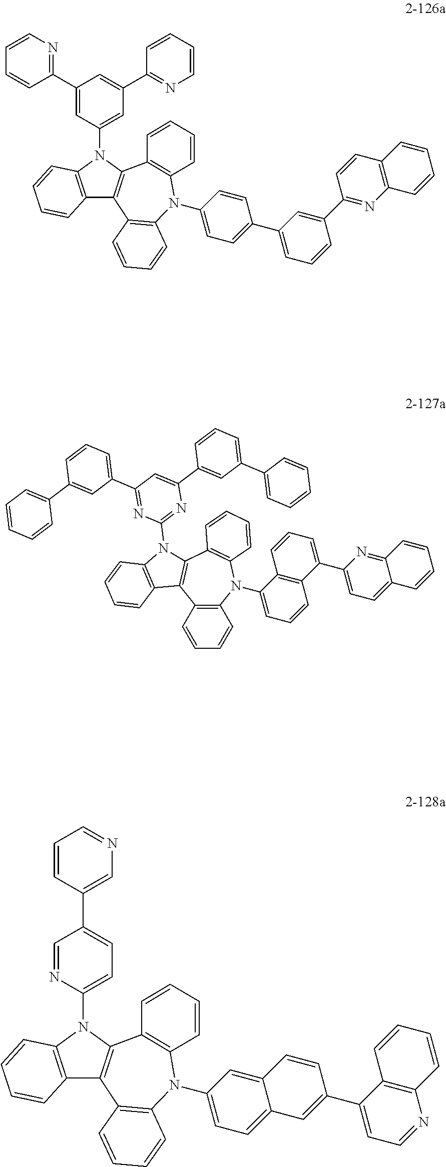 [SMILES: c1ccc(-c2cc(-c3ccccn3)cc(-n3c4c(c5ccccc53)-c3ccccc3N(c3ccc(-c5cccc(-c6ccc7ccccc7n6)c5)cc3)c3ccccc3-4)c2)nc1 ; c1ccc(-c2cccc(-c3cc(-c4cccc(-c5ccccc5)c4)nc(-n4c5c(c6ccccc64)-c4ccccc4N(c4cccc6c(-c7ccc8ccccc8n7)cccc46)c4ccccc4-5)n3)c2)cc1 ; c1cncc(-c2ccc(-n3c4c(c5ccccc53)-c3ccccc3N(c3ccc5cc(-c6ccnc7ccccc67)ccc5c3)c3ccccc3-4)nc2)c1]

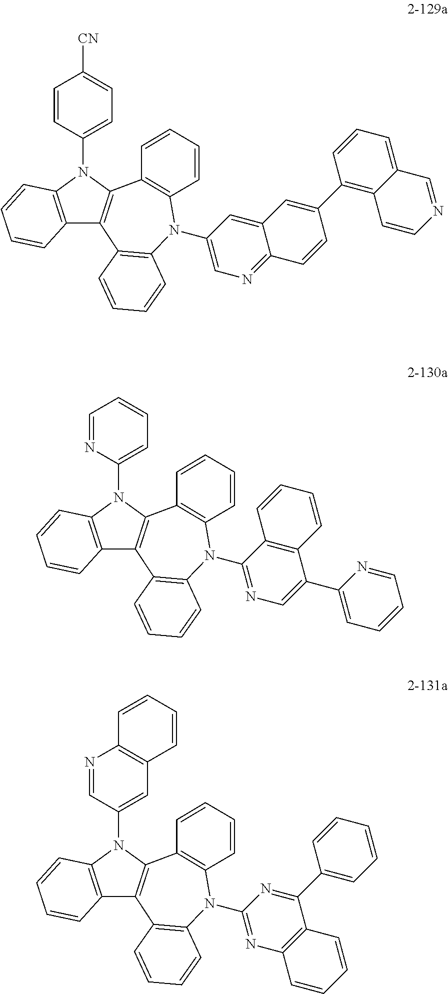 [SMILES: N#Cc1ccc(-n2c3c(c4ccccc42)-c2ccccc2N(c2cnc4ccc(-c5cccc6cnccc56)cc4c2)c2ccccc2-3)cc1 ; c1ccc(-c2cnc(N3c4ccccc4-c4c(n(-c5ccccn5)c5ccccc45)-c4ccccc43)c3ccccc23)nc1 ; c1ccc(-c2nc(N3c4ccccc4-c4c(n(-c5cnc6ccccc6c5)c5ccccc45)-c4ccccc43)nc3ccccc23)cc1]

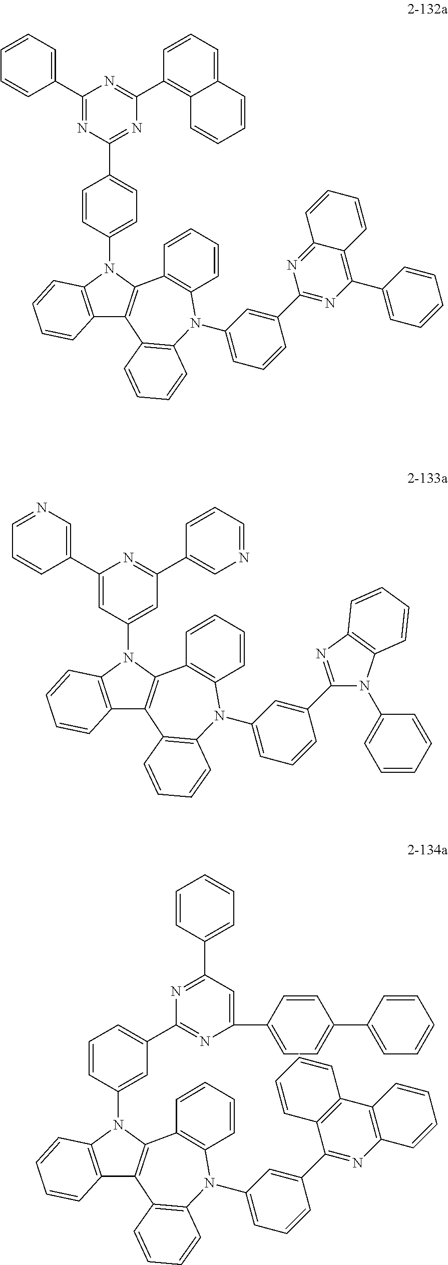 [SMILES: c1ccc(-c2nc(-c3ccc(-n4c5c(c6ccccc64)-c4ccccc4N(c4cccc(-c6nc(-c7ccccc7)c7ccccc7n6)c4)c4ccccc4-5)cc3)nc(-c3cccc4ccccc34)n2)cc1 ; c1ccc(-n2c(-c3cccc(N4c5ccccc5-c5c(n(-c6cc(-c7cccnc7)nc(-c7cccnc7)c6)c6ccccc56)-c5ccccc54)c3)nc3ccccc32)cc1 ; c1ccc(-c2ccc(-c3cc(-c4ccccc4)nc(-c4cccc(-n5c6c(c7ccccc75)-c5ccccc5N(c5cccc(-c7nc8ccccc8c8ccccc78)c5)c5ccccc5-6)c4)n3)cc2)cc1]

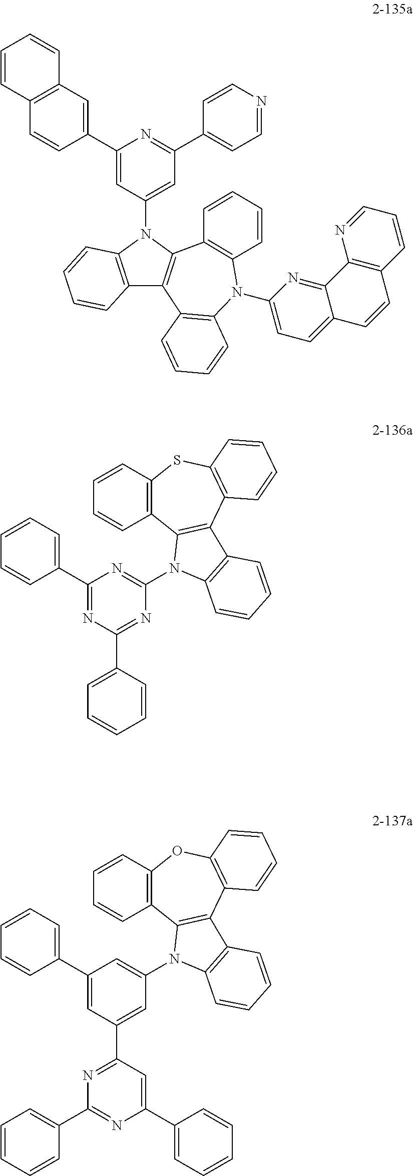 [SMILES: c1ccc2c(c1)-c1c(n(-c3cc(-c4ccncc4)nc(-c4ccc5ccccc5c4)c3)c3ccccc13)-c1ccccc1N2c1ccc2ccc3cccnc3c2n1 ; c1ccc(-c2nc(-c3ccccc3)nc(-n3c4c(c5ccccc53)-c3ccccc3Sc3ccccc3-4)n2)cc1 ; c1ccc(-c2cc(-c3cc(-c4ccccc4)nc(-c4ccccc4)n3)cc(-n3c4c(c5ccccc53)-c3ccccc3Oc3ccccc3-4)c2)cc1]

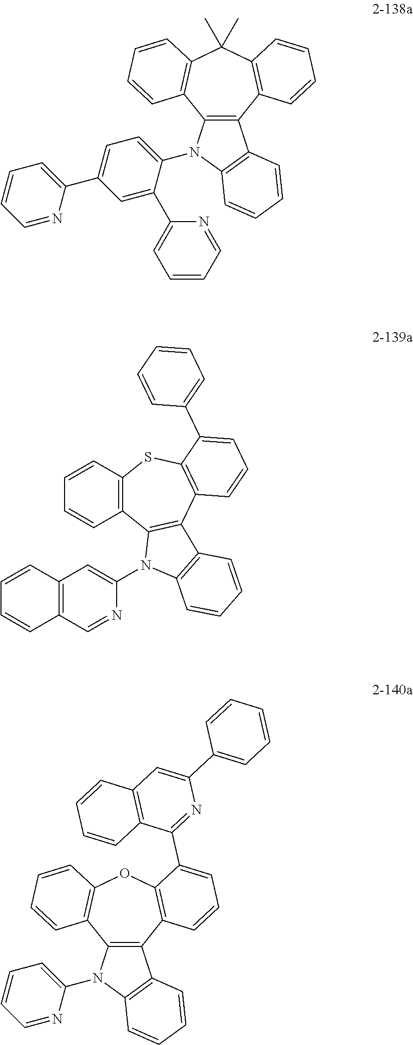 [SMILES: CC1(C)c2ccccc2-c2c(n(-c3ccc(-c4ccccn4)cc3-c3ccccn3)c3ccccc23)-c2ccccc21 ; c1ccc(-c2cccc3c2Sc2ccccc2-c2c-3c3ccccc3n2-c2cc3ccccc3cn2)cc1 ; c1ccc(-c2cc3ccccc3c(-c3cccc4c3Oc3ccccc3-c3c-4c4ccccc4n3-c3ccccn3)n2)cc1]

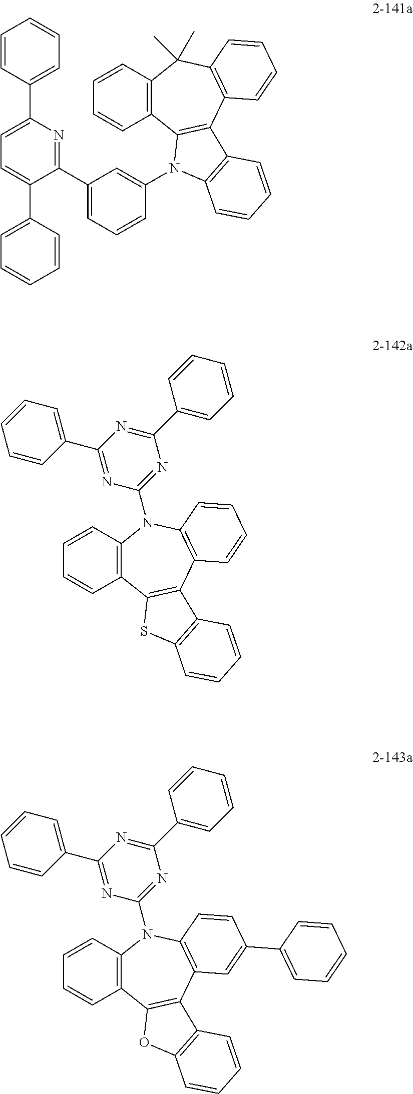 [SMILES: CC1(C)c2ccccc2-c2c(n(-c3cccc(-c4nc(-c5ccccc5)ccc4-c4ccccc4)c3)c3ccccc23)-c2ccccc21 ; c1ccc(-c2nc(-c3ccccc3)nc(N3c4ccccc4-c4sc5ccccc5c4-c4ccccc43)n2)cc1 ; c1ccc(-c2ccc3c(c2)-c2c(oc4ccccc24)-c2ccccc2N3c2nc(-c3ccccc3)nc(-c3ccccc3)n2)cc1]

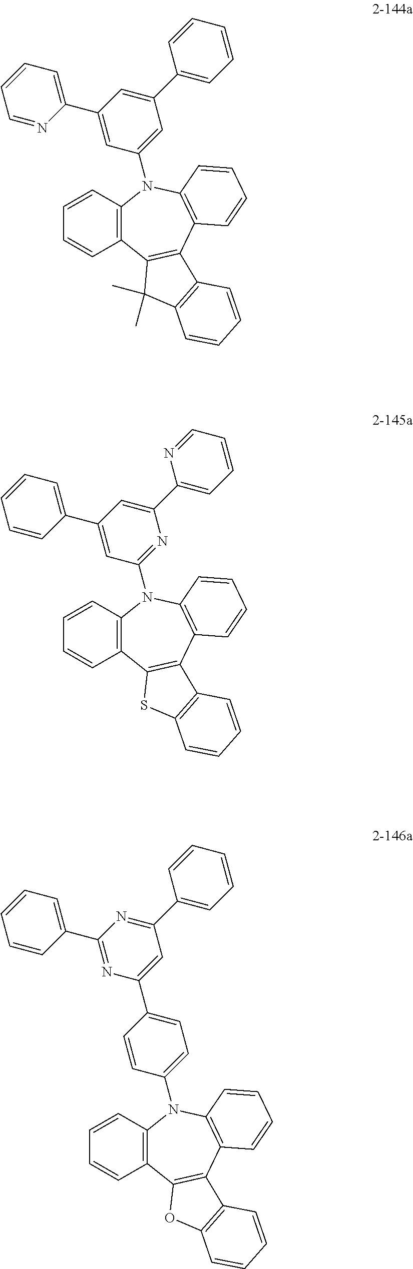 [SMILES: CC1(C)C2=C(c3ccccc3N(c3cc(-c4ccccc4)cc(-c4ccccn4)c3)c3ccccc32)c2ccccc21 ; c1ccc(-c2cc(-c3ccccn3)nc(N3c4ccccc4-c4sc5ccccc5c4-c4ccccc43)c2)cc1 ; c1ccc(-c2cc(-c3ccc(N4c5ccccc5-c5oc6ccccc6c5-c5ccccc54)cc3)nc(-c3ccccc3)n2)cc1]

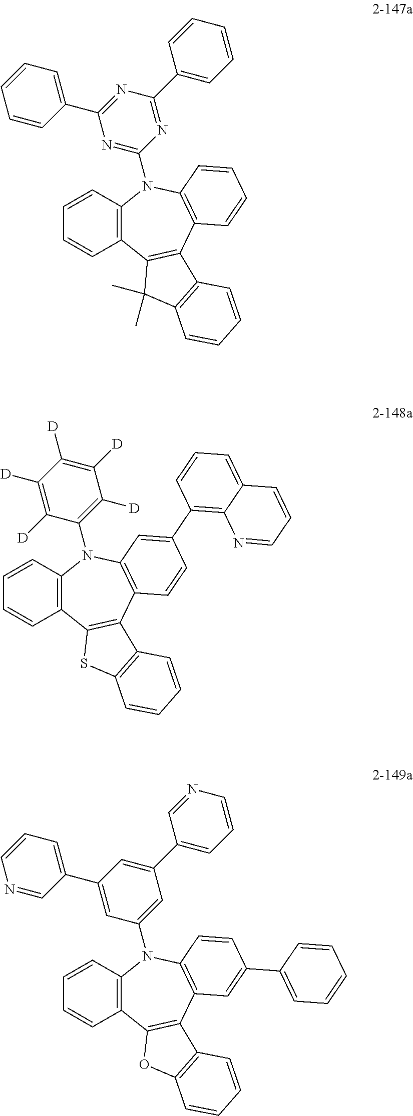 [SMILES: CC1(C)C2=C(c3ccccc3N(c3nc(-c4ccccc4)nc(-c4ccccc4)n3)c3ccccc32)c2ccccc21 ; [2H]c1c([2H])c([2H])c(N2c3ccccc3-c3sc4ccccc4c3-c3ccc(-c4cccc5cccnc45)cc32)c([2H])c1[2H] ; c1ccc(-c2ccc3c(c2)-c2c(oc4ccccc24)-c2ccccc2N3c2cc(-c3cccnc3)cc(-c3cccnc3)c2)cc1]

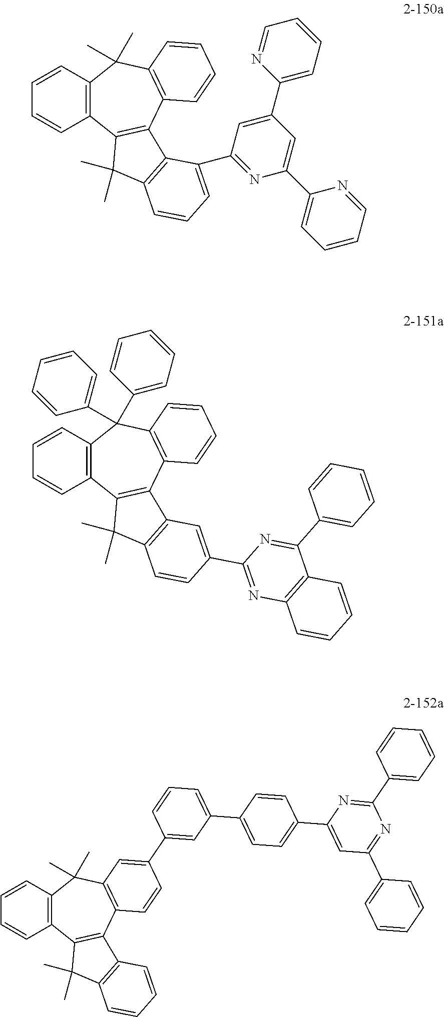 [SMILES: CC1(C)C2=C(c3ccccc3C(C)(C)c3ccccc32)c2c(-c3cc(-c4ccccn4)cc(-c4ccccn4)n3)cccc21 ; CC1(C)C2=C(c3cc(-c4nc(-c5ccccc5)c5ccccc5n4)ccc31)c1ccccc1C(c1ccccc1)(c1ccccc1)c1ccccc12 ; CC1(C)C2=C(c3ccccc31)c1ccc(-c3cccc(-c4ccc(-c5cc(-c6ccccc6)nc(-c6ccccc6)n5)cc4)c3)cc1C(C)(C)c1ccccc12]

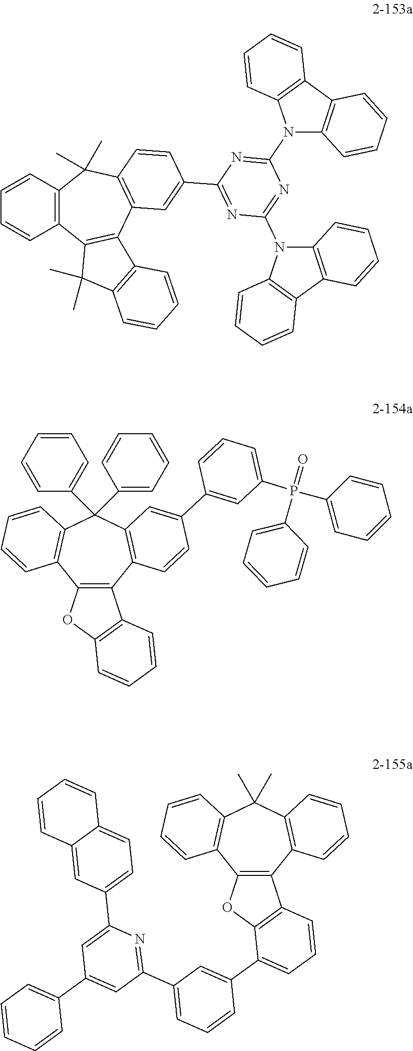 [SMILES: CC1(C)C2=C(c3ccccc31)c1cc(-c3nc(-n4c5ccccc5c5ccccc54)nc(-n4c5ccccc5c5ccccc54)n3)ccc1C(C)(C)c1ccccc12 ; O=P(c1ccccc1)(c1ccccc1)c1cccc(-c2ccc3c(c2)C(c2ccccc2)(c2ccccc2)c2ccccc2-c2oc4ccccc4c2-3)c1 ; CC1(C)c2ccccc2-c2oc3c(-c4cccc(-c5cc(-c6ccccc6)cc(-c6ccc7ccccc7c6)n5)c4)cccc3c2-c2ccccc21]

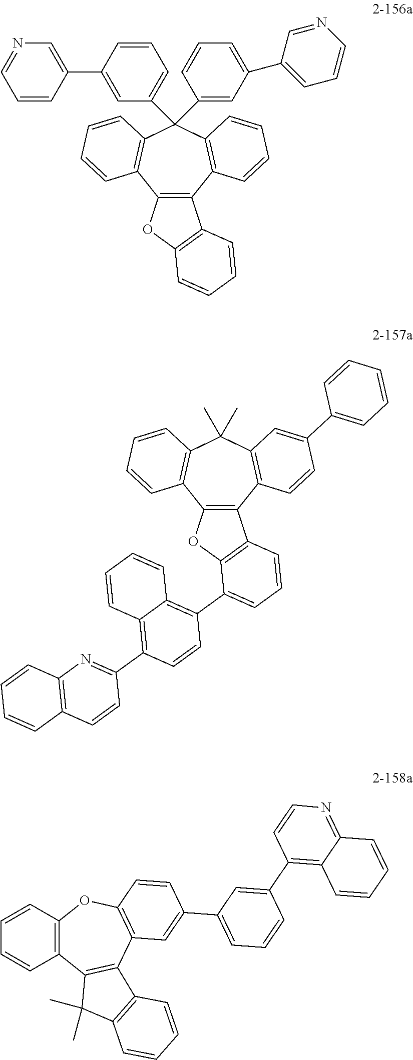 [SMILES: c1cncc(-c2cccc(C3(c4cccc(-c5cccnc5)c4)c4ccccc4-c4oc5ccccc5c4-c4ccccc43)c2)c1 ; CC1(C)c2ccccc2-c2oc3c(-c4ccc(-c5ccc6ccccc6n5)c5ccccc45)cccc3c2-c2ccc(-c3ccccc3)cc21 ; CC1(C)C2=C(c3cc(-c4cccc(-c5ccnc6ccccc56)c4)ccc3Oc3ccccc32)c2ccccc21]

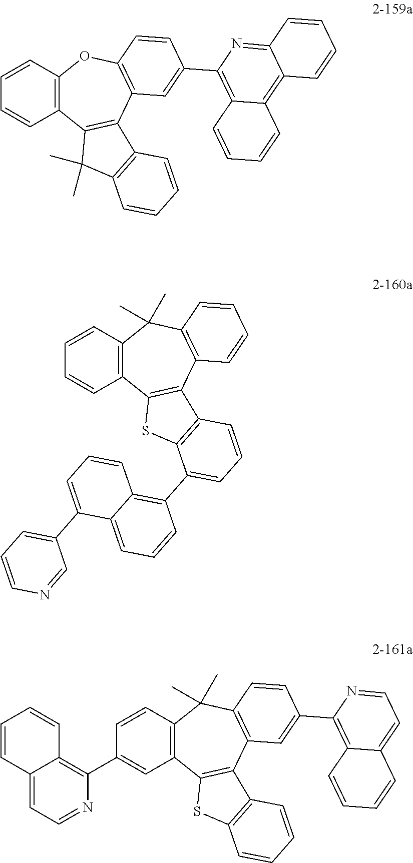 [SMILES: CC1(C)C2=C(c3cc(-c4nc5ccccc5c5ccccc45)ccc3Oc3ccccc32)c2ccccc21 ; CC1(C)c2ccccc2-c2sc3c(-c4cccc5c(-c6cccnc6)cccc45)cccc3c2-c2ccccc21 ; CC1(C)c2ccc(-c3nccc4ccccc34)cc2-c2sc3ccccc3c2-c2cc(-c3nccc4ccccc34)ccc21]

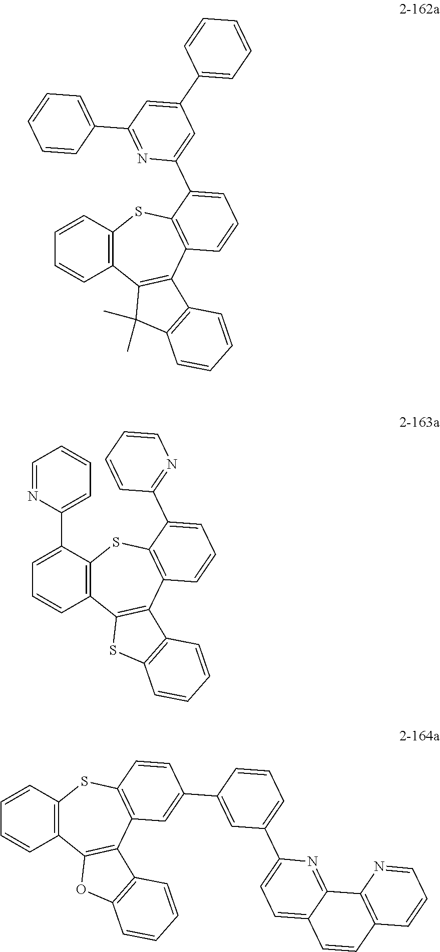 [SMILES: CC1(C)C2=C(c3ccccc31)c1cccc(-c3cc(-c4ccccc4)cc(-c4ccccc4)n3)c1Sc1ccccc12 ; c1ccc(-c2cccc3c2Sc2c(-c4ccccn4)cccc2-c2c-3sc3ccccc23)nc1 ; c1cc(-c2ccc3c(c2)-c2c(oc4ccccc24)-c2ccccc2S3)cc(-c2ccc3ccc4cccnc4c3n2)c1]

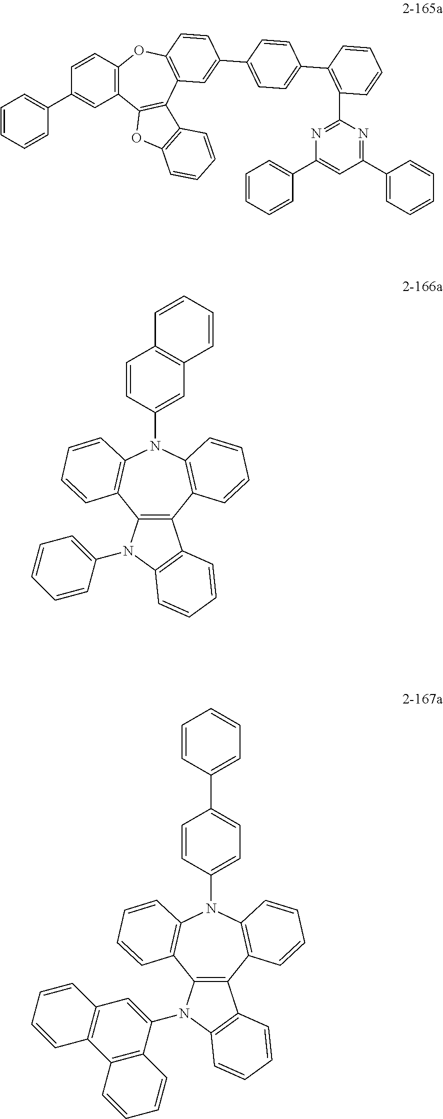 [SMILES: c1ccc(-c2ccc3c(c2)-c2oc4ccccc4c2-c2cc(-c4ccc(-c5ccccc5-c5nc(-c6ccccc6)cc(-c6ccccc6)n5)cc4)ccc2O3)cc1 ; c1ccc(-n2c3c(c4ccccc42)-c2ccccc2N(c2ccc4ccccc4c2)c2ccccc2-3)cc1 ; c1ccc(-c2ccc(N3c4ccccc4-c4c(n(-c5cc6ccccc6c6ccccc56)c5ccccc45)-c4ccccc43)cc2)cc1]

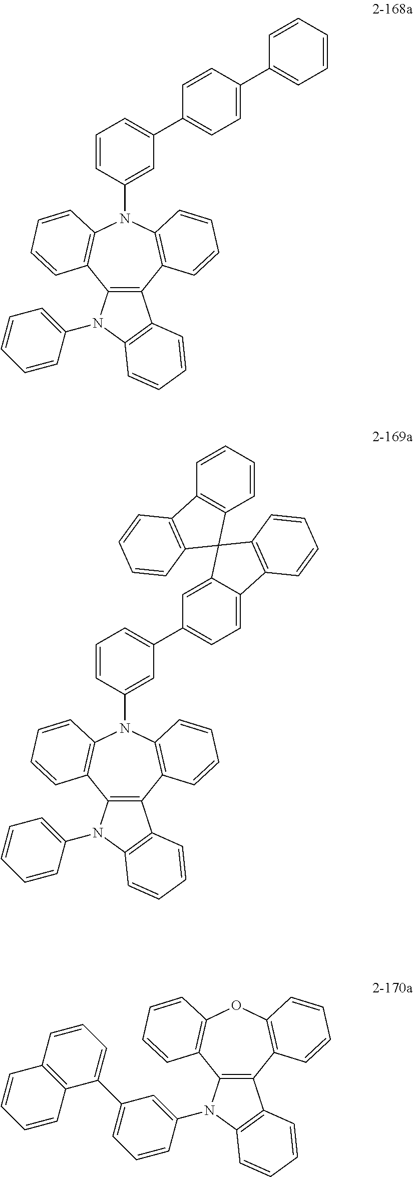 [SMILES: c1ccc(-c2ccc(-c3cccc(N4c5ccccc5-c5c(n(-c6ccccc6)c6ccccc56)-c5ccccc54)c3)cc2)cc1 ; c1ccc(-n2c3c(c4ccccc42)-c2ccccc2N(c2cccc(-c4ccc5c(c4)C4(c6ccccc6-c6ccccc64)c4ccccc4-5)c2)c2ccccc2-3)cc1 ; c1cc(-c2cccc3ccccc23)cc(-n2c3c(c4ccccc42)-c2ccccc2Oc2ccccc2-3)c1]

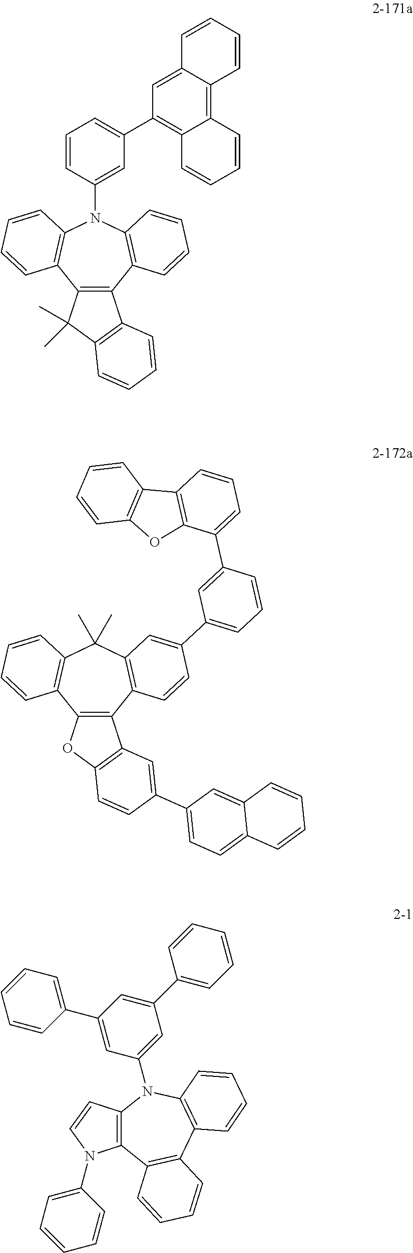 [SMILES: CC1(C)C2=C(c3ccccc3N(c3cccc(-c4cc5ccccc5c5ccccc45)c3)c3ccccc32)c2ccccc21 ; CC1(C)c2ccccc2-c2oc3ccc(-c4ccc5ccccc5c4)cc3c2-c2ccc(-c3cccc(-c4cccc5c4oc4ccccc45)c3)cc21 ; c1ccc(-c2cc(-c3ccccc3)cc(N3c4ccccc4-c4ccccc4-c4c3ccn4-c3ccccc3)c2)cc1]

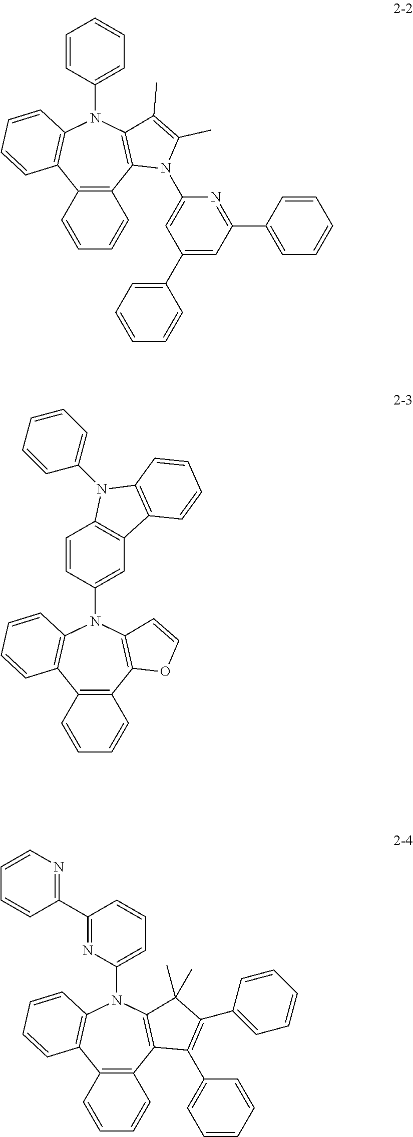 [SMILES: Cc1c2c(n(-c3cc(-c4ccccc4)cc(-c4ccccc4)n3)c1C)-c1ccccc1-c1ccccc1N2c1ccccc1 ; c1ccc(-n2c3ccccc3c3cc(N4c5ccccc5-c5ccccc5-c5occc54)ccc32)cc1 ; CC1(C)C(c2ccccc2)=C(c2ccccc2)C2=C1N(c1cccc(-c3ccccn3)n1)c1ccccc1-c1ccccc12]

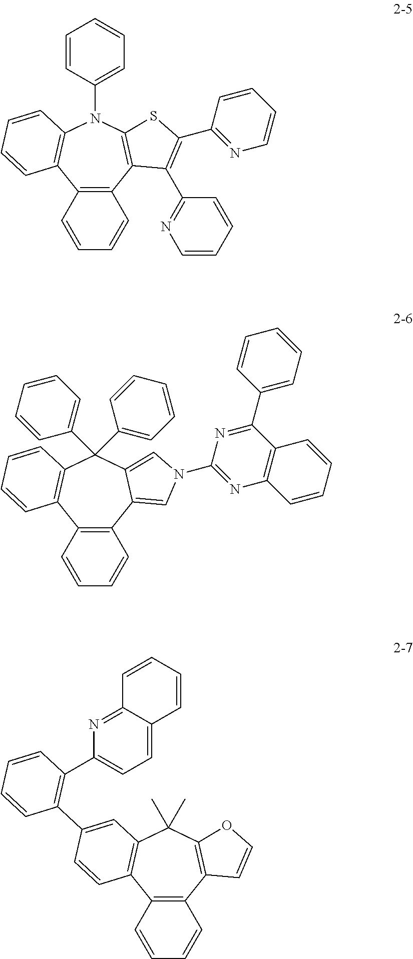 [SMILES: c1ccc(N2c3ccccc3-c3ccccc3-c3c2sc(-c2ccccn2)c3-c2ccccn2)cc1 ; c1ccc(-c2nc(-n3cc4c(c3)C(c3ccccc3)(c3ccccc3)c3ccccc3-c3ccccc3-4)nc3ccccc23)cc1 ; CC1(C)c2cc(-c3ccccc3-c3ccc4ccccc4n3)ccc2-c2ccccc2-c2ccoc21]

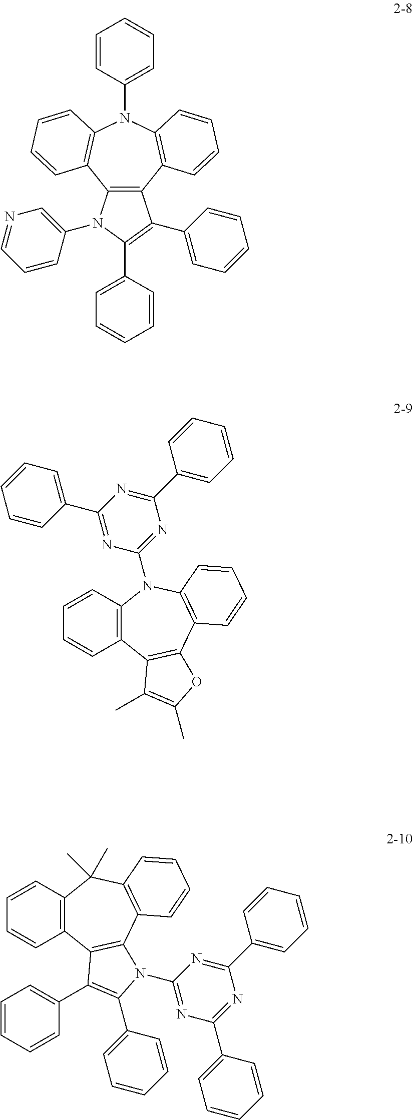 [SMILES: c1ccc(-c2c3c(n(-c4cccnc4)c2-c2ccccc2)-c2ccccc2N(c2ccccc2)c2ccccc2-3)cc1 ; Cc1oc2c(c1C)-c1ccccc1N(c1nc(-c3ccccc3)nc(-c3ccccc3)n1)c1ccccc1-2 ; CC1(C)c2ccccc2-c2c(-c3ccccc3)c(-c3ccccc3)n(-c3nc(-c4ccccc4)nc(-c4ccccc4)n3)c2-c2ccccc21]

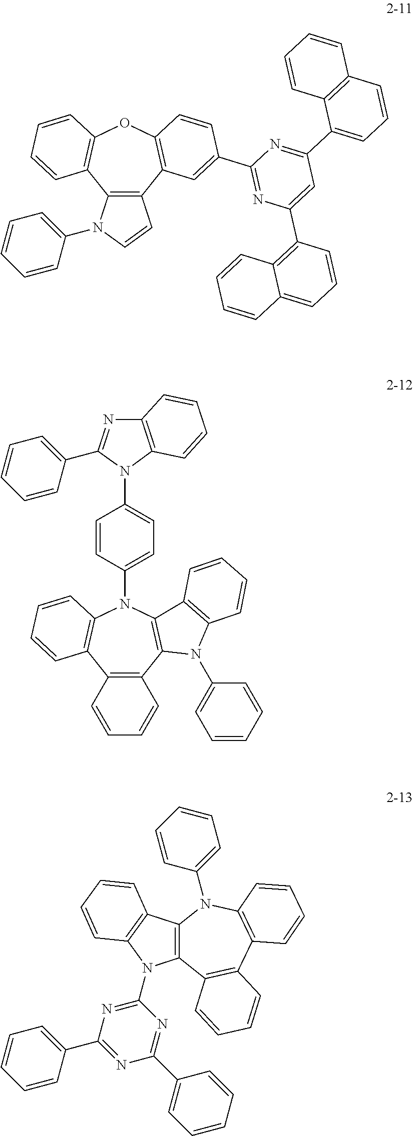 [SMILES: c1ccc(-n2ccc3c2-c2ccccc2Oc2ccc(-c4nc(-c5cccc6ccccc56)cc(-c5cccc6ccccc56)n4)cc2-3)cc1 ; c1ccc(-c2nc3ccccc3n2-c2ccc(N3c4ccccc4-c4ccccc4-c4c3c3ccccc3n4-c3ccccc3)cc2)cc1 ; c1ccc(-c2nc(-c3ccccc3)nc(-n3c4c(c5ccccc53)N(c3ccccc3)c3ccccc3-c3ccccc3-4)n2)cc1]

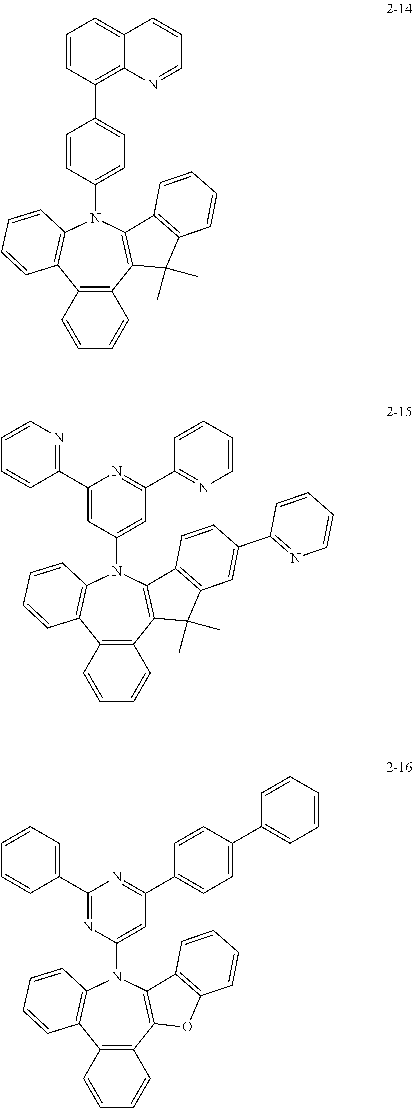 [SMILES: CC1(C)C2=C(c3ccccc31)N(c1ccc(-c3cccc4cccnc34)cc1)c1ccccc1-c1ccccc12 ; CC1(C)C2=C(c3ccc(-c4ccccn4)cc31)N(c1cc(-c3ccccn3)nc(-c3ccccn3)c1)c1ccccc1-c1ccccc12 ; c1ccc(-c2ccc(-c3cc(N4c5ccccc5-c5ccccc5-c5oc6ccccc6c54)nc(-c4ccccc4)n3)cc2)cc1]

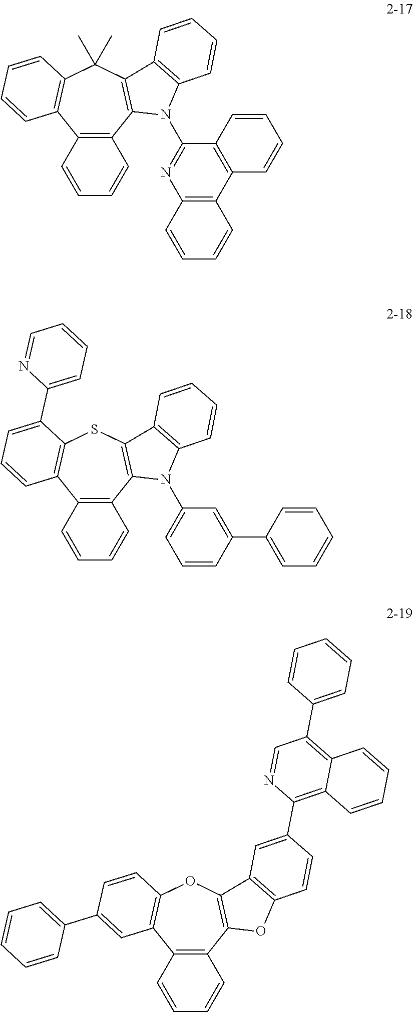 [SMILES: CC1(C)c2ccccc2-c2ccccc2-c2c1c1ccccc1n2-c1nc2ccccc2c2ccccc12 ; c1ccc(-c2cccc(-n3c4c(c5ccccc53)Sc3c(-c5ccccn5)cccc3-c3ccccc3-4)c2)cc1 ; c1ccc(-c2ccc3c(c2)-c2ccccc2-c2oc4ccc(-c5ncc(-c6ccccc6)c6ccccc56)cc4c2O3)cc1]

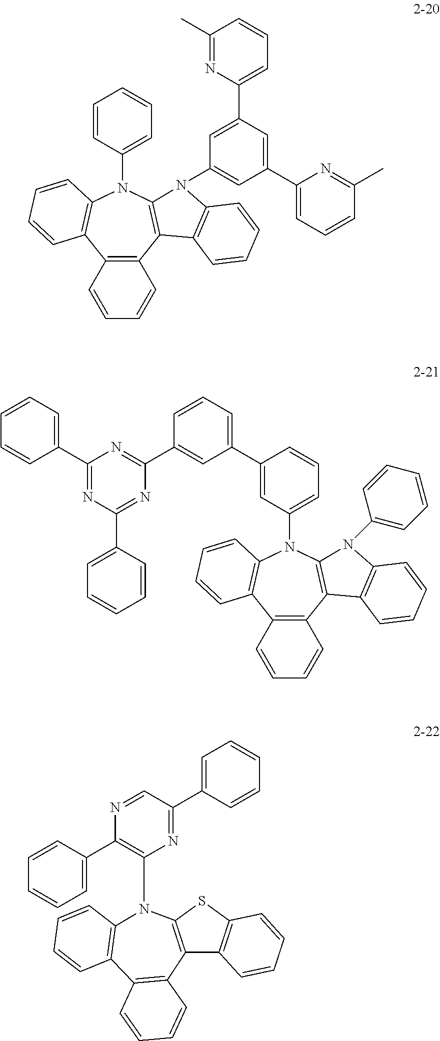 [SMILES: Cc1cccc(-c2cc(-c3cccc(C)n3)cc(-n3c4c(c5ccccc53)-c3ccccc3-c3ccccc3N4c3ccccc3)c2)n1 ; c1ccc(-c2nc(-c3ccccc3)nc(-c3cccc(-c4cccc(N5c6ccccc6-c6ccccc6-c6c5n(-c5ccccc5)c5ccccc65)c4)c3)n2)cc1 ; c1ccc(-c2cnc(-c3ccccc3)c(N3c4ccccc4-c4ccccc4-c4c3sc3ccccc43)n2)cc1]

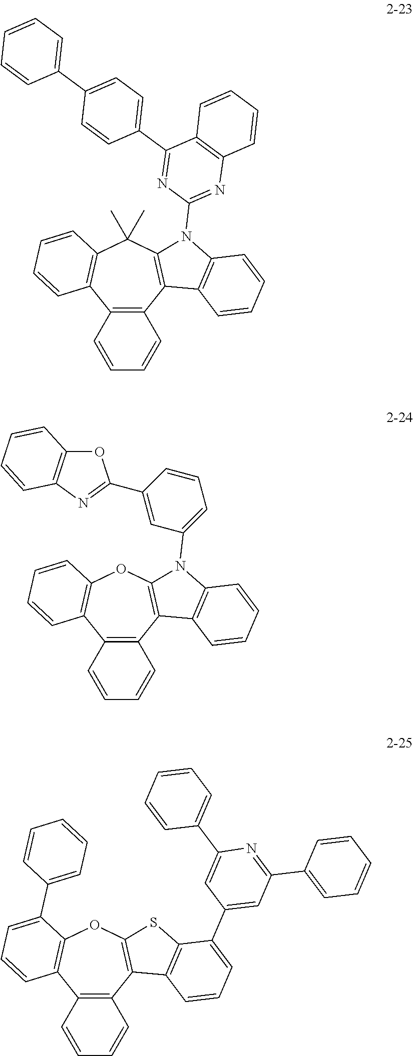 [SMILES: CC1(C)c2ccccc2-c2ccccc2-c2c1n(-c1nc(-c3ccc(-c4ccccc4)cc3)c3ccccc3n1)c1ccccc21 ; c1cc(-c2nc3ccccc3o2)cc(-n2c3c(c4ccccc42)-c2ccccc2-c2ccccc2O3)c1 ; c1ccc(-c2cc(-c3cccc4c5c(sc34)Oc3c(-c4ccccc4)cccc3-c3ccccc3-5)cc(-c3ccccc3)n2)cc1]

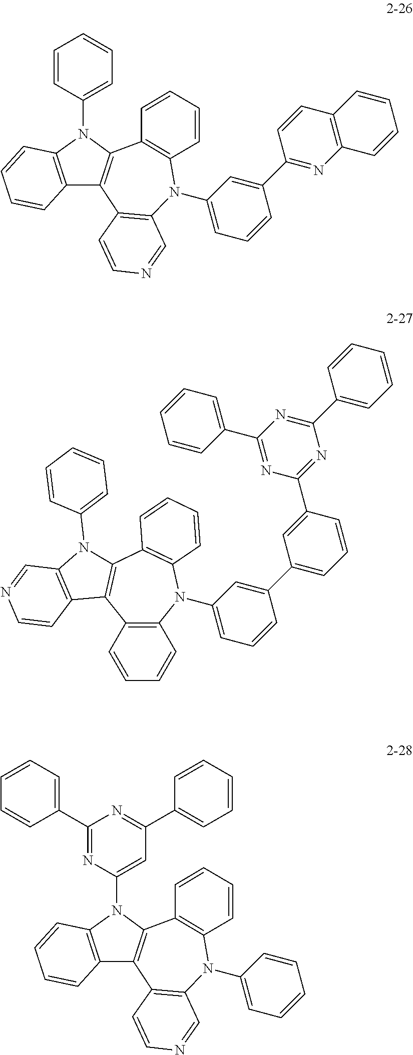 [SMILES: c1ccc(-n2c3c(c4ccccc42)-c2ccncc2N(c2cccc(-c4ccc5ccccc5n4)c2)c2ccccc2-3)cc1 ; c1ccc(-c2nc(-c3ccccc3)nc(-c3cccc(-c4cccc(N5c6ccccc6-c6c(n(-c7ccccc7)c7cnccc67)-c6ccccc65)c4)c3)n2)cc1 ; c1ccc(-c2cc(-n3c4c(c5ccccc53)-c3ccncc3N(c3ccccc3)c3ccccc3-4)nc(-c3ccccc3)n2)cc1]

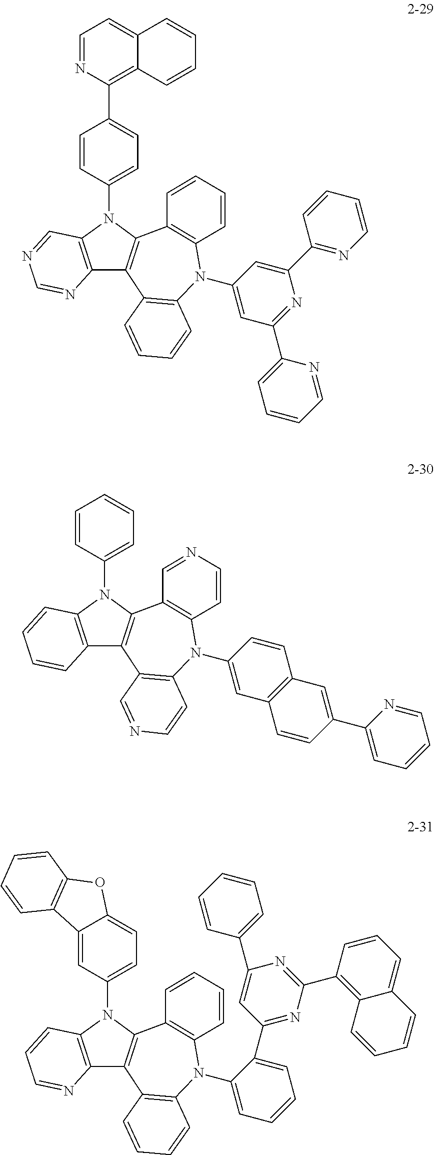 [SMILES: c1ccc(-c2cc(N3c4ccccc4-c4c(n(-c5ccc(-c6nccc7ccccc67)cc5)c5cncnc45)-c4ccccc43)cc(-c3ccccn3)n2)nc1 ; c1ccc(-n2c3c(c4ccccc42)-c2cnccc2N(c2ccc4cc(-c5ccccn5)ccc4c2)c2ccncc2-3)cc1 ; c1ccc(-c2cc(-c3ccccc3N3c4ccccc4-c4c(n(-c5ccc6oc7ccccc7c6c5)c5cccnc45)-c4ccccc43)nc(-c3cccc4ccccc34)n2)cc1]

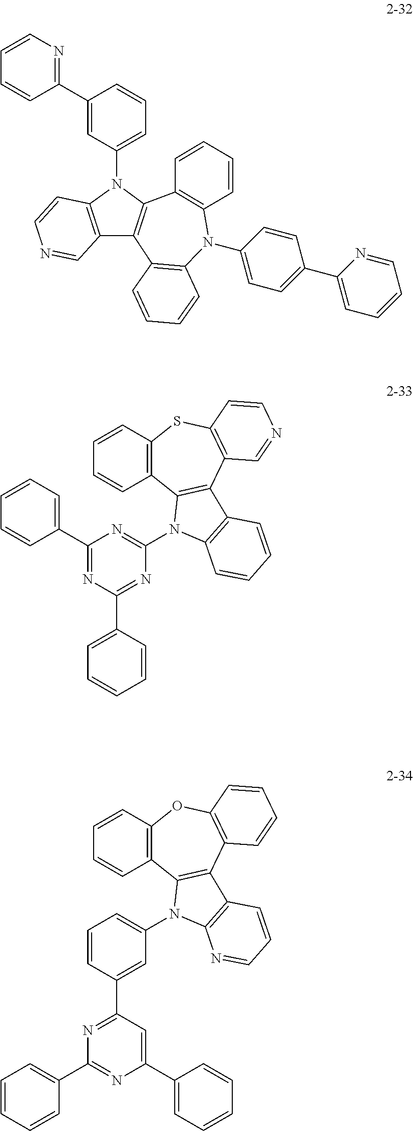 [SMILES: c1ccc(-c2ccc(N3c4ccccc4-c4c(n(-c5cccc(-c6ccccn6)c5)c5ccncc45)-c4ccccc43)cc2)nc1 ; c1ccc(-c2nc(-c3ccccc3)nc(-n3c4c(c5ccccc53)-c3cnccc3Sc3ccccc3-4)n2)cc1 ; c1ccc(-c2cc(-c3cccc(-n4c5c(c6cccnc64)-c4ccccc4Oc4ccccc4-5)c3)nc(-c3ccccc3)n2)cc1]

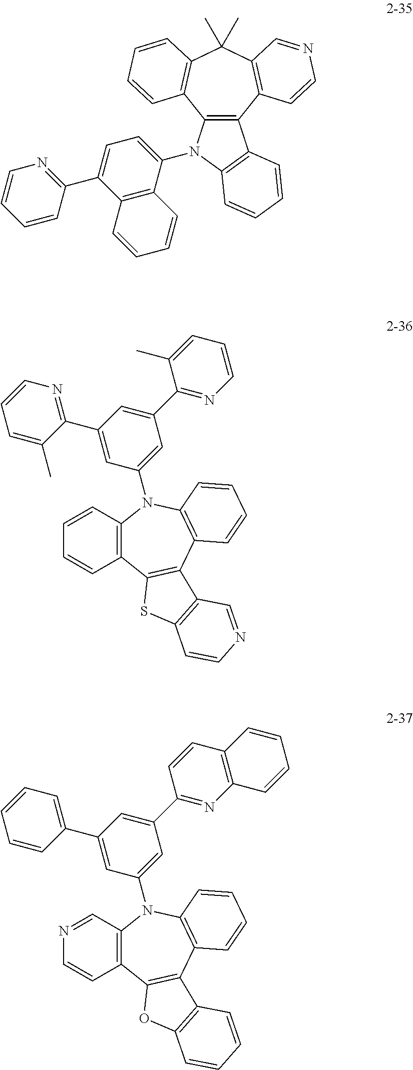 [SMILES: CC1(C)c2cnccc2-c2c(n(-c3ccc(-c4ccccn4)c4ccccc34)c3ccccc23)-c2ccccc21 ; Cc1cccnc1-c1cc(-c2ncccc2C)cc(N2c3ccccc3-c3sc4ccncc4c3-c3ccccc32)c1 ; c1ccc(-c2cc(-c3ccc4ccccc4n3)cc(N3c4cnccc4-c4oc5ccccc5c4-c4ccccc43)c2)cc1]

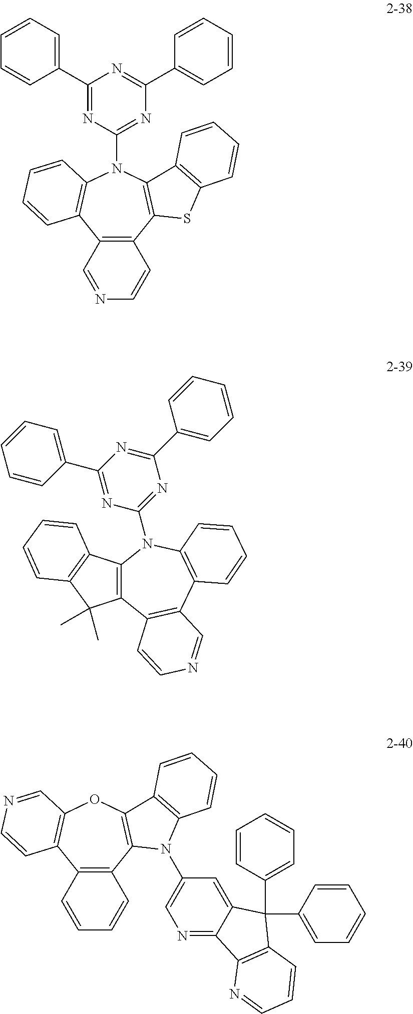 [SMILES: c1ccc(-c2nc(-c3ccccc3)nc(N3c4ccccc4-c4cnccc4-c4sc5ccccc5c43)n2)cc1 ; CC1(C)C2=C(c3ccccc31)N(c1nc(-c3ccccc3)nc(-c3ccccc3)n1)c1ccccc1-c1cnccc12 ; c1ccc(C2(c3ccccc3)c3cccnc3-c3ncc(-n4c5c(c6ccccc64)Oc4cnccc4-c4ccccc4-5)cc32)cc1]

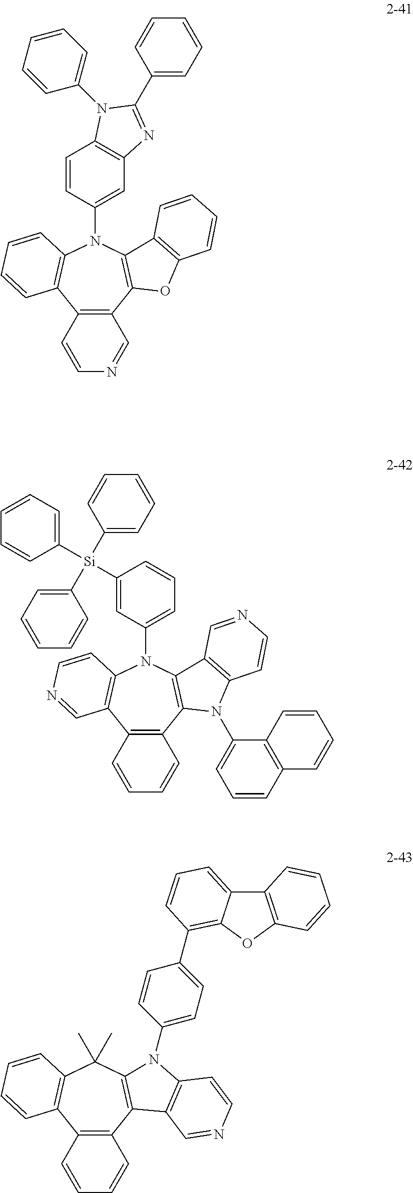 [SMILES: c1ccc(-c2nc3cc(N4c5ccccc5-c5ccncc5-c5oc6ccccc6c54)ccc3n2-c2ccccc2)cc1 ; c1ccc([Si](c2ccccc2)(c2ccccc2)c2cccc(N3c4ccncc4-c4ccccc4-c4c3c3cnccc3n4-c3cccc4ccccc34)c2)cc1 ; CC1(C)c2ccccc2-c2ccccc2-c2c1n(-c1ccc(-c3cccc4c3oc3ccccc34)cc1)c1ccncc21]

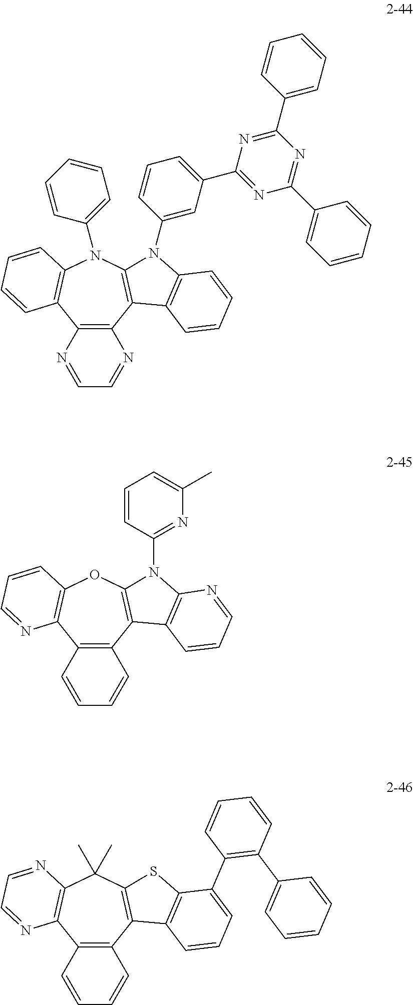 [SMILES: c1ccc(-c2nc(-c3ccccc3)nc(-c3cccc(-n4c5c(c6ccccc64)-c4nccnc4-c4ccccc4N5c4ccccc4)c3)n2)cc1 ; Cc1cccc(-n2c3c(c4cccnc42)-c2ccccc2-c2ncccc2O3)n1 ; CC1(C)c2nccnc2-c2ccccc2-c2c1sc1c(-c3ccccc3-c3ccccc3)cccc21]

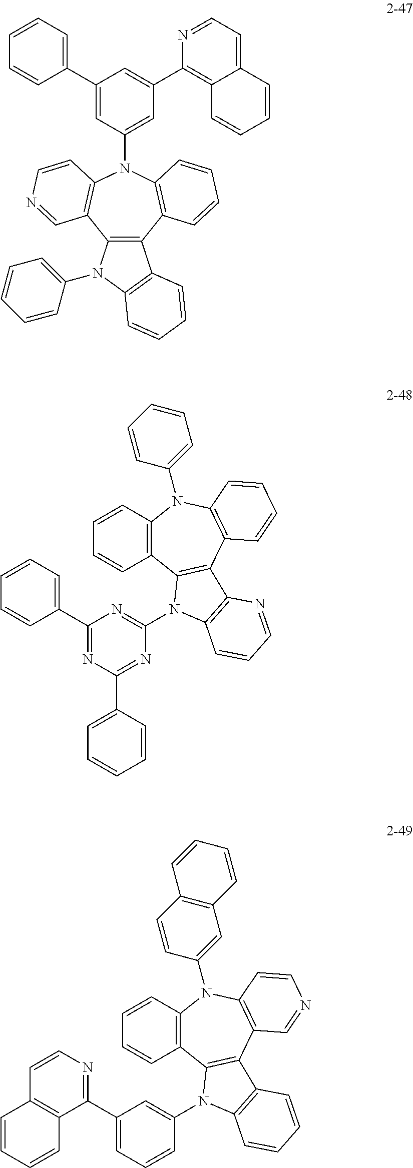 [SMILES: c1ccc(-c2cc(-c3nccc4ccccc34)cc(N3c4ccccc4-c4c(n(-c5ccccc5)c5ccccc45)-c4cnccc43)c2)cc1 ; c1ccc(-c2nc(-c3ccccc3)nc(-n3c4c(c5ncccc53)-c3ccccc3N(c3ccccc3)c3ccccc3-4)n2)cc1 ; c1cc(-c2nccc3ccccc23)cc(-n2c3c(c4ccccc42)-c2cnccc2N(c2ccc4ccccc4c2)c2ccccc2-3)c1]

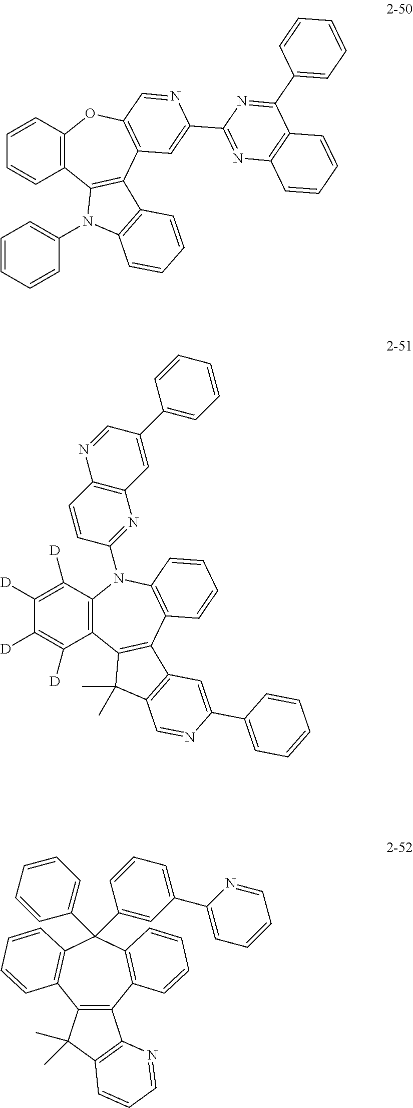 [SMILES: c1ccc(-c2nc(-c3cc4c(cn3)Oc3ccccc3-c3c-4c4ccccc4n3-c3ccccc3)nc3ccccc23)cc1 ; [2H]c1c([2H])c([2H])c2c(c1[2H])C1=C(c3ccccc3N2c2ccc3ncc(-c4ccccc4)cc3n2)c2cc(-c3ccccc3)ncc2C1(C)C ; CC1(C)C2=C(c3ccccc3C(c3ccccc3)(c3cccc(-c4ccccn4)c3)c3ccccc32)c2ncccc21]

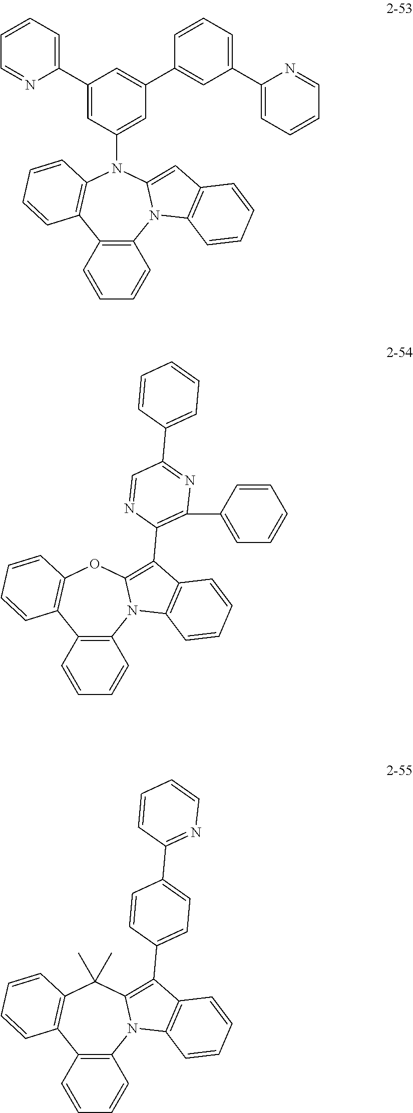 [SMILES: c1ccc(-c2cccc(-c3cc(-c4ccccn4)cc(N4c5ccccc5-c5ccccc5-n5c4cc4ccccc45)c3)c2)nc1 ; c1ccc(-c2cnc(-c3c4n(c5ccccc35)-c3ccccc3-c3ccccc3O4)c(-c3ccccc3)n2)cc1 ; CC1(C)c2ccccc2-c2ccccc2-n2c1c(-c1ccc(-c3ccccn3)cc1)c1ccccc12]

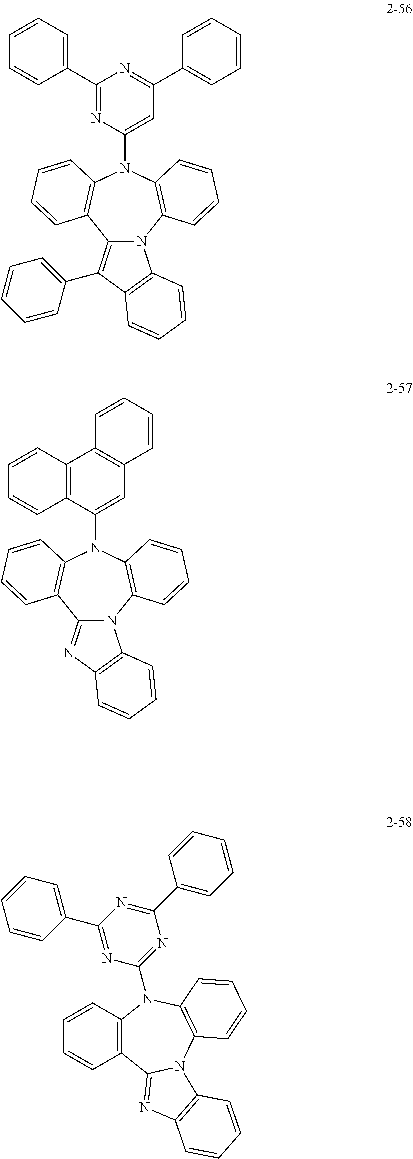 [SMILES: c1ccc(-c2cc(N3c4ccccc4-c4c(-c5ccccc5)c5ccccc5n4-c4ccccc43)nc(-c3ccccc3)n2)cc1 ; c1ccc2c(c1)-c1nc3ccccc3n1-c1ccccc1N2c1cc2ccccc2c2ccccc12 ; c1ccc(-c2nc(-c3ccccc3)nc(N3c4ccccc4-c4nc5ccccc5n4-c4ccccc43)n2)cc1]

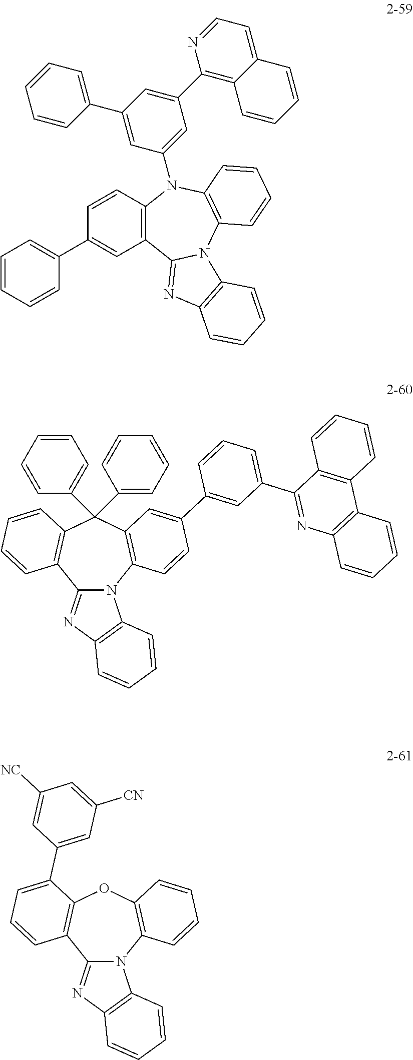 [SMILES: c1ccc(-c2cc(-c3nccc4ccccc34)cc(N3c4ccc(-c5ccccc5)cc4-c4nc5ccccc5n4-c4ccccc43)c2)cc1 ; c1ccc(C2(c3ccccc3)c3ccccc3-c3nc4ccccc4n3-c3ccc(-c4cccc(-c5nc6ccccc6c6ccccc56)c4)cc32)cc1 ; N#Cc1cc(C#N)cc(-c2cccc3c2Oc2ccccc2-n2c-3nc3ccccc32)c1]

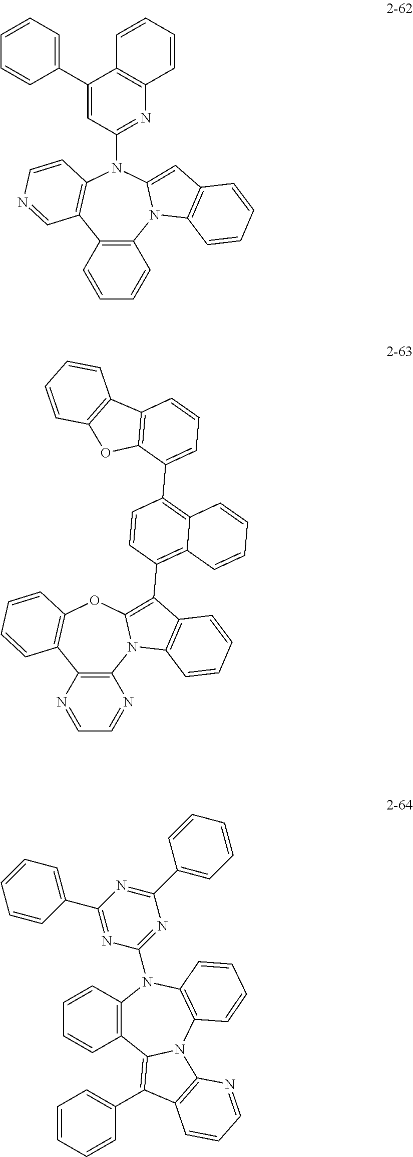 [SMILES: c1ccc(-c2cc(N3c4ccncc4-c4ccccc4-n4c3cc3ccccc34)nc3ccccc23)cc1 ; c1ccc2c(c1)Oc1c(-c3ccc(-c4cccc5c4oc4ccccc45)c4ccccc34)c3ccccc3n1-c1nccnc1-2 ; c1ccc(-c2nc(-c3ccccc3)nc(N3c4ccccc4-c4c(-c5ccccc5)c5cccnc5n4-c4ccccc43)n2)cc1]

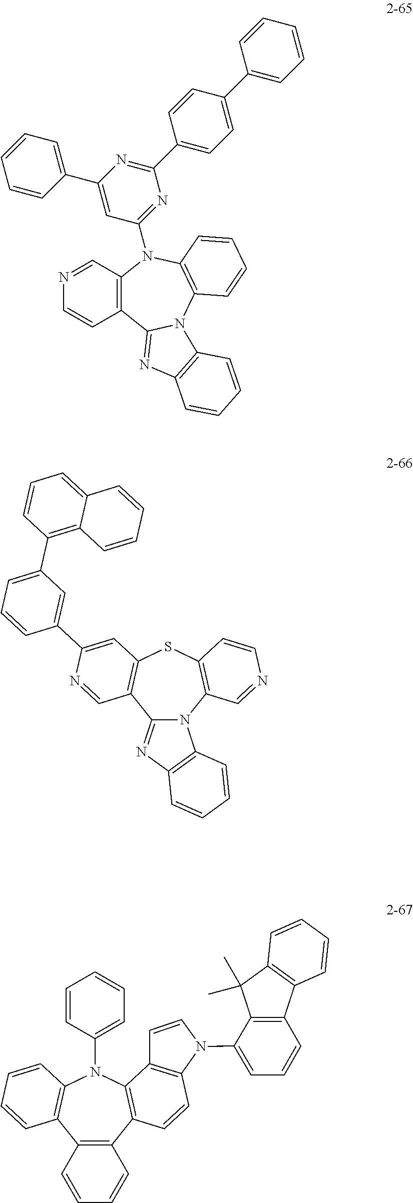 [SMILES: c1ccc(-c2ccc(-c3nc(-c4ccccc4)cc(N4c5cnccc5-c5nc6ccccc6n5-c5ccccc54)n3)cc2)cc1 ; c1cc(-c2cc3c(cn2)-c2nc4ccccc4n2-c2cnccc2S3)cc(-c2cccc3ccccc23)c1 ; CC1(C)c2ccccc2-c2cccc(-n3ccc4c5c(ccc43)-c3ccccc3-c3ccccc3N5c3ccccc3)c21]

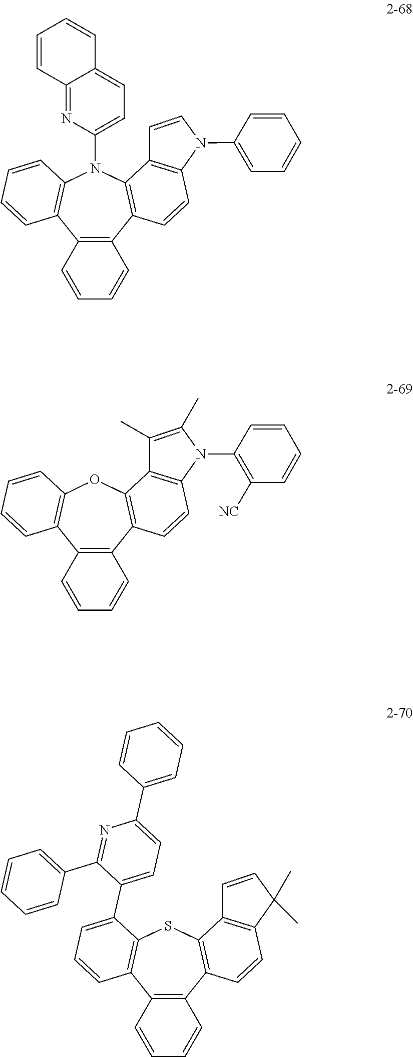 [SMILES: c1ccc(-n2ccc3c4c(ccc32)-c2ccccc2-c2ccccc2N4c2ccc3ccccc3n2)cc1 ; Cc1c(C)n(-c2ccccc2C#N)c2ccc3c(c12)Oc1ccccc1-c1ccccc1-3 ; CC1(C)C=Cc2c1ccc1c2Sc2c(cccc2-c2ccc(-c3ccccc3)nc2-c2ccccc2)-c2ccccc2-1]

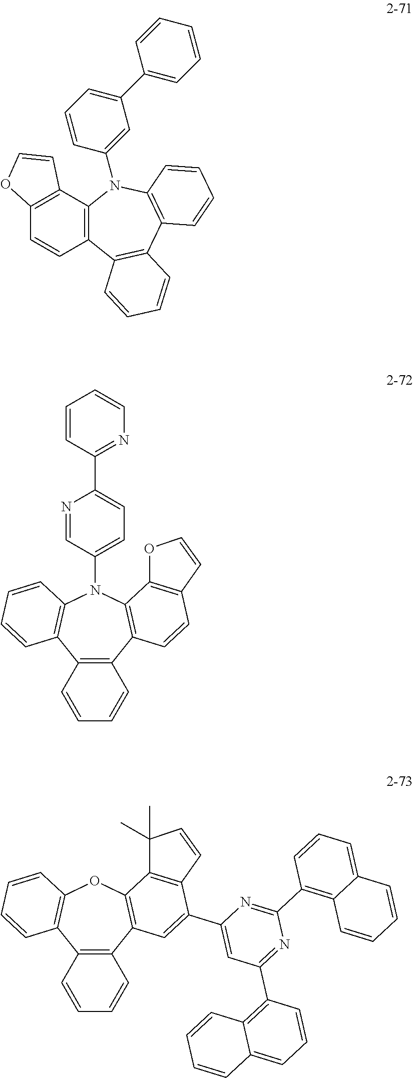 [SMILES: c1ccc(-c2cccc(N3c4ccccc4-c4ccccc4-c4ccc5occc5c43)c2)cc1 ; c1ccc(-c2ccc(N3c4ccccc4-c4ccccc4-c4ccc5ccoc5c43)cn2)nc1 ; CC1(C)C=Cc2c(-c3cc(-c4cccc5ccccc45)nc(-c4cccc5ccccc45)n3)cc3c(c21)Oc1ccccc1-c1ccccc1-3]

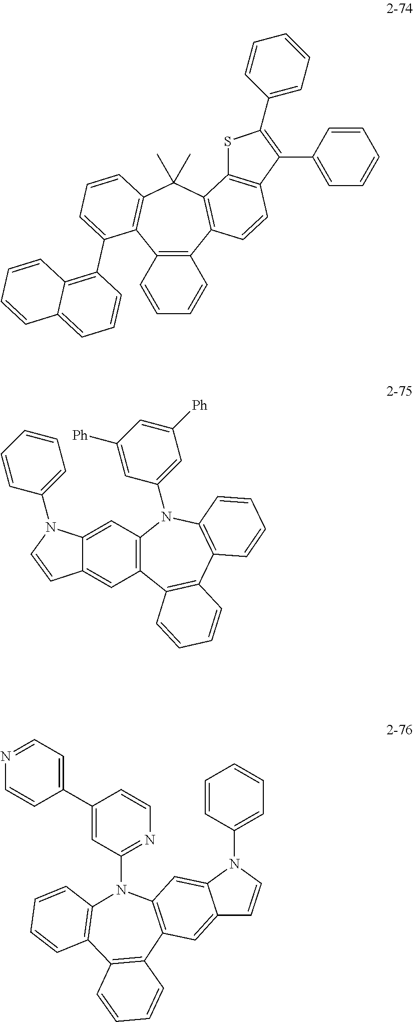 [SMILES: CC1(C)c2cccc(-c3cccc4ccccc34)c2-c2ccccc2-c2ccc3c(-c4ccccc4)c(-c4ccccc4)sc3c21 ; c1ccc(-c2cc(-c3ccccc3)cc(N3c4ccccc4-c4ccccc4-c4cc5ccn(-c6ccccc6)c5cc43)c2)cc1 ; c1ccc(-n2ccc3cc4c(cc32)N(c2cc(-c3ccncc3)ccn2)c2ccccc2-c2ccccc2-4)cc1]

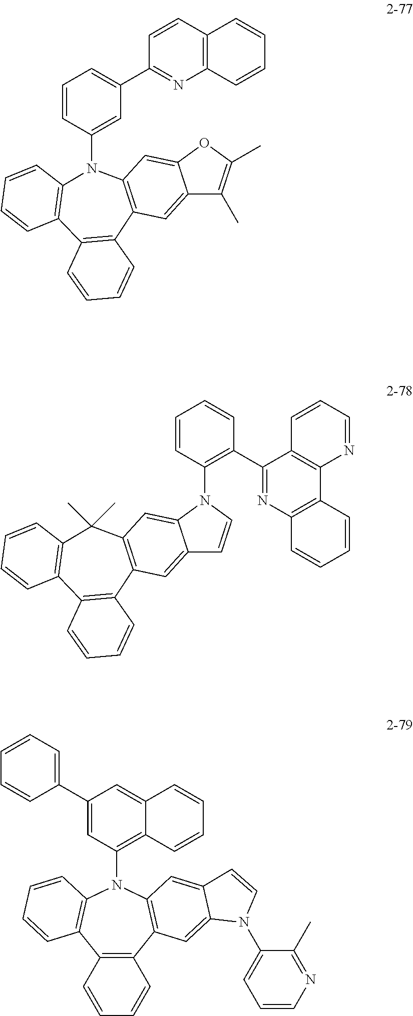 [SMILES: Cc1oc2cc3c(cc2c1C)-c1ccccc1-c1ccccc1N3c1cccc(-c2ccc3ccccc3n2)c1 ; CC1(C)c2ccccc2-c2ccccc2-c2cc3ccn(-c4ccccc4-c4nc5ccccc5c5ncccc45)c3cc21 ; Cc1ncccc1-n1ccc2cc3c(cc21)-c1ccccc1-c1ccccc1N3c1cc(-c2ccccc2)cc2ccccc12]

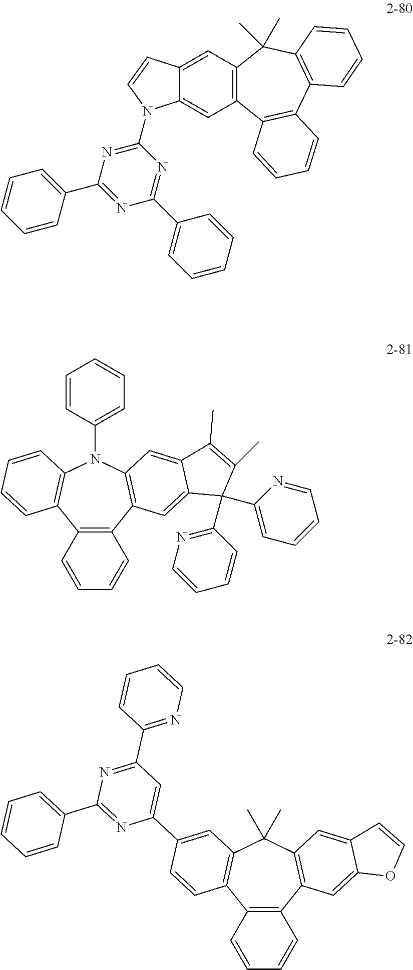 [SMILES: CC1(C)c2ccccc2-c2ccccc2-c2cc3c(ccn3-c3nc(-c4ccccc4)nc(-c4ccccc4)n3)cc21 ; CC1=C(C)C(c2ccccn2)(c2ccccn2)c2cc3c(cc21)N(c1ccccc1)c1ccccc1-c1ccccc1-3 ; CC1(C)c2cc(-c3cc(-c4ccccn4)nc(-c4ccccc4)n3)ccc2-c2ccccc2-c2cc3occc3cc21]

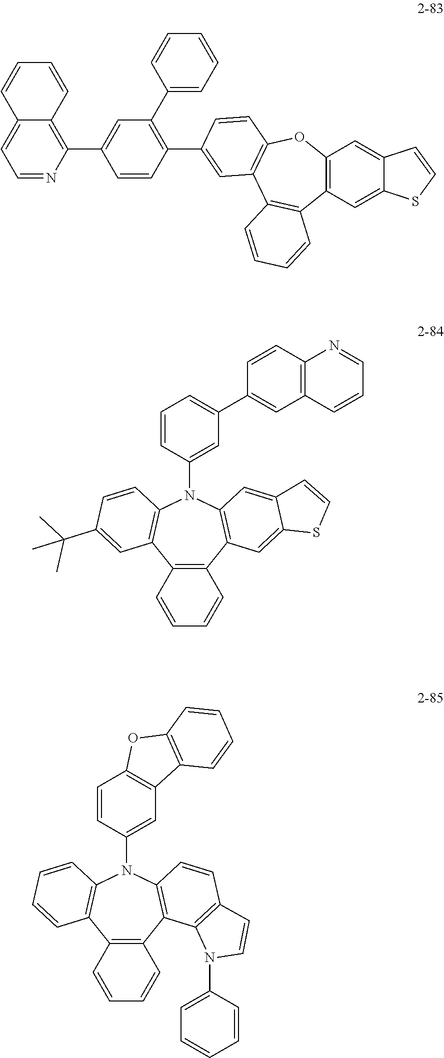 [SMILES: c1ccc(-c2cc(-c3nccc4ccccc34)ccc2-c2ccc3c(c2)-c2ccccc2-c2cc4sccc4cc2O3)cc1 ; CC(C)(C)c1ccc2c(c1)-c1ccccc1-c1cc3sccc3cc1N2c1cccc(-c2ccc3ncccc3c2)c1 ; c1ccc(-n2ccc3ccc4c(c32)-c2ccccc2-c2ccccc2N4c2ccc3oc4ccccc4c3c2)cc1]

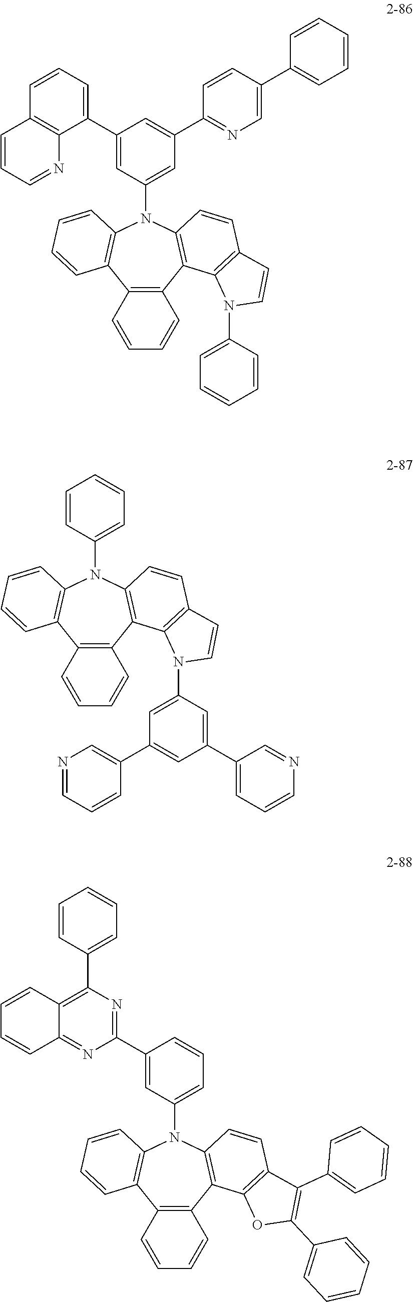 [SMILES: c1ccc(-c2ccc(-c3cc(-c4cccc5cccnc45)cc(N4c5ccccc5-c5ccccc5-c5c4ccc4ccn(-c6ccccc6)c54)c3)nc2)cc1 ; c1ccc(N2c3ccccc3-c3ccccc3-c3c2ccc2ccn(-c4cc(-c5cccnc5)cc(-c5cccnc5)c4)c32)cc1 ; c1ccc(-c2oc3c4c(ccc3c2-c2ccccc2)N(c2cccc(-c3nc(-c5ccccc5)c5ccccc5n3)c2)c2ccccc2-c2ccccc2-4)cc1]

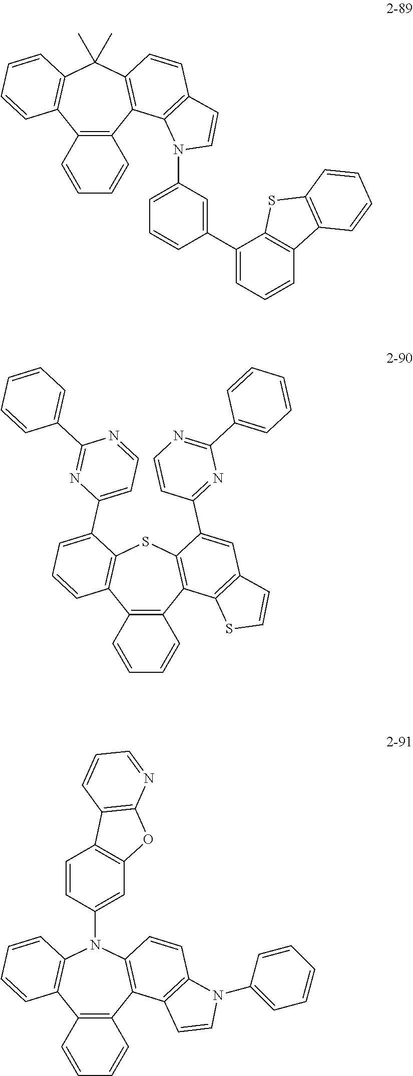 [SMILES: CC1(C)c2ccccc2-c2ccccc2-c2c1ccc1ccn(-c3cccc(-c4cccc5c4sc4ccccc45)c3)c21 ; c1ccc(-c2nccc(-c3cccc4c3Sc3c(-c5ccnc(-c6ccccc6)n5)cc5ccsc5c3-c3ccccc3-4)n2)cc1 ; c1ccc(-n2ccc3c4c(ccc32)N(c2ccc3c(c2)oc2ncccc23)c2ccccc2-c2ccccc2-4)cc1]

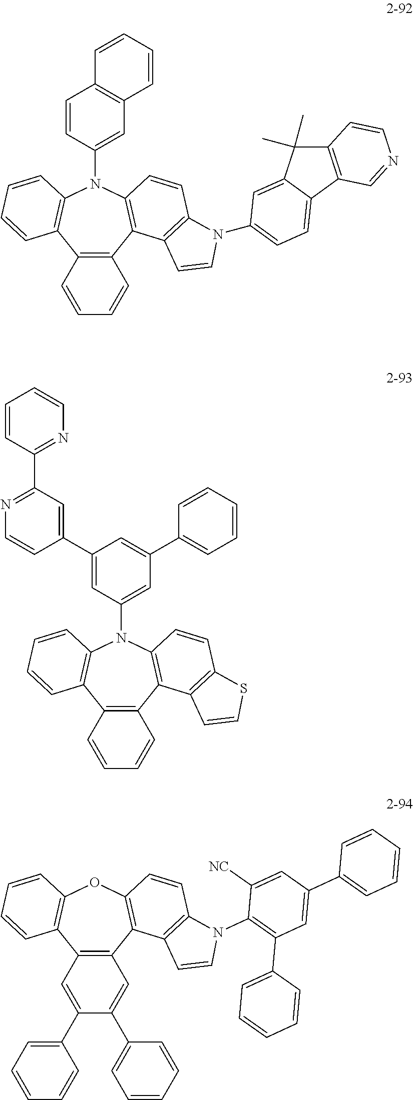 [SMILES: CC1(C)c2ccncc2-c2ccc(-n3ccc4c5c(ccc43)N(c3ccc4ccccc4c3)c3ccccc3-c3ccccc3-5)cc21 ; c1ccc(-c2cc(-c3ccnc(-c4ccccn4)c3)cc(N3c4ccccc4-c4ccccc4-c4c3ccc3sccc43)c2)cc1 ; N#Cc1cc(-c2ccccc2)cc(-c2ccccc2)c1-n1ccc2c3c(ccc21)Oc1ccccc1-c1cc(-c2ccccc2)c(-c2ccccc2)cc1-3]

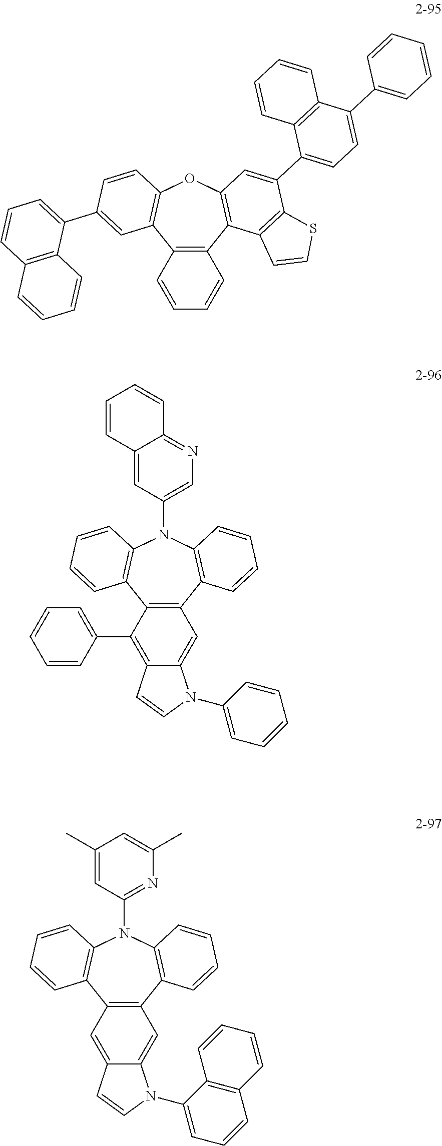 [SMILES: c1ccc(-c2ccc(-c3cc4c(c5ccsc35)-c3ccccc3-c3cc(-c5cccc6ccccc56)ccc3O4)c3ccccc23)cc1 ; c1ccc(-c2c3c(cc4c2ccn4-c2ccccc2)-c2ccccc2N(c2cnc4ccccc4c2)c2ccccc2-3)cc1 ; Cc1cc(C)nc(N2c3ccccc3-c3cc4ccn(-c5cccc6ccccc56)c4cc3-c3ccccc32)c1]

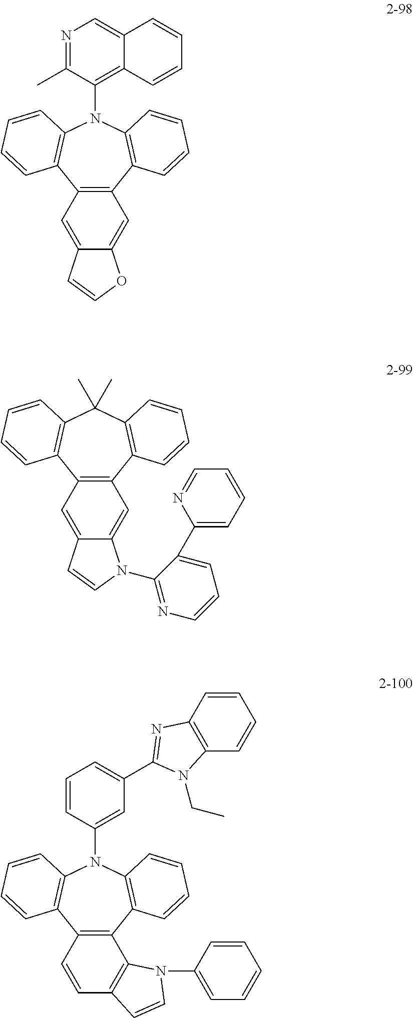 [SMILES: Cc1ncc2ccccc2c1N1c2ccccc2-c2cc3ccoc3cc2-c2ccccc21 ; CC1(C)c2ccccc2-c2cc3ccn(-c4ncccc4-c4ccccn4)c3cc2-c2ccccc21 ; CCn1c(-c2cccc(N3c4ccccc4-c4ccc5ccn(-c6ccccc6)c5c4-c4ccccc43)c2)nc2ccccc21]

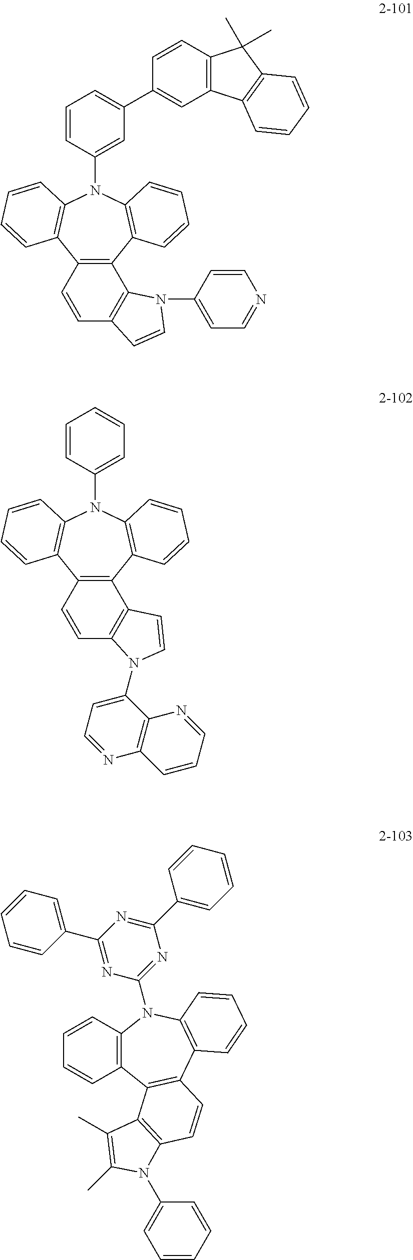 [SMILES: CC1(C)c2ccccc2-c2cc(-c3cccc(N4c5ccccc5-c5ccc6ccn(-c7ccncc7)c6c5-c5ccccc54)c3)ccc21 ; c1ccc(N2c3ccccc3-c3ccc4c(ccn4-c4ccnc5cccnc45)c3-c3ccccc32)cc1 ; Cc1c(C)n(-c2ccccc2)c2ccc3c(c12)-c1ccccc1N(c1nc(-c2ccccc2)nc(-c2ccccc2)n1)c1ccccc1-3]

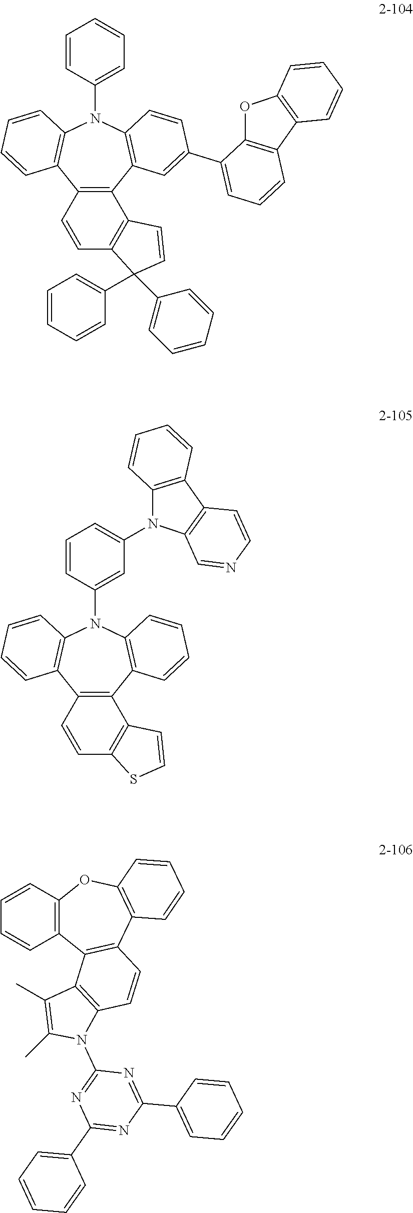 [SMILES: C1=CC(c2ccccc2)(c2ccccc2)c2ccc3c(c21)-c1cc(-c2cccc4c2oc2ccccc24)ccc1N(c1ccccc1)c1ccccc1-3 ; c1cc(N2c3ccccc3-c3ccc4sccc4c3-c3ccccc32)cc(-n2c3ccccc3c3ccncc32)c1 ; Cc1c(C)n(-c2nc(-c3ccccc3)nc(-c3ccccc3)n2)c2ccc3c(c12)-c1ccccc1Oc1ccccc1-3]

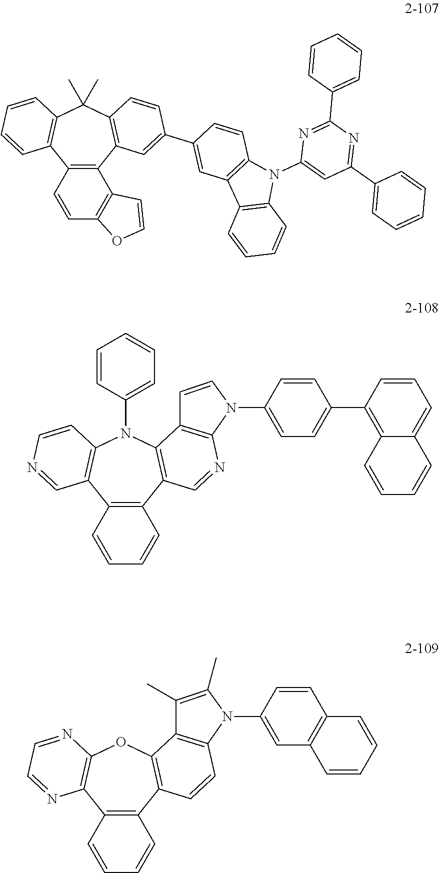 [SMILES: CC1(C)c2ccccc2-c2ccc3occc3c2-c2cc(-c3ccc4c(c3)c3ccccc3n4-c3cc(-c4ccccc4)nc(-c4ccccc4)n3)ccc21 ; c1ccc(N2c3ccncc3-c3ccccc3-c3cnc4c(ccn4-c4ccc(-c5cccc6ccccc56)cc4)c32)cc1 ; Cc1c(C)n(-c2ccc3ccccc3c2)c2ccc3c(c12)Oc1nccnc1-c1ccccc1-3]

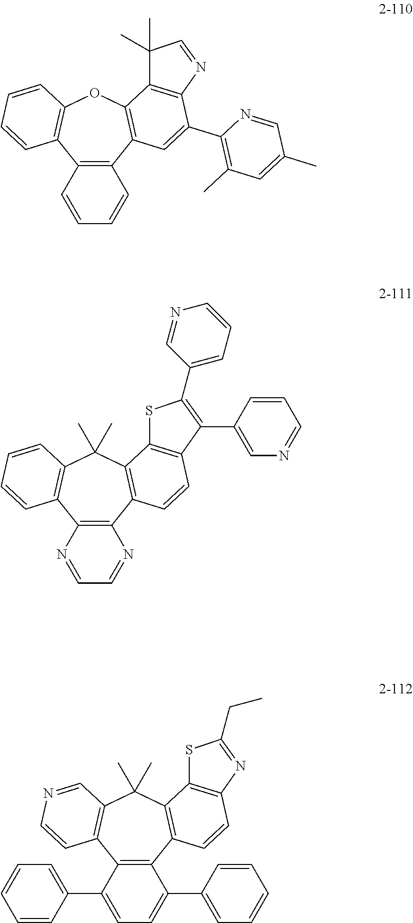 [SMILES: Cc1cnc(-c2cc3c(c4c2N=CC4(C)C)Oc2ccccc2-c2ccccc2-3)c(C)c1 ; CC1(C)c2ccccc2-c2nccnc2-c2ccc3c(-c4cccnc4)c(-c4cccnc4)sc3c21 ; CCc1nc2ccc3c(c2s1)C(C)(C)c1cnccc1-c1c(-c2ccccc2)ccc(-c2ccccc2)c1-3]

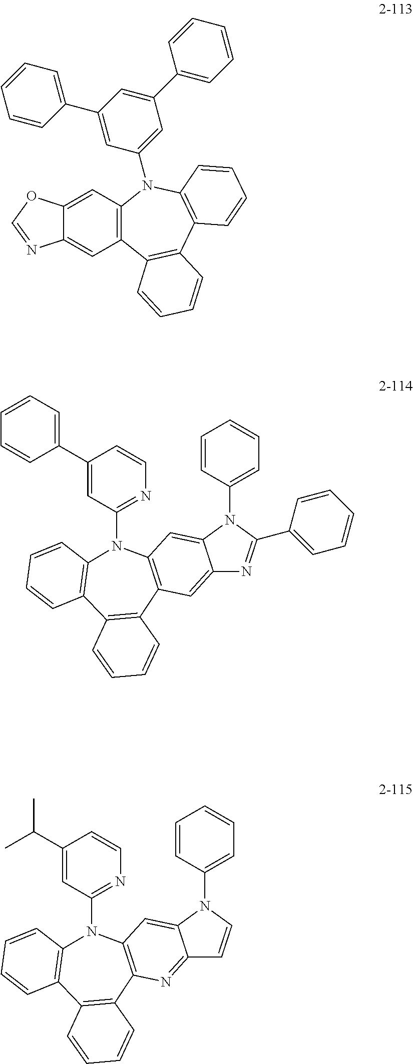 [SMILES: c1ccc(-c2cc(-c3ccccc3)cc(N3c4ccccc4-c4ccccc4-c4cc5ncoc5cc43)c2)cc1 ; c1ccc(-c2ccnc(N3c4ccccc4-c4ccccc4-c4cc5nc(-c6ccccc6)n(-c6ccccc6)c5cc43)c2)cc1 ; CC(C)c1ccnc(N2c3ccccc3-c3ccccc3-c3nc4ccn(-c5ccccc5)c4cc32)c1]

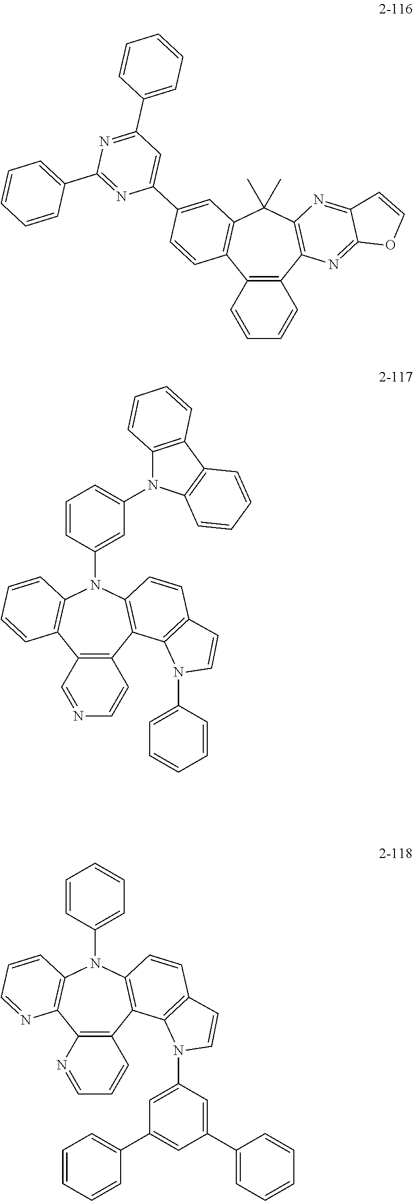 [SMILES: CC1(C)c2cc(-c3cc(-c4ccccc4)nc(-c4ccccc4)n3)ccc2-c2ccccc2-c2nc3occc3nc21 ; c1ccc(-n2ccc3ccc4c(c32)-c2ccncc2-c2ccccc2N4c2cccc(-n3c4ccccc4c4ccccc43)c2)cc1 ; c1ccc(-c2cc(-c3ccccc3)cc(-n3ccc4ccc5c(c43)-c3cccnc3-c3ncccc3N5c3ccccc3)c2)cc1]

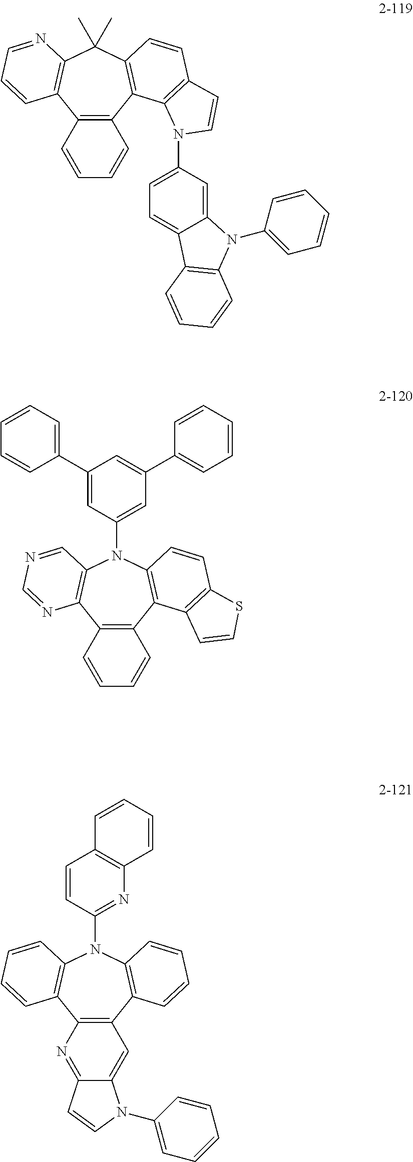 [SMILES: CC1(C)c2ccc3ccn(-c4ccc5c6ccccc6n(-c6ccccc6)c5c4)c3c2-c2ccccc2-c2cccnc21 ; c1ccc(-c2cc(-c3ccccc3)cc(N3c4cncnc4-c4ccccc4-c4c3ccc3sccc43)c2)cc1 ; c1ccc(-n2ccc3nc4c(cc32)-c2ccccc2N(c2ccc3ccccc3n2)c2ccccc2-4)cc1]

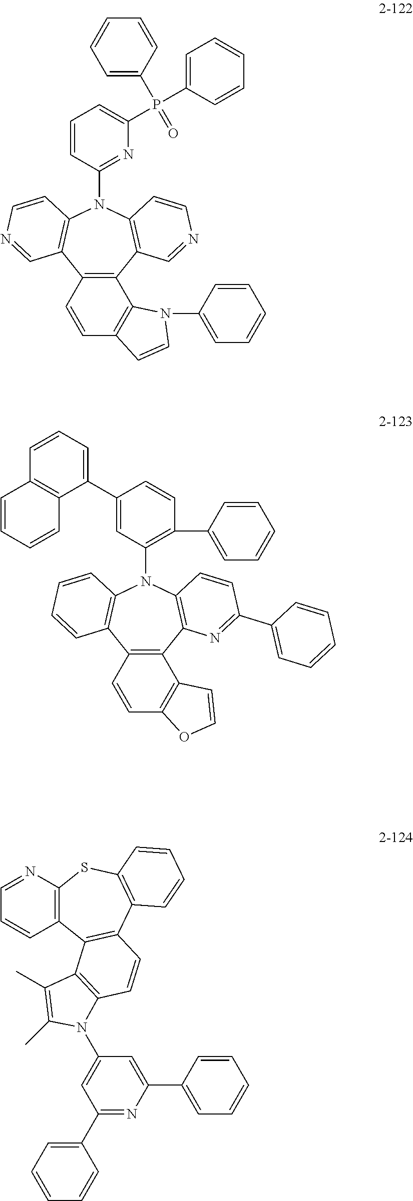 [SMILES: O=P(c1ccccc1)(c1ccccc1)c1cccc(N2c3ccncc3-c3ccc4ccn(-c5ccccc5)c4c3-c3cnccc32)n1 ; c1ccc(-c2ccc3c(n2)-c2c(ccc4occc24)-c2ccccc2N3c2cc(-c3cccc4ccccc34)ccc2-c2ccccc2)cc1 ; Cc1c(C)n(-c2cc(-c3ccccc3)nc(-c3ccccc3)c2)c2ccc3c(c12)-c1cccnc1Sc1ccccc1-3]

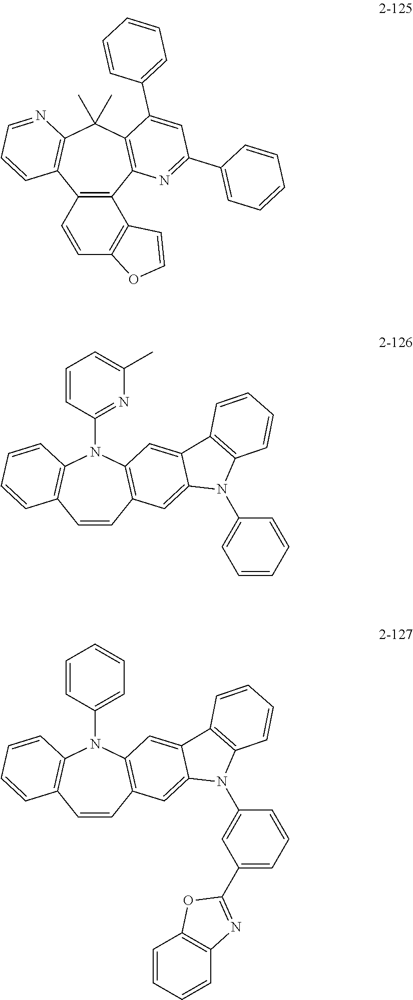 [SMILES: CC1(C)c2ncccc2-c2ccc3occc3c2-c2nc(-c3ccccc3)cc(-c3ccccc3)c21 ; Cc1cccc(N2c3ccccc3C=Cc3cc4c(cc32)c2ccccc2n4-c2ccccc2)n1 ; C1=Cc2cc3c(cc2N(c2ccccc2)c2ccccc21)c1ccccc1n3-c1cccc(-c2nc3ccccc3o2)c1]

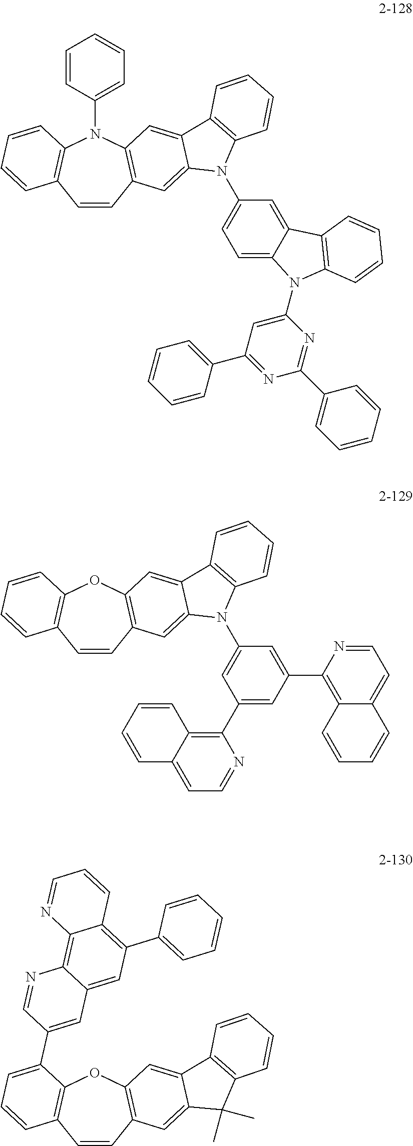 [SMILES: C1=Cc2cc3c(cc2N(c2ccccc2)c2ccccc21)c1ccccc1n3-c1ccc2c(c1)c1ccccc1n2-c1cc(-c2ccccc2)nc(-c2ccccc2)n1 ; C1=Cc2cc3c(cc2Oc2ccccc21)c1ccccc1n3-c1cc(-c2nccc3ccccc23)cc(-c2nccc3ccccc23)c1 ; CC1(C)c2ccccc2-c2cc3c(cc21)C=Cc1cccc(-c2cnc4c(c2)cc(-c2ccccc2)c2cccnc24)c1O3]

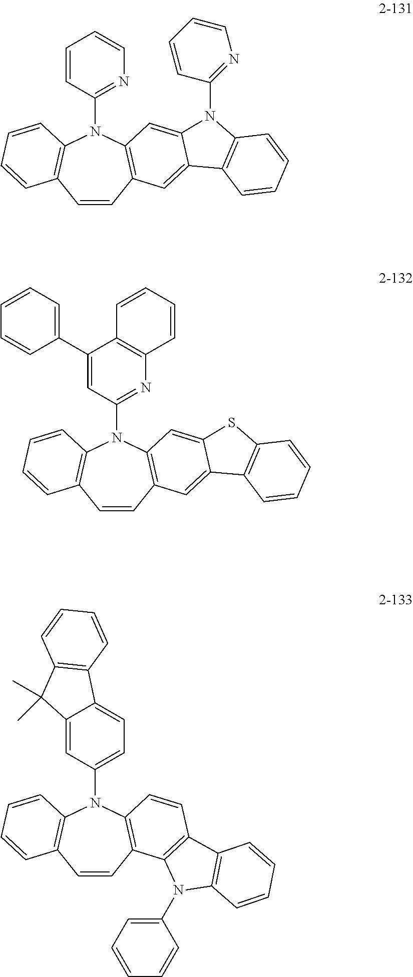 [SMILES: C1=Cc2cc3c4ccccc4n(-c4ccccn4)c3cc2N(c2ccccn2)c2ccccc21 ; C1=Cc2cc3c(cc2N(c2cc(-c4ccccc4)c4ccccc4n2)c2ccccc21)sc1ccccc13 ; CC1(C)c2ccccc2-c2ccc(N3c4ccccc4C=Cc4c3ccc3c5ccccc5n(-c5ccccc5)c43)cc21]

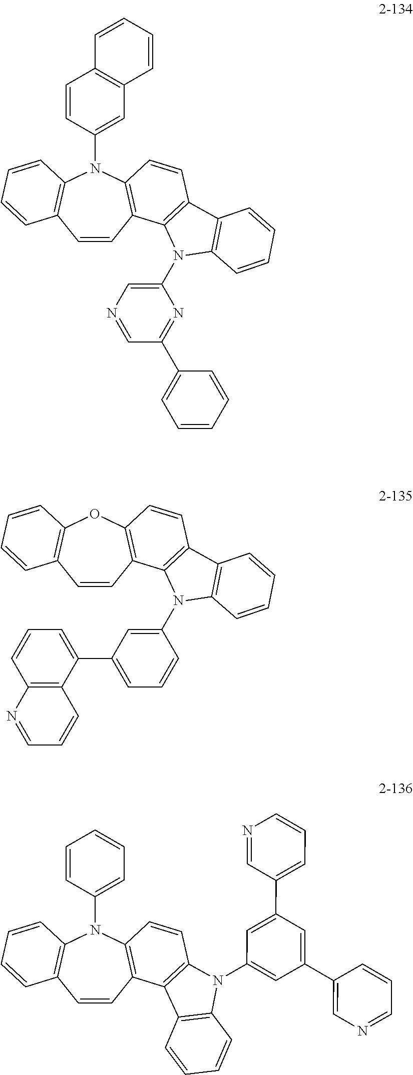 [SMILES: C1=Cc2c(ccc3c4ccccc4n(-c4cncc(-c5ccccc5)n4)c23)N(c2ccc3ccccc3c2)c2ccccc21 ; C1=Cc2c(ccc3c4ccccc4n(-c4cccc(-c5cccc6ncccc56)c4)c23)Oc2ccccc21 ; C1=Cc2c(ccc3c2c2ccccc2n3-c2cc(-c3cccnc3)cc(-c3cccnc3)c2)N(c2ccccc2)c2ccccc21]

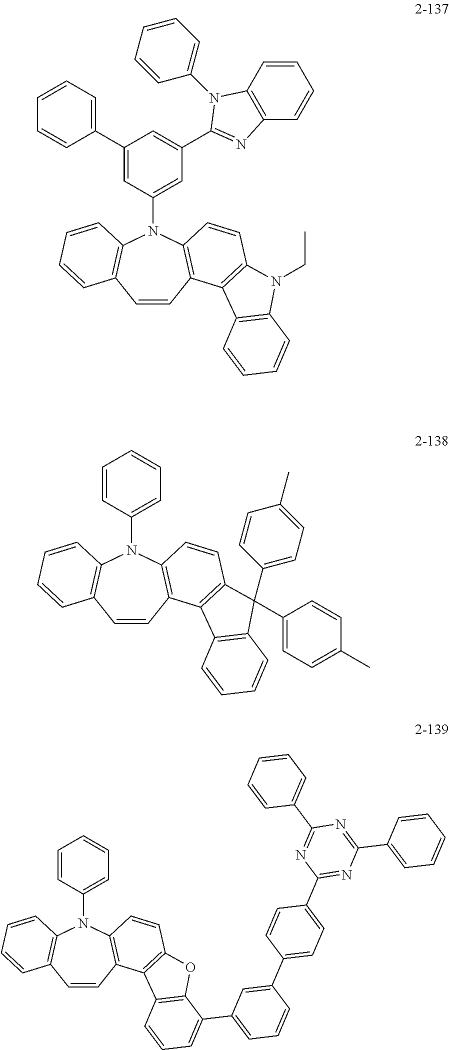 [SMILES: CCn1c2ccccc2c2c3c(ccc21)N(c1cc(-c2ccccc2)cc(-c2nc4ccccc4n2-c2ccccc2)c1)c1ccccc1C=C3 ; Cc1ccc(C2(c3ccc(C)cc3)c3ccccc3-c3c2ccc2c3C=Cc3ccccc3N2c2ccccc2)cc1 ; C1=Cc2c(ccc3oc4c(-c5cccc(-c6ccc(-c7nc(-c8ccccc8)nc(-c8ccccc8)n7)cc6)c5)cccc4c23)N(c2ccccc2)c2ccccc21]

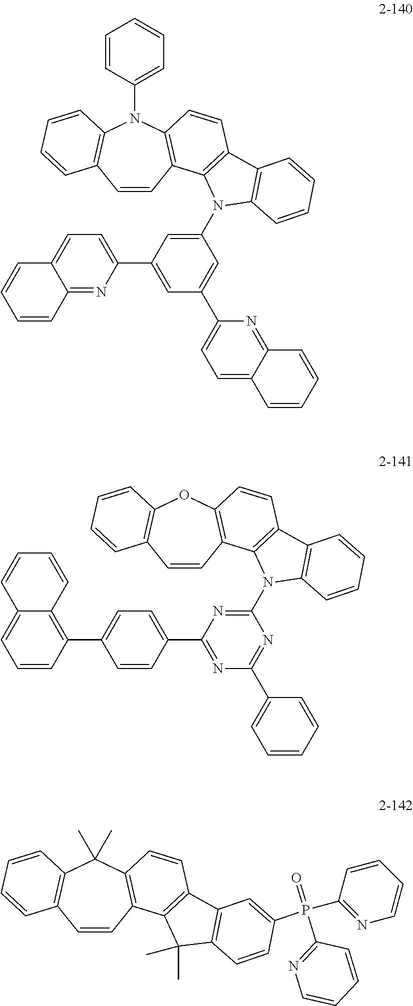 [SMILES: C1=Cc2c(ccc3c4ccccc4n(-c4cc(-c5ccc6ccccc6n5)cc(-c5ccc6ccccc6n5)c4)c23)N(c2ccccc2)c2ccccc21 ; C1=Cc2c(ccc3c4ccccc4n(-c4nc(-c5ccccc5)nc(-c5ccc(-c6cccc7ccccc67)cc5)n4)c23)Oc2ccccc21 ; CC1(C)c2ccccc2C=Cc2c1ccc1c2C(C)(C)c2ccc(P(=O)(c3ccccn3)c3ccccn3)cc2-1]

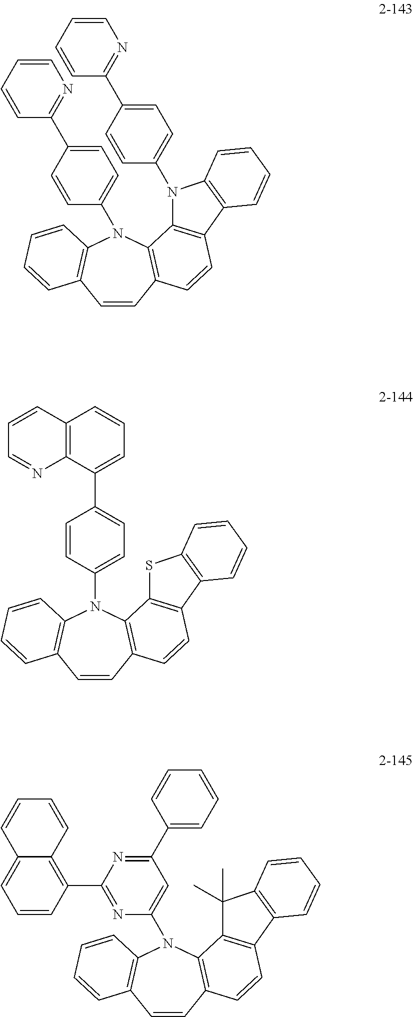 [SMILES: C1=Cc2ccc3c4ccccc4n(-c4ccc(-c5ccccn5)cc4)c3c2N(c2ccc(-c3ccccn3)cc2)c2ccccc21 ; C1=Cc2ccc3c(sc4ccccc43)c2N(c2ccc(-c3cccc4cccnc34)cc2)c2ccccc21 ; CC1(C)c2ccccc2-c2ccc3c(c21)N(c1cc(-c2ccccc2)nc(-c2cccc4ccccc24)n1)c1ccccc1C=C3]

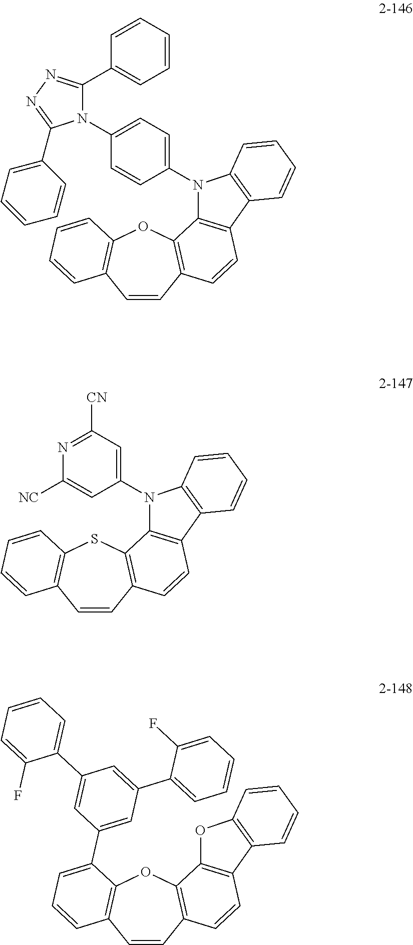 [SMILES: C1=Cc2ccc3c4ccccc4n(-c4ccc(-n5c(-c6ccccc6)nnc5-c5ccccc5)cc4)c3c2Oc2ccccc21 ; N#Cc1cc(-n2c3ccccc3c3ccc4c(c32)Sc2ccccc2C=C4)cc(C#N)n1 ; Fc1ccccc1-c1cc(-c2ccccc2F)cc(-c2cccc3c2Oc2c(ccc4c2oc2ccccc24)C=C3)c1]

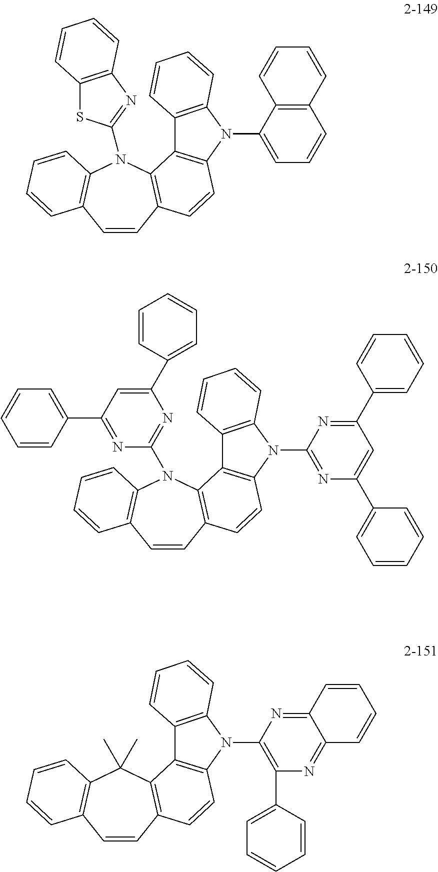 [SMILES: C1=Cc2ccc3c(c2N(c2nc4ccccc4s2)c2ccccc21)c1ccccc1n3-c1cccc2ccccc12 ; C1=Cc2ccc3c(c2N(c2nc(-c4ccccc4)cc(-c4ccccc4)n2)c2ccccc21)c1ccccc1n3-c1nc(-c2ccccc2)cc(-c2ccccc2)n1 ; CC1(C)c2ccccc2C=Cc2ccc3c(c21)c1ccccc1n3-c1nc2ccccc2nc1-c1ccccc1]

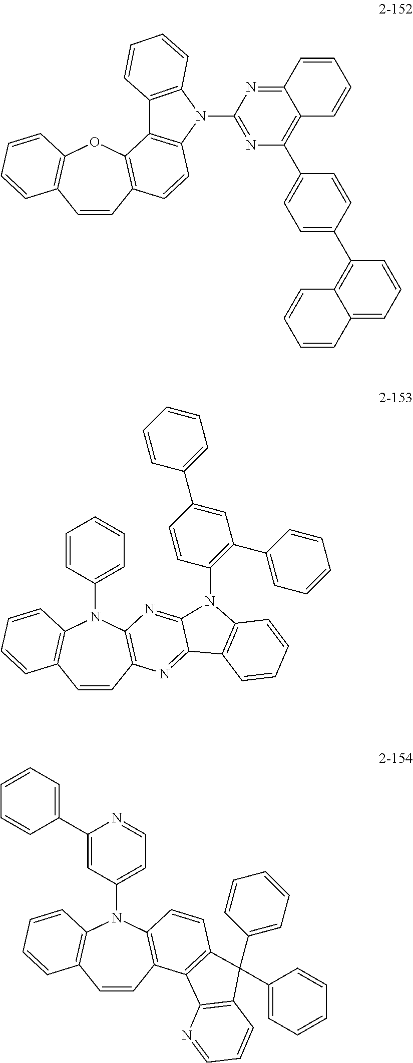 [SMILES: C1=Cc2ccc3c(c2Oc2ccccc21)c1ccccc1n3-c1nc(-c2ccc(-c3cccc4ccccc34)cc2)c2ccccc2n1 ; C1=Cc2nc3c4ccccc4n(-c4ccc(-c5ccccc5)cc4-c4ccccc4)c3nc2N(c2ccccc2)c2ccccc21 ; C1=Cc2c(ccc3c2-c2ncccc2C3(c2ccccc2)c2ccccc2)N(c2ccnc(-c3ccccc3)c2)c2ccccc21]

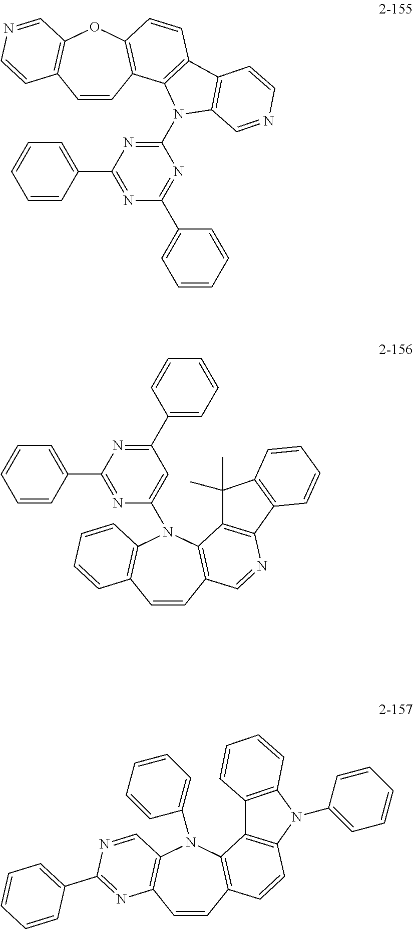 [SMILES: C1=Cc2c(ccc3c4ccncc4n(-c4nc(-c5ccccc5)nc(-c5ccccc5)n4)c23)Oc2cnccc21 ; CC1(C)c2ccccc2-c2ncc3c(c21)N(c1cc(-c2ccccc2)nc(-c2ccccc2)n1)c1ccccc1C=C3 ; C1=Cc2nc(-c3ccccc3)ncc2N(c2ccccc2)c2c1ccc1c2c2ccccc2n1-c1ccccc1]

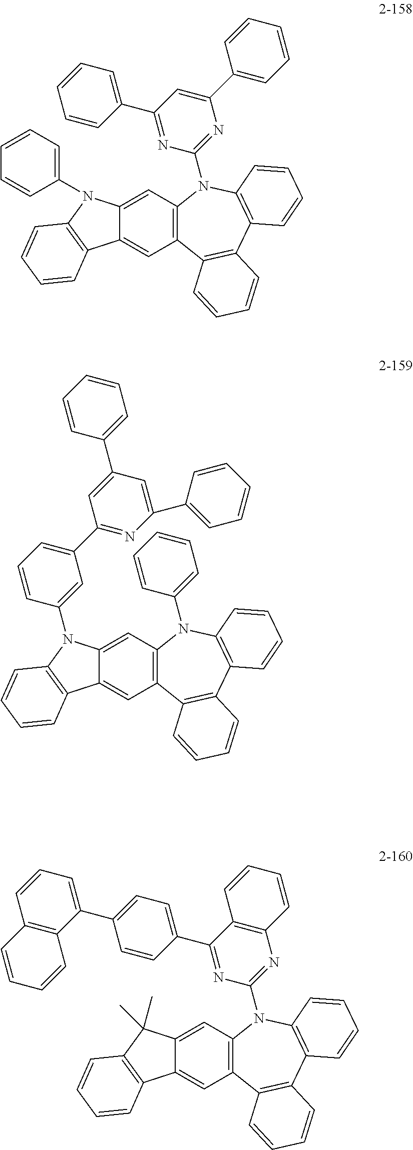 [SMILES: c1ccc(-c2cc(-c3ccccc3)nc(N3c4ccccc4-c4ccccc4-c4cc5c6ccccc6n(-c6ccccc6)c5cc43)n2)cc1 ; c1ccc(-c2cc(-c3ccccc3)nc(-c3cccc(-n4c5ccccc5c5cc6c(cc54)N(c4ccccc4)c4ccccc4-c4ccccc4-6)c3)c2)cc1 ; CC1(C)c2ccccc2-c2cc3c(cc21)N(c1nc(-c2ccc(-c4cccc5ccccc45)cc2)c2ccccc2n1)c1ccccc1-c1ccccc1-3]

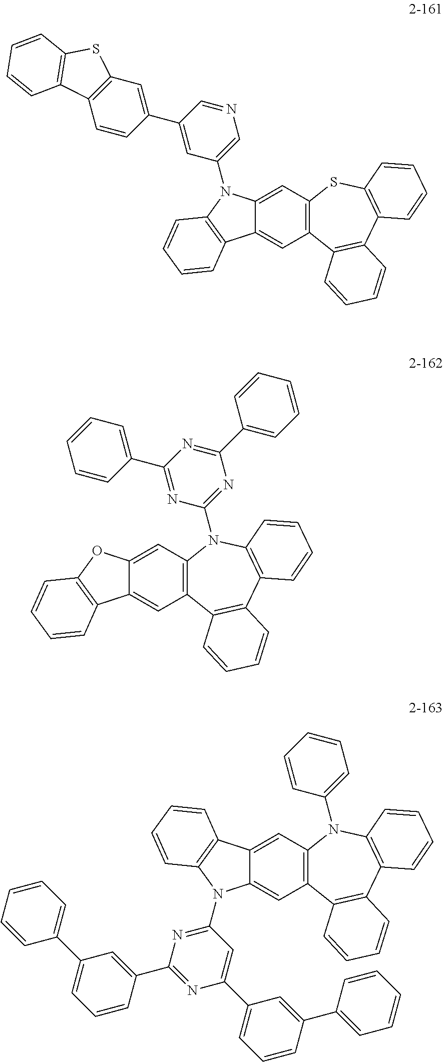 [SMILES: c1ccc2c(c1)Sc1cc3c(cc1-c1ccccc1-2)c1ccccc1n3-c1cncc(-c2ccc3c(c2)sc2ccccc23)c1 ; c1ccc(-c2nc(-c3ccccc3)nc(N3c4ccccc4-c4ccccc4-c4cc5c(cc43)oc3ccccc35)n2)cc1 ; c1ccc(-c2cccc(-c3cc(-n4c5ccccc5c5cc6c(cc54)-c4ccccc4-c4ccccc4N6c4ccccc4)nc(-c4cccc(-c5ccccc5)c4)n3)c2)cc1]

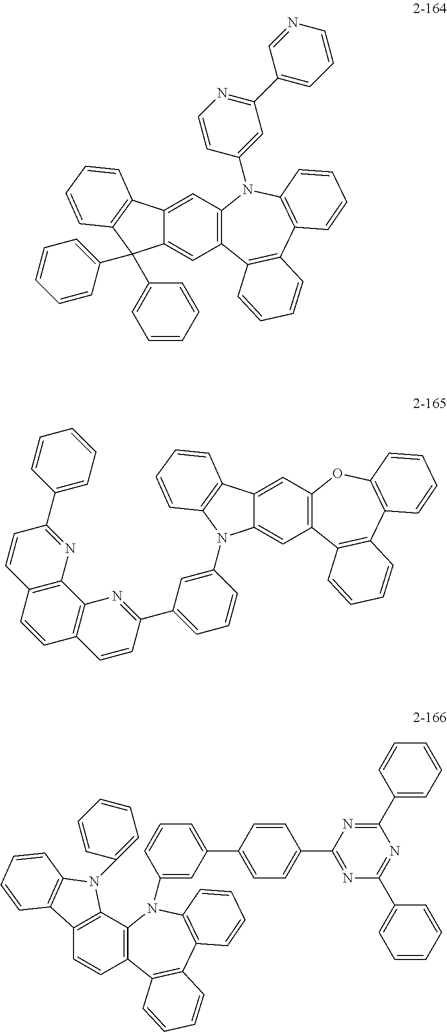 [SMILES: c1ccc(C2(c3ccccc3)c3ccccc3-c3cc4c(cc32)-c2ccccc2-c2ccccc2N4c2ccnc(-c3cccnc3)c2)cc1 ; c1ccc(-c2ccc3ccc4ccc(-c5cccc(-n6c7ccccc7c7cc8c(cc76)-c6ccccc6-c6ccccc6O8)c5)nc4c3n2)cc1 ; c1ccc(-c2nc(-c3ccccc3)nc(-c3ccc(-c4cccc(N5c6ccccc6-c6ccccc6-c6ccc7c8ccccc8n(-c8ccccc8)c7c65)c4)cc3)n2)cc1]

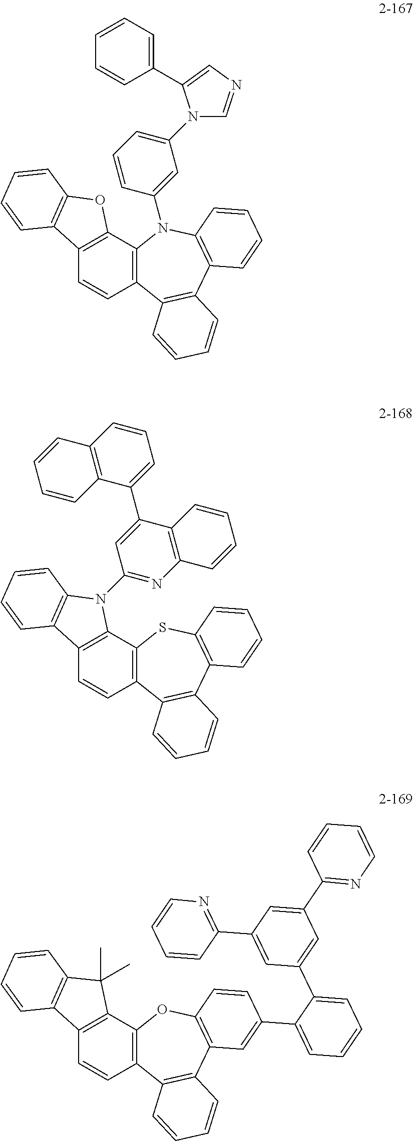 [SMILES: c1ccc(-c2cncn2-c2cccc(N3c4ccccc4-c4ccccc4-c4ccc5c(oc6ccccc65)c43)c2)cc1 ; c1ccc2c(c1)Sc1c(ccc3c4ccccc4n(-c4cc(-c5cccc6ccccc56)c5ccccc5n4)c13)-c1ccccc1-2 ; CC1(C)c2ccccc2-c2ccc3c(c21)Oc1ccc(-c2ccccc2-c2cc(-c4ccccn4)cc(-c4ccccn4)c2)cc1-c1ccccc1-3]

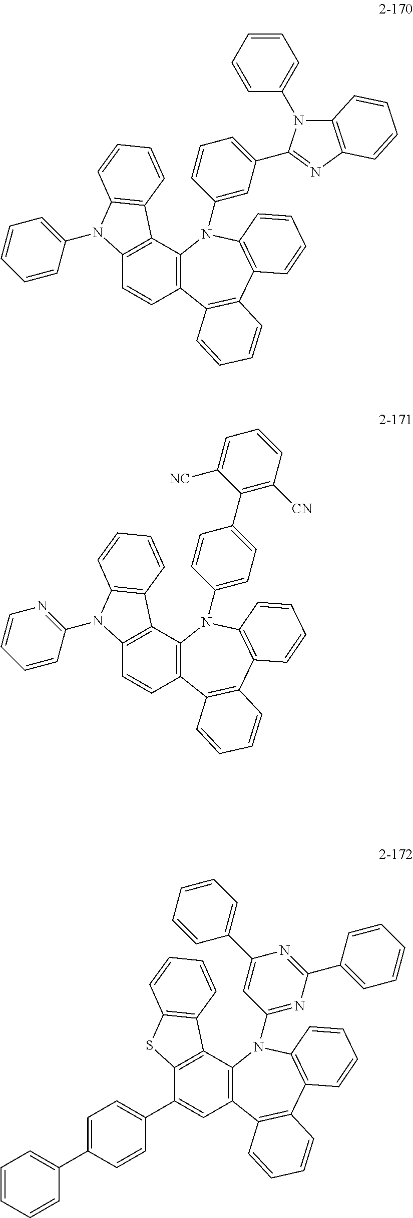 [SMILES: c1ccc(-n2c(-c3cccc(N4c5ccccc5-c5ccccc5-c5ccc6c(c54)c4ccccc4n6-c4ccccc4)c3)nc3ccccc32)cc1 ; N#Cc1cccc(C#N)c1-c1ccc(N2c3ccccc3-c3ccccc3-c3ccc4c(c32)c2ccccc2n4-c2ccccn2)cc1 ; c1ccc(-c2ccc(-c3cc4c(c5c3sc3ccccc35)N(c3cc(-c5ccccc5)nc(-c5ccccc5)n3)c3ccccc3-c3ccccc3-4)cc2)cc1]

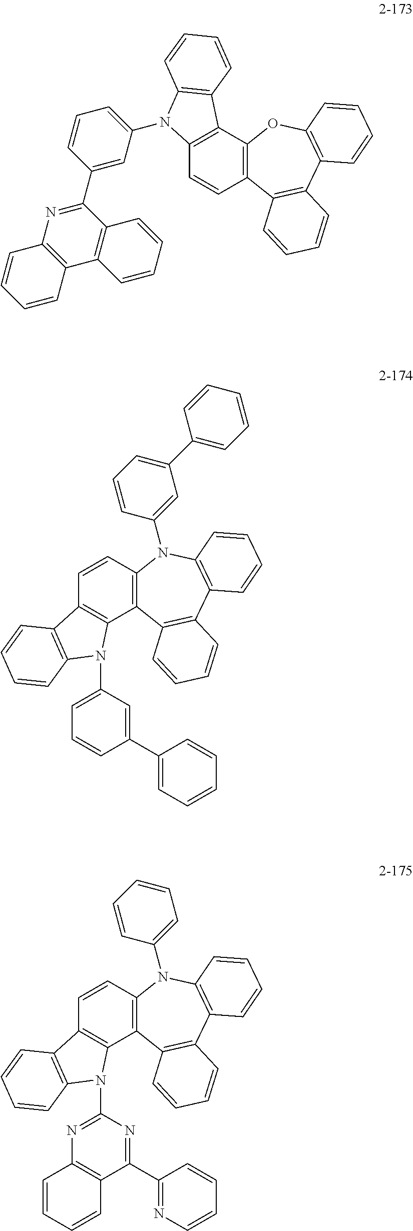 [SMILES: c1cc(-c2nc3ccccc3c3ccccc23)cc(-n2c3ccccc3c3c4c(ccc32)-c2ccccc2-c2ccccc2O4)c1 ; c1ccc(-c2cccc(N3c4ccccc4-c4ccccc4-c4c3ccc3c5ccccc5n(-c5cccc(-c6ccccc6)c5)c43)c2)cc1 ; c1ccc(N2c3ccccc3-c3ccccc3-c3c2ccc2c4ccccc4n(-c4nc(-c5ccccn5)c5ccccc5n4)c32)cc1]

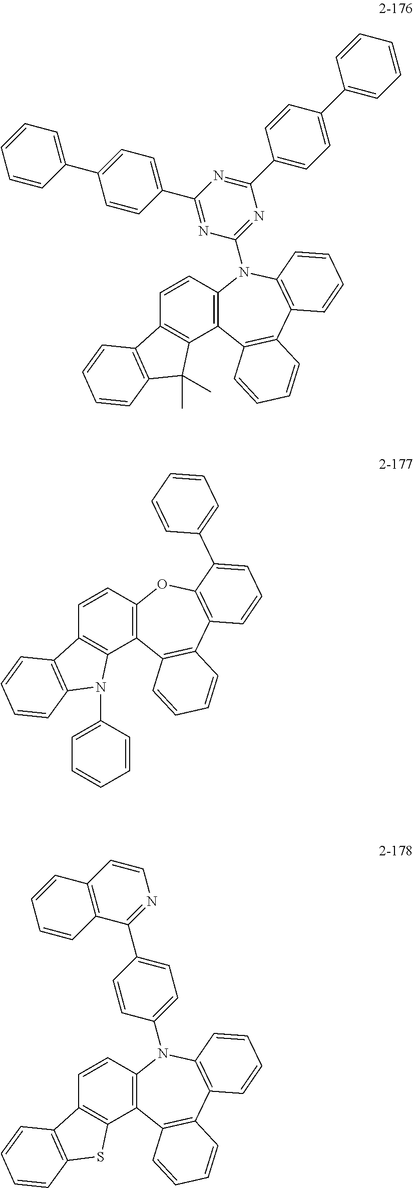 [SMILES: CC1(C)c2ccccc2-c2ccc3c(c21)-c1ccccc1-c1ccccc1N3c1nc(-c2ccc(-c3ccccc3)cc2)nc(-c2ccc(-c3ccccc3)cc2)n1 ; c1ccc(-c2cccc3c2Oc2ccc4c5ccccc5n(-c5ccccc5)c4c2-c2ccccc2-3)cc1 ; c1ccc2c(c1)-c1ccccc1N(c1ccc(-c3nccc4ccccc34)cc1)c1ccc3c(sc4ccccc43)c1-2]

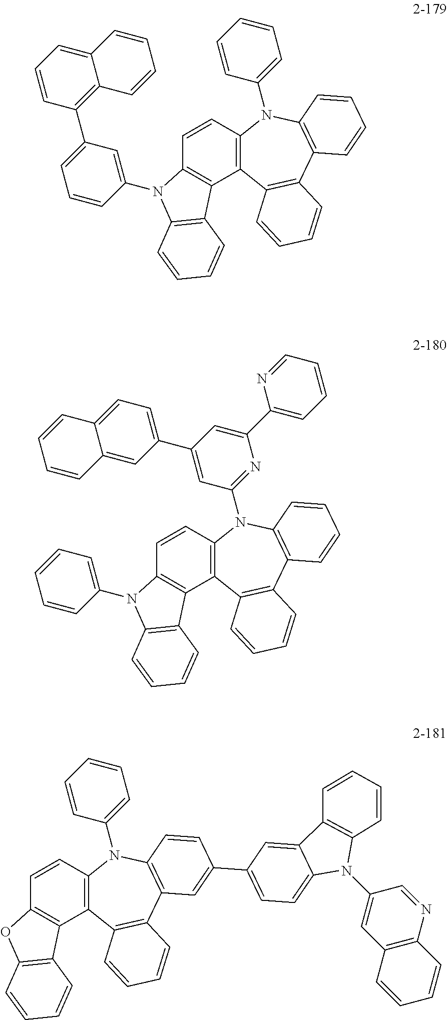 [SMILES: c1ccc(N2c3ccccc3-c3ccccc3-c3c2ccc2c3c3ccccc3n2-c2cccc(-c3cccc4ccccc34)c2)cc1 ; c1ccc(-n2c3ccccc3c3c4c(ccc32)N(c2cc(-c3ccc5ccccc5c3)cc(-c3ccccn3)n2)c2ccccc2-c2ccccc2-4)cc1 ; c1ccc(N2c3ccc(-c4ccc5c(c4)c4ccccc4n5-c4cnc5ccccc5c4)cc3-c3ccccc3-c3c2ccc2oc4ccccc4c32)cc1]

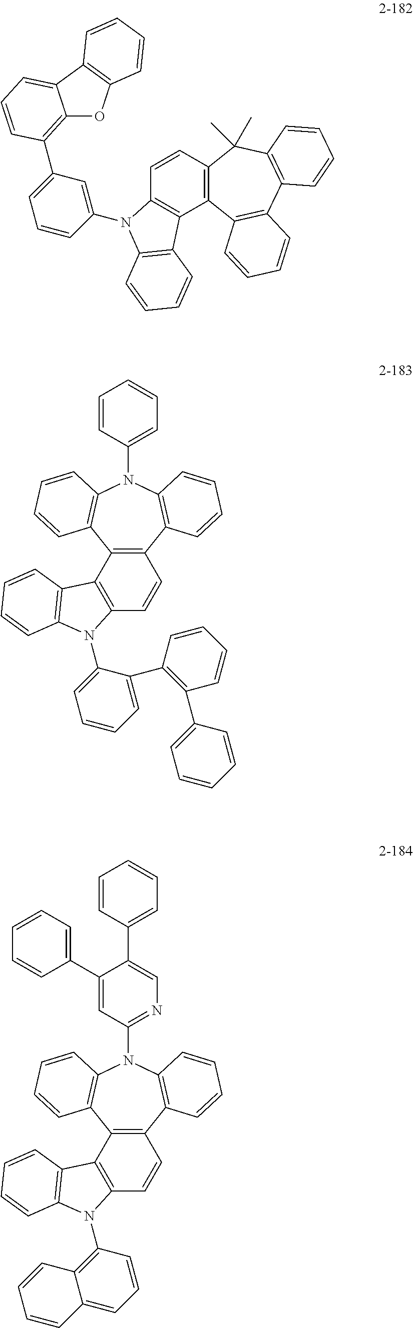 [SMILES: CC1(C)c2ccccc2-c2ccccc2-c2c1ccc1c2c2ccccc2n1-c1cccc(-c2cccc3c2oc2ccccc23)c1 ; c1ccc(-c2ccccc2-c2ccccc2-n2c3ccccc3c3c4c(ccc32)-c2ccccc2N(c2ccccc2)c2ccccc2-4)cc1 ; c1ccc(-c2cnc(N3c4ccccc4-c4ccc5c(c4-c4ccccc43)c3ccccc3n5-c3cccc4ccccc34)cc2-c2ccccc2)cc1]

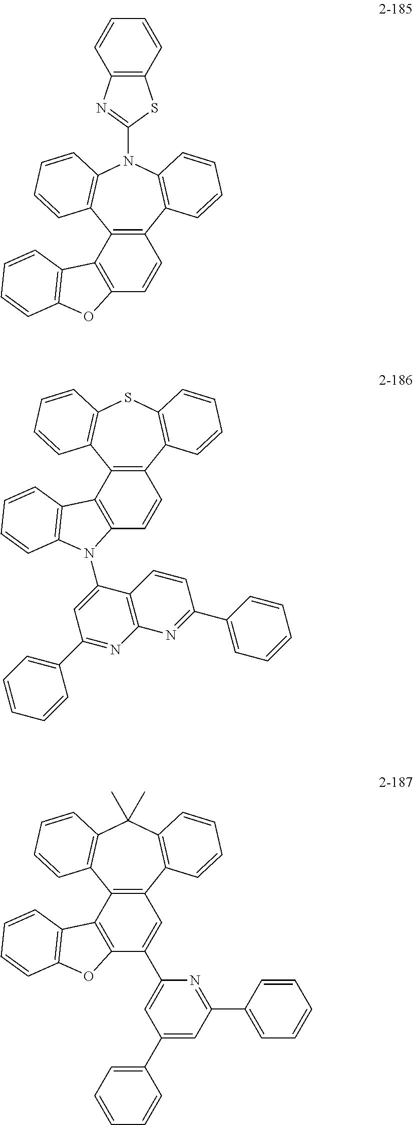 [SMILES: c1ccc2c(c1)-c1ccc3oc4ccccc4c3c1-c1ccccc1N2c1nc2ccccc2s1 ; c1ccc(-c2ccc3c(-n4c5ccccc5c5c6c(ccc54)-c4ccccc4Sc4ccccc4-6)cc(-c4ccccc4)nc3n2)cc1 ; CC1(C)c2ccccc2-c2cc(-c3cc(-c4ccccc4)cc(-c4ccccc4)n3)c3oc4ccccc4c3c2-c2ccccc21]

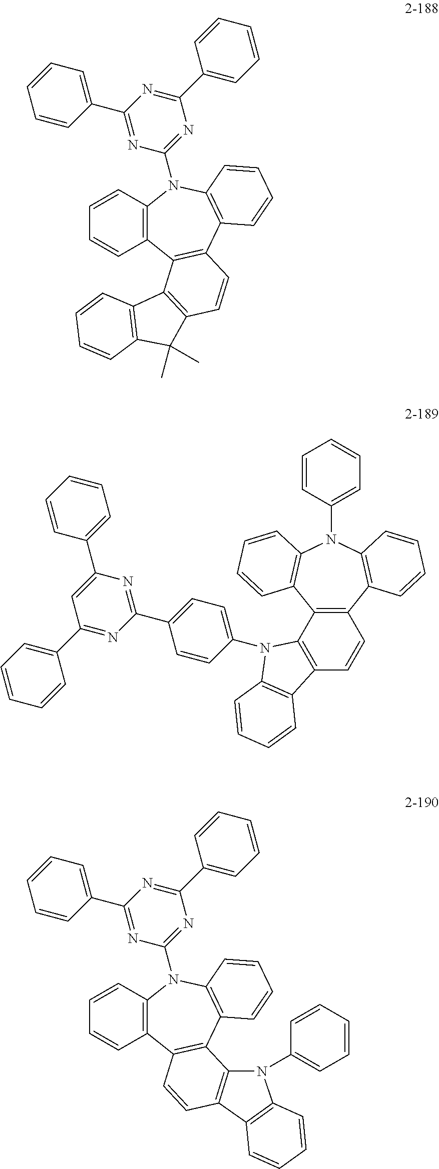 [SMILES: CC1(C)c2ccccc2-c2c1ccc1c2-c2ccccc2N(c2nc(-c3ccccc3)nc(-c3ccccc3)n2)c2ccccc2-1 ; c1ccc(-c2cc(-c3ccccc3)nc(-c3ccc(-n4c5ccccc5c5ccc6c(c54)-c4ccccc4N(c4ccccc4)c4ccccc4-6)cc3)n2)cc1 ; c1ccc(-c2nc(-c3ccccc3)nc(N3c4ccccc4-c4ccc5c6ccccc6n(-c6ccccc6)c5c4-c4ccccc43)n2)cc1]

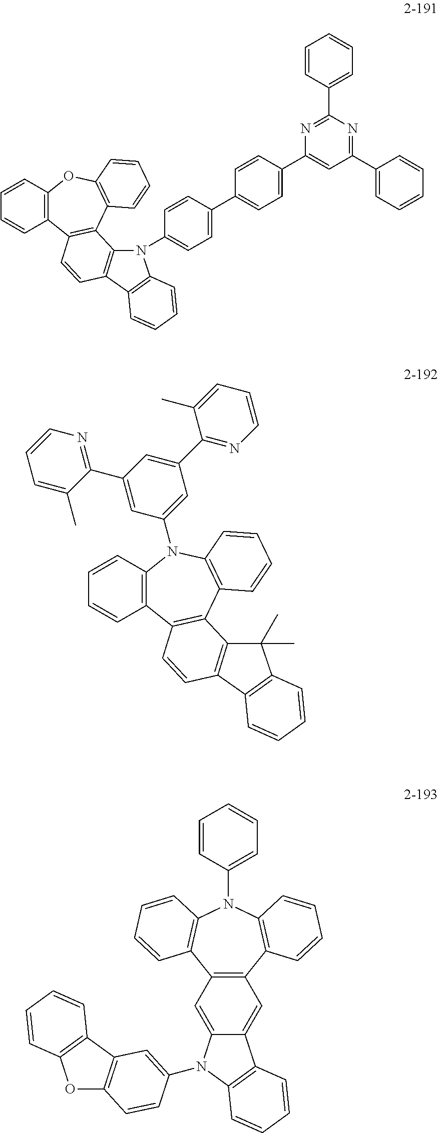 [SMILES: c1ccc(-c2cc(-c3ccc(-c4ccc(-n5c6ccccc6c6ccc7c(c65)-c5ccccc5Oc5ccccc5-7)cc4)cc3)nc(-c3ccccc3)n2)cc1 ; Cc1cccnc1-c1cc(-c2ncccc2C)cc(N2c3ccccc3-c3ccc4c(c3-c3ccccc32)C(C)(C)c2ccccc2-4)c1 ; c1ccc(N2c3ccccc3-c3cc4c5ccccc5n(-c5ccc6oc7ccccc7c6c5)c4cc3-c3ccccc32)cc1]

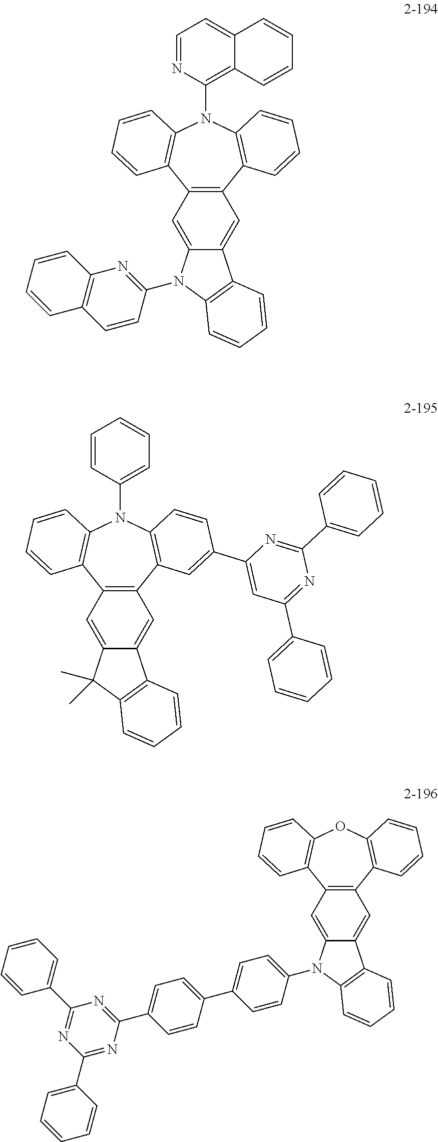 [SMILES: c1ccc2c(c1)-c1cc3c4ccccc4n(-c4ccc5ccccc5n4)c3cc1-c1ccccc1N2c1nccc2ccccc12 ; CC1(C)c2ccccc2-c2cc3c(cc21)-c1ccccc1N(c1ccccc1)c1ccc(-c2cc(-c4ccccc4)nc(-c4ccccc4)n2)cc1-3 ; c1ccc(-c2nc(-c3ccccc3)nc(-c3ccc(-c4ccc(-n5c6ccccc6c6cc7c(cc65)-c5ccccc5Oc5ccccc5-7)cc4)cc3)n2)cc1]

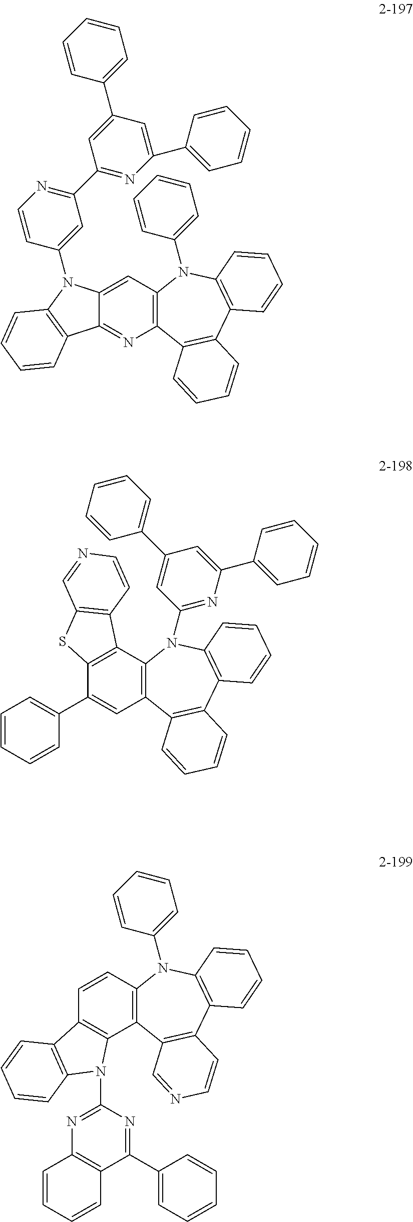 [SMILES: c1ccc(-c2cc(-c3ccccc3)nc(-c3cc(-n4c5ccccc5c5nc6c(cc54)N(c4ccccc4)c4ccccc4-c4ccccc4-6)ccn3)c2)cc1 ; c1ccc(-c2cc(-c3ccccc3)nc(N3c4ccccc4-c4ccccc4-c4cc(-c5ccccc5)c5sc6cnccc6c5c43)c2)cc1 ; c1ccc(-c2nc(-n3c4ccccc4c4ccc5c(c43)-c3cnccc3-c3ccccc3N5c3ccccc3)nc3ccccc23)cc1]

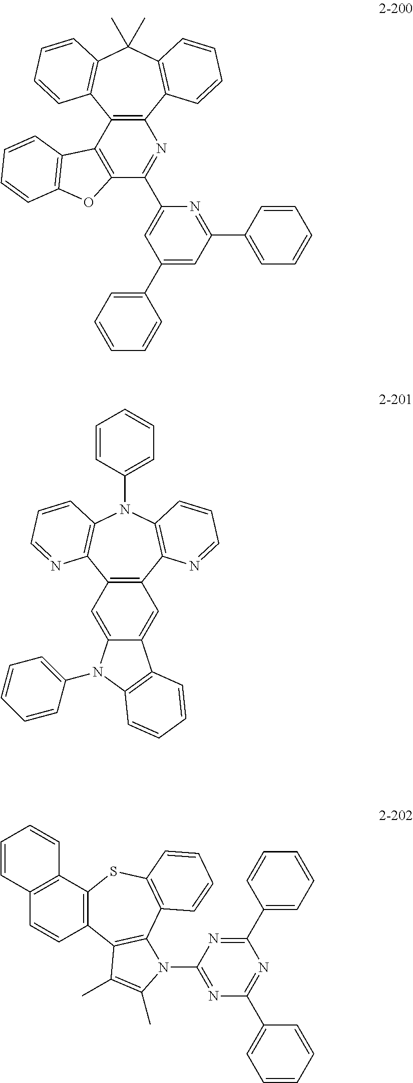 [SMILES: CC1(C)c2ccccc2-c2nc(-c3cc(-c4ccccc4)cc(-c4ccccc4)n3)c3oc4ccccc4c3c2-c2ccccc21 ; c1ccc(N2c3cccnc3-c3cc4c5ccccc5n(-c5ccccc5)c4cc3-c3ncccc32)cc1 ; Cc1c2c(n(-c3nc(-c4ccccc4)nc(-c4ccccc4)n3)c1C)-c1ccccc1Sc1c-2ccc2ccccc12]

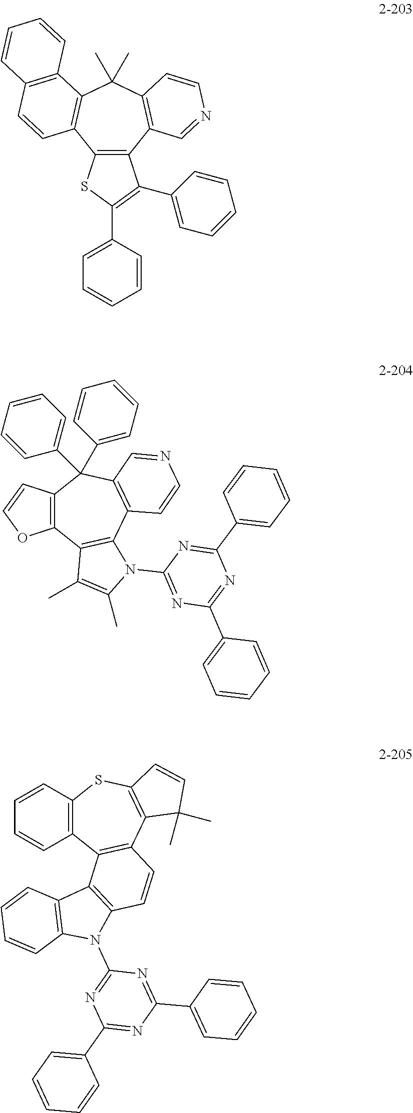 [SMILES: CC1(C)c2ccncc2-c2c(sc(-c3ccccc3)c2-c2ccccc2)-c2ccc3ccccc3c21 ; Cc1c2c(n(-c3nc(-c4ccccc4)nc(-c4ccccc4)n3)c1C)-c1ccncc1C(c1ccccc1)(c1ccccc1)c1ccoc1-2 ; CC1(C)C=CC2=C1c1ccc3c(c1-c1ccccc1S2)c1ccccc1n3-c1nc(-c2ccccc2)nc(-c2ccccc2)n1]

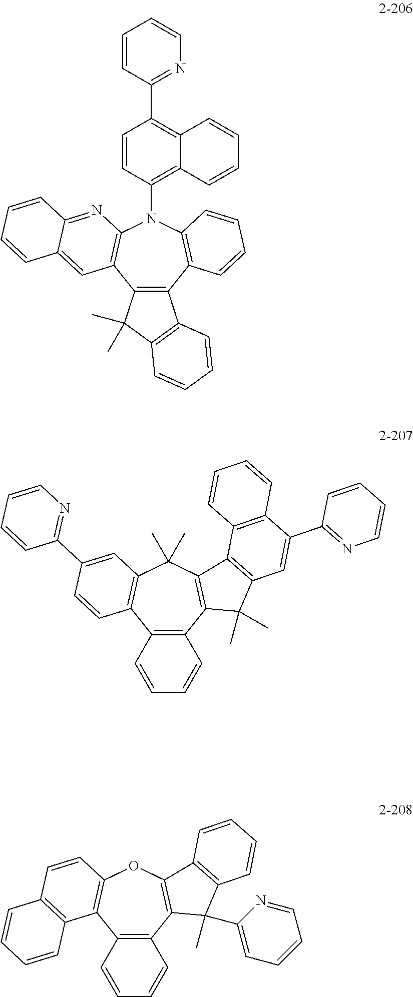 [SMILES: CC1(C)C2=C(c3ccccc3N(c3ccc(-c4ccccn4)c4ccccc34)c3nc4ccccc4cc32)c2ccccc21 ; CC1(C)C2=C(c3ccccc3-c3ccc(-c4ccccn4)cc31)C(C)(C)c1cc(-c3ccccn3)c3ccccc3c12 ; CC1(c2ccccn2)C2=C(Oc3ccc4ccccc4c3-c3ccccc32)c2ccccc21]

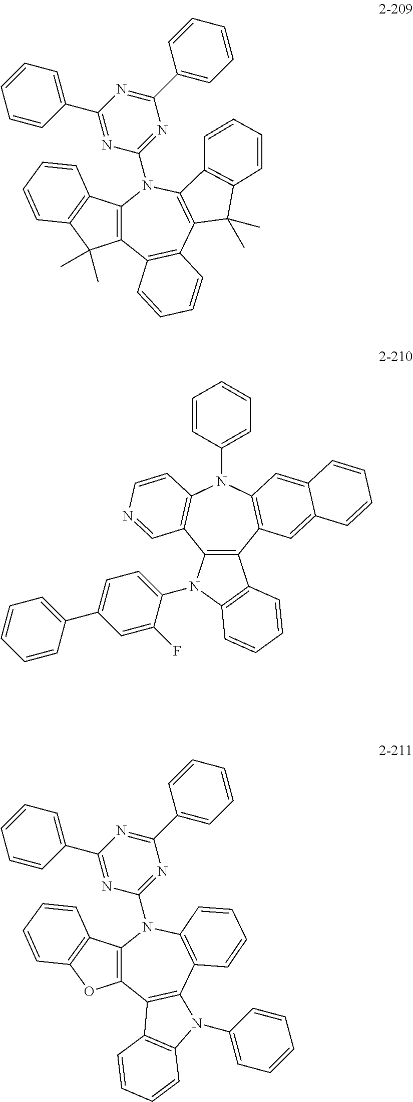 [SMILES: CC1(C)C2=C(c3ccccc31)N(c1nc(-c3ccccc3)nc(-c3ccccc3)n1)C1=C(c3ccccc32)C(C)(C)c2ccccc21 ; Fc1cc(-c2ccccc2)ccc1-n1c2c(c3ccccc31)-c1cc3ccccc3cc1N(c1ccccc1)c1ccncc1-2 ; c1ccc(-c2nc(-c3ccccc3)nc(N3c4ccccc4-c4c(c5ccccc5n4-c4ccccc4)-c4oc5ccccc5c43)n2)cc1]

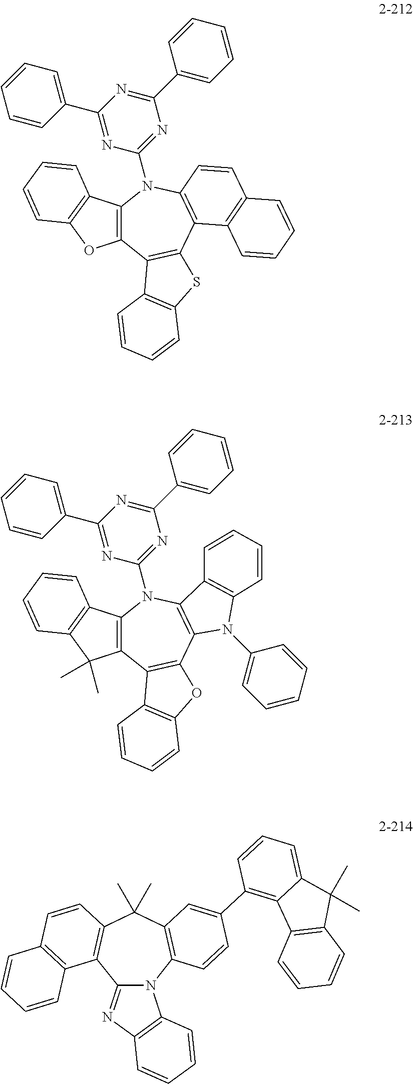 [SMILES: c1ccc(-c2nc(-c3ccccc3)nc(N3c4ccc5ccccc5c4-c4sc5ccccc5c4-c4oc5ccccc5c43)n2)cc1 ; CC1(C)C2=C(c3ccccc31)N(c1nc(-c3ccccc3)nc(-c3ccccc3)n1)c1c(n(-c3ccccc3)c3ccccc13)-c1oc3ccccc3c12 ; CC1(C)c2ccccc2-c2c(-c3ccc4c(c3)C(C)(C)c3ccc5ccccc5c3-c3nc5ccccc5n3-4)cccc21]

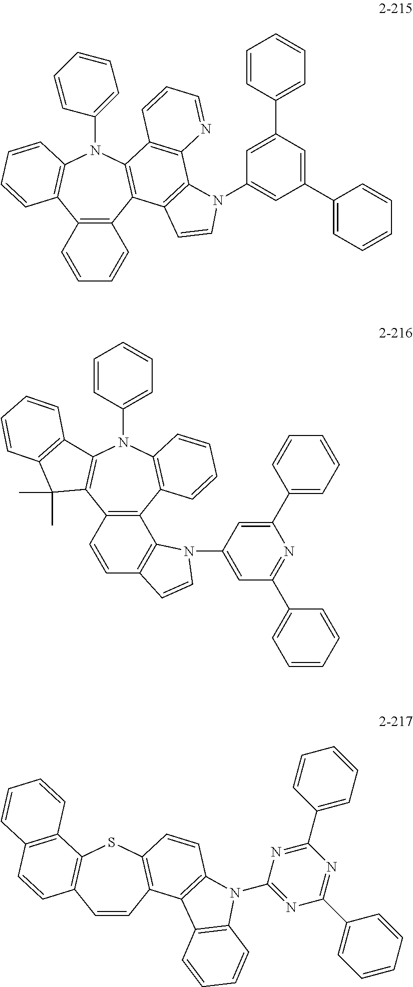 [SMILES: c1ccc(-c2cc(-c3ccccc3)cc(-n3ccc4c5c(c6cccnc6c43)N(c3ccccc3)c3ccccc3-c3ccccc3-5)c2)cc1 ; CC1(C)C2=C(c3ccccc31)N(c1ccccc1)c1ccccc1-c1c2ccc2ccn(-c3cc(-c4ccccc4)nc(-c4ccccc4)c3)c12 ; C1=Cc2c(ccc3c2c2ccccc2n3-c2nc(-c3ccccc3)nc(-c3ccccc3)n2)Sc2c1ccc1ccccc21]

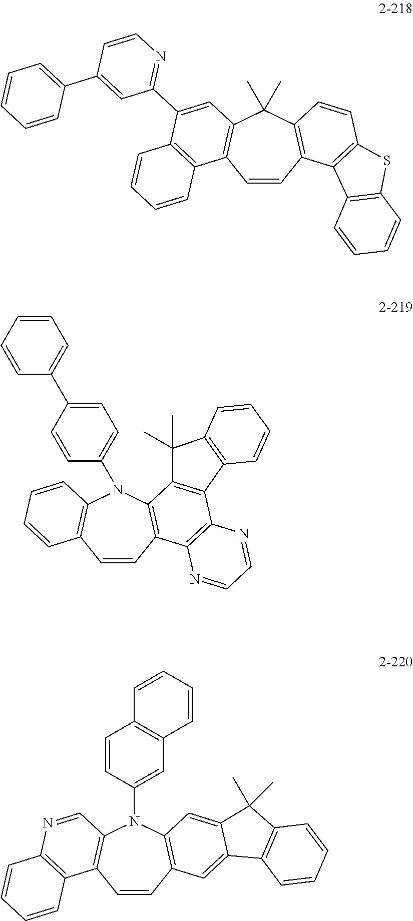 [SMILES: CC1(C)c2cc(-c3cc(-c4ccccc4)ccn3)c3ccccc3c2C=Cc2c1ccc1sc3ccccc3c21 ; CC1(C)c2ccccc2-c2c1c1c(c3nccnc23)C=Cc2ccccc2N1c1ccc(-c2ccccc2)cc1 ; CC1(C)c2ccccc2-c2cc3c(cc21)N(c1ccc2ccccc2c1)c1cnc2ccccc2c1C=C3]

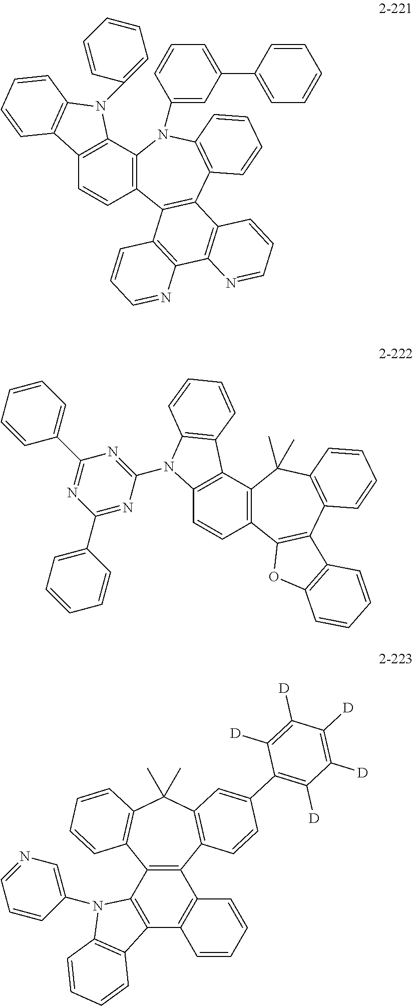 [SMILES: c1ccc(-c2cccc(N3c4ccccc4-c4c(c5cccnc5c5ncccc45)-c4ccc5c6ccccc6n(-c6ccccc6)c5c43)c2)cc1 ; CC1(C)c2ccccc2-c2c(oc3ccccc23)-c2ccc3c(c21)c1ccccc1n3-c1nc(-c2ccccc2)nc(-c2ccccc2)n1 ; [2H]c1c([2H])c([2H])c(-c2ccc3c(c2)C(C)(C)c2ccccc2-c2c-3c3ccccc3c3c4ccccc4n(-c4cccnc4)c23)c([2H])c1[2H]]

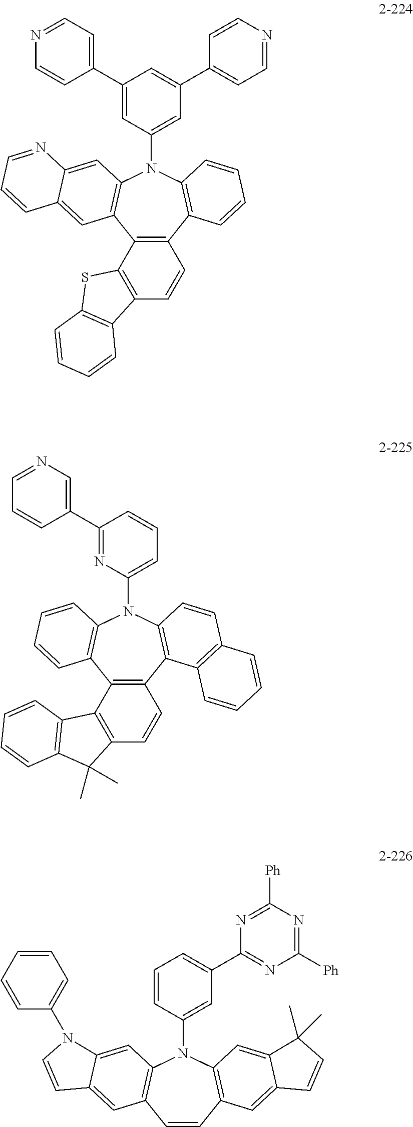 [SMILES: c1ccc2c(c1)-c1ccc3c(sc4ccccc43)c1-c1cc3cccnc3cc1N2c1cc(-c2ccncc2)cc(-c2ccncc2)c1 ; CC1(C)c2ccccc2-c2c1ccc1c2-c2ccccc2N(c2cccc(-c3cccnc3)n2)c2ccc3ccccc3c2-1 ; CC1(C)C=Cc2cc3c(cc21)N(c1cccc(-c2nc(-c4ccccc4)nc(-c4ccccc4)n2)c1)c1cc2c(ccn2-c2ccccc2)cc1C=C3]

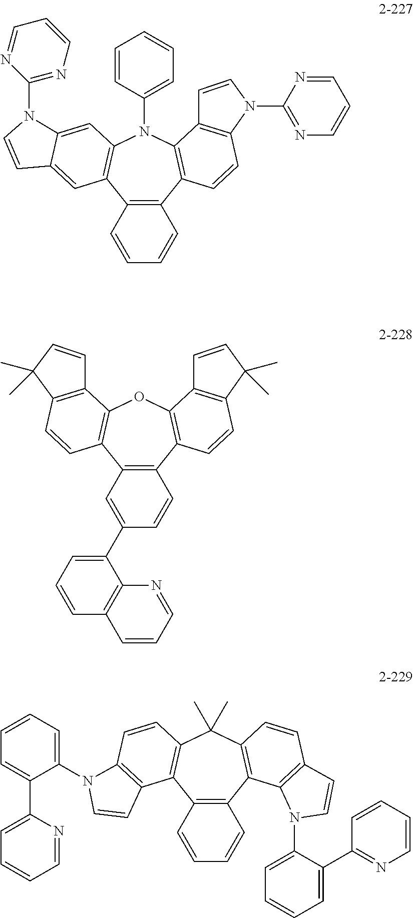

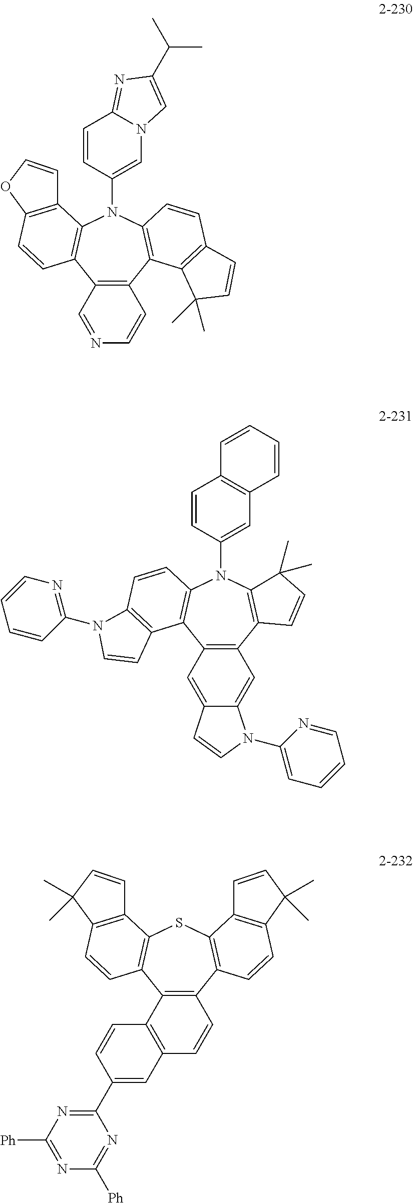 [SMILES: CC(C)c1cn2cc(N3c4ccc5c(c4-c4ccncc4-c4ccc6occc6c43)C(C)(C)C=C5)ccc2n1 ; CC1(C)C=CC2=C1N(c1ccc3ccccc3c1)c1ccc3c(ccn3-c3ccccn3)c1-c1cc3ccn(-c4ccccn4)c3cc12 ; CC1(C)C=Cc2c1ccc1c2Sc2c(ccc3c2C=CC3(C)C)-c2c-1ccc1cc(-c3nc(-c4ccccc4)nc(-c4ccccc4)n3)ccc21]

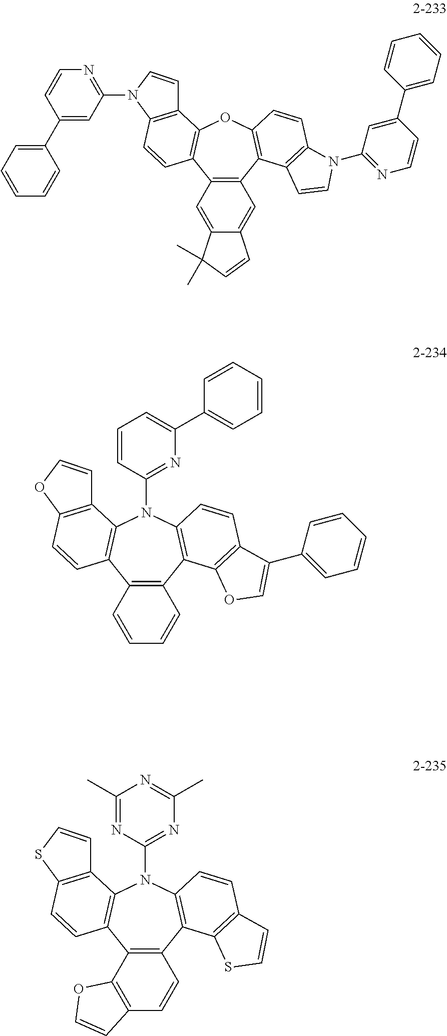 [SMILES: CC1(C)C=Cc2cc3c(cc21)-c1ccc2c(ccn2-c2cc(-c4ccccc4)ccn2)c1Oc1ccc2c(ccn2-c2cc(-c4ccccc4)ccn2)c1-3 ; c1ccc(-c2cccc(N3c4ccc5c(-c6ccccc6)coc5c4-c4ccccc4-c4ccc5occc5c43)n2)cc1 ; Cc1nc(C)nc(N2c3ccc4ccsc4c3-c3ccc4ccoc4c3-c3ccc4sccc4c32)n1]

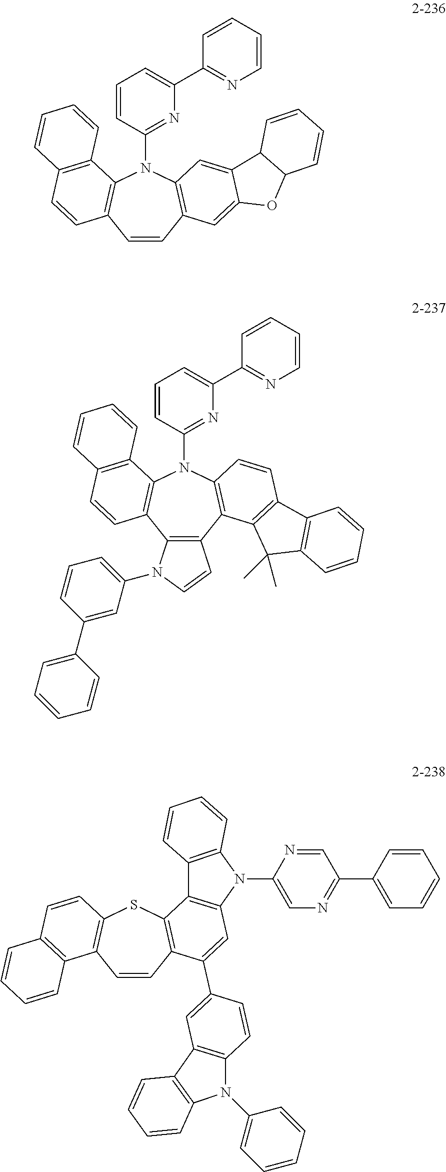 [SMILES: C1=CC2Oc3cc4c(cc3C2C=C1)N(c1cccc(-c2ccccn2)n1)c1c(ccc2ccccc12)C=C4 ; CC1(C)c2ccccc2-c2ccc3c(c21)-c1ccn(-c2cccc(-c4ccccc4)c2)c1-c1ccc2ccccc2c1N3c1cccc(-c2ccccn2)n1 ; C1=Cc2c(ccc3ccccc23)Sc2c1c(-c1ccc3c(c1)c1ccccc1n3-c1ccccc1)cc1c2c2ccccc2n1-c1cnc(-c2ccccc2)cn1]

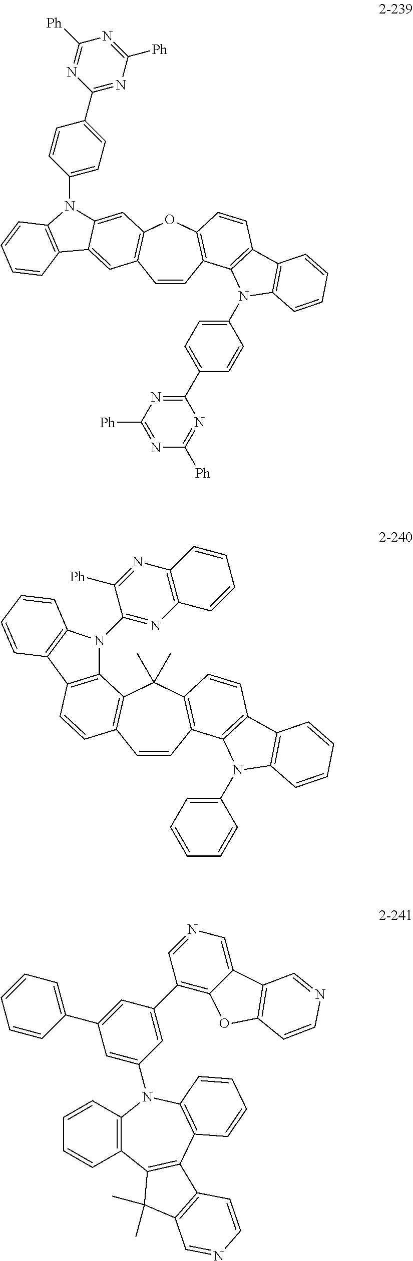 [SMILES: C1=Cc2c(ccc3c4ccccc4n(-c4ccc(-c5nc(-c6ccccc6)nc(-c6ccccc6)n5)cc4)c23)Oc2cc3c(cc21)c1ccccc1n3-c1ccc(-c2nc(-c3ccccc3)nc(-c3ccccc3)n2)cc1 ; CC1(C)c2ccc3c4ccccc4n(-c4ccccc4)c3c2C=Cc2ccc3c4ccccc4n(-c4nc5ccccc5nc4-c4ccccc4)c3c21 ; CC1(C)C2=C(c3ccccc3N(c3cc(-c4ccccc4)cc(-c4cncc5c4oc4ccncc45)c3)c3ccccc32)c2ccncc21]

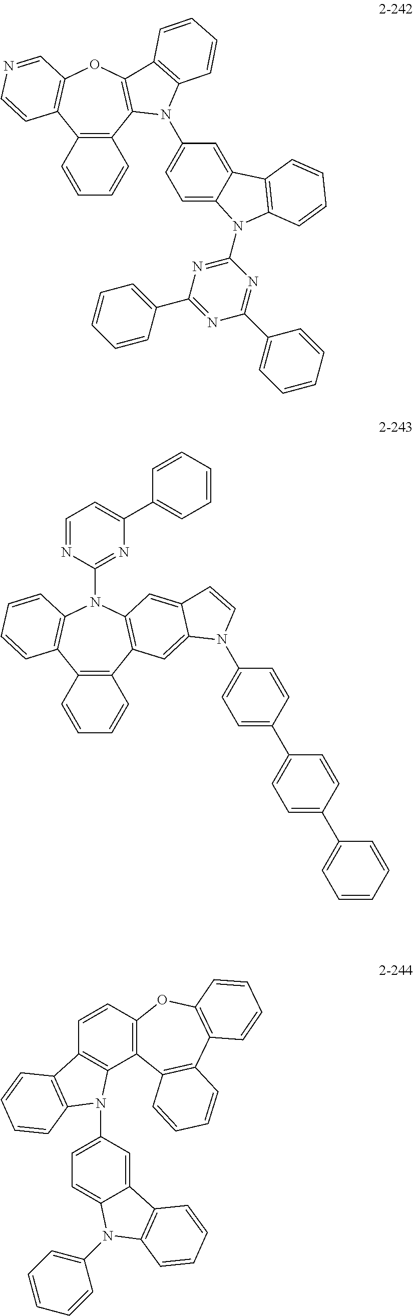 [SMILES: c1ccc(-c2nc(-c3ccccc3)nc(-n3c4ccccc4c4cc(-n5c6c(c7ccccc75)Oc5cnccc5-c5ccccc5-6)ccc43)n2)cc1 ; c1ccc(-c2ccc(-c3ccc(-n4ccc5cc6c(cc54)-c4ccccc4-c4ccccc4N6c4nccc(-c5ccccc5)n4)cc3)cc2)cc1 ; c1ccc(-n2c3ccccc3c3cc(-n4c5ccccc5c5ccc6c(c54)-c4ccccc4-c4ccccc4O6)ccc32)cc1]

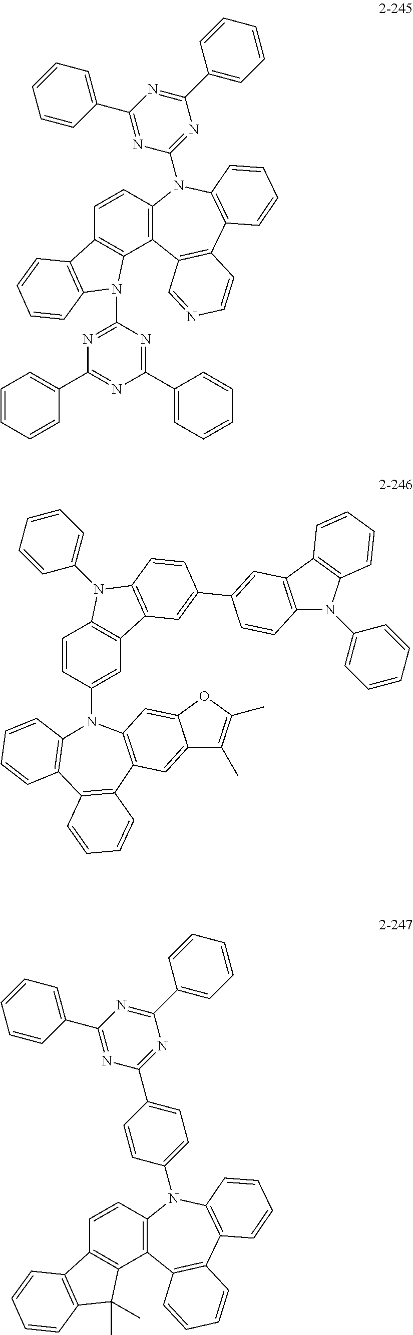 [SMILES: c1ccc(-c2nc(-c3ccccc3)nc(N3c4ccccc4-c4ccncc4-c4c3ccc3c5ccccc5n(-c5nc(-c6ccccc6)nc(-c6ccccc6)n5)c43)n2)cc1 ; Cc1oc2cc3c(cc2c1C)-c1ccccc1-c1ccccc1N3c1ccc2c(c1)c1cc(-c3ccc4c(c3)c3ccccc3n4-c3ccccc3)ccc1n2-c1ccccc1 ; CC1(C)c2ccccc2-c2ccc3c(c21)-c1ccccc1-c1ccccc1N3c1ccc(-c2nc(-c3ccccc3)nc(-c3ccccc3)n2)cc1]

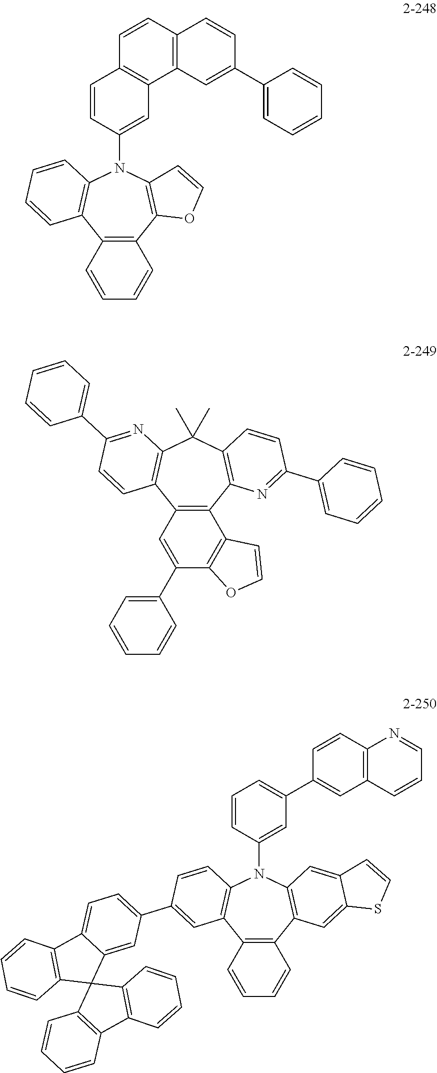 [SMILES: c1ccc(-c2ccc3ccc4ccc(N5c6ccccc6-c6ccccc6-c6occc65)cc4c3c2)cc1 ; CC1(C)c2ccc(-c3ccccc3)nc2-c2c(cc(-c3ccccc3)c3occc23)-c2ccc(-c3ccccc3)nc21 ; c1cc(-c2ccc3ncccc3c2)cc(N2c3ccc(-c4ccc5c(c4)C4(c6ccccc6-c6ccccc64)c4ccccc4-5)cc3-c3ccccc3-c3cc4sccc4cc32)c1]

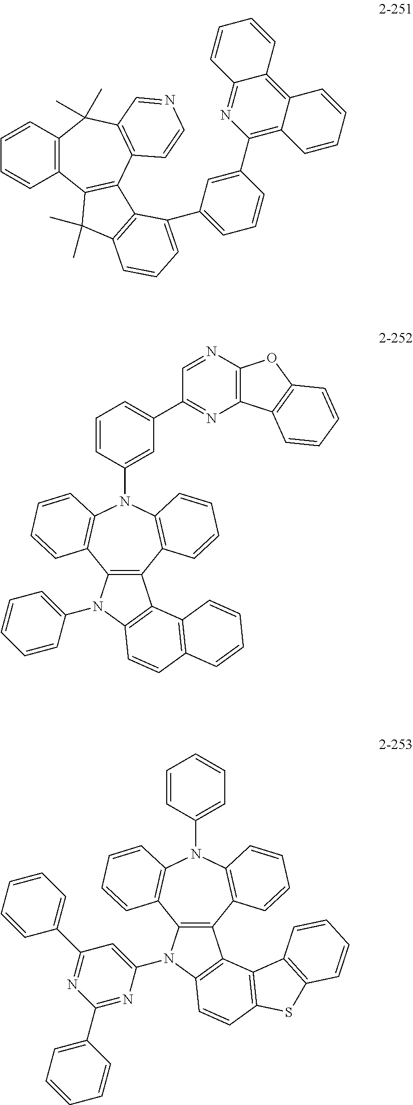 [SMILES: CC1(C)C2=C(c3ccncc3C(C)(C)c3ccccc32)c2c(-c3cccc(-c4nc5ccccc5c5ccccc45)c3)cccc21 ; c1ccc(-n2c3c(c4c5ccccc5ccc42)-c2ccccc2N(c2cccc(-c4cnc5oc6ccccc6c5n4)c2)c2ccccc2-3)cc1 ; c1ccc(-c2cc(-n3c4c(c5c6c(ccc53)sc3ccccc36)-c3ccccc3N(c3ccccc3)c3ccccc3-4)nc(-c3ccccc3)n2)cc1]

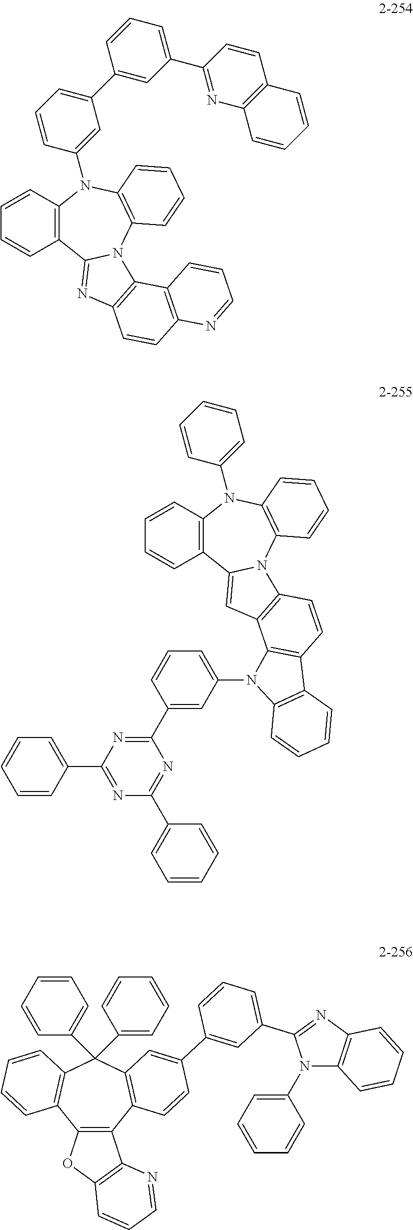 [SMILES: c1cc(-c2cccc(N3c4ccccc4-c4nc5ccc6ncccc6c5n4-c4ccccc43)c2)cc(-c2ccc3ccccc3n2)c1 ; c1ccc(-c2nc(-c3ccccc3)nc(-c3cccc(-n4c5ccccc5c5ccc6c(cc7n6-c6ccccc6N(c6ccccc6)c6ccccc6-7)c54)c3)n2)cc1 ; c1ccc(-n2c(-c3cccc(-c4ccc5c(c4)C(c4ccccc4)(c4ccccc4)c4ccccc4-c4oc6cccnc6c4-5)c3)nc3ccccc32)cc1]

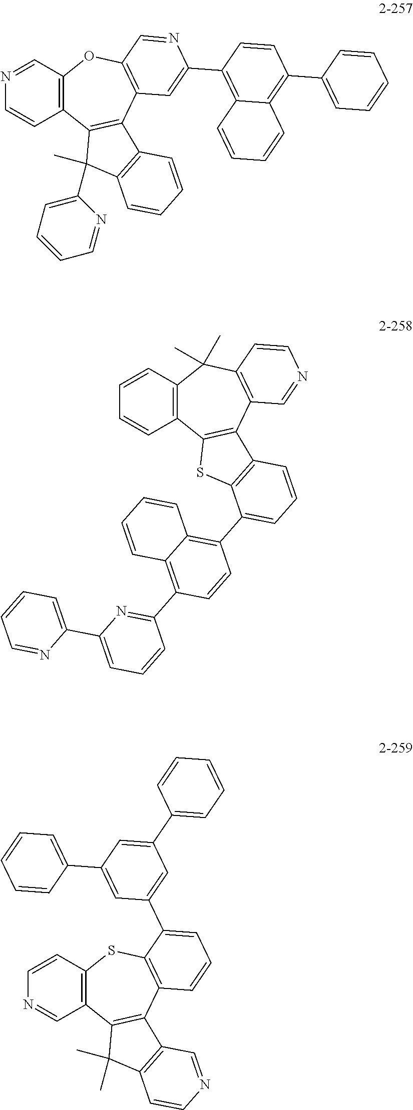 [SMILES: CC1(c2ccccn2)C2=C(c3cc(-c4ccc(-c5ccccc5)c5ccccc45)ncc3Oc3cnccc32)c2ccccc21 ; CC1(C)c2ccccc2-c2sc3c(-c4ccc(-c5cccc(-c6ccccn6)n5)c5ccccc45)cccc3c2-c2cnccc21 ; CC1(C)C2=C(c3cnccc31)c1cccc(-c3cc(-c4ccccc4)cc(-c4ccccc4)c3)c1Sc1ccncc12]

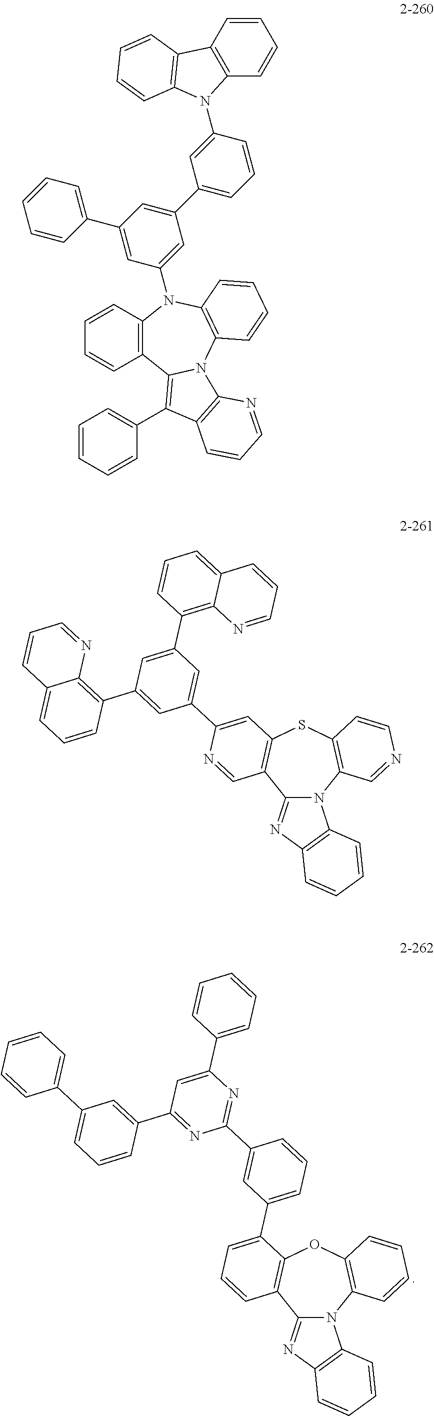 [SMILES: c1ccc(-c2cc(-c3cccc(-n4c5ccccc5c5ccccc54)c3)cc(N3c4ccccc4-c4c(-c5ccccc5)c5cccnc5n4-c4ccccc43)c2)cc1 ; c1cnc2c(-c3cc(-c4cc5c(cn4)-c4nc6ccccc6n4-c4cnccc4S5)cc(-c4cccc5cccnc45)c3)cccc2c1 ; c1ccc(-c2cccc(-c3cc(-c4ccccc4)nc(-c4cccc(-c5cccc6c5Oc5ccccc5-n5c-6nc6ccccc65)c4)n3)c2)cc1]

Any suitable combinations of ring A₁, ring A₂, X₁, L₁ to L₃, a1 to a3, Ar₁ to Arₐ, R₁, R₂, b1, b2, c1 to c3, d11, and d12 in Formula 1 may be applicable within the scope described herein.

Any suitable combinations of ring A₂₁, ring A₂₂, ring A₂₃, X₂₁, and T₁₁ to T₁₄ in Formulae 2A and 2B may be applicable within the scope described herein.

Any suitable combinations of *-[(L₂₂)ₐ₂₂-(R₂₂)_{b22}], C(R₂₃)(R₂₄), Si(R₂₃)(R₂₄), and N-[(L₂₁)ₐ₂₁-(R₂₁)_{b21}] may be applicable within the scope of L₂₁, L₂₂, a21, a22, R₂₁ to R₂₄, b21, and b22 described herein.

In various embodiments, in the organic light-emitting device, the first electrode may be an anode, the second electrode may be a cathode, the organic layer may include an emission layer and an electron transport region between the second electrode and the emission layer, the emission layer may include the first compound, and the electron transport region may include the second compound.

Since the emission layer of the organic light-emitting device includes the first compound and at least one selected from the hole transport region and the electron transport region includes the second compound, a balance of electrons and/or holes injected or transported into the emission layer may be easily adjusted, thus reducing or preventing a leakage current from occurring. Thus, the organic light-emitting device may have low driving voltage and high efficiency characteristics.

In various embodiments, triplet energy of the second compound may be about 2.2 eV or more. For example, the triplet energy of the second compound may be about 2.3 eV or more, or may be about 2.4 eV or more.

When the triplet energy of the second compound is within these ranges, it is expected that the emission efficiency of a fluorescent organic light-emitting device will be improved due to triplet-triplet fusion (TTF). In a phosphorescent organic light-emitting device, it is possible to reduce or prevent a reduction in efficiency of an organic light-emitting device by blocking transition of triplet excitons formed in an emission layer.

For example, the emission layer may include a first host and a second host, wherein the first host may include the first compound.

In various embodiments, the hole transport region may include an emission auxiliary layer, the emission auxiliary layer may directly contact the emission layer, and the second compound may be included in the emission auxiliary layer.

In various embodiments, the electron transport region may include a buffer layer, the buffer layer may directly contact the emission layer, and the second compound may be included in the buffer layer, but embodiments of the present disclosure are not limited thereto.

When both the hole transport region and the electron transport region in the organic light-emitting device include the second compound described above, the second compound included in the hole transport region and the second compound included in the electron transport region may be identical to or different from each other.

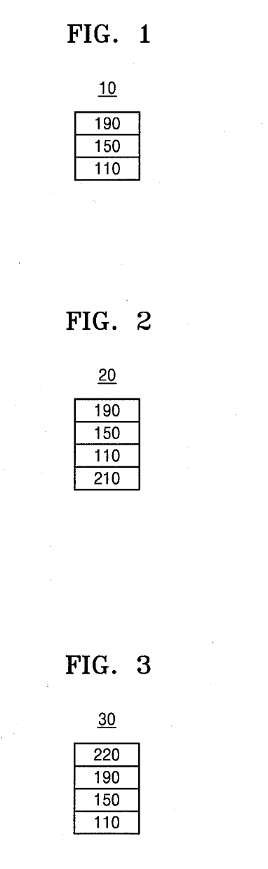

### Description of FIG. 1

FIG. 1 is a schematic view of an organic light-emitting device 10 according to an embodiment. The organic light-emitting device 10 may include a first electrode 110, an organic layer 150, and a second electrode 190.

Hereinafter, the structure of the organic light-emitting device 10 according to an embodiment and a method of manufacturing the organic light-emitting device 10 according to an embodiment will be described in connection with FIG. 1.

### First Electrode 110

In FIG. 1, a substrate may be additionally disposed under the first electrode 110 or above the second electrode 190. The substrate may be a glass substrate or a plastic substrate, each having excellent mechanical strength, thermal stability, transparency, surface smoothness, ease of handling, and/or water-resistance.

The first electrode 110 may be formed by depositing or sputtering a material for forming the first electrode 110 on the substrate. When the first electrode 110 is an anode, the material for forming the first electrode 110 may be selected from materials with a high work function to facilitate hole injection.

The first electrode 110 may be a reflective electrode, a semi-transmissive electrode, or a transmissive electrode. When the first electrode 110 is a transmissible electrode, a material for forming the first electrode 110 may be selected from indium tin oxide (ITO), indium zinc oxide (IZO), tin oxide (SnO₂), zinc oxide (ZnO), and combinations thereof, but embodiments of the present disclosure are not limited thereto. When the first electrode 110 is a semi-transmissive electrode or a reflective electrode, as a material for forming the first electrode 110, magnesium (Mg), silver (Ag), aluminum (Al), aluminum-lithium (Al—Li), calcium (Ca), magnesium-indium (Mg—In), magnesium-silver (Mg—Ag), or a combination thereof may be utilized. However, the material for forming the first electrode 110 is not limited thereto.

The first electrode 110 may have a single-layered structure, or a multi-layered structure including two or more layers. For example, the first electrode 110 may have a three-layered structure of ITO/Ag/ITO, but the structure of the first electrode 110 is not limited thereto.

### Organic Layer 150

The organic layer 150 is disposed on the first electrode 110. The organic layer 150 may include an emission layer.

The organic layer 150 may include a hole transport region between the first electrode 110 and the emission layer, and an electron transport region between the emission layer and the second electrode 190.

### Hole Transport Region in Organic Layer 150

The hole transport region may have i) a single-layered structure including a single layer including a single material, ii) a single-layered structure including a single layer including a plurality of different materials, or iii) a multi-layered structure having a plurality of layers including a plurality of different materials.

The hole transport region may include at least one layer selected from a hole injection layer, a hole transport layer, an emission auxiliary layer, and an electron blocking layer.

For example, the hole transport region may have a single-layered structure including a single layer including a plurality of different materials, or a multi-layered structure having a structure of hole injection layer/hole transport layer, hole injection layer/hole transport layer/emission auxiliary layer, hole injection layer/emission auxiliary layer, hole transport layer/emission auxiliary layer or hole injection layer/hole transport layer/electron blocking layer, wherein in each of these structures, constituting layers are sequentially stacked from the first electrode 110 in this stated order, but the structure of the hole transport region is not limited thereto.

The hole transport region may include the second compound as described above.

In various embodiments, the hole transport region may include an emission auxiliary layer. The emission auxiliary layer may directly contact the emission layer.

In various embodiments, the hole transport region may include a hole injection layer and a hole transport layer, may include a hole injection layer and an emission auxiliary layer, or may include a hole injection layer, a hole transport layer, and an emission auxiliary layer, wherein in each of these cases, constituting layers are sequentially stacked from the first electrode 110 in this stated order, but embodiments of the present disclosure are not limited thereto.

When the hole transport region includes the emission auxiliary layer, the emission auxiliary layer may include the second compound as described above.

The hole transport region may include at least one selected from m-MTDATA, TDATA, 2-TNATA, NPB(NPD), β-NPB, TPD, spiro-TPD, spiro-NPB, methylated-NPB, TAPC, HMTPD, 4,4′,4″-tris(N-carbazolyl)triphenylamine (TCTA), polyaniline/dodecylbenzenesulfonic acid (Pani/DBSA), poly(3,4-ethylenedioxythiophene)/poly(4-styrenesulfonate) (PEDOT/PSS), polyaniline/camphor sulfonic acid (Pani/CSA), polyaniline/poly(4-styrenesulfonate) (Pani/PSS), a compound represented by Formula 201, and a compound represented by Formula 202:

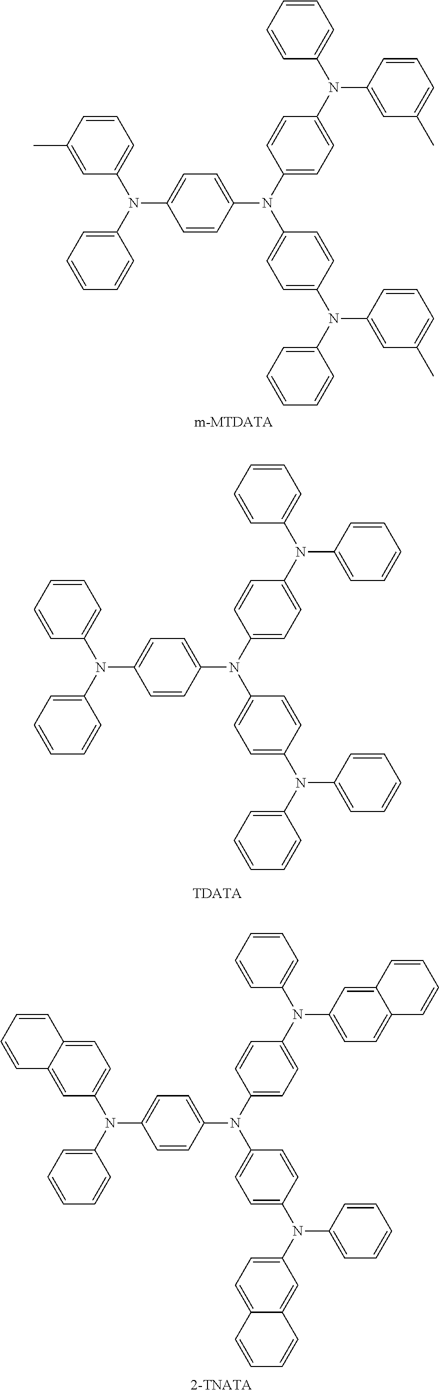

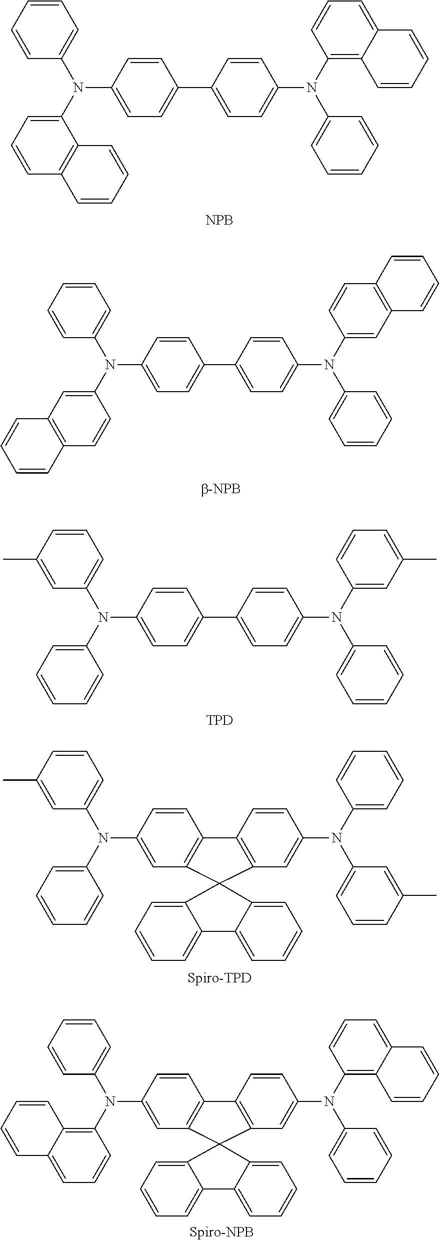

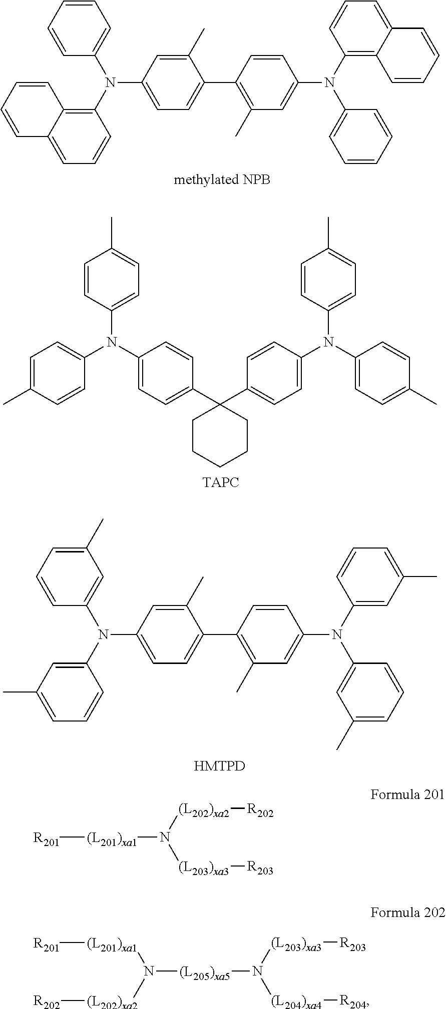

wherein, in Formulae 201 and 202,

L₂₀₁ to L₂₀₄ may each independently be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

L₂₀₅ may be selected from *—O—*′, *—S—′, *—N(Q₂₀₁)-*′, a substituted or unsubstituted C₁-C₂₀ alkylene group, a substituted or unsubstituted C₂-C₂₀ alkenylene group, a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

xa1 to xa4 may each independently be an integer selected from 0 to 3,

xa5 may be an integer selected from 1 to 10, and

R₂₀₁ to R₂₀₄ and Q₂₀₁ may each independently be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group.

For example, in Formula 202, R₂₀₁ and R₂₀₂ may be optionally connected to each other via a single bond, a dimethyl-methylene group, or a diphenyl-methylene group, and R₂₀₃ and R₂₀₄ may be optionally connected to each other via a single bond, a dimethyl-methylene group, or a diphenyl-methylene group.

In various embodiments, in Formulae 201 and 202,

L₂₀₁ to L₂₀₅ may each independently be selected from the group consisting of:

a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group; and

a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, —Si(Q₃₁)(Q₃₂)(Q₃₃), and —N(Q₃₁)(Q₃₂),

wherein Q₃₁ to Q₃₃ may each independently be selected from a C₁-C₁₀ alkyl group, a C₁-C₁₀ alkoxy group, a phenyl group, a biphenyl group, a terphenyl group, and a naphthyl group.

In various embodiments, xa1 to xa4 may each independently be 0, 1, or 2.

In various embodiments, xa5 may be 1, 2, 3, or 4.

In various embodiments, R₂₀₁ to R₂₀₄ and Q₂₀₁ may each independently be selected from the group consisting of:

a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group; and

a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, —Si(Q₃₁)(Q₃₂)(Q₃₃), and —N(Q₃₁)(Q₃₂),

wherein Q₃₁ to Q₃₃ are the same as described above.

In various embodiments, at least one selected from R₂₀₁ to R₂₀₃ in Formula 201 may each independently be selected from the group consisting of:

a fluorenyl group, a spiro-bifluorenyl group, a carbazolyl group, a dibenzofuranyl group, and a dibenzothiophenyl group; and

a fluorenyl group, a spiro-bifluorenyl group, a carbazolyl group, a dibenzofuranyl group, and a dibenzothiophenyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a naphthyl group, a fluorenyl group, a spiro-bifluorenyl group, a carbazolyl group, a dibenzofuranyl group, and a dibenzothiophenyl group,

but embodiments of the present disclosure are not limited thereto.

In various embodiments, in Formula 202, i) R₂₀₁ and R₂₀₂ may be connected to each other via a single bond, and/or ii) R₂₀₃ and R₂₀₄ may be connected to each other via a single bond.

In various embodiments, at least one selected from R₂₀₁ to R₂₀₄ in Formula 202 may be selected from the group consisting of:

a carbazolyl group; and

a carbazolyl group substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a naphthyl group, a fluorenyl group, a spiro-bifluorenyl group, a carbazolyl group, a dibenzofuranyl group, and a dibenzothiophenyl group,

but embodiments of the present disclosure are not limited thereto.

The compound represented by Formula 201 may be represented by Formula 201A:

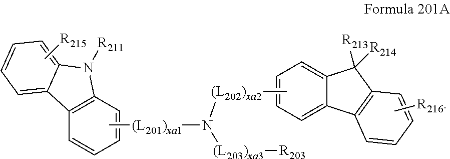

In various embodiments, the compound represented by Formula 201 may be represented by Formula 201A(1), but embodiments of the present disclosure are not limited thereto:

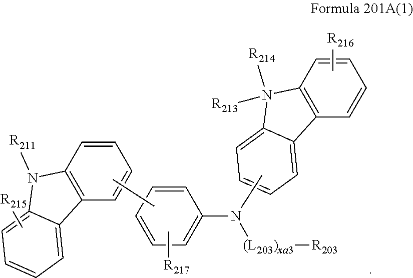

In various embodiments, the compound represented by Formula 201 may be represented by Formula 201A-1, but embodiments of the present disclosure are not limited thereto:

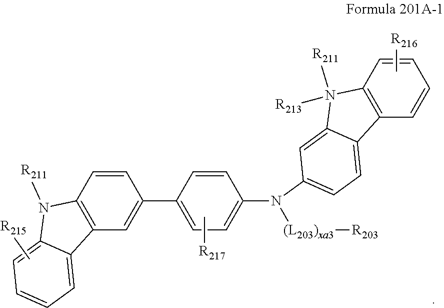

In various embodiments, the compound represented by Formula 202 may be represented by Formula 202A:

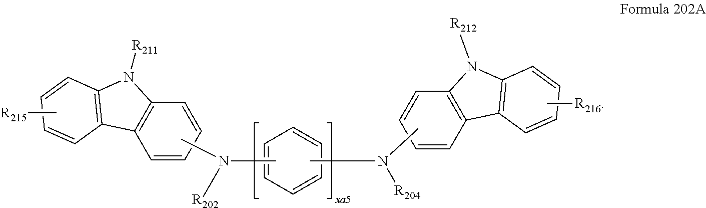

In various embodiments, the compound represented by Formula 202 may be represented by Formula 202A-1:

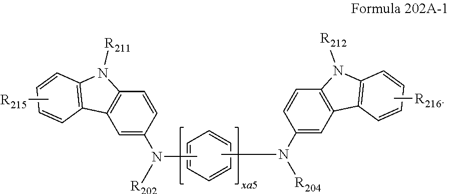

In Formulae 201A, 201A(1), 201A-1, 202A, and 202A-1,

L₂₀₁ to L₂₀₃, xa1 to xa3, xa5, and R₂₀₂ to R₂₀₄ are the same as described above,

R₂₁₁ and R₂₁₂ are the same as described above in connection with R₂₀₃, and

R₂₁₃ to R₂₁₇ may each independently be selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group.

The hole transport region may include at least one compound selected from Compounds HT1 to HT39, but embodiments of the present disclosure are not limited thereto:

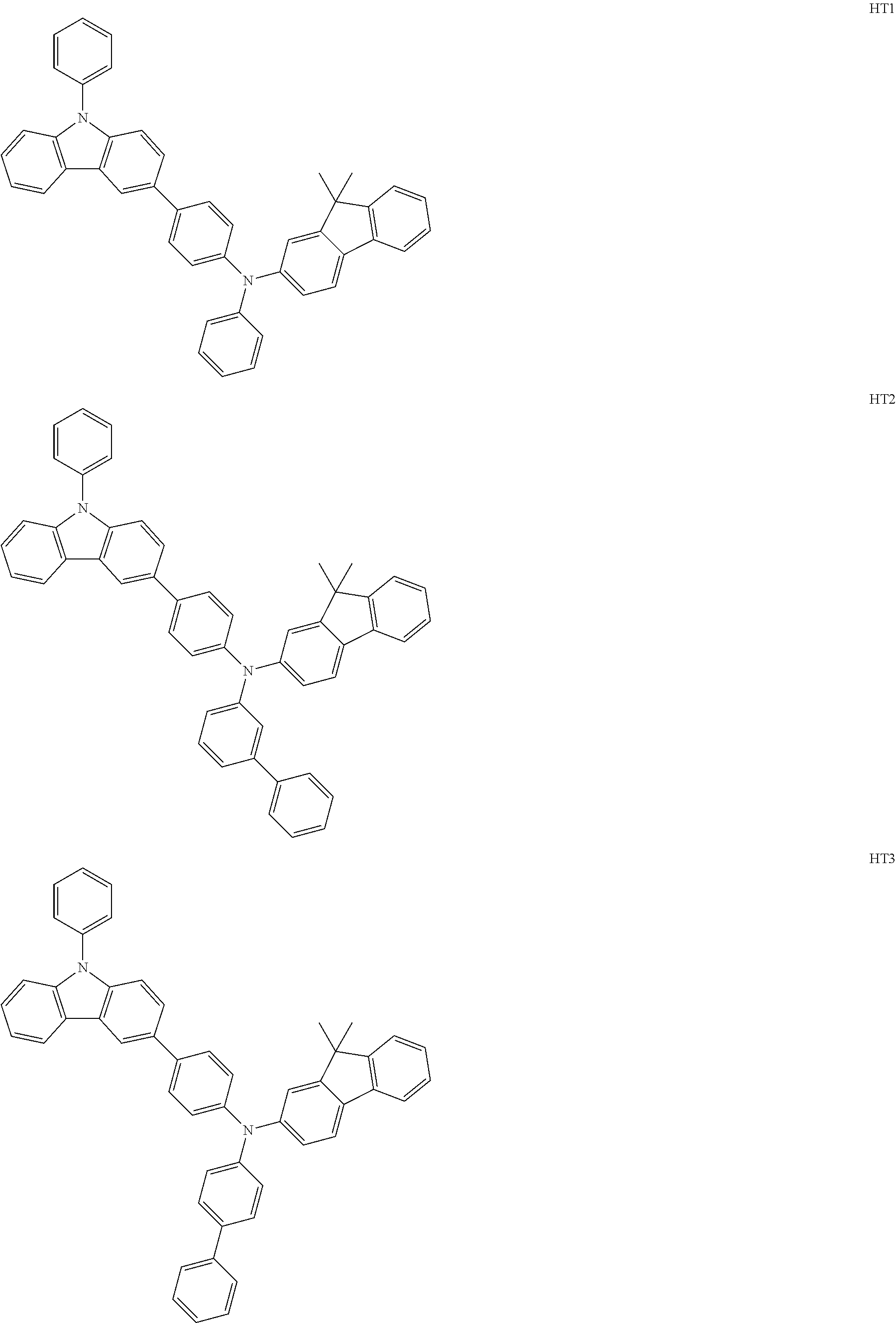 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

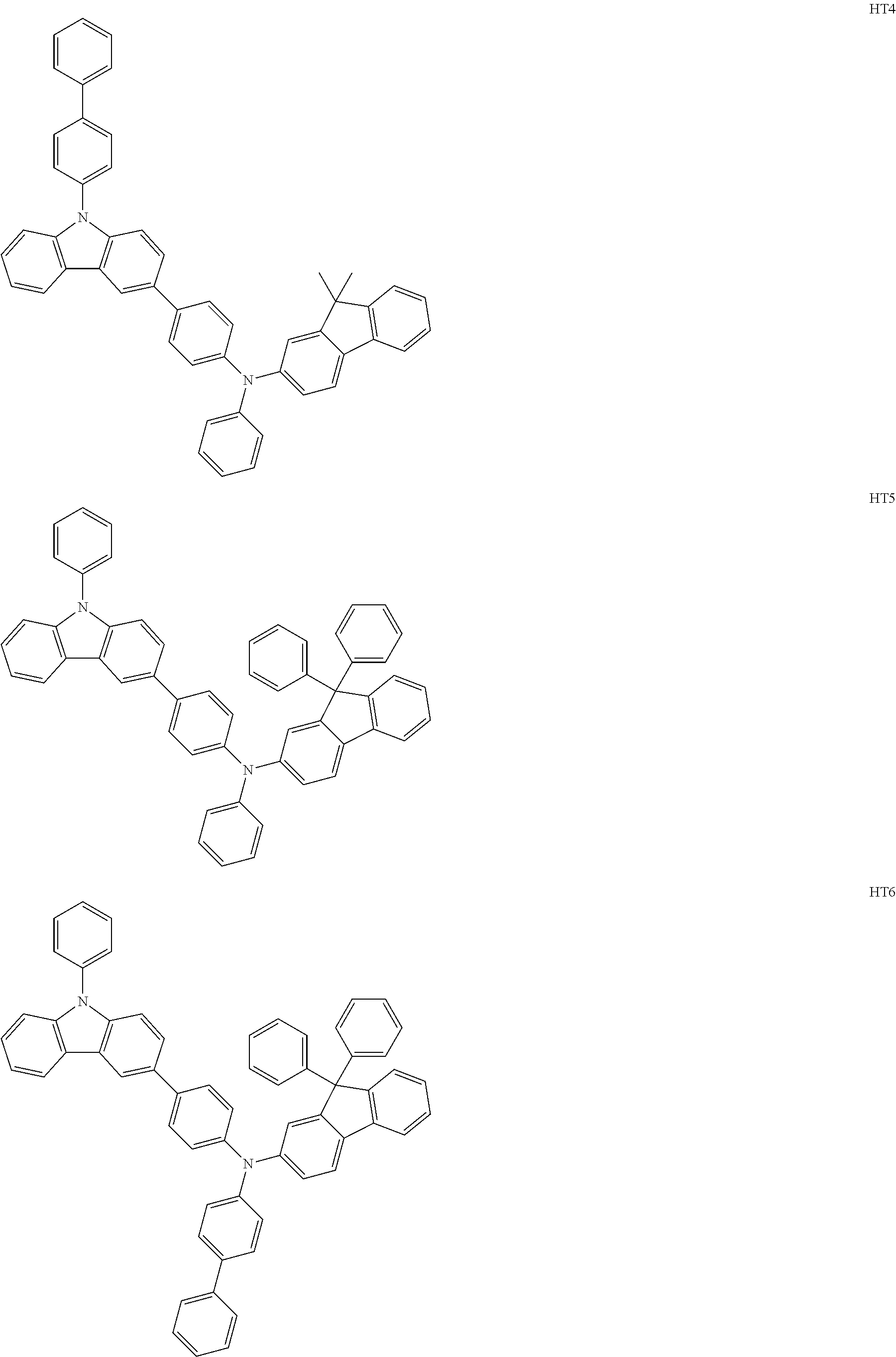 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

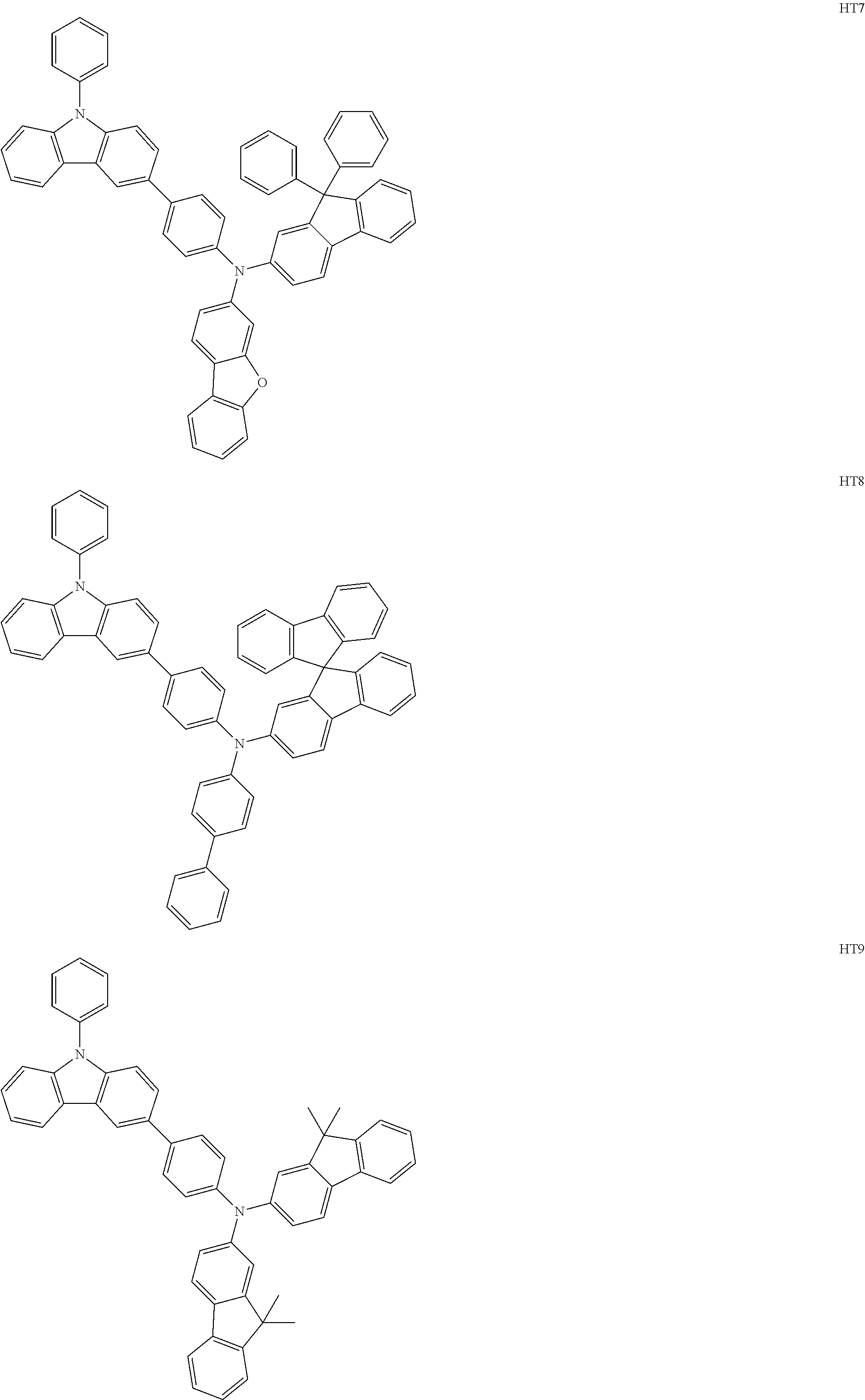 [SMILES: c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

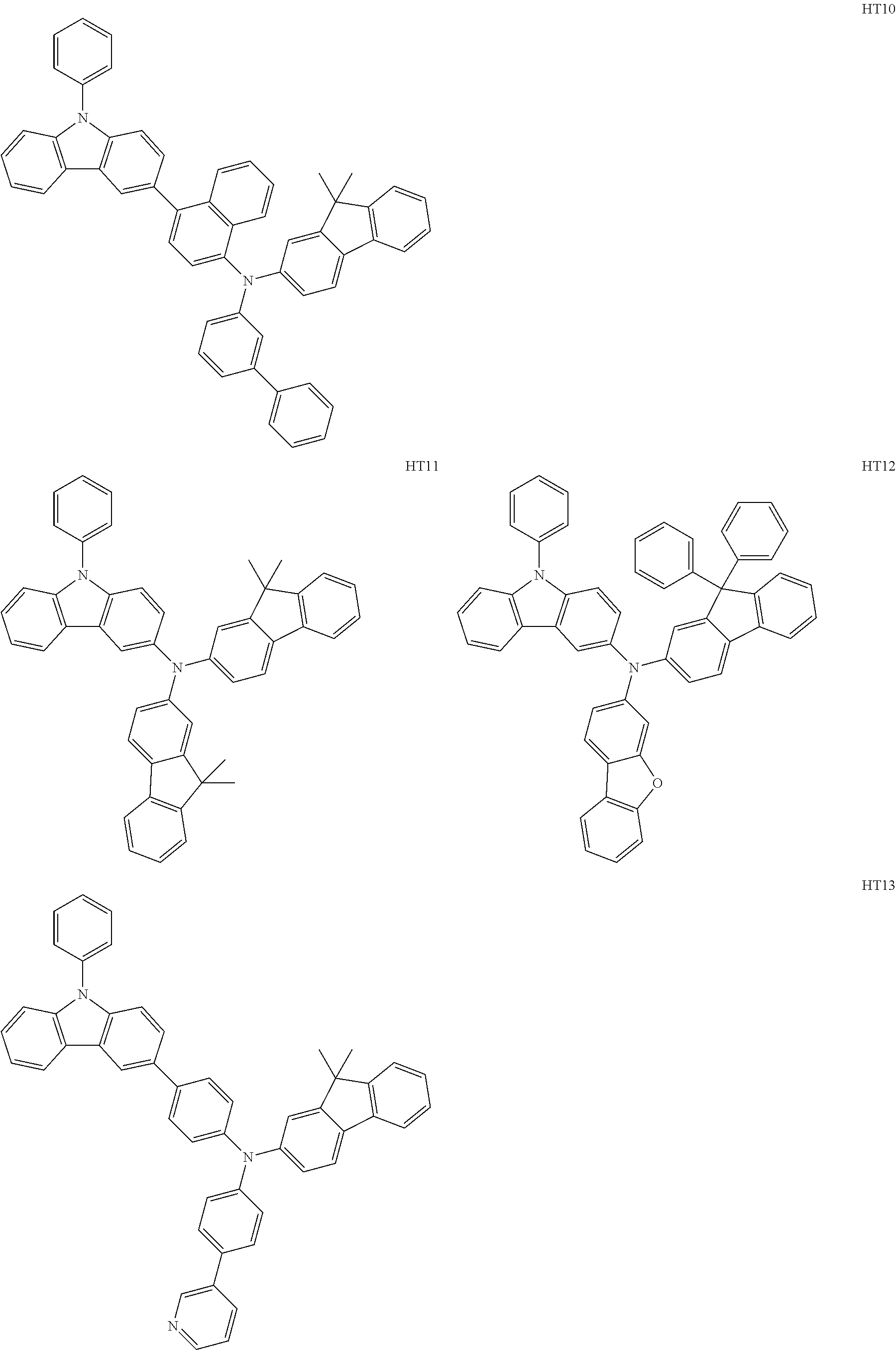 [SMILES: CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1 ; CC1(C)c2ccccc2-c2ccc(N(c3ccc(-c4cccnc4)cc3)c3ccc(-c4ccc5c(c4)c4ccccc4n5-c4ccccc4)cc3)cc21]

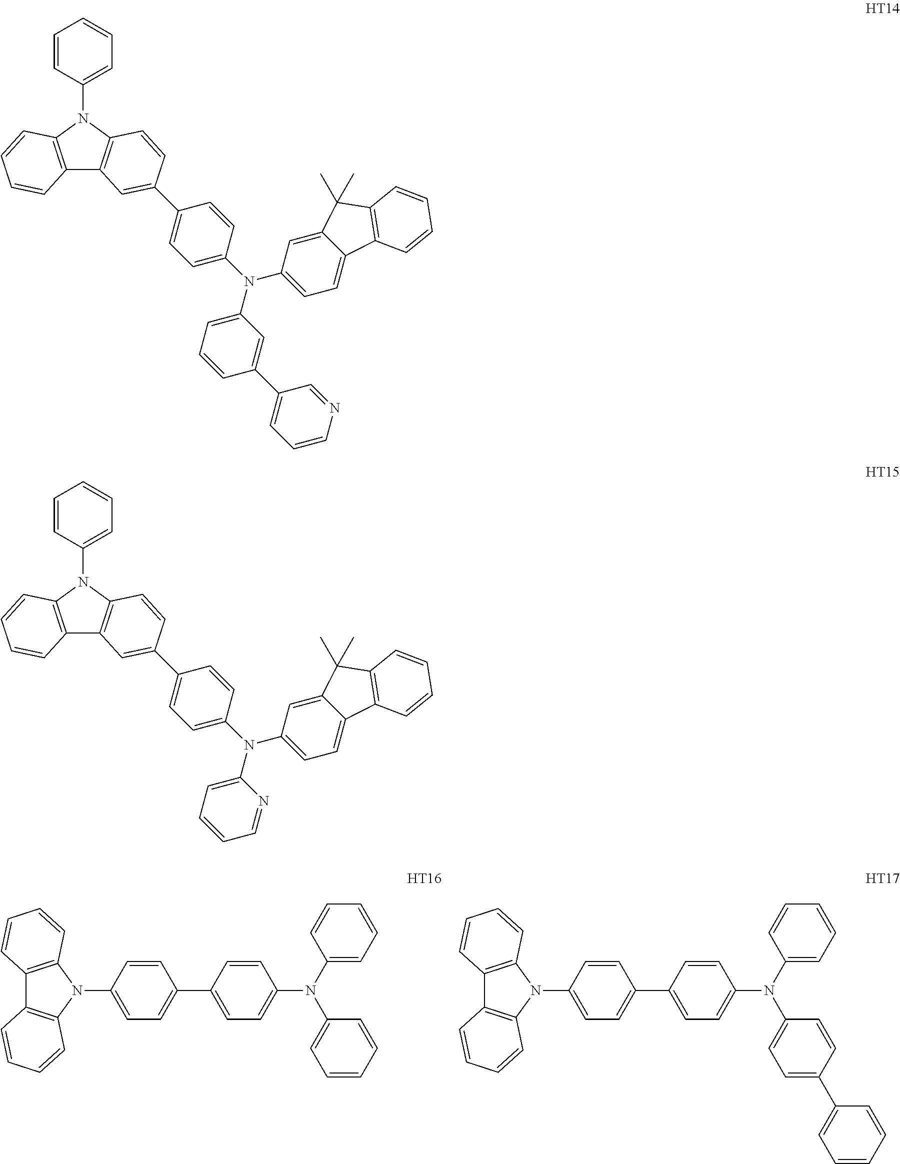 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1]

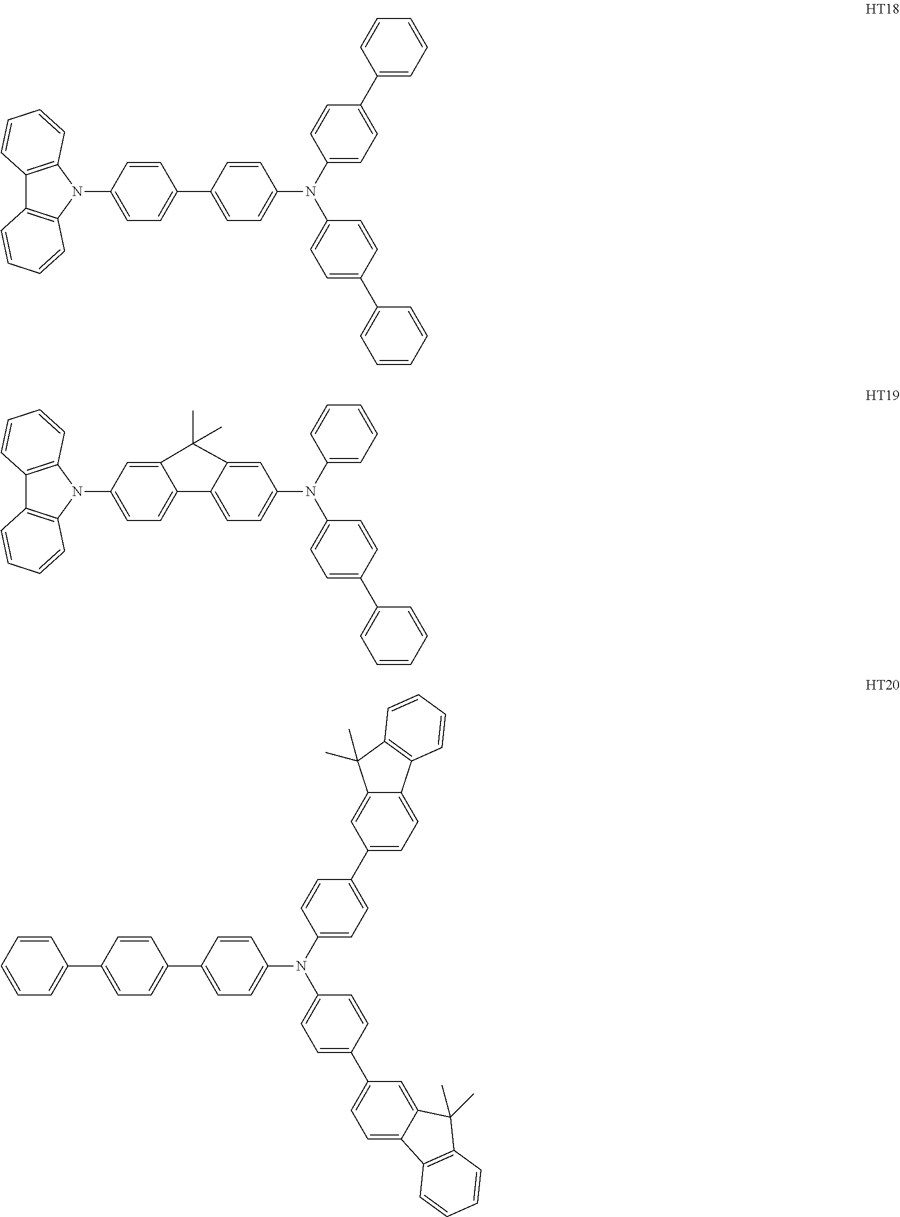

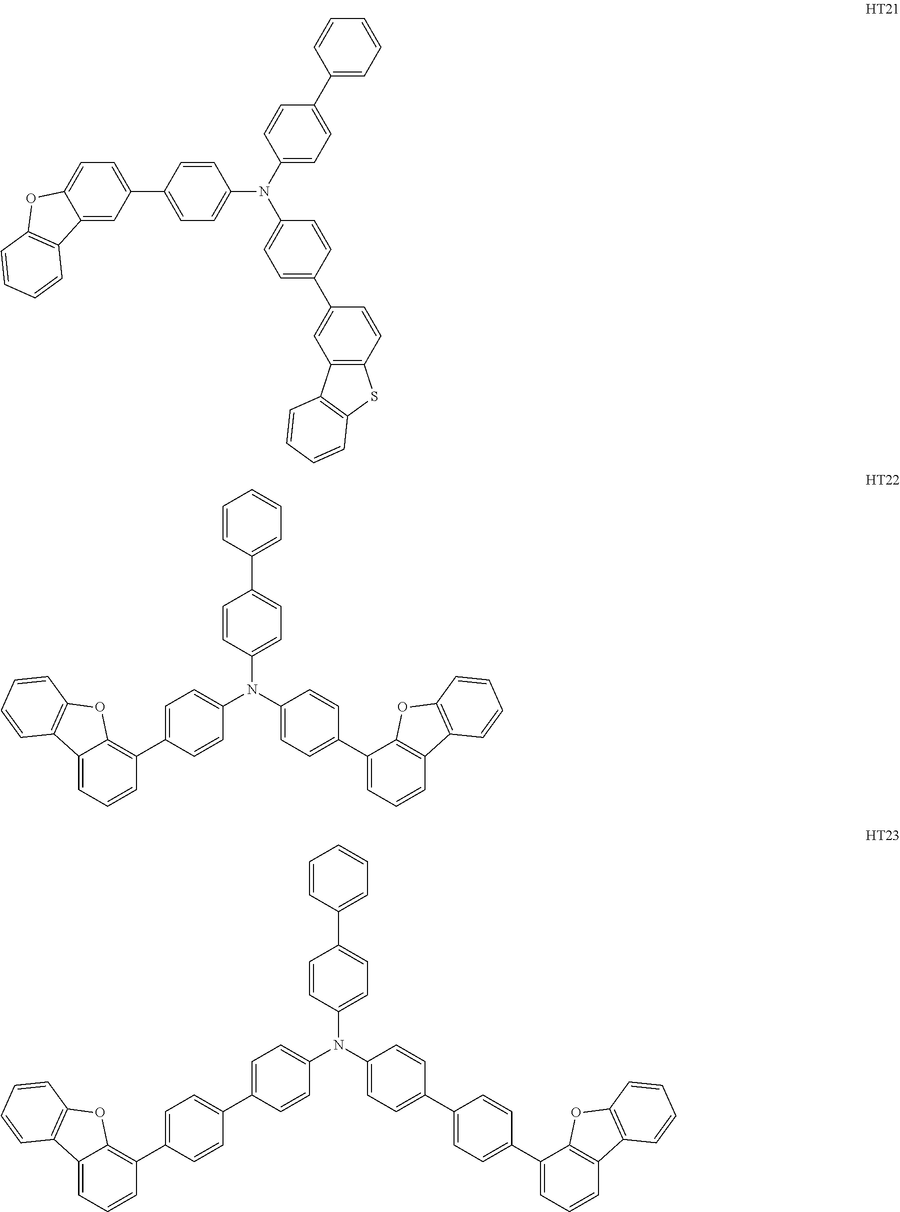 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

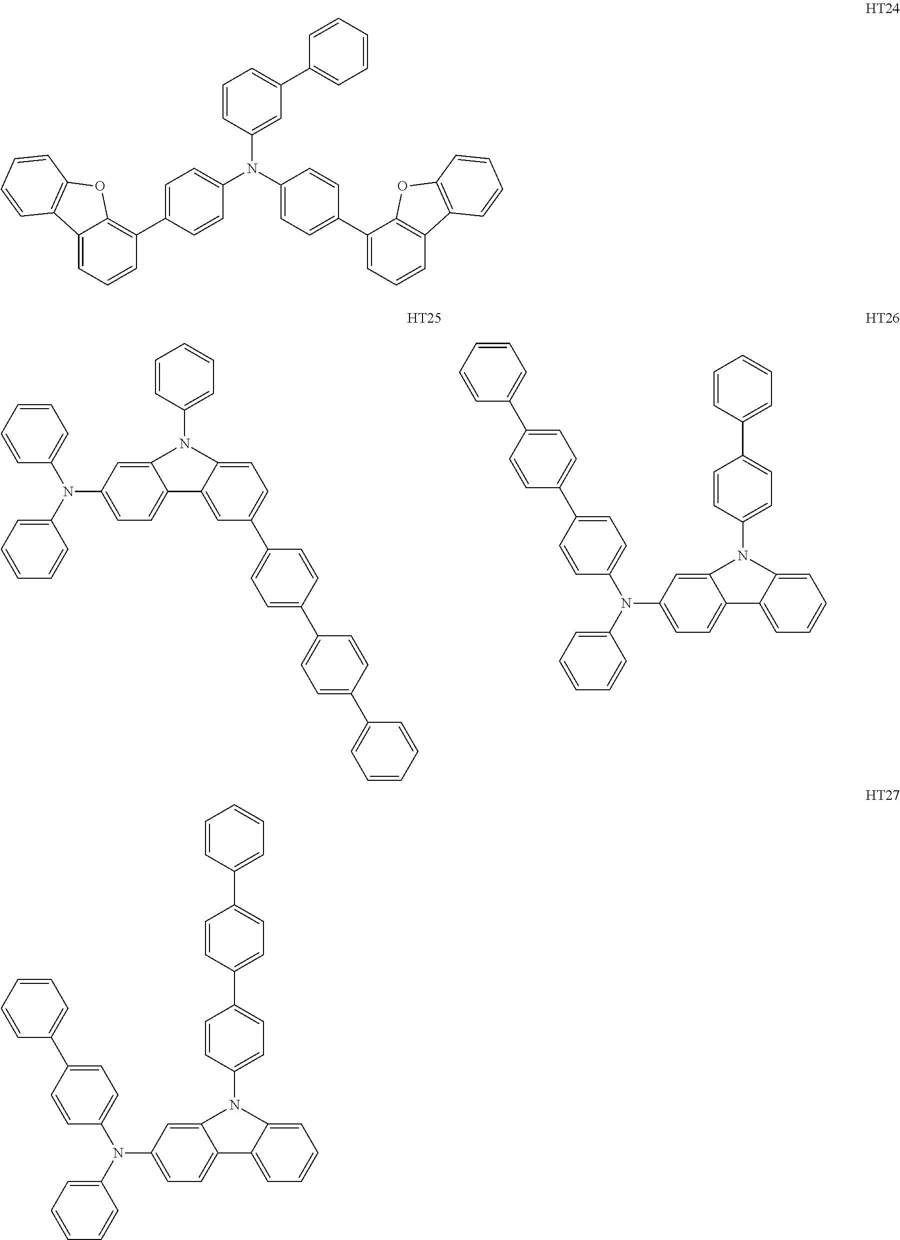 [SMILES: c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(-c3ccc(-n4c5ccccc5c5ccc(N(c6ccccc6)c6ccc(-c7ccccc7)cc6)cc54)cc3)cc2)cc1]

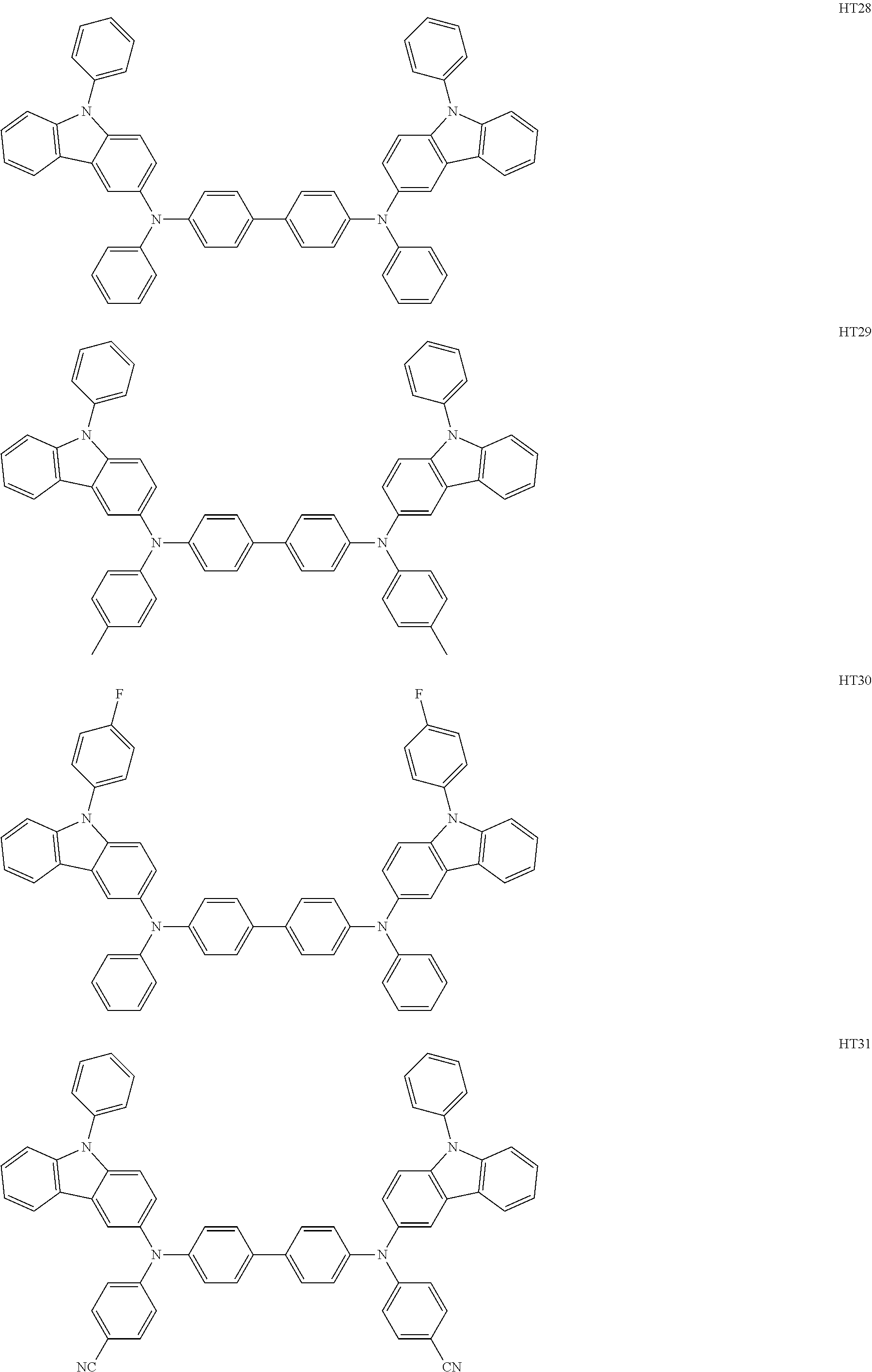

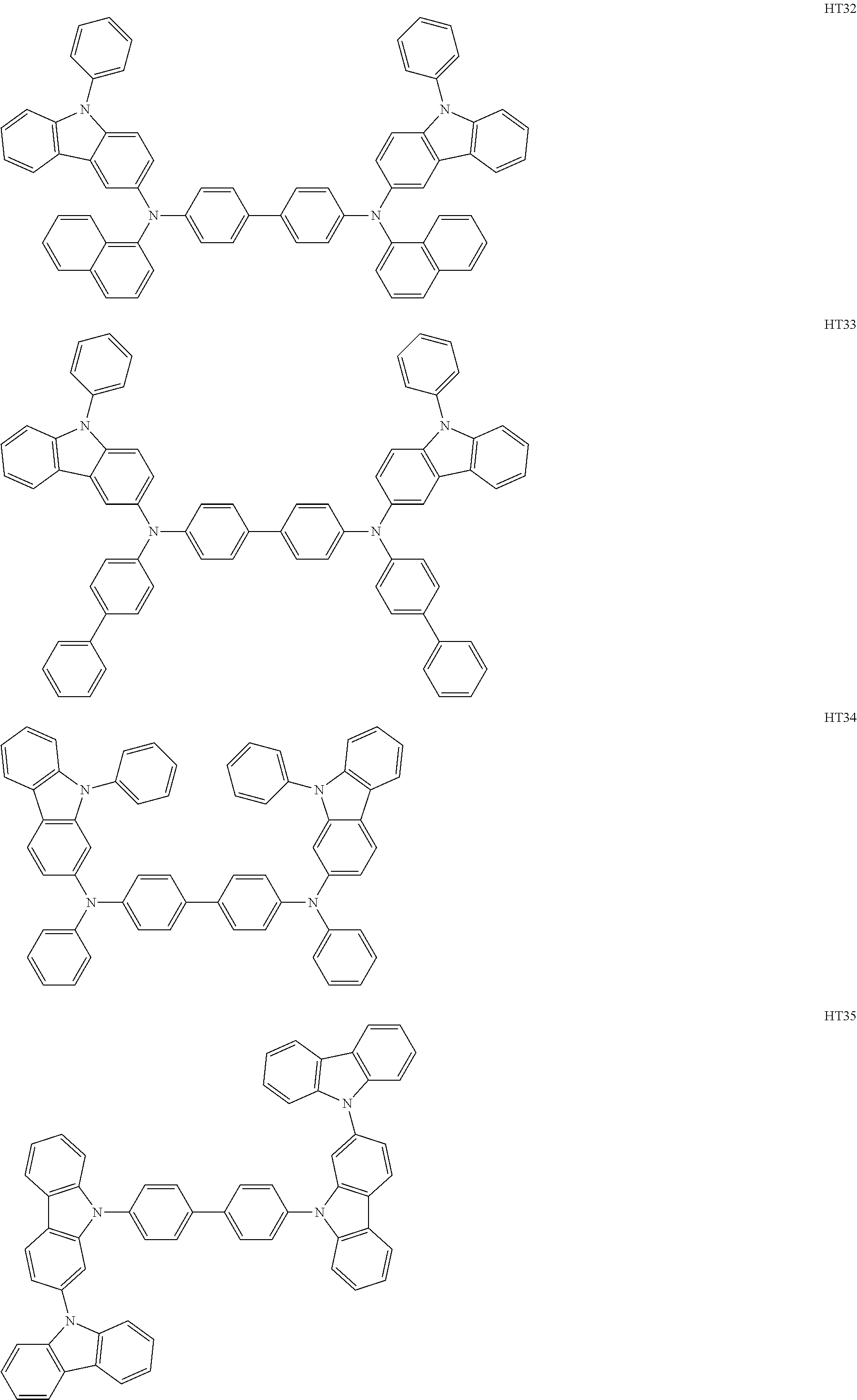

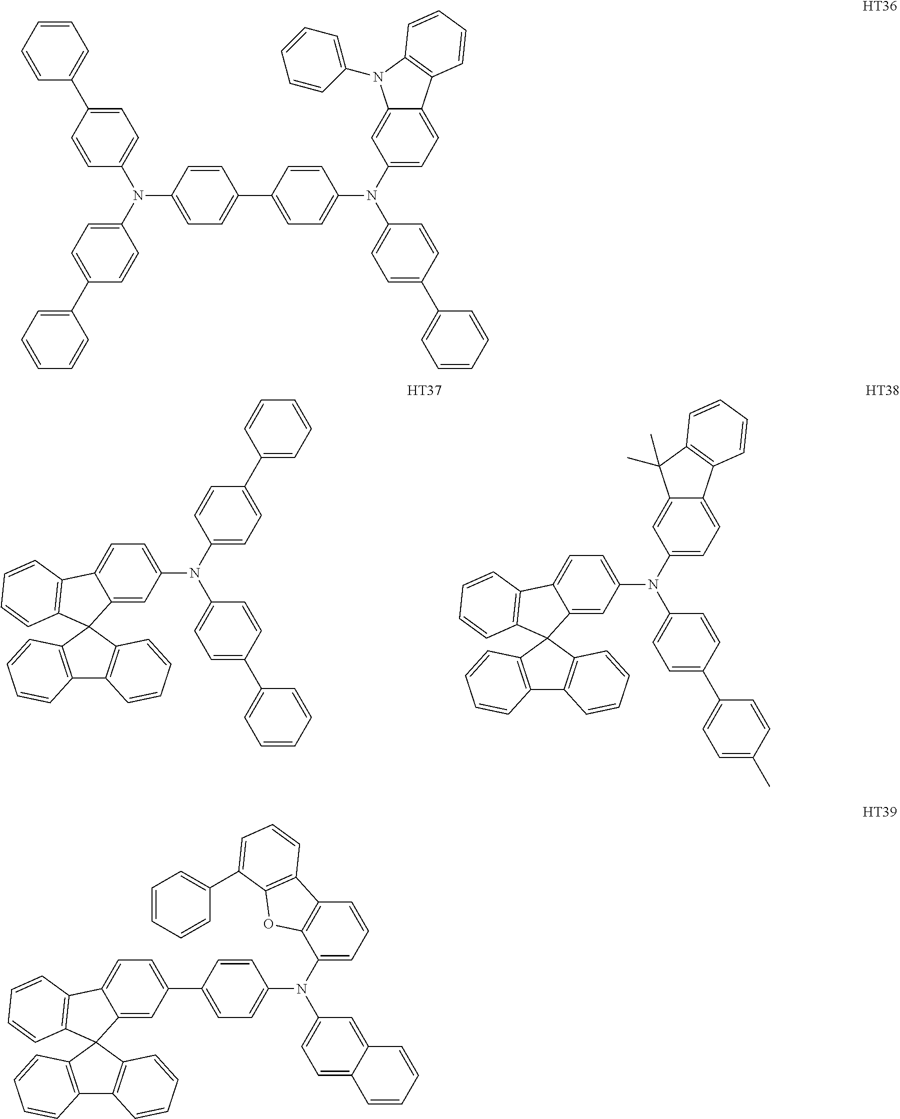 [SMILES: c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; "HT36" ; c1ccc(-c2ccc(N(c3ccc(-c4ccccc4)cc3)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; "HT39"]

A thickness of the hole transport region may be in a range of about 100 Å to about 10,000 Å, for example, about 100 Å to about 1,000 Å. When the hole transport region includes at least one selected from a hole injection layer and a hole transport layer, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within these ranges, satisfactory hole transporting characteristics may be obtained without a substantial increase in driving voltage.

The emission auxiliary layer may increase light-emission efficiency by compensating for an optical resonance distance according to the wavelength of light emitted by an emission layer, and the electron blocking layer may block the flow of electrons from an electron transport region. The emission auxiliary layer and the electron blocking layer may include the materials as described above.

p-Dopant

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant.

A doping concentration of the p-dopant may be in a range of about 0.1 wt % to about 20 wt %, for example, about 0.5 wt % to about 10 wt %.

In various embodiments, a lowest unoccupied molecular orbital (LUMO) of the p-dopant may be about −3.5 eV or less.

The p-dopant may include at least one selected from a quinone derivative, a metal oxide, and a cyano group-containing compound, but embodiments of the present disclosure are not limited thereto.

For example, the p-dopant may include at least one selected from the group consisting of:

a quinone derivative, such as tetracyanoquinodimethane (TCNQ) and/or 2,3,5,6-tetrafluoro-7,7,8,8-tetracyanoquinodimethane (F4-TCNQ);

a metal oxide, such as a tungsten oxide and/or a molybdenum oxide;

1,4,5,8,9,11-hexaazatriphenylene-hexacarbonitrile (HAT-CN); and

a compound represented by Formula 221,

but embodiments of the present disclosure are not limited thereto:

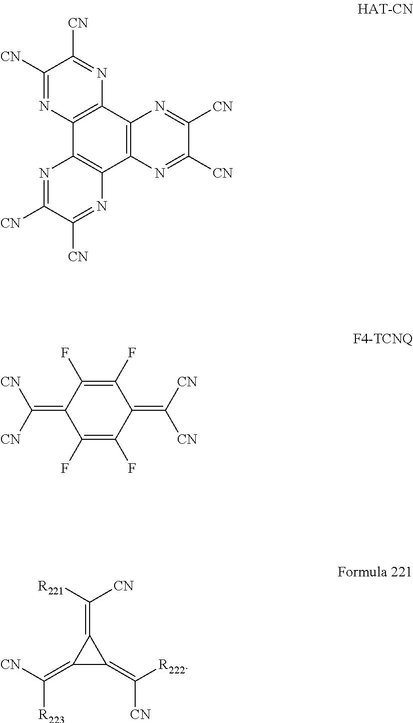

In Formula 221,

R₂₂₁ to R₂₂₃ may each independently be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, wherein at least one selected from R₂₂₁ to R₂₂₃ may have at least one substituent selected from a cyano group, —F, —Cl, —Br, —I, a C₁-C₂₀ alkyl group substituted with —F, a C₁-C₂₀ alkyl group substituted with —Cl, a C₁-C₂₀ alkyl group substituted with —Br, and a C₁-C₂₀ alkyl group substituted with —I.

### Emission Layer in Organic Layer 150

When the organic light-emitting device 10 is a full color organic light-emitting device, the emission layer may be patterned into a red emission layer, a green emission layer, or a blue emission layer, according to a sub-pixel. In various embodiments, the emission layer may have a stacked structure of two or more layers selected from a red emission layer, a green emission layer, and a blue emission layer, in which the two or more layers contact each other or are separated from each other. In various embodiments, the emission layer may include two or more materials selected from a red-light emission material, a green-light emission material, and a blue-light emission material, in which the two or more materials are mixed with each other in a single layer to emit white light.

In various embodiments, the emission layer of the organic light-emitting device 10 may be a first-color-light emission layer,

the organic light-emitting device 10 may further include i) at least one second-color-light emission layer or ii) at least one second-color-light emission layer and at least one third-color-light emission layer, between the first electrode 110 and the second electrode 190,

a maximum emission wavelength of the first-color-light emission layer, a maximum emission wavelength of the second-color-light emission layer, and a maximum emission wavelength of the third-color-light emission layer may be identical to or different from one another, and

the organic light-emitting device 10 may emit mixed light including first-color-light and second-color-light, or mixed light including first-color-light, second-color-light, and third-color-light, but embodiments of the present disclosure are not limited thereto.

For example, the maximum emission wavelength of the first-color-light emission layer may be different from the maximum emission wavelength of the second-color-light emission layer, and the mixed light including first-color-light and second-color-light may be white light, but embodiments of the present disclosure are not limited thereto.

In various embodiments, the maximum emission wavelength of the first-color-light emission layer, the maximum emission wavelength of the second-color-light emission layer, and the maximum emission wavelength of the third-color-light emission layer may be different from one another, and the mixed light including first-color-light, second-color-light, and third-color-light may be white light. However, embodiments of the present disclosure are not limited thereto.

The emission layer may include a host and a dopant. The dopant may include at least one selected from a phosphorescent dopant and a fluorescent dopant.

An amount of the dopant in the emission layer may be, in general, in a range of about 0.01 to about 15 parts by weight based on 100 parts by weight of the host, but embodiments of the present disclosure are not limited thereto.

A thickness of the emission layer may be in a range of about 100 Å to about 1,000 Å, for example, about 200 Å to about 600 Å. When the thickness of the emission layer is within these ranges, excellent light-emission characteristics may be obtained without a substantial increase in driving voltage.

### Host in Emission Layer

The emission layer may include the first compound as a host. The first compound is the same as described above.

The emission layer may include the first compound as a first host, and may further include a second host different from the first host.

For example, the second host may be selected from compounds other than the first compound.

In various embodiments, the second host may be selected from 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di-9-carbazolylbenzene (mCP), and 1,3,5-tri(carbazol-9-yl)benzene (TCP), but embodiments of the present disclosure are not limited thereto.

A weight ratio of the first host to the second host in the emission layer may be, for example, about 90:10 to about 10:90, about 80:20 to about 20:80, or about 50:50, but embodiments of the present disclosure are not limited thereto.

### Phosphorescent Dopant Included in Emission Layer in Organic Layer 150

The phosphorescent dopant may include an organometallic complex represented by Formula 401:

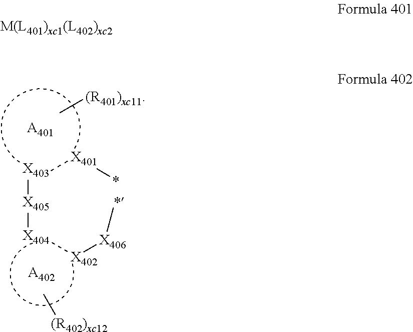

Wherein, in Formulae 401 and 402,

M may be selected from iridium (Ir), platinum (Pt), palladium (Pd), osmium (Os), titanium (Ti), zirconium (Zr), hafnium (Hf), europium (Eu), terbium (Tb), rhodium (Rh), and thulium (Tm),

L₄₀₁ may be selected from ligands represented by Formula 402, and xc1 may be 1, 2, or 3, wherein when xc1 is two or more, two or more L₄₀₁(s) may be identical to or different from each other,

L₄₀₂ may be an organic ligand, and xc2 may be an integer selected from 0 to 4, wherein when xc2 is two or more, two or more L₄₀₂(s) may be identical to or different from each other,

X₄₀₁ to X₄₀₄ may each independently be nitrogen or carbon,

X₄₀₁ and X₄₀₃ may be connected to each other via a single bond or a double bond, and X₄₀₂ and X₄₀₄ may be connected to each other via a single bond or a double bond,

A₄₀₁ and A₄₀₂ may each independently be a C₅-C₆₀ carbocyclic group or a C₁-C₆₀ heterocyclic group,

X₄₀₅ may be a single bond, *—O—*′, *—S—′, *—C(═O)—*′, *—N(Q₄₁₁)-*′, *—C(Q₄₁₁)(Q₄₁₂)-*′, *—C(Q₄₁₁)═C(Q₄₁₂)-′, *—C(Q₄₁₁)=*,′ or *═C(Q₄₁₁)═*, wherein Q₄₁₁ and Q₄₁₂ may each independently be hydrogen, deuterium, a C₁-C₂₀ alkyl group, a C₁-C₂₀ alkoxy group, a phenyl group, a biphenyl group, a terphenyl group, or a naphthyl group,

X₄₀₆ may be a single bond, O, or S,

R₄₀₁ and R₄₀₂ may each independently be selected from hydrogen, deuterium, —F, —Cl, —Br, —I, —CD₃, —CF₃, a hydroxyl group, a cyano group, a nitro group, an amidino group, a hydrazino group, a hydrazono group, a substituted or unsubstituted C₁-C₂₀ alkyl group, a substituted or unsubstituted C₁-C₂₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), and —P(═O)(Q₄₀₁)(Q₄₀₂), wherein Q₄₀₁ to Q₄₀₃ may each independently be selected from a C₁-C₁₀ alkyl group, a C₁-C₁₀ alkoxy group, a C₆-C₂₀ aryl group, and a C₁-C₂₀ heteroaryl group,

xc11 and xc12 may each independently be an integer selected from 0 to 10, and

* and *′ in Formula 402 each indicate a binding site to M in Formula 401.

In various embodiments, A₄₀₁ and A₄₀₂ in Formula 402 may each independently be selected from a benzene group, a naphthalene group, a fluorene group, a spiro-bifluorene group, an indene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, a quinoline group, an isoquinoline group, a benzoquinoline group, a quinoxaline group, a quinazoline group, a carbazole group, a benzoimidazole group, a benzofuran group, a benzothiophene group, an isobenzothiophene group, a benzoxazole group, an isobenzoxazole group, a triazole group, a tetrazole group, an oxadiazole group, a triazine group, a dibenzofuran group, and a dibenzothiophene group.

In various embodiments, in Formula 402, i) X₄₀₁ may be nitrogen and X₄₀₂ may be carbon, or ii) both X₄₀₁ and X402 may be nitrogen.

In various embodiments, R₄₀₁ and R₄₀₂ in Formula 402 may each independently be selected from the group consisting of:

hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;

a C₁-C₂₀ alkyl group and a C₁-C₂₀ alkoxy group, each substituted with at least one selected from deuterium, —F, —Cl, —Br, —I, a hydroxyl group, a cyano group, a nitro group, an amidino group, a hydrazino group, a hydrazono group, a phenyl group, a naphthyl group, a cyclopentyl group, a cyclohexyl group, an adamantanyl group, a norbornanyl group, and a norbornenyl group;

a cyclopentyl group, a cyclohexyl group, an adamantanyl group, a norbornanyl group, a norbornenyl group, a phenyl group, a biphenyl group, a terphenyl group, a naphthyl group, a fluorenyl group, a pyridinyl group, a pyrazinyl group, a pyrimidinyl group, a pyridazinyl group, a triazinyl group, a quinolinyl group, an isoquinolinyl group, a quinoxalinyl group, a quinazolinyl group, a carbazolyl group, a dibenzofuranyl group, and a dibenzothiophenyl group;

a cyclopentyl group, a cyclohexyl group, an adamantanyl group, a norbornanyl group, a norbornenyl group, a phenyl group, a biphenyl group, a terphenyl group, a naphthyl group, a fluorenyl group, a pyridinyl group, a pyrazinyl group, a pyrimidinyl group, a pyridazinyl group, a triazinyl group, a quinolinyl group, an isoquinolinyl group, a quinoxalinyl group, a quinazolinyl group, a carbazolyl group, a dibenzofuranyl group, and a dibenzothiophenyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, an adamantanyl group, a norbornanyl group, a norbornenyl group, a phenyl group, a biphenyl group, a terphenyl group, a naphthyl group, a fluorenyl group, a pyridinyl group, a pyrazinyl group, a pyrimidinyl group, a pyridazinyl group, a triazinyl group, a quinolinyl group, an isoquinolinyl group, a quinoxalinyl group, a quinazolinyl group, a carbazolyl group, a dibenzofuranyl group, and a dibenzothiophenyl group; and

—Si(Q₄₀₁)(Q₄₀₂)(Q₄₀₃), —N(Q₄₀₁)(Q₄₀₂), —B(Q₄₀₁)(Q₄₀₂), —C—(═O)(Q₄₀₁), —S(═O)₂(Q₄₀₁), and —P(═O)(Q₄₀₁)(Q₄₀₂),

wherein Q₄₀₁ to Q₄₀₃ may each independently be selected from a C₁-C₁₀ alkyl group, a C₁-C₁₀ alkoxy group, a phenyl group, a biphenyl group, and a naphthyl group, but embodiments of the present disclosure are not limited thereto.

In various embodiments, when xc1 in Formula 401 is two or more, two A₄₀₁(s) selected from two or more L₄₀₁(s) may be optionally connected via a linking group X₄₀₇, or two A₄₀₂(s) may be optionally connected via a linking group X₄₀₈ (see Compounds PD1 to PD4 and PD7 below). X₄₀₇ and X₄₀₈ may each independently be a single bond, *—O—*′, *—S—*′, *—C(═O)—′, *—N(Q₄₁₃)-*′, *—C(Q₄₁₃)(Q₄₁₄)-*′, or *—C(Q₄₁₃)=C(Q₄₁₄)-*′ (wherein Q₄₁₃ and Q₄₁₄ may each independently be hydrogen, deuterium, a C₁-C₂₀ alkyl group, a C₁-C₂₀ alkoxy group, a phenyl group, a biphenyl group, a terphenyl group, or a naphthyl group), but embodiments of the present disclosure are not limited thereto.

L₄₀₂ in Formula 401 may be any monovalent, divalent, or trivalent organic ligand. For example, L₄₀₂ may be selected from a halogen, a diketone (for example, an acetylacetonate), a carboxylic acid (for example, a picolinate), —C(═O), an isonitrile, —CN, and phosphorus (for example, a phosphine or a phosphite), but embodiments of the present disclosure are not limited thereto.

In various embodiments, the phosphorescent dopant may be selected from, for example, Compounds PD1 to PD25, but embodiments of the present disclosure are not limited thereto:

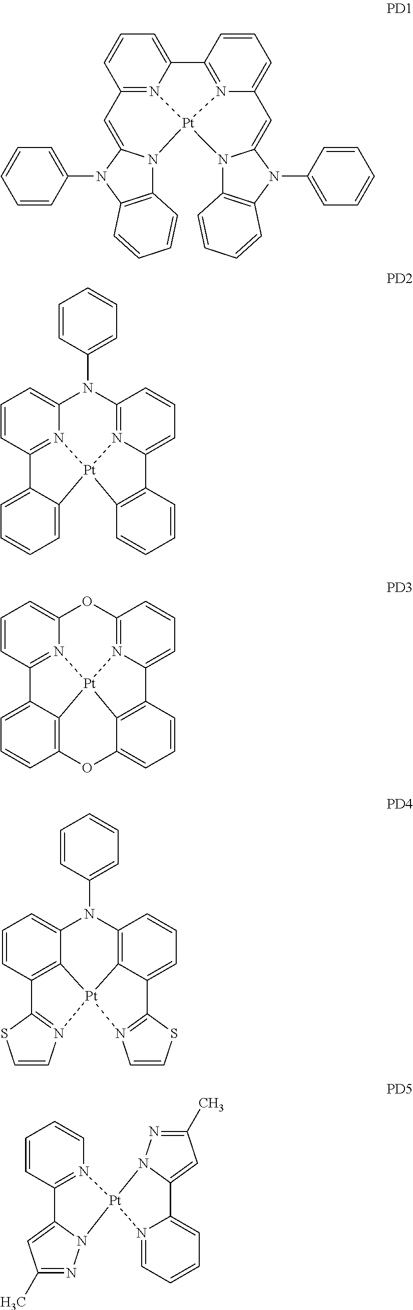

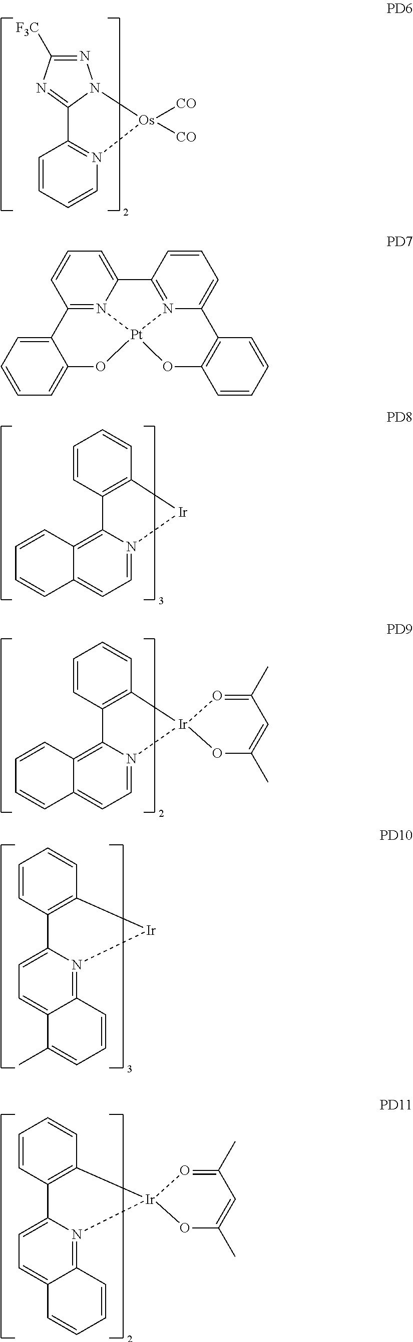

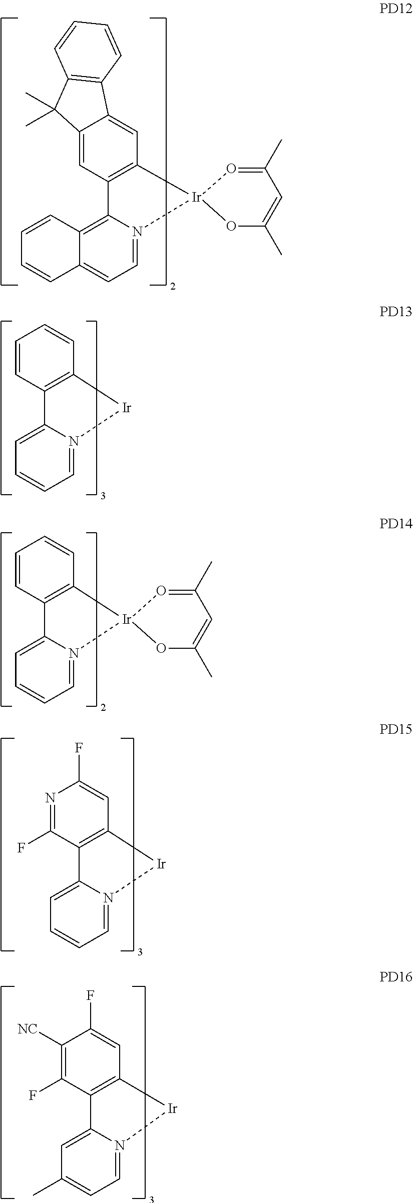

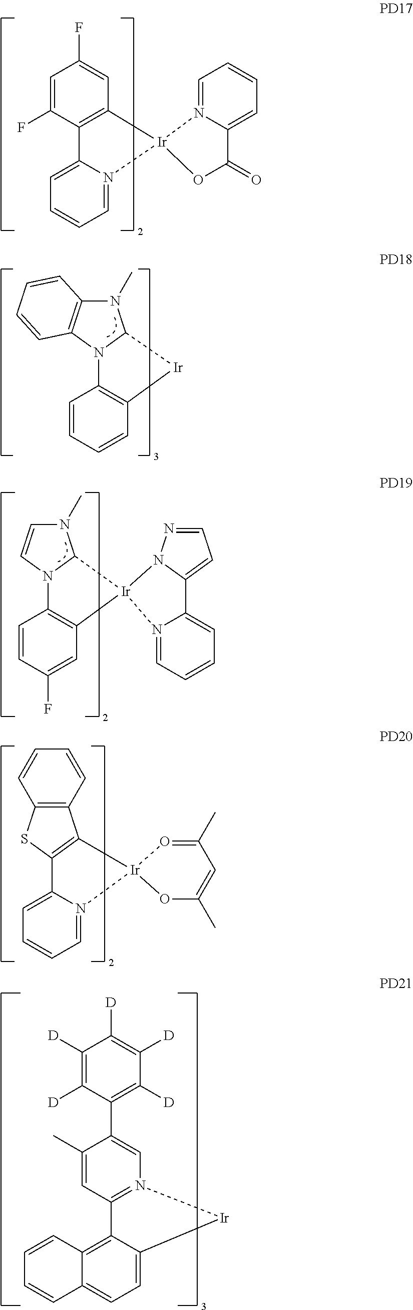

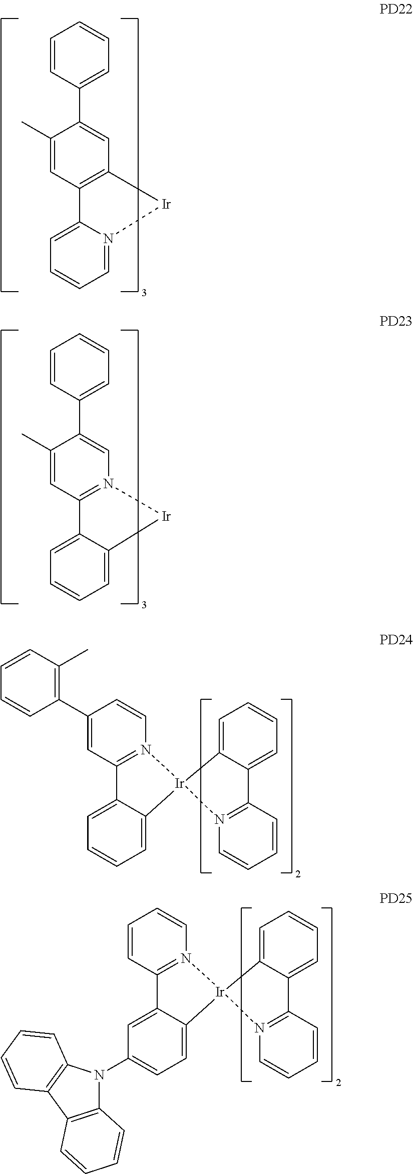

### Fluorescent Dopant in Emission Layer

The fluorescent dopant may include an arylamine compound or a styrylamine compound.

In various embodiments, the fluorescent dopant may include a compound represented by Formula 501 below:

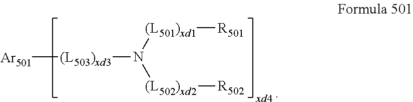

In Formula 501,

Ar₅₀₁ may be a substituted or unsubstituted C₅-C₆₀ carbocyclic group or a substituted or unsubstituted C₁-C₆₀ heterocyclic group,

L₅₀₁ to L₅₀₃ may each independently be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

xd1 to xd3 may each independently be an integer selected from 0 to 3,

R₅₀₁ and R₅₀₂ may each independently be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and

xd4 may be an integer selected from 1 to 6.

In various embodiments, Ar₅₀₁ in Formula 501 may be selected from the group consisting of:

a naphthalene group, a heptalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, and an indenophenanthrene group; and

a naphthalene group, a heptalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, and an indenophenanthrene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, and a naphthyl group.

In various embodiments, L₅₀₁ to L₅₀₃ in Formula 501 may each independently be selected from the group consisting of:

a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group; and

a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group.

In various embodiments, R₅₀₁ and R₅₀₂ in Formula 501 may each independently be selected from the group consisting of:

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group; and

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, and a pyridinyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, and —Si(Q₃₁)(Q₃₂)(Q₃₃),

wherein Q₃₁ to Q₃₃ may each independently be selected from a C₁-C₁₀ alkyl group, a C₁-C₁₀ alkoxy group, a phenyl group, a biphenyl group, a terphenyl group, and a naphthyl group.

In various embodiments, xd4 in Formula 501 may be two, but embodiments of the present disclosure are not limited thereto.

For example, the fluorescent dopant may be selected from Compounds FD1 to FD22:

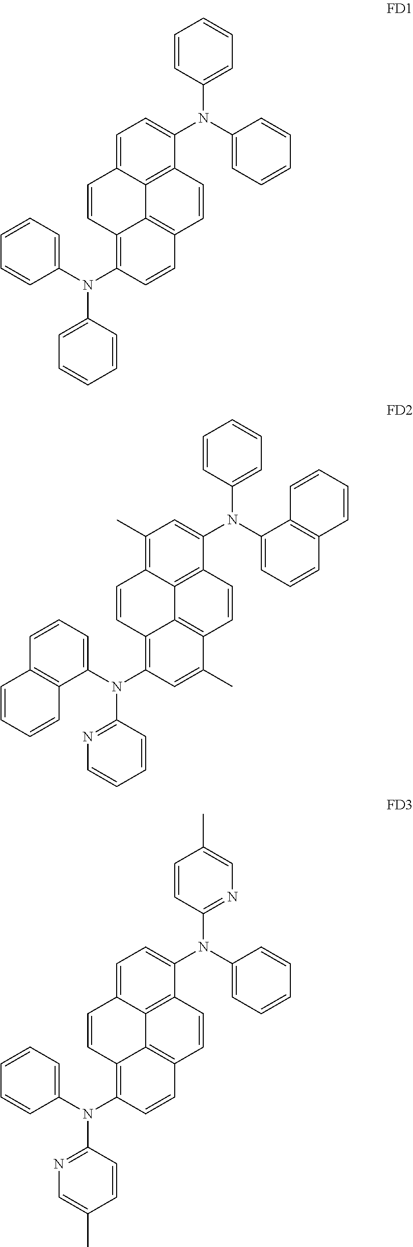 [SMILES: c1ccc(N(c2ccccc2)c2ccc3ccc4c(N(c5ccccc5)c5ccccc5)ccc5ccc2c3c54)cc1 ; Cc1cc(N(c2ccccc2)c2cccc3ccccc23)c2ccc3c(C)cc(N(c4ccccn4)c4cccc5ccccc45)c4ccc1c2c34 ; Cc1ccc(N(c2ccccc2)c2ccc3ccc4c(N(c5ccccc5)c5ccc(C)cn5)ccc5ccc2c3c54)nc1]

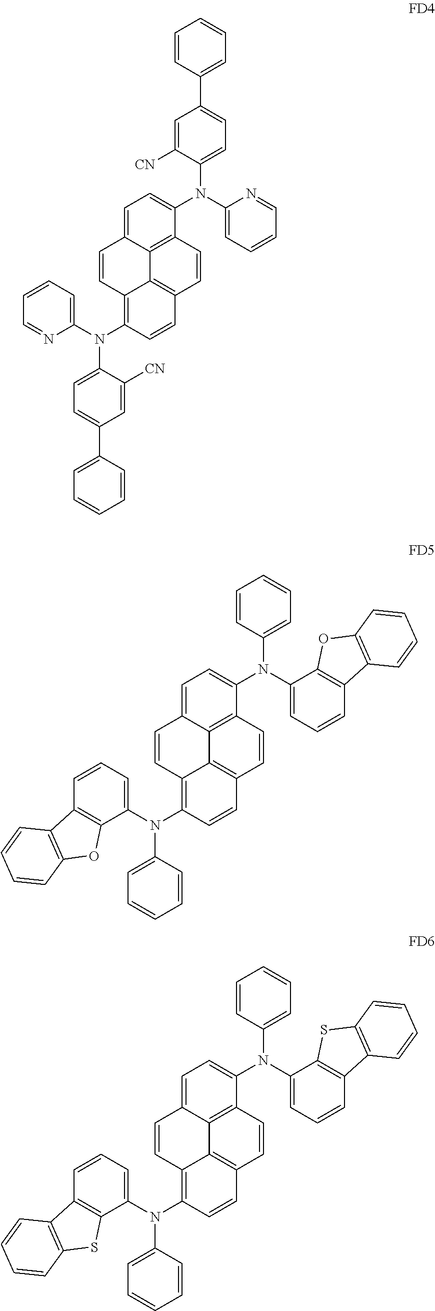

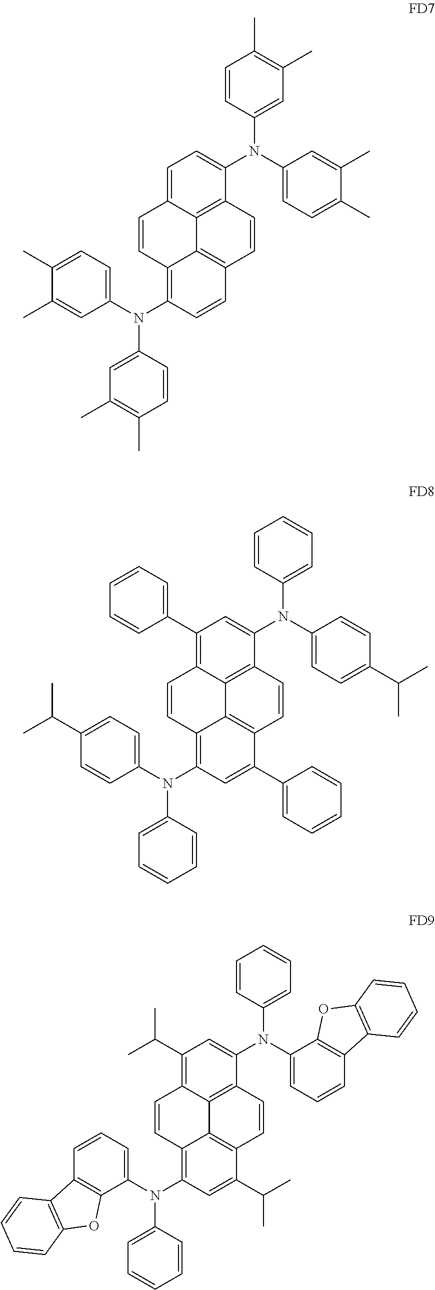

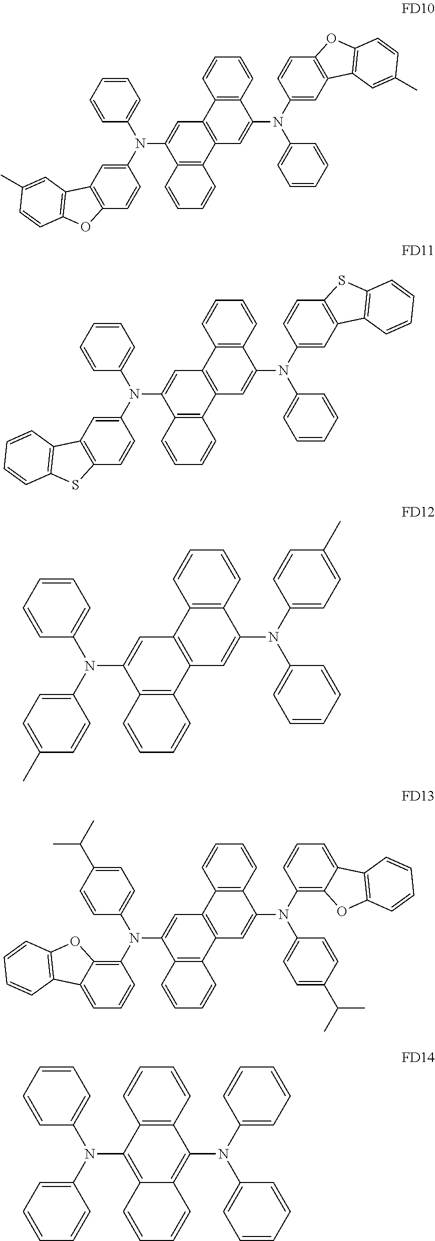

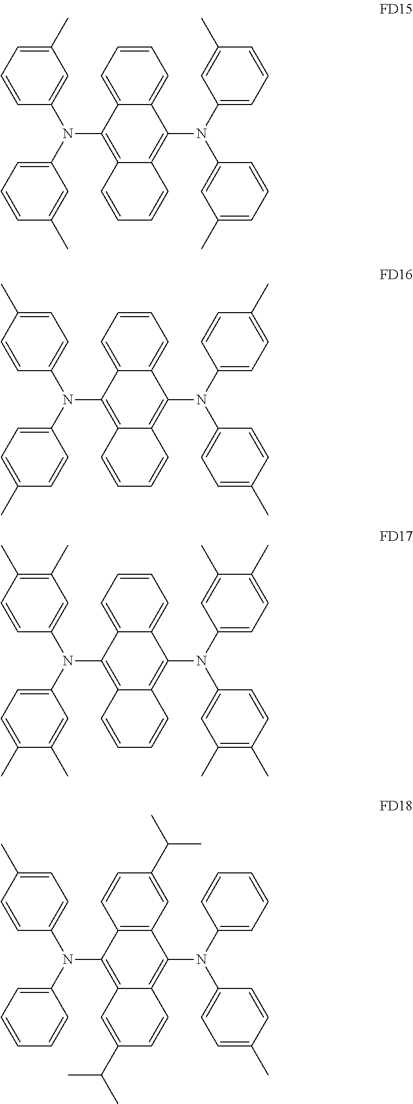

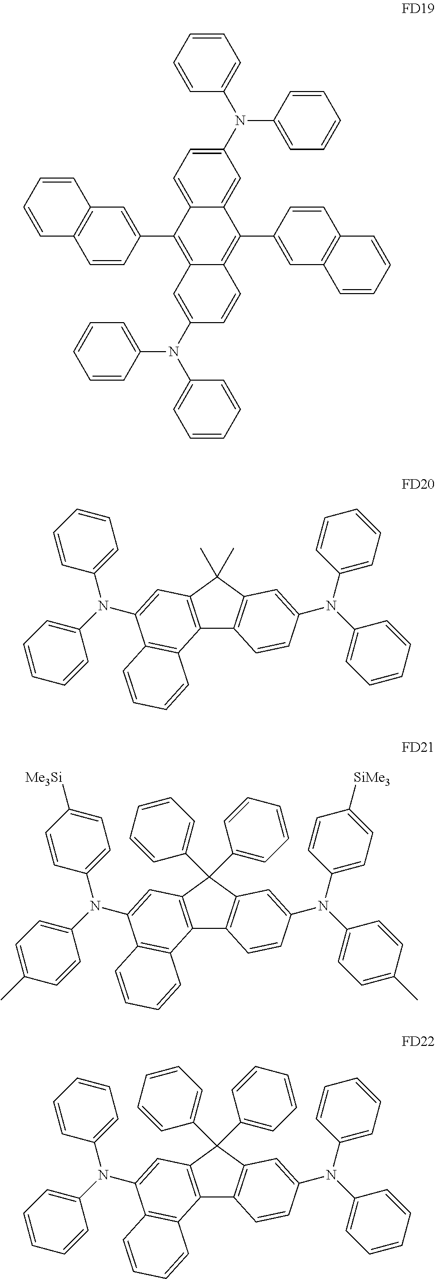

In various embodiments, the fluorescent dopant may be selected from compounds illustrated below, but embodiments of the present disclosure are not limited thereto:

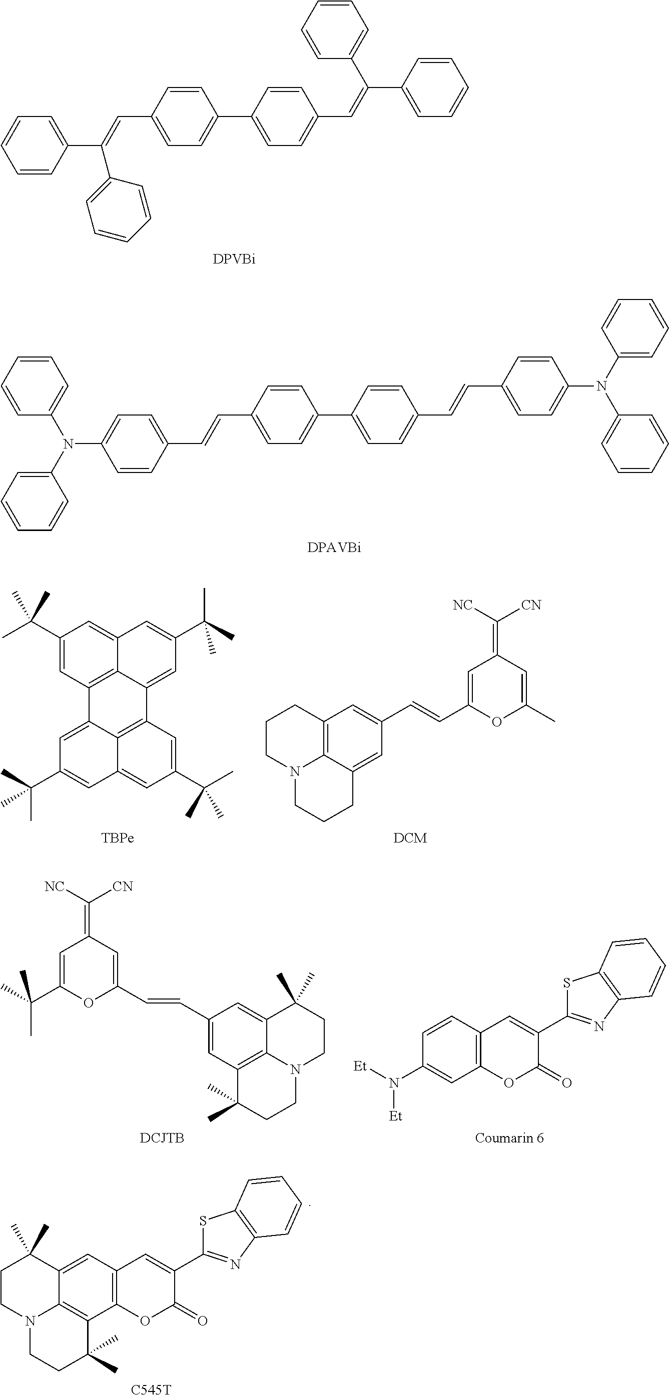

### Electron Transport Region in Organic Layer 150

The electron transport region may have i) a single-layered structure including a single layer including a single material, ii) a single-layered structure including a single layer including a plurality of different materials, or iii) a multi-layered structure having a plurality of layers including a plurality of different materials.

The electron transport region may include at least one selected from a buffer layer, a hole blocking layer, an electron control layer, an electron transport layer (ETL), and an electron injection layer, but embodiments of the present disclosure are not limited thereto.

For example, the electron transport region may have a structure of electron transport layer/electron injection layer, a structure of hole blocking layer/electron transport layer/electron injection layer, a structure of electron control layer/electron transport layer/electron injection layer, or a structure of buffer layer/electron transport layer/electron injection layer, wherein in each of these structures, constituting layers are sequentially stacked in this stated order from an emission layer. However, the structure of the electron transport layer is not limited thereto.

The electron transport region may include the second compound as described above.

In various embodiments, the electron transport region may include a buffer layer, the buffer layer may directly contact the emission layer, and the buffer layer may include the second compound as described above.

In various embodiments, the electron transport region may include a buffer layer, an electron transport layer, and an electron injection layer, which are sequentially stacked from the emission layer in this stated order, and the buffer layer may include the second compound as described above.

The electron transport region (for example, a hole blocking layer, an electron control layer, or an electron transport layer in the electron transport region) may include a metal-free compound containing at least one π electron-depleted nitrogen-containing ring.

The “π electron-depleted nitrogen-containing ring” refers to a C₁-C₆₀ heterocyclic group having at least one *—N=*′ moiety as a ring-forming moiety.

For example, the “π electron-depleted nitrogen-containing ring” may be i) a 5-membered to 7-membered hetero monocyclic group having at least one *—N=*′ moiety, ii) a heteropoly cyclic group in which two or more 5-membered to 7-membered hetero monocyclic groups each having at least one *—N=*′ moiety are condensed with each other, or iii) a heteropoly cyclic group in which at least one selected from 5-membered to 7-membered hetero monocyclic groups, each having at least one *—N=*′ moiety, is condensed with at least one C₅-C₆₀ carbocyclic group.

Examples of the π electron-depleted nitrogen-containing ring include an imidazole group, a pyrazole group, a thiazole group, an isothiazole group, an oxazole group, an isoxazole group, a pyridine group, a pyrazine group, a pyrimidine group, a pyridazine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzoimidazole group, an isobenzothiazole group, a benzoxazole group, an isobenzoxazole group, a triazole group, a tetrazole group, an oxadiazole group, a triazine group, a thiadiazol group, an imidazopyridine group, an imidazopyrimidine group, and an azacarbazole group, but embodiments of the present disclosure are not limited thereto.

For example, the electron transport region may include a compound represented by Formula 601:

[Ar₆₀₁]ₓₑ₁₁-[(L₆₀₁)ₓₑ₁-R₆₀₁]ₓₑ₂₁. Formula 601

In Formula 601,

Ar₆₀₁ may be a substituted or unsubstituted C₅-C₆₀ carbocyclic group or a substituted or unsubstituted C₁-C₆₀ heterocyclic group,

xe11 may be 1, 2, or 3,

L₆₀₁ may be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

xe1 may be an integer selected from 0 to 5,

R₆₀₁ may be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₆₀₁)(Q₆₀₂)(Q₆₀₃), —C(═O)(Q₆₀₁), —S(═O)₂(Q₆₀₁), and —P(═O)(Q₆₀₁)(Q₆₀₂),

Q₆₀₁ to Q₆₀₃ may each independently be selected from a C₁-C₁₀ alkyl group, a C₁-C₁₀ alkoxy group, a phenyl group, a biphenyl group, a terphenyl group, and a naphthyl group, and

xe21 may be an integer selected from 1 to 5.

In various embodiments, at least one selected from Ar₆₀₁(s) in number of xe11 and R₆₀₁(s) in number of xe21 may include the π electron-depleted nitrogen-containing ring as described above.

In various embodiments, ring Ar₆₀₁ in Formula 601 may be selected from the group consisting of:

a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, a dibenzothiophene group, a carbazole group, an imidazole group, a pyrazole group, a thiazole group, an isothiazole group, an oxazole group, an isoxazole group, a pyridine group, a pyrazine group, a pyrimidine group, a pyridazine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzoimidazole group, an iso-benzothiazole group, a benzoxazole group, an isobenzoxazole group, a triazole group, a tetrazole group, an oxadiazole group, a triazine group, a thiadiazol group, an imidazopyridine group, an imidazopyrimidine group, and an azacarbazole group; and

a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, a dibenzothiophene group, a carbazole group, an imidazole group, a pyrazole group, a thiazole group, an isothiazole group, an oxazole group, an isoxazole group, a pyridine group, a pyrazine group, a pyrimidine group, a pyridazine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzoimidazole group, an iso-benzothiazole group, a benzoxazole group, an isobenzoxazole group, a triazole group, a tetrazole group, an oxadiazole group, a triazine group, thiadiazol group, an imidazopyridine group, an imidazopyrimidine group, and an azacarbazole group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, —Si(Q₃₁)(Q₃₂)(Q₃₃), —S(═O)₂(Q₃₁), and —P(═O)(Q₃₁)(Q₃₂),

wherein Q₃₁ to Q₃₃ may each independently be selected from a C₁-C₁₀ alkyl group, a C₁-C₁₀ alkoxy group, a phenyl group, a biphenyl group, a terphenyl group, and a naphthyl group.

When xe11 in Formula 601 is two or more, two or more Ar₆₀₁(s) may be connected to each other via a single bond.

In various embodiments, Ar₆₀₁ in Formula 601 may be an anthracene group.

In various embodiments, the compound represented by Formula 601 may be represented by Formula 601-1:

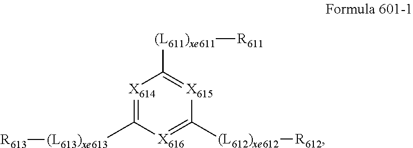

wherein, in Formula 601-1,

X₆₁₄ may be N or C(R₆₁₄), X₆₁₅ may be N or C(R₆₁₅), X₆₁₆ may be N or C(R₆₁₆), and at least one selected from X₆₁₄ to X₆₁₆ may be N,

L₆₁₁ to L₆₁₃ are each independently the same as described above in connection with L₆₀₁,

xe611 to xe613 are each independently the same as described above in connection with xe1,

R₆₁₁ to R₆₁₃ are each independently the same as described above in connection with R₆₀₁, and

R₆₁₄ to R₆₁₆ may each independently be selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, and a naphthyl group.

In various embodiments, L₆₀₁ and L₆₁₁ to L₆₁₃ in Formulae 601 and 601-1 may each independently be selected from the group consisting of:

a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, a pyridinylene group, an imidazolylene group, a pyrazolylene group, a thiazolylene group, an isothiazolylene group, an oxazolylene group, an isoxazolylene group, a thiadiazolylene group, an oxadiazolylene group, a pyrazinylene group, a pyrimidinylene group, a pyridazinylene group, a triazinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzoimidazolylene group, an isobenzothiazolylene group, a benzoxazolylene group, an isobenzoxazolylene group, a triazolylene group, a tetrazolylene group, an imidazopyridinylene group, an imidazopyrimidinylene group, and an azacarbazolylene group; and

a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, a pyridinylene group, an imidazolylene group, a pyrazolylene group, a thiazolylene group, an isothiazolylene group, an oxazolylene group, an isoxazolylene group, a thiadiazolylene group, an oxadiazolylene group, a pyrazinylene group, a pyrimidinylene group, a pyridazinylene group, a triazinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzoimidazolylene group, an isobenzothiazolylene group, a benzoxazolylene group, an isobenzoxazolylene group, a triazolylene group, a tetrazolylene group, an imidazopyridinylene group, an imidazopyrimidinylene group, and an azacarbazolylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzoimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group,

but embodiments of the present disclosure are not limited thereto.

In various embodiments, xe1 and xe611 to xe613 in Formulae 601 and 601-1 may each independently be 0, 1, or 2.

In various embodiments, R₆₀₁ and R₆₁₁ to R₆₁₃ in Formulae 601 and 601-1 may each independently be selected from the group consisting of:

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzoimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group;

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzoimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzoimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group; and

—S(═O)₂(Q₆₀₁) and —P(═O)(Q₆₀₁)(Q₆₀₂),

wherein Q₆₀₁ and Q₆₀₂ are the same as described above.

The electron transport region may include at least one compound selected from Compounds ET1 to ET36, but embodiments of the present disclosure are not limited thereto:

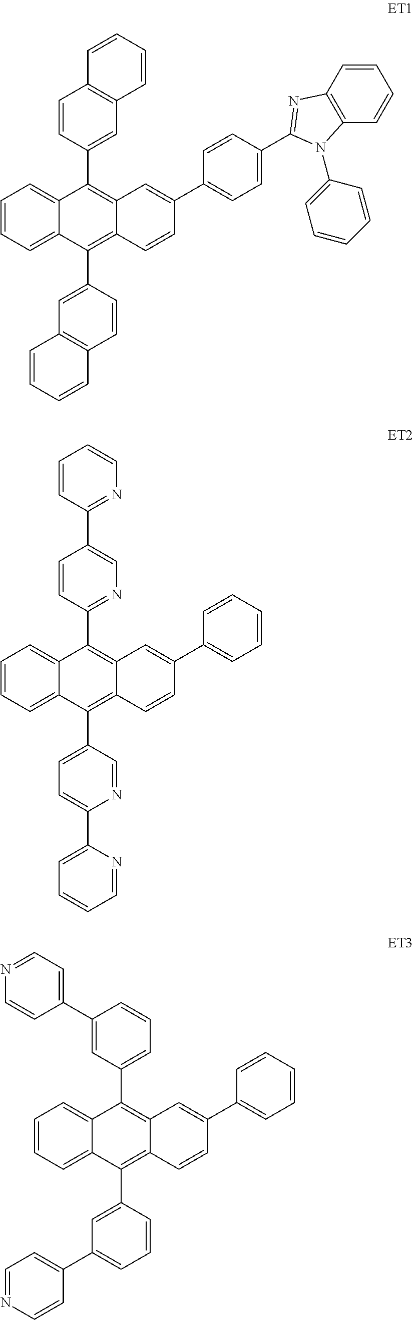 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)cn4)c3c2)cc1 ; c1ccc(-c2ccc3c(-c4cccc(-c5ccncc5)c4)c4ccccc4c(-c4cccc(-c5ccncc5)c4)c3c2)cc1]

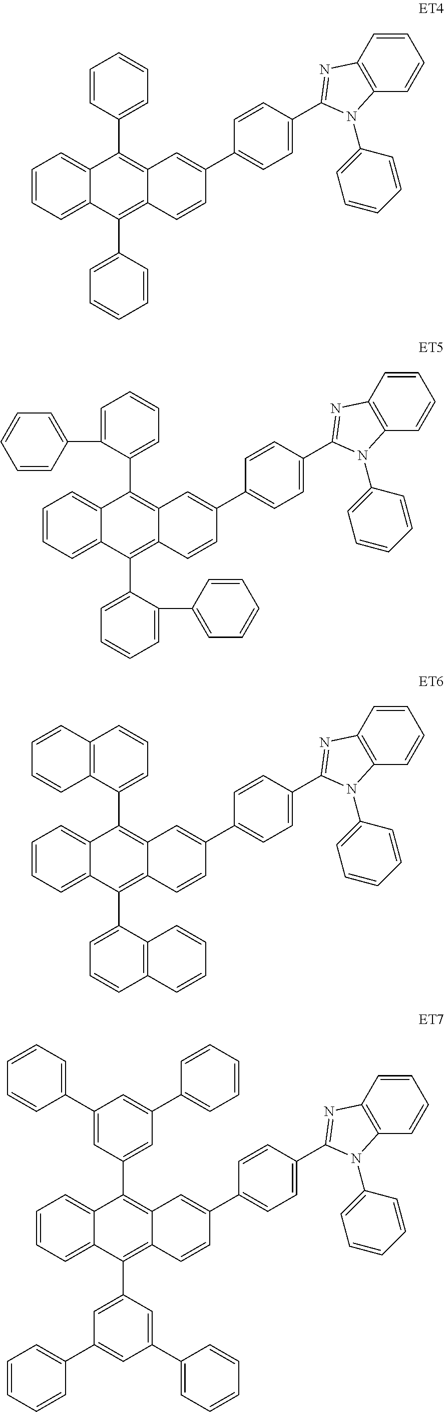 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

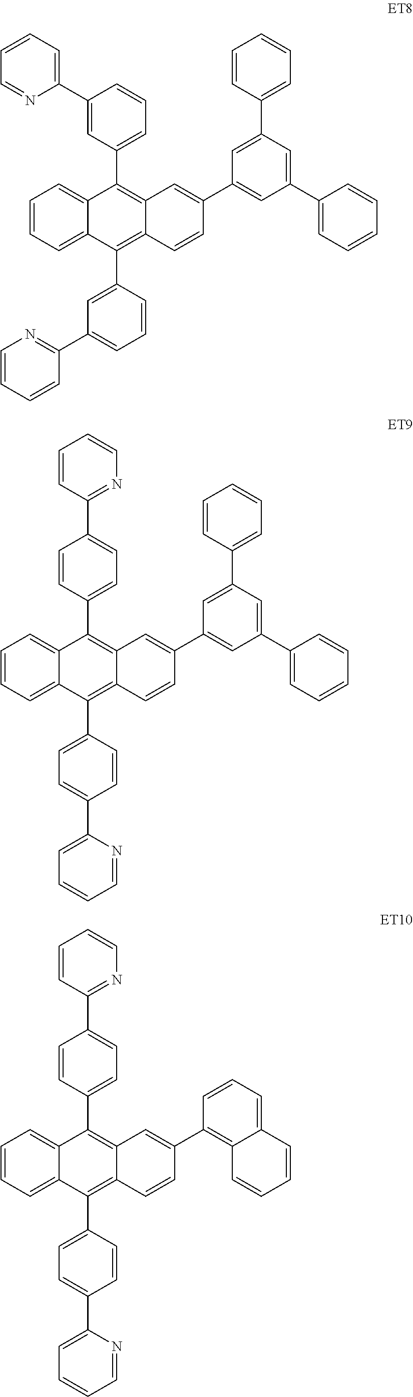

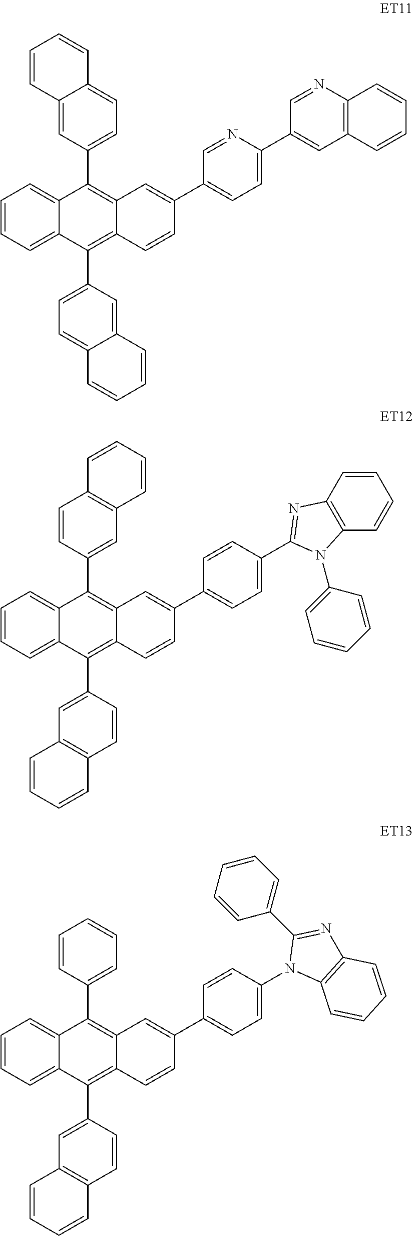

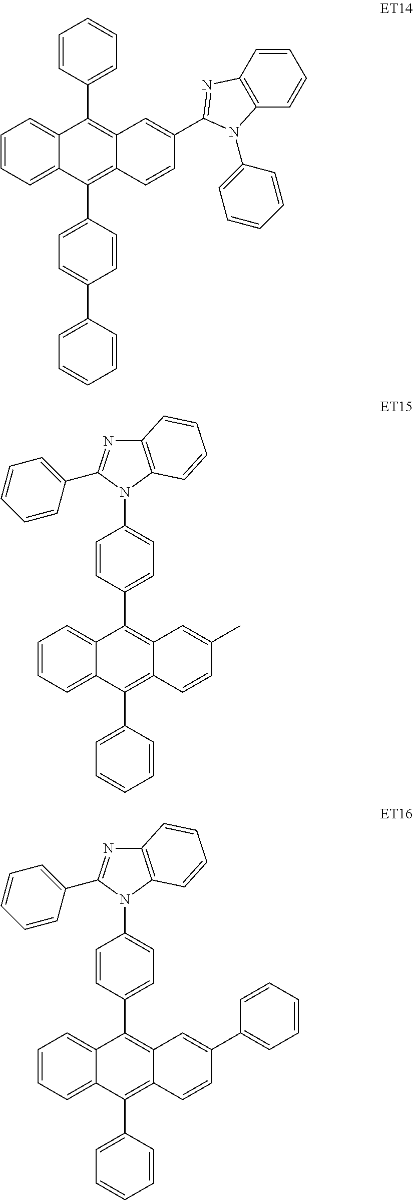 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

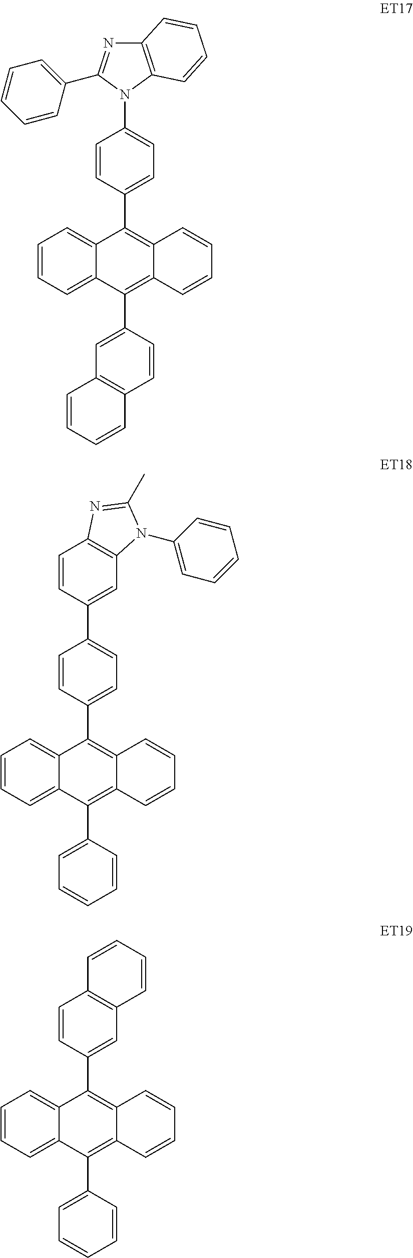

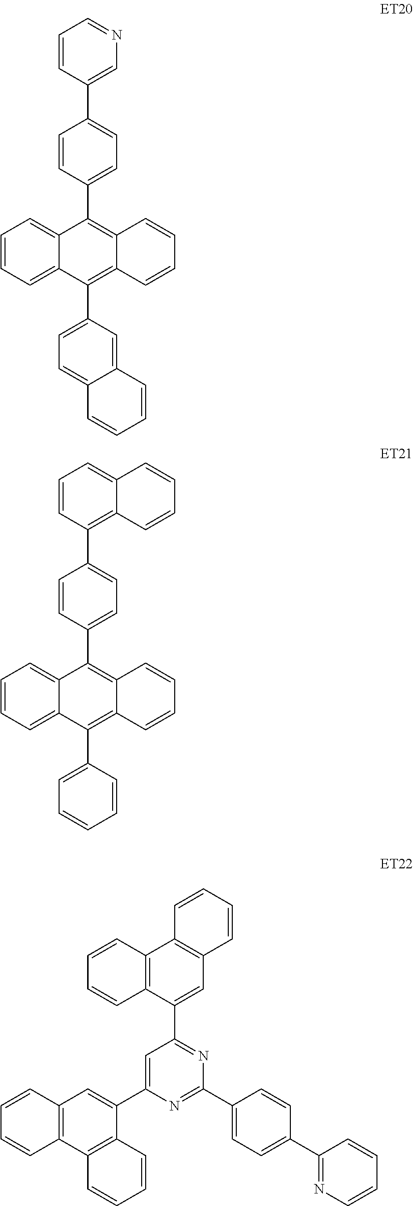

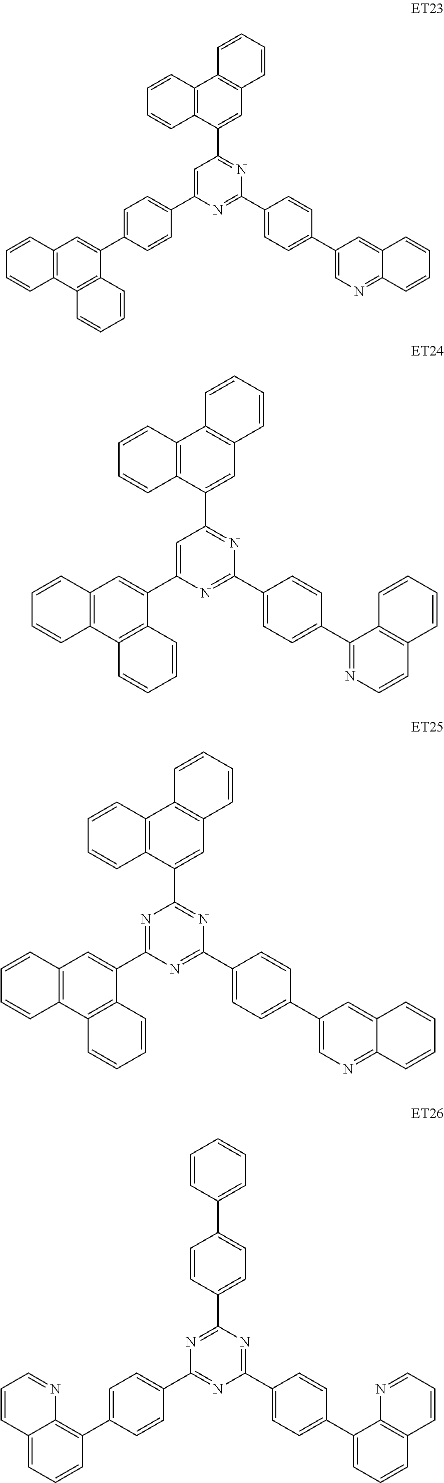 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

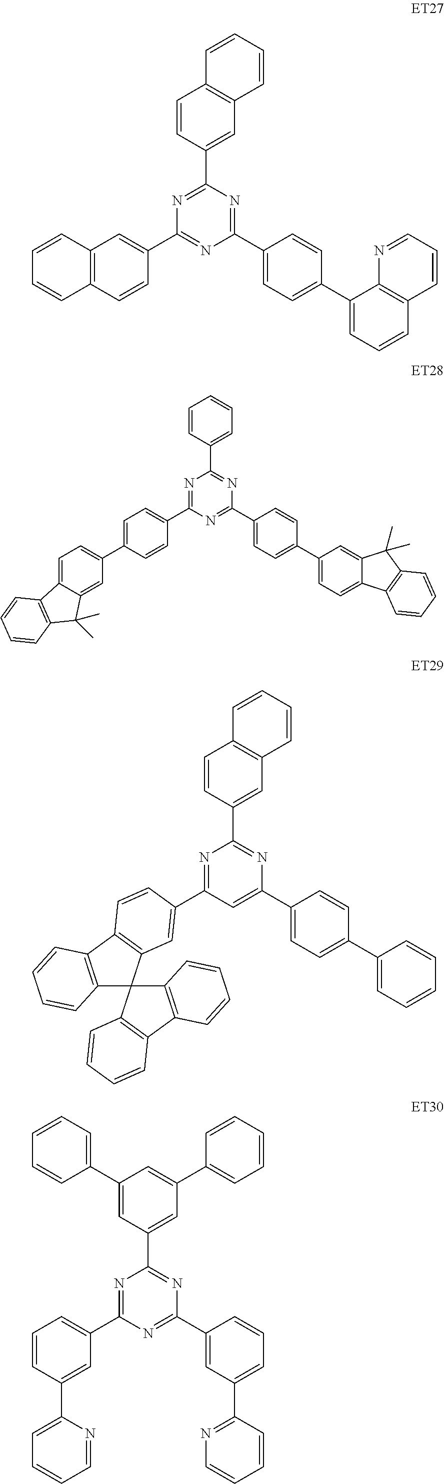 [SMILES: c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

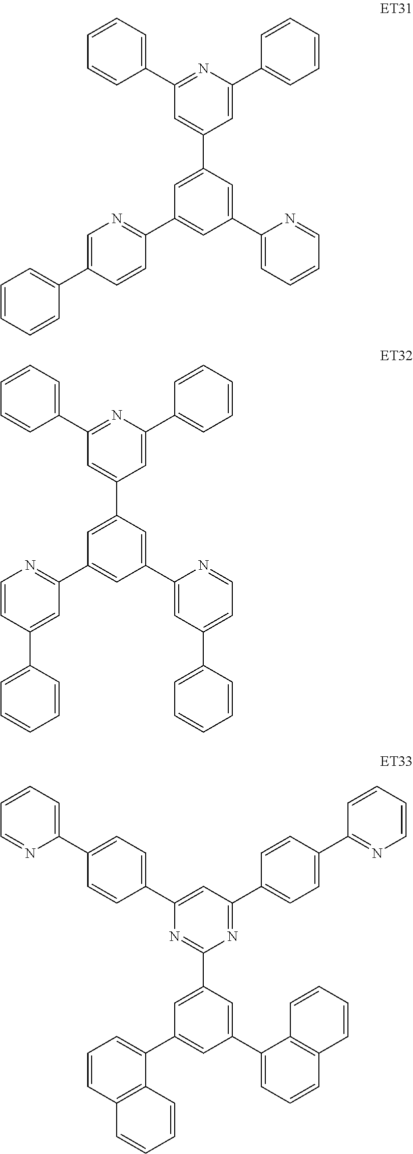

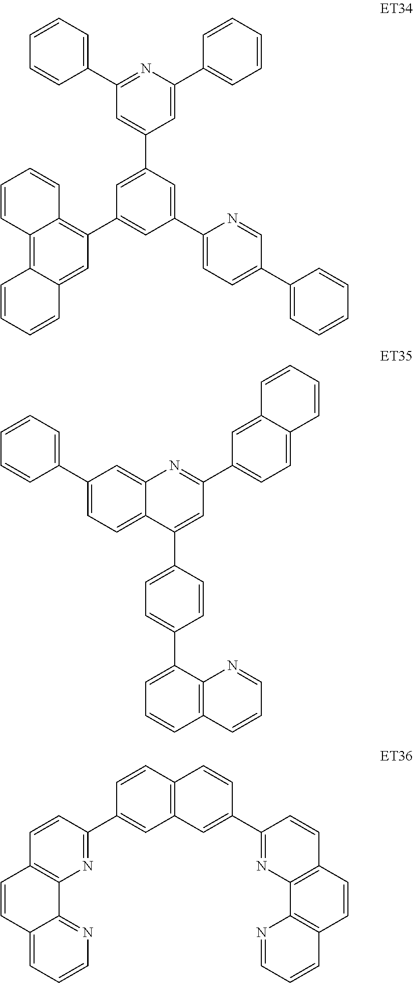

In various embodiments, the electron transport region may include at least one compound selected from 2,9-dimethyl-4,7-diphenyl-1,10-phenanthroline (BCP), 4,7-diphenyl-1,10-phenanthroline (Bphen), Alq₃, Balq, 3-(biphenyl-4-yl)-5-(4-tert-butylphenyl)-4-phenyl-4H-1,2,4-triazole (TAZ), and NTAZ:

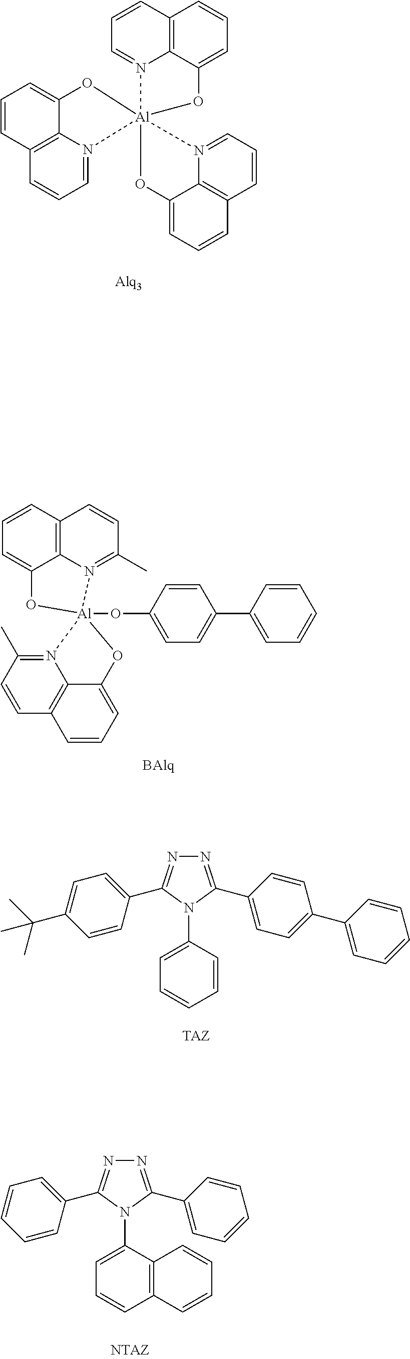

The thickness of the buffer layer, the hole blocking layer, and/or the electron control layer may each independently be in a range of about 20 Å to about 1,000 Å, for example, about 30 Å to about 300 Å. When the thickness of the buffer layer, the hole blocking layer, and/or the electron control layer are within the ranges described above, the electron blocking layer may have excellent electron blocking characteristics or electron control characteristics without a substantial increase in driving voltage.

A thickness of the electron transport layer may be in a range of about 100 Å to about 1,000 Å, for example, about 150 Å to about 500 Å. When the thickness of the electron transport layer is within the ranges described above, the electron transport layer may have satisfactory electron transport characteristics without a substantial increase in driving voltage.

The electron transport region (for example, the electron transport layer in the electron transport region) may further include, in addition to the materials described above, a metal-containing material.

The metal-containing material may include at least one selected from an alkaline metal complex and an alkaline earth-metal complex. The alkaline metal complex may include a metal ion selected from an Li ion, a Na ion, a K ion, a Rb ion, and a Cs ion, and the alkaline earth-metal complex may include a metal ion selected from a Be ion, a Mg ion, a Ca ion, a Sr ion, and a Ba ion. A ligand coordinated with the metal ion of the alkaline metal complex or the alkaline earth-metal complex may each independently be selected from a hydroxy quinoline, a hydroxy isoquinoline, a hydroxy benzoquinoline, a hydroxy acridine, a hydroxy phenanthridine, a hydroxy phenyloxazole, a hydroxy phenylthiazole, a hydroxy diphenyloxadiazole, a hydroxy diphenylthiadiazol, a hydroxy phenylpyridine, a hydroxy phenylbenzimidazole, a hydroxy phenylbenzothiazole, a bipyridine, a phenanthroline, and a cyclopentadiene, but embodiments of the present disclosure are not limited thereto.

For example, the metal-containing material may include a Li complex. The Li complex may include, for example, Compound ET-D1 (lithium quinolate, LiQ) or ET-D2:

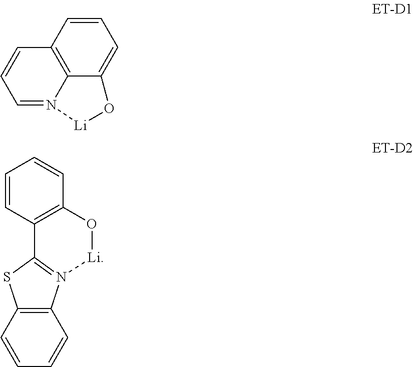

The electron transport region may include an electron injection layer that facilitates injection of electrons from the second electrode 190. The electron injection layer may directly contact the second electrode 190.

The electron injection layer may have i) a single-layered structure including a single layer including a single material, ii) a single-layered structure including a single layer including a plurality of different materials, or iii) a multi-layered structure having a plurality of layers including a plurality of different materials.

The electron injection layer may include an alkaline metal, an alkaline earth metal, a rare-earth metal, an alkaline metal compound, an alkaline earth-metal compound, a rare-earth metal compound, an alkaline metal complex, an alkaline earth-metal complex, a rare-earth metal complex, or a combination thereof.

In various embodiments, the electron injection layer may include Li, Na, K, Rb, Cs, Mg, Ca, Er, Tm, Yb, or a combination thereof. However, a material included in the electron injection layer is not limited thereto.

The alkaline metal may be selected from Li, Na, K, Rb, and Cs. In various embodiments, the alkaline metal may be Li, Na, or Cs. In various embodiments, the alkaline metal may be Li or Cs, but embodiments of the present disclosure are not limited thereto.

The alkaline earth metal may be selected from Mg, Ca, Sr, and Ba.

The rare-earth metal may be selected from Sc, Y, Ce, Yb, Gd, and Tb.

The alkaline metal compound, the alkaline earth-metal compound, and the rare-earth metal compound may be selected from oxides and halides (for example, fluorides, chlorides, bromides, or iodines) of the alkaline metal, the alkaline earth-metal, and the rare-earth metal.

The alkaline metal compound may be selected from alkaline metal oxides, such as Li₂O, Cs₂O, or K₂O, and alkaline metal halides, such as LiF, NaF, CsF, KF, Lil, NaI, CsI, RbI, or Kl. In various embodiments, the alkaline metal compound may be selected from LiF, Li₂O, NaF, Lil, NaI, CsI, and Kl, but embodiments of the present disclosure are not limited thereto.

The alkaline earth-metal compound may be selected from alkaline earth-metal compounds, such as BaO, SrO, CaO, BaₓSr₁₋ₓO (0<x<1), or BaₓCa₁₋ₓO (0<x<1). In various embodiments, the alkaline earth-metal compound may be selected from BaO, SrO, and CaO, but embodiments of the present disclosure are not limited thereto.

The rare-earth metal compound may be selected from YbF₃, ScF₃, ScO₃, Y₂O₃, Ce₂O₃, GdF₃, and TbF₃. In various embodiments, the rare-earth metal compound may be selected from YbF₃, ScF₃, TbF₃, YbI₃, ScI₃, and TbI₃, but embodiments of the present disclosure are not limited thereto.

The alkaline metal complex, the alkaline earth-metal complex, and the rare-earth metal complex may include an ion of alkaline metal, alkaline earth-metal, and rare-earth metal as described above, and a ligand coordinated with a metal ion of the alkaline metal complex, the alkaline earth-metal complex, and the rare-earth metal complex may each independently be selected from a hydroxy quinoline, a hydroxy isoquinoline, a hydroxy benzoquinoline, a hydroxy acridine, a hydroxy phenanthridine, a hydroxy phenylan oxazole, a hydroxy phenylthiazole, a hydroxy diphenylan oxadiazole, a hydroxy diphenylthiadiazol, a hydroxy phenylpyridine, a hydroxy phenylbenzimidazole, a hydroxy phenylbenzothiazole, a bipyridine, and a phenanthroline and cyclopentadiene, but embodiments of the present disclosure are not limited thereto.

The electron injection layer may include (e.g., consist of) an alkaline metal, an alkaline earth metal, a rare-earth metal, an alkaline metal compound, an alkaline earth-metal compound, a rare-earth metal compound, an alkaline metal complex, an alkaline earth-metal complex, a rare-earth metal complex, or a combination thereof, as described above. In various embodiments, the electron injection layer may further include an organic material. When the electron injection layer further includes an organic material, an alkaline metal, an alkaline earth metal, a rare-earth-metal, an alkaline metal compound, an alkaline earth-metal compound, a rare-earth metal compound, an alkaline metal complex, an alkaline earth-metal complex, a rare-earth metal complex, or a combination thereof may be homogeneously or non-homogeneously dispersed in a matrix including the organic material.

A thickness of the electron injection layer may be in a range of about 1 Å to about 100 Å, for example, about 3 Å to about 90 Å. When the thickness of the electron injection layer is within the ranges described above, the electron injection layer may have satisfactory electron injection characteristics without a substantial increase in driving voltage.

At least one layer selected from the electron transport layer and the electron injection layer may include an alkaline metal, an alkaline earth metal, a rare-earth-metal, an alkaline metal compound, an alkaline earth-metal compound, a rare-earth metal compound, an alkaline metal complex, an alkaline earth-metal complex, a rare-earth metal complex, or a combination thereof.

### Second Electrode 190

The second electrode 190 may be disposed on the organic layer 150 having such a structure. The second electrode 190 may be a cathode that is an electron injection electrode, and in this regard, a material for forming the second electrode 190 may be a material having a low work function, and such a material may be metal, alloy, an electrically conductive compound, or a combination thereof.

The second electrode 190 may include at least one selected from lithium (Li), silver (Ag), magnesium (Mg), aluminum (Al), aluminum-lithium (Al—Li), calcium (Ca), magnesium-indium (Mg—In), magnesium-silver (Mg—Ag), ITO, and IZO, but embodiments of the present disclosure are not limited thereto. The second electrode 190 may be a transmissive electrode, a semi-transmissive electrode, or a reflective electrode.

The second electrode 190 may have a single-layered structure, or a multi-layered structure including two or more layers.

### Description of FIGS. 2 to 5

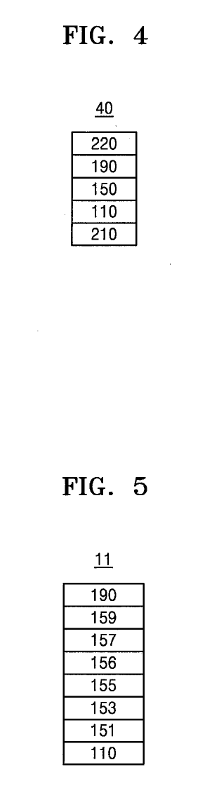

An organic light-emitting device 20 of FIG. 2 may include a first capping layer 210, a first electrode 110, an organic layer 150, and a second electrode 190, which are sequentially stacked in this stated order, an organic light-emitting device 30 of FIG. 3 may include a first electrode 110, an organic layer 150, a second electrode 190, and a second capping layer 220, which are sequentially stacked in this stated order, and an organic light-emitting device 40 of FIG. 4 may include a first capping layer 210, a first electrode 110, an organic layer 150, a second electrode 190, and a second capping layer 220, which are sequentially stacked in this stated order.

Regarding FIGS. 2 to 4, the first electrode 110, the organic layer 150, and the second electrode 190 may be understood by referring to the description respectively presented in connection with FIG. 1.

In the organic layer 150 of each of the organic light-emitting devices 20 and 40, light generated in the emission layer may pass through the first electrode 110, which is a semi-transmissive electrode or a transmissive electrode, and the first capping layer 210 toward the outside, and in the organic layer 150 of each of the organic light-emitting devices 30 and 40, light generated in the emission layer may pass through the second electrode 190, which is a semi-transmissive electrode or a transmissive electrode, and the second capping layer 220 toward the outside.

The first capping layer 210 and the second capping layer 220 may increase external luminescent efficiency according to the principle of constructive interference.

The first capping layer 210 and the second capping layer 220 may each independently be a capping layer including an organic material, an inorganic capping layer including an inorganic material, or a composite capping layer including an organic material and an inorganic material.

At least one selected from the first capping layer 210 and the second capping layer 220 may each independently include at least one material selected from carbocyclic compounds, heterocyclic compounds, amine-based compounds, porphine derivatives, phthalocyanine derivatives, naphthalocyanine derivatives, alkaline metal complexes, and alkaline earth-based complexes. The carbocyclic compound, the heterocyclic compound, and the amine-based compound may be optionally substituted with a substituent containing at least one element selected from O, N, S, Se, Si, F, Cl, Br, and I. In various embodiments, at least one selected from the first capping layer 210 and the second capping layer 220 may each independently include an amine-based compound.

In various embodiments, at least one selected from the first capping layer 210 and the second capping layer 220 may each independently include the compound represented by Formula 201 or the compound represented by Formula 202.

In various embodiments, at least one selected from the first capping layer 210 and the second capping layer 220 may each independently include a compound selected from Compounds HT28 to HT33 and Compounds CP1 to CP5, but embodiments of the present disclosure are not limited thereto:

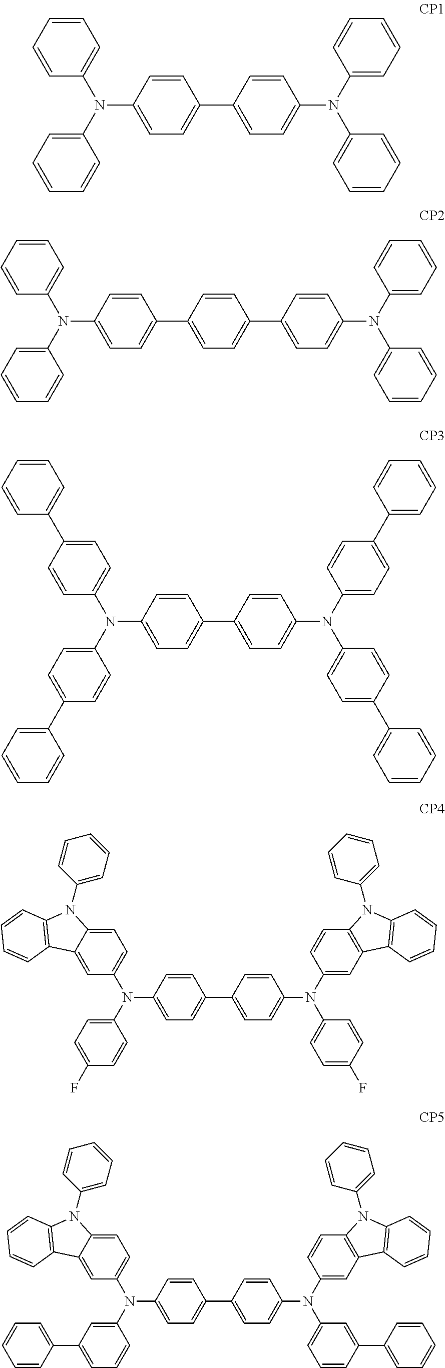 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

FIG. 5 is a schematic view of an organic light-emitting device 11 according to various embodiments. The organic light-emitting device 11 may include a first electrode 110, a hole transport layer 151, an emission auxiliary layer 153, an emission layer 155, a buffer layer 156, an electron transport layer 157, an electron injection layer 159, and a second electrode 190, which are sequentially stacked.

Respective layers constituting the organic light-emitting device 11 of FIG. 5 may be understood by referring to corresponding descriptions above.

Hereinbefore, the organic light-emitting device according to various embodiments has been described in connection with FIGS. 1 to 5. However, embodiments of the present disclosure are not limited thereto.

Layers constituting the hole transport region, the emission layer, and layers constituting the electron transport region may be formed in a certain region by utilizing one or more suitable methods selected from vacuum deposition, spin coating, casting, a Langmuir-Blodgett (LB) method, ink-jet printing, laser-printing, and laser-induced thermal imaging.

When the respective layers of the hole transport region, the emission layer, and the respective layers of the electron transport region are formed by vacuum deposition, the deposition may be performed at a deposition temperature of about 100° C. to about 500° C., at a vacuum degree of about 10⁻⁸ torr to about 10⁻³ torr, and at a deposition rate of about 0.01 Å/sec to about 100 Å/sec by taking into account a material for forming a layer to be deposited, and a structure of the layer to be formed.

When layers constituting the hole transport region, the emission layer, and layers constituting the electron transport region are formed by spin coating, the spin coating may be performed at a coating speed of about 2,000 rpm to about 5,000 rpm and at a heat treatment temperature of about 80° C. to 200° C. by taking into account a material to be included in a to-be-formed layer, and a structure of the to-be-formed layer.

### General Definition of Substituents

The term “C₁-C₆₀ alkyl group,” as used herein, refers to a linear or branched aliphatic saturated hydrocarbon monovalent group having 1 to 60 carbon atoms, and non-limiting examples thereof may include a methyl group, an ethyl group, a propyl group, an isobutyl group, a sec-butyl group, a tert-butyl group, a pentyl group, an iso-amyl group, and a hexyl group. The term “C₁-C₆₀ alkylene group,” as used herein, refers to a divalent group having substantially the same structure as the C₁-C₆₀ alkyl group.

The term “C₂-C₆₀ alkenyl group,” as used herein, refers to a hydrocarbon group having at least one carbon-carbon double bond at one or more positions along the hydrocarbon chain of the C₂-C₆₀ alkyl group (e.g., in the middle or at the terminus of the C₂-C₆₀ alkyl group), and non-limiting examples thereof may include an ethenyl group, a propenyl group, and a butenyl group. The term “C₂-C₆₀ alkenylene group,” as used herein, refers to a divalent group having substantially the same structure as the C₂-C₆₀ alkenyl group.

The term “C₂-C₆₀ alkynyl group,” as used herein, refers to a hydrocarbon group having at least one carbon-carbon triple bond at one or more positions along the hydrocarbon chain of the C₂-C₆₀ alkyl group (e.g., in the middle or at the terminus of the C₂-C₆₀ alkyl group), and non-limiting examples thereof may include an ethynyl group, and a propynyl group. The term “C₂-C₆₀ alkynylene group,” as used herein, refers to a divalent group having substantially the same structure as the C₂-C₆₀ alkynyl group.

The term “C₁-C₆₀ alkoxy group,” as used herein, refers to a monovalent group represented by —OA₁₀₁ (wherein A₁₀₁ is the C₁-C₆₀ alkyl group), and non-limiting examples thereof may include a methoxy group, an ethoxy group, and an isopropyloxy group.

The term “C₃-C₁₀ cycloalkyl group,” as used herein, refers to a monovalent saturated hydrocarbon monocyclic group having 3 to 10 carbon atoms, and non-limiting examples thereof may include a cyclopropyl group, a cyclobutyl group, a cyclopentyl group, a cyclohexyl group, and a cycloheptyl group. The term “C₃-C₁₀ cycloalkylene group,” as used herein, refers to a divalent group having substantially the same structure as the C₃-C₁₀ cycloalkyl group.

The term “C₁-C₁₀ heterocycloalkyl group,” as used herein, refers to a monovalent saturated monocyclic group having at least one heteroatom selected from N, O, Si, P, and S as a ring-forming atom in addition to 1 to 10 carbon atoms, and non-limiting examples thereof may include a 1,2,3,4-oxatriazolidinyl group, a tetrahydrofuranyl group, and a tetrahydrothiophenyl group. The term “C₁-C₁₀ heterocycloalkylene group,” as used herein, refers to a divalent group having substantially the same structure as the C₁-C₁₀ heterocycloalkyl group.

The term “C₃-C₁₀ cycloalkenyl group,” as used herein, refers to a monovalent saturated monocyclic group that has 3 to 10 carbon atoms and at least one double bond in the ring thereof and does not have aromaticity, and non-limiting examples thereof may include a cyclopentenyl group, a cyclohexenyl group, and a cycloheptenyl group. The term “C₃-C₁₀ cycloalkenylene group,” as used herein, refers to a divalent group having substantially the same structure as the C₃-C₁₀ cycloalkenyl group.

The term “C₁-C₁₀ heterocycloalkenyl group,” as used herein, refers to a monovalent monocyclic group that has at least one heteroatom selected from N, O, Si, P, and S as a ring-forming atom in addition to 1 to 10 carbon atoms, and at least one double bond in its ring. Non-limiting examples of the C₁-C₁₀ heterocycloalkenyl group may include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group,” as used herein, refers to a divalent group having substantially the same structure as the C₁-C₁₀ heterocycloalkenyl group.

The term “C₆-C₆₀ aryl group,” as used herein, refers to a monovalent group having a carbocyclic aromatic system having 6 to 60 carbon atoms, and the term “C₆-C₆₀ group,” as used herein, refers to a divalent group having a carbocyclic aromatic system having 6 to 60 carbon atoms. Non-limiting examples of the C₆-C₆₀ aryl group may include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The term “C₁-C₆₀ heteroaryl group,” as used herein, refers to a monovalent group having a heterocyclic aromatic system that has at least one heteroatom selected from N, O, Si, P, and S as a ring-forming atom in addition to 1 to 60 carbon atoms. The term “C₁-C₆₀ heteroarylene group,” as used herein, refers to a divalent group having a heterocyclic aromatic system that has at least one heteroatom selected from N, O, Si, P, and S as a ring-forming atom in addition to 1 to 60 carbon atoms. Non-limiting examples of the C₁-C₆₀ heteroaryl group may include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be respectively fused to each other.

The term “C₆-C₆₀ aryloxy group,” as used herein, refers to a group represented by —OA₁₀₂ (wherein A₁₀₂ is the C₆-C₆₀ aryl group), and the term “C₆-C₆₀ arylthio group,” as used herein, refers to a group represented by —SA₁₀₃ (wherein A₁₀₃ is the C₆-C₆₀ aryl group).

The term “monovalent non-aromatic condensed polycyclic group,” as used herein, refers to a monovalent group (for example, having 8 to 60 carbon atoms) that has two or more rings condensed with each other, only carbon atoms as a ring forming atom, and non-aromaticity in the entire molecular structure. Non-limiting examples of the monovalent non-aromatic condensed polycyclic group may include a fluorenyl group. The term “divalent non-aromatic condensed polycyclic group,” as used herein, refers to a divalent group having substantially the same structure as the monovalent non-aromatic condensed polycyclic group.

The term “monovalent non-aromatic condensed heteropolycyclic group,” as used herein, refers to a monovalent group (for example, having 1 to 60 carbon atoms) that has two or more rings condensed to each other, has at least one heteroatom selected from N, O, Si, P, and S, in addition to carbon atoms, as a ring forming atom, and has non-aromaticity in the entire molecular structure. An example of the monovalent non-aromatic condensed heteropolycyclic group is a carbazolyl group. The term “divalent non-aromatic condensed heteropolycyclic group,” as used herein, refers to a divalent group having substantially the same structure as the monovalent non-aromatic condensed heteropolycyclic group.

The term “C₅-C₆₀ carbocyclic group,” as used herein, refers to a monocyclic or polycyclic group having 5 to 60 carbon atoms in which the ring-forming atoms include only carbon atoms. The term “C₅-C₆₀ carbocyclic group,” as used herein, refers to an aromatic carbocyclic group or a non-aromatic carbocyclic group. The term “C₅-C₆₀ carbocyclic group,” as used herein, refers to a ring, such as a benzene group, a monovalent group, such as a phenyl group, or a divalent group, such as a phenylene group. In various embodiments, depending on the number of substituents connected to the C₅-C₆₀ carbocyclic group, the C₅-C₆₀ carbocyclic group may be a trivalent group or a quadrivalent group.

The term “C₁-C₆₀ heterocyclic group,” as used herein, refers to a group having substantially the same structure as the C₅-C₆₀ carbocyclic group, except that as a ring-forming atom, at least one heteroatom selected from N, O, Si, P, and S is used in addition to carbon atom (the number of carbon atoms may be in a range of 1 to 60).

At least one substituent selected from the substituted C₅-C₆₀ carbocyclic group, the substituted C₁-C₆₀ the heterocyclic group, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, the substituted divalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may be selected from the group consisting of:

deuterium (-D), —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, a hydroxyl group, a cyano group, a nitro group, an amidino group, a hydrazino group, a hydrazono group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), and —P(═O)(Q₁₁)(Q₁₂);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), and —P(═O)(Q₂₁)(Q₂₂); and

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

wherein Q₁₁ to Q₁₃, Q₂₁ to Q₂₃, and Q₃₁ to Q₃₃ may each independently be selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with a C₁-C₆₀ alkyl group, a C₆-C₆₀ aryl group substituted with a C₆-C₆₀ aryl group, a terphenyl group, a C₁-C₆₀ heteroaryl group, a C₁-C₆₀ heteroaryl group substituted with a C₁-C₆₀ alkyl group, a C₁-C₆₀ heteroaryl group substituted with a C₆-C₆₀ aryl group, a monovalent non-aromatic condensed polycyclic group, and a monovalent non-aromatic condensed heteropolycyclic group.

The term “Ph”, as used herein, may refer to a phenyl group; the term “Me”, as used herein, may refer to a methyl group; the term “Et”, as used herein, may refer to an ethyl group; the terms “ter-Bu” or “Bu^{t}”, as used herein, may refer to a tert-butyl group; the term “OMe,” as used herein, may refer to a methoxy group, and the term “D”, as used herein, may refer to deuterium.

The term “biphenyl group” as used herein refers to “a phenyl group substituted with a phenyl group.” The “biphenyl group” belongs to “a substituted phenyl group” having “a C₆-C₆₀ aryl group” as a substituent.

The term “terphenyl group” as used herein refers to “a phenyl group substituted with a biphenyl group.” The “terphenyl group” belongs to “a substituted phenyl group” having “a C₆-C₆₀ aryl group substituted with a C₆-C₆₀ aryl group.”

Symbols * and *′ as used herein, unless defined otherwise, each refer to a binding site to a neighboring atom in a corresponding formula.

Hereinafter, a compound according to one or more embodiments and an organic light-emitting device according to one or more embodiments will be described in more detail with reference to the Synthesis Examples and Examples. The phrase “B was utilized instead of A” utilized in describing Synthesis Examples refers to that an identical number of molar equivalent of B was utilized in place of molar equivalent of A.

### EXAMPLE

### Example 1-1: Manufacture of Red Organic Light-Emitting Device

An anode was prepared by cutting an ITO glass substrate (manufactured by Corning) on which ITO was formed to a thickness of 15 Ω/cm² (1,200 Å) to a size of 50 mm×50 mm×0.5 mm, ultrasonically cleaning the ITO glass substrate utilizing isopropyl alcohol and pure water each for 15 minutes, and then, exposing to irradiation of UV light for 30 minutes and ozone to clean. Then, the ITO glass substrate was loaded into a vacuum deposition apparatus.

m-MTDATA was vacuum-deposited on the ITO glass substrate (anode) to have a thickness of 700 Å to form a hole transport layer. Then, TCTA was vacuum deposited on the hole transport layer to have a thickness of 100 Å to form an emission auxiliary layer.

Compound 1-1 (as a host) and PD11 (as a dopant) were co-deposited on the emission auxiliary layer at a weight ratio of 98:2 to form an emission layer having a thickness of 300 Å.

Compound 2-9 was deposited on the emission layer to form a buffer layer having a thickness of 100 Å, and then, Alq₃ was vacuum deposited on the buffer layer to form an electron transport layer having a thickness of 200 Å. LiF was deposited on the electron transport layer to form an electron injection layer having a thickness of 10 Å.

Al was deposited on the electron injection layer to form a cathode having a thickness of 2,000 Å, thereby completing the manufacture of an organic light-emitting device.

### Examples 1-2 to 1-10 and Comparative Examples 1-1 to 1-3

Organic light-emitting devices were manufactured in substantially the same manner as in Example 1-1, except that compounds shown in Table 5 were each utilized in forming an emission layer and a buffer layer.

### Evaluation Example 1

The driving voltage and efficiency of the organic light-emitting devices of Examples 1-1 to 1-10 and Comparative Examples 1-1 to 1-3 were evaluated at 5 mA/cm² by utilizing a Keithley SMU 236 meter. Results thereof are shown in Table 5.

TABLE 5

| | Emission layer | | Driving | Efficiency |
|---|---|---|---|---|
| | (host) | Buffer layer | voltage (V) | (cd/A) |
| Example | Compound | Compound | 5.3 | 23.9 |
| 1-1 | 1-1 | 2-9 | | |
| Example | Compound | Compound | 5.4 | 24.5 |
| 1-2 | 1-6 | 2-48 | | |
| Example | Compound | Compound | 5.2 | 23.7 |
| 1-3 | 1-124 | 2-147a | | |
| Example | Compound | Compound | 5.3 | 24.1 |
| 1-4 | 1-97 | 2-143a | | |
| Example | Compound | Compound | 5.5 | 23.8 |
| 1-5 | 1-41 | 2-48 | | |
| Example | Compound | Compound | 5.5 | 24.5 |
| 1-6 | 1-19 | 2-93 | | |
| Example | Compound | Compound | 5.3 | 25.3 |
| 1-7 | 1-57 | 2-153 | | |
| Example | Compound | Compound | 5.3 | 25.1 |
| 1-8 | 1-64 | 2-165 | | |
| Example | Compound | Compound | 5.4 | 24.0 |
| 1-9 | 1-126 | 2-189 | | |
| Example | Compound | Compound | 5.2 | 24.7 |
| 1-10 | 1-137 | 2-211 | | |
| Comparative | CBP | Compound | 5.9 | 22.3 |
| Example | | 2-9 | | |
| 1-1 | | | | |
| Comparative | Compound | BAlq | 5.8 | 22.7 |
| Example | 1-1 | | | |
| 1-2 | | | | |
| Comparative | CBP | BAlq | 6.2 | 21.6 |
| Example | | | | |
| 1-3 | | | | |

Referring to Table 5, it was confirmed that the organic light-emitting devices of Examples 1-1 to 1-10 had a low driving voltage and high efficiency, compared to those of the organic light-emitting devices of Comparative Examples 1-1 to 1-3.

### Example 2-1: Manufacture of Green (Phosphorescent) Organic Light-Emitting Device

An anode was prepared by cutting an ITO glass substrate (manufactured by Corning) on which ITO was formed to a thickness of 15 Ω/cm² (1,200 Å) to a size of 50 mm×50 mm×0.5 mm, ultrasonically cleaning the ITO glass substrate utilizing isopropyl alcohol and pure water each for 15 minutes, and then, exposing to irradiation of UV light for 30 minutes and ozone to clean. Then, the ITO glass substrate was loaded into a vacuum deposition apparatus.

m-MTDATA was vacuum deposited on the ITO glass substrate (anode) to a thickness of 700 Å to form a hole transport layer. Then, TCTA was vacuum deposited on the hole transport layer to a thickness of 100 Å to form an emission auxiliary layer.

Compound 1-1 (as a host) and PD13 (as a dopant) were co-deposited on the emission auxiliary layer at a weight ratio of 90:10 to form an emission layer having a thickness of 300 Å.

Compound 2-9 was deposited on the emission layer to form a buffer layer having a thickness of 100 Å, and then, Alq₃ was vacuum deposited on the buffer layer to form an electron transport layer having a thickness of 200 Å. LiF was deposited on the electron transport layer to form an electron injection layer having a thickness of 10 Å.

Al was deposited on the electron injection layer to form a cathode having a thickness of 2,000 Å, thereby completing the manufacture of an organic light-emitting device.

### Examples 2-2 to 2-5 and Comparative Examples 2-1 to 2-3

Organic light-emitting devices were manufactured in substantially the same manner as in Example 2-1, except that compounds shown in Table 6 were each utilized in forming an emission layer and a buffer layer.

### Example 2-6

An organic light-emitting device was manufactured in substantially the same manner as in Example 2-1, except that Compound 1-1 (as a first host), CBP (as a second host), and PD13 (as a dopant) were co-deposited at a weight ratio of 50:50:10 in forming an emission layer.

### Examples 2-7 to 2-10

Organic light-emitting devices were manufactured in substantially the same manner as in Example 2-6, except that compounds shown in Table 7 were each utilized in forming an emission layer and a buffer layer.

### Example 2-11: Manufacture of Green (Fluorescent) Organic Light-Emitting Device

An anode was prepared by cutting an ITO glass substrate (manufactured by Corning) on which ITO was formed to a thickness of 15 Ω/cm² (1,200 Å) to a size of 50 mm×50 mm×0.5 mm, ultrasonically cleaning the ITO glass substrate utilizing isopropyl alcohol and pure water each for 15 minutes, and then, exposing to irradiation of UV light for 30 minutes and ozone to clean. Then, the ITO glass substrate was loaded into a vacuum deposition apparatus.

m-MTDATA was vacuum deposited on the ITO glass substrate (anode) to a thickness of 700 Å to form a hole transport layer. Then, NPB was vacuum deposited on the hole transport layer to a thickness of 100 Å to form an emission auxiliary layer.

Compound 1-166 (as a host) and FD19 (as a dopant) were co-deposited on the emission auxiliary layer at a weight ratio of 95:5 to form an emission layer having a thickness of 300 Å.

Compound 2-9 was deposited on the emission layer to form a buffer layer having a thickness of 100 Å, and then, Alq₃ was vacuum deposited on the buffer layer to form an electron transport layer having a thickness of 200 Å. LiF was deposited on the electron transport layer to form an electron injection layer having a thickness of 10 Å.

Al was deposited on the electron injection layer to form a cathode having a thickness of 2,000 Å, thereby completing the manufacture of an organic light-emitting device.

### Examples 2-12 to 2-15 and Comparative Examples 2-4 to 2-6

Organic light-emitting devices were manufactured in substantially the same manner as in Example 2-11, except that compounds shown in Table 6 are each utilized in forming an emission layer and a buffer layer.

### Evaluation Example 2

The driving voltage and efficiency of the organic light-emitting devices of Examples 2-1 to 2-15 and Comparative Examples 2-1 to 2-6 were evaluated at 5 mA/cm² (phosphorescence) and 10 mA/cm² (fluorescence) by utilizing a Keithley SMU 236 meter. Results thereof are shown in Tables 6 and 7.

TABLE 6

| | Emission | Emission | | Weight | Driving | |
|---|---|---|---|---|---|---|
| | layer | layer | Buffer | ratio host: | voltage | Efficiency |
| | (host) | (dopant) | layer | (dopant) | (V) | (cd/A) |
| Example 2-1 | Compound | PD13 | Compound | 90:10 | 5.5 | 41.5 |
| | 1-1 | | 2-9 | | | |
| Example 2-2 | Compound | PD13 | Compound | 90:10 | 5.2 | 43.6 |
| | 1-20 | | 2-48 | | | |
| Example 2-3 | Compound | PD13 | Compound | 90:10 | 5.4 | 42.8 |
| | 1-46 | | 2-136a | | | |
| Example 2-4 | Compound | PD13 | Compound | 90:10 | 5.4 | 43.1 |
| | 1-59 | | 2-103 | | | |
| Example 2-5 | Compound | PD13 | Compound | 90:10 | 5.3 | 42.6 |
| | 1-104 | | 2-162 | | | |
| Comparative | CBP | PD13 | Compound | 90:10 | 5.9 | 38.7 |
| Example 2-1 | | | 2-9 | | | |
| Comparative | Compound | PD13 | BAlq | 90:10 | 5.9 | 38.3 |
| Example 2-2 | 1-1 | | | | | |
| Comparative | CBP | PD13 | BAlq | 90:10 | 6.1 | 36.1 |
| Example 2-3 | | | | | | |
| Example 2-11 | Compound | FD19 | Compound | 95:5 | 4.5 | 19.1 |
| | 1-1 | | 2-9 | | | |
| Example 2-12 | Compound | FD19 | Compound | 95:5 | 4.7 | 19.9 |
| | 1-20 | | 2-48 | | | |
| Example 2-13 | Compound | FD19 | Compound | 95:5 | 4.4 | 20.1 |
| | 1-46 | | 2-136a | | | |
| Example 2-14 | Compound | FD19 | Compound | 95:5 | 4.3 | 19.8 |
| | 1-59 | | 2-103 | | | |
| Example 2-15 | Compound | FD19 | Compound | 95:5 | 4.5 | 20.3 |
| | 1-104 | | 2-162 | | | |
| Comparative | AND | FD19 | Compound | 95:5 | 4.8 | 18.3 |
| Example 2-4 | | | 2-9 | | | |
| Comparative | Compound | FD19 | Alq₃ | 95:5 | 4.6 | 17.8 |
| Example 2-5 | 1-166 | | | | | |
| Comparative | AND | FD19 | Alq₃ | 95:5 | 5.0 | 16.2 |
| Example 2-6 | | | | | | |

TABLE 7

| | Emission | | | Weight ratio | | |
|---|---|---|---|---|---|---|
| | layer | Emission | | (first host: | Driving | |
| | (first host: | layer | Buffer | second host: | voltage | Efficiency |
| | second host) | (dopant) | layer | dopant) | (V) | (cd/A) |
| Example 2-6 | Compound 1-1: | PD13 | Compound | 50:50:10 | 5.5 | 41.1 |
| | CPB | | 2-9 | | | |
| Example 2-7 | Compound 1-1: | PD13 | Compound | 50:50:10 | 5.3 | 42.3 |
| | Compound 1-39 | | 2-48 | | | |
| Example 2-8 | Compound 1-20: | PD13 | Compound | 50:50:10 | 5.2 | 42.7 |
| | Compound 1-41 | | 2-136a | | | |
| Example 2-9 | Compound 1-113: | PD13 | Compound | 50:50:10 | 5.4 | 42.0 |
| | Compound 1-60 | | 2-103 | | | |
| Example 2-10 | Compound 1-46: | PD13 | Compound | 50:50:10 | 5.3 | 43.2 |
| | Compound 1-16 | | 2-162 | | | |

Referring to Tables 6 and 7, it was confirmed that the organic light-emitting devices of Examples 2-1 to 2-10 had a low driving voltage and high efficiency, compared to those of the organic light-emitting devices of Comparative Examples 2-1 to 2-3, and the organic light-emitting devices of Examples 2-11 to 2-15 had a low driving voltage and high efficiency, compared to those of the organic light-emitting devices of Comparative Examples 2-4 to 2-6.

### Example 3-1: Manufacture of Blue Organic Light-Emitting Device

An anode was prepared by cutting an ITO glass substrate (manufactured by Corning) on which ITO was formed to a thickness of 15 Ω/cm² (1,200 Å) to a size of 50 mm×50 mm×0.5 mm, ultrasonically cleaning the ITO glass substrate utilizing isopropyl alcohol and pure water each for 15 minutes, and then, exposing to irradiation of UV light for 30 minutes and ozone to clean. Then, the ITO glass substrate was loaded into a vacuum deposition apparatus.

m-MTDATA was vacuum deposited on the ITO glass substrate (anode) to a thickness of 700 Å to form a hole transport layer. Then, NPB was vacuum deposited on the hole transport layer to a thickness of 100 Å to form an emission auxiliary layer.

Compound 1-166 (as a host) and FD1 (as a dopant) were co-deposited on the emission auxiliary layer at a weight ratio of 95:5 to form an emission layer having a thickness of 300 Å.

Compound 2-9 was deposited on the emission layer to form a buffer layer having a thickness of 100 Å, and then, Alq₃ was vacuum deposited on the buffer layer to form an electron transport layer having a thickness of 200 Å. LiF was deposited on the electron transport layer to form an electron injection layer having a thickness of 10 Å.

Al was deposited on the electron injection layer to form a cathode having a thickness of 2,000 Å, thereby completing the manufacture of an organic light-emitting device.

### Examples 3-2 to 3-5 and Comparative Examples 3-1 to 3-3

Organic light-emitting devices were manufactured in substantially the same manner as in Example 3-1, except that compounds shown in Table 8 were each utilized in forming an emission layer and a buffer layer.

### Examples 3-6 to 3-10

Organic light-emitting devices were manufactured in substantially the same manner as in Example 3-1, except that 1 wt % of F4-TCNQ was doped in forming a hole transport layer and that compounds shown in Table 8 were each utilized in forming an emission layer and a buffer layer.

TABLE 8

| | Emission layer | | Driving voltage | Efficiency |
|---|---|---|---|---|
| | (host) | Buffer layer | (V) | (cd/A) |
| Example | Compound | Compound | 4.5 | 5.1 |
| 3-1 | 1-166 | 2-9 | | |
| Example | Compound | Compound | 4.5 | 5.3 |
| 3-2 | 1-164 | 2-48 | | |
| Example | Compound | Compound | 4.6 | 5.0 |
| 3-3 | 1-178 | 2-136a | | |
| Example | Compound | Compound | 4.4 | 4.9 |
| 3-4 | 1-164 | 2-103 | | |
| Example | Compound | Compound | 4.4 | 5.2 |
| 3-5 | 1-178 | 2-162 | | |
| Example | Compound | Compound | 4.2 | 5.2 |
| 3-6 | 1-165 | 2-131 | | |
| Example | Compound | Compound | 4.1 | 5.0 |
| 3-7 | 1-171 | 2-121a | | |
| Example | Compound | Compound | 4.2 | 5.0 |
| 3-8 | 1-171 | 2-180 | | |
| Example | Compound | Compound | 4.2 | 5.2 |
| 3-9 | 1-176 | 2-13a | | |
| Example | Compound | Compound | 4.3 | 5.1 |
| 3-10 | 1-176 | 2-242 | | |
| Comparative | ADN | Compound | 4.7 | 4.6 |
| Example | | 2-9 | | |
| 3-1 | | | | |
| Comparative | Compound | Alq₃ | 4.6 | 4.8 |
| Example | 1-166 | | | |
| 3-2 | | | | |
| Comparative | ADN | Alq₃ | 4.9 | 4.4 |
| Example | | | | |
| 3-3 | | | | |

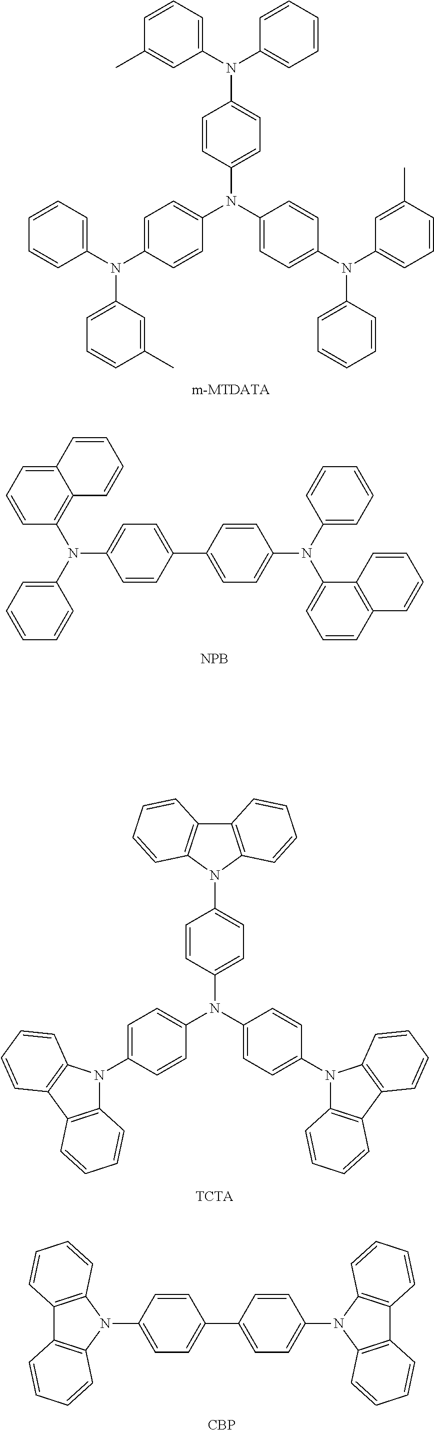 [SMILES: Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; c1ccc(N(c2ccc(-c3ccc(N(c4ccccc4)c4cccc5ccccc45)cc3)cc2)c2cccc3ccccc23)cc1 ; "NPB" ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; c1ccc2c(c1)c1ccccc1n2-c1ccc(-c2ccc(-n3c4ccccc4c4ccccc43)cc2)cc1 ; "CBP"]

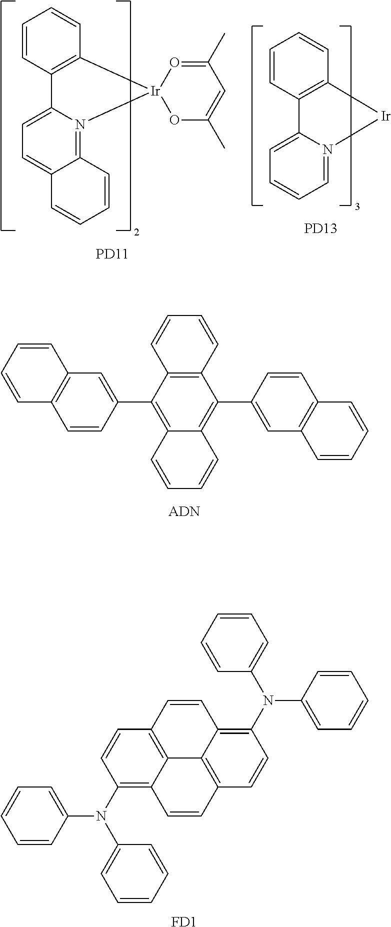

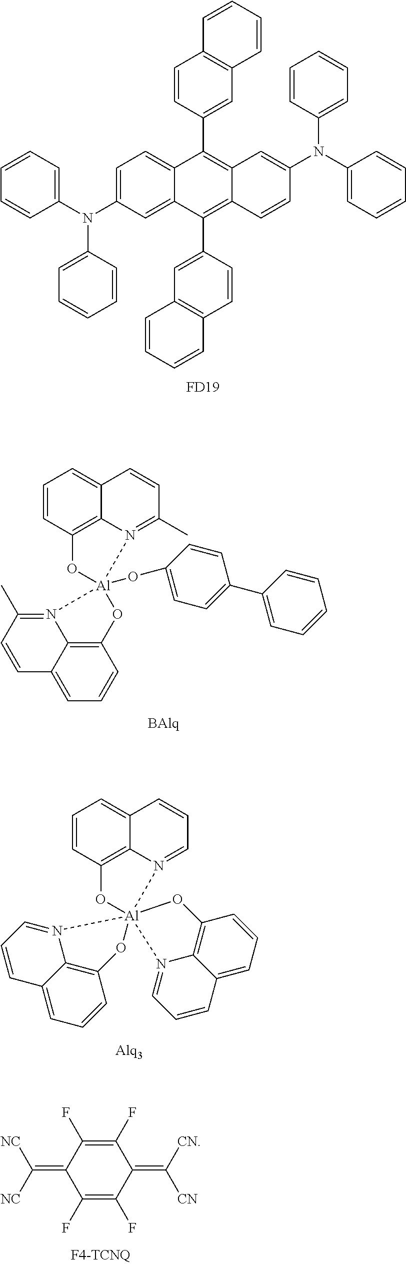

Referring to Table 8, it was confirmed that the organic light-emitting devices of Examples 3-1 to 3-10 had a low driving voltage and high efficiency, compared to those of the organic light-emitting devices of Comparative Examples 3-1 to 3-3.

According to one or more embodiments, an organic light-emitting device may have a low driving voltage and high efficiency.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims, and equivalents thereof.

What is claimed is:

1. An organic light-emitting device comprising:
a first electrode;
a second electrode facing the first electrode;
an emission layer between the first electrode and the second electrode;
a hole transport region between the first electrode and the emission layer; and
an electron transport region between the emission layer and the second electrode,
wherein the emission layer comprises a first compound,
at least one selected from the hole transport region and the electron transport region comprises a second compound, and
the first compound is represented by Formula 1, provided that a case where Formula 1 is a 4,4′-bis(N-carbazolyl)-1,1′-biphenyl (CBP) is excluded, and the second compound is represented by Formula 2A or 2B: 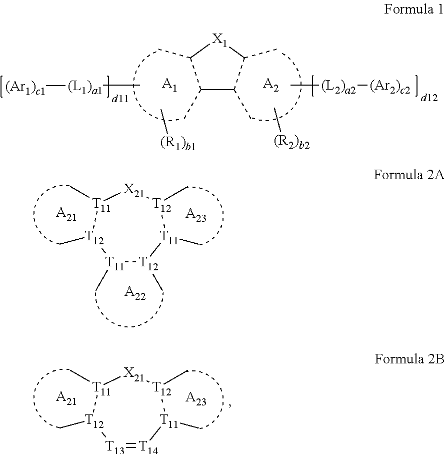
wherein, in Formulae 1, 2A, and 2B,
rings A₁ and A₂ are each independently selected from a C₅-C₆₀ carbocyclic group and a C₁-C₆₀ heterocyclic group,
rings A₁ and A₂ are each condensed with a 5-membered ring in Formula 1,
rings A₂₁, A₂₂, and A₂₃ are each independently a C₅-C₆₀ carbocyclic group or a C₁-C₆₀ heterocyclic group, each substituted with at least one *-[(L₂₂)ₐ₂₂-(R₂₂)_{b22}],
T₁₁ and T₁₂ are each independently carbon or nitrogen,
T₁₃ is N or C(R₂₇),
T₁₄ is N or C(R₂₈),
two or more selected from three T₁₁(s) in Formula 2A are identical to or different from each other, two or more selected from three T₁₂(s) in Formula 2A are identical to or different from each other, two T₁₁(s) in Formula 2B are identical to or different from each other, two T₁₂(s) in Formula 2B are identical to or different from each other, T₁₁ and T₁₂ are connected to each other via a single bond or a double bond,
wherein the three T₁₁(s) and three T₁₂(s) in Formula 2A are not all nitrogen, and the two T₁₁(s), two T₁₂(s), T₁₃, and T₁₄ in Formula 2B are not all nitrogen,
rings A₂₁, A₂₂, and A₂₃ are each fused with a central 7-membered ring in Formulae 2A and 2B, such that they each share a T₁₁ and a T₁₂ with the central 7-membered ring,
X₁ is selected from N[(L₃)ₐ₃-(Ar₃)_{c3}], Si(R₃)(R₄), O, S, and Se,
X₂₁ is selected from O, S, Se, C(R₂₃)(R₂₄), Si(R₂₃)(R₂₄), and N[(L₂₁)ₐ₂₁-(R₂₁)_{b21}],
L₁ to L₃, L₂₁, and L₂₂ are each independently selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,
a1 to a3, a21, and a22 are each independently an integer selected from 0 to 5,
Ar₁ to Ar₃ are each independently selected from a substituted or unsubstituted C₁-C₆₀ alkyl group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂),
c1 to c3 are each independently an integer selected from 1 to 3,
R₁ to R₄, R₂₁ to R₂₄, R₂₇, and R₂₈ are each independently selected from hydrogen, deuterium (-D), —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅),
b1 and b2 are each independently an integer selected from 1 to 6,
b21 and b22 are each independently an integer selected from 1 to 3,
d11 and d12 are each independently an integer selected from 0 to 4, and
at least one substituent of the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, the substituted divalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group is selected from the group consisting of:
deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, and a C₁-C₆₀ alkoxy group;
a C₁-C₆₀ alkyl group, a C₂-C₆₀ alkenyl group, a C₂-C₆₀ alkynyl group, and a C₁-C₆₀ group, each substituted with at least one selected from deuterium, —F, —Cl, —Br, —I, a hydroxyl group, a cyano group, a nitro group, an amidino group, a hydrazino group, a hydrazono group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), and —P(═O)(Q₁₁)(Q₁₂);
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, a biphenyl group, and a terphenyl group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), and —P(═O)(Q₂₁)(Q₂₂), and
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),
wherein Q₁ to Q₆, Q₁₁ to Q₁₃, Q₂₁ to Q₂₃, and Q₃₁ to Q₃₃ are each independently selected from hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with a C₁-C₆₀ alkyl group, a C₆-C₆₀ aryl group substituted with a C₆-C₆₀ aryl group, a terphenyl group, a C₁-C₆₀ heteroaryl group, a C₁-C₆₀ heteroaryl group substituted with a C₁-C₆₀ alkyl group, a C₁-C₆₀ heteroaryl group substituted with a C₆-C₆₀ aryl group, a monovalent non-aromatic condensed polycyclic group, and a monovalent non-aromatic condensed heteropolycyclic group.

2. The organic light-emitting device of claim 1, wherein
rings A₁ and A₂ in Formula 1 are each independently selected from a benzene group, a naphthalene group, an anthracene group, a phenanthrene group, an indene group, a fluorene group, a pyridine group, a pyrimidine group, a pyrazine group, a pyrrole group, a pyrazole group, an imidazole group, a quinoline group, a quinoxaline group, an isoquinoline group, a cinnoline group, a phthalazine group, a quinazoline group, a phenanthroline group, a phenanthridine group, a furan group, a thiophene group, an indole group, a benzofuran group, a benzothiophene group, a benzoxazole group, a benzothiazole group, a benzoimidazole group, a benzocarbazole group, a benzofluorene group, a benzonaphthofuran group, a benzonaphthothiophene group, a carbazole group, a dibenzofuran group, a dibenzothiophene group, a pyridoindole group, an indenopyridine group, a benzofuropyrimidine group, a benzofuropyridine group, an indenofluorene group, an indenoindole group, a benzoindole group, a naphthofuran group, a dipyridofuran group, a dipyridothiophene group, a pyrimidobenzofuran group, a pyridobenzofuran group, a pyrimidobenzothiophene group, a pyridobenzothiophene group, a group represented by Formula 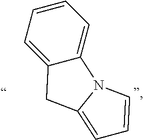 [SMILES: c1ccc2c(c1)Cc1cccn1-2]
a group represented by Formula 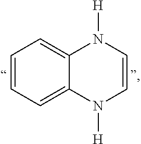
a group represented by Formula 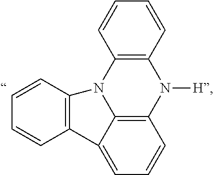
and a group represented by Formula

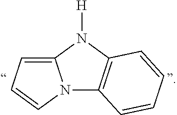 [SMILES: c1ccc2c(c1)[nH]c1cccn12]

3. The organic light-emitting device of claim 1, wherein
rings A₂₁, A₂₂, and A₂₃ in Formulae 2A and 2B are each independently selected from a benzene group, a naphthalene group, an anthracene group, an indene group, a fluorene group, a pyridine group, a pyrimidine group, a pyrazine group, a pyridazine group, a quinoline group, an isoquinoline group, a pyrrole group, a pyrazole group, an imidazole group, an oxazole group, a thiazole group, a cyclopentadiene group, a silole group, a selenophene group, a furan group, a thiophene group, an indole group, a benzimidazole group, a benzoxazole group, a benzothiazole group, an indene group, a benzosilole group, a benzoselenophene group, a benzofuran group, a benzothiophene group, a carbazole group, a fluorene group, a dibenzosilole group, a dibenzoselenophene group, a dibenzofuran group, a dibenzothiophene group, a pyrrolopyridine group, a cyclopentapyridine group, a silolopyridine group, a selenophenopyridine group, a furopyridine group, a thienopyridine group, a pyrrolopyrimidine group, a cyclopentapyrimidine group, a silolopyrimidine group, a selenophenopyrimidine group, a furopyrimidine group, a thienopyrimidine group, a pyrrolopyrazine group, a cyclopentapyrazine group, a silolopyrazine group, a selenophenopyrazine group, a furopyrazine group, a thienopyrazine group, a naphthopyrrole group, a cyclopentanaphthalene group, a naphthosilole group, a naphthoselenothiophene group, a naphthofuran group, a naphthothiophene group, a pyrroloquinoline group, a cyclopentaquinoline group, a siloloquinoline group, a selenophenoquinoline group, a furoquinoline group, a thienoquinoline group, a pyrroloisoquinoline group, a cyclopentaisoquinoline group, a siloloisoquinoline group, a selenophenoisoquinoline group, a furoisoquinoline group, a thienoisoquinoline group, an azacarbazole group, an azafluorene group, an azadibenzosilole group, an azadibenzoselenophene group, an azadibenzofuran group, an azadibenzothiophene group, an indenoquinoline group, an indenoisoquinoline group, an indenoquinoxaline group, a phenanthroline group, and a naphthoindole group, each substituted with at least one *-[(L₂₂)ₐ₂₂-(R₂₂)_{b22}].

4. The organic light-emitting device of claim 1, wherein
rings A₂₁, A₂₂, and A₂₃ in Formulae 2A and 2B are each independently selected from groups represented by Formulae 2-1 to 2-36, each substituted with at least one *-[(L₂₂)ₐ₂₂-(R₂₂)_{b22})]: 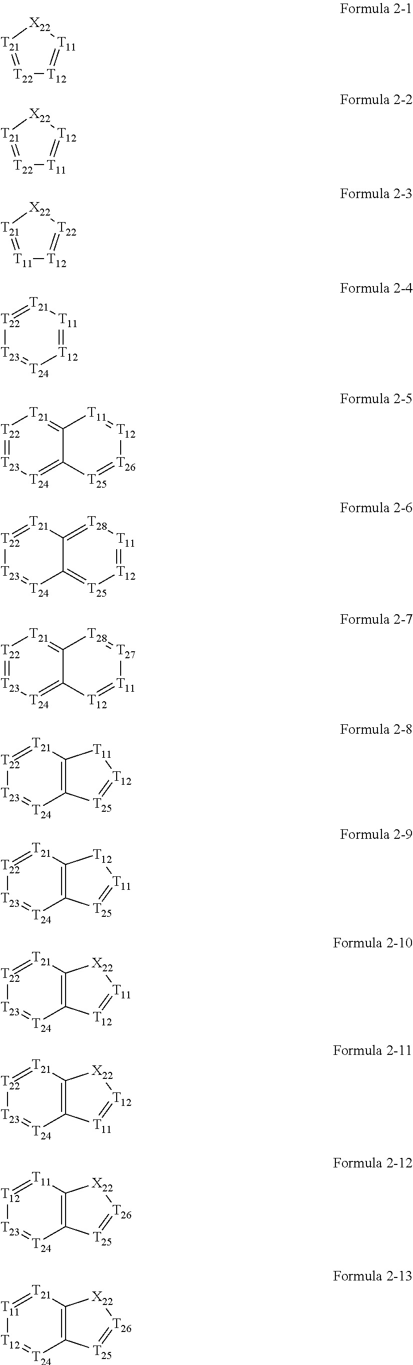 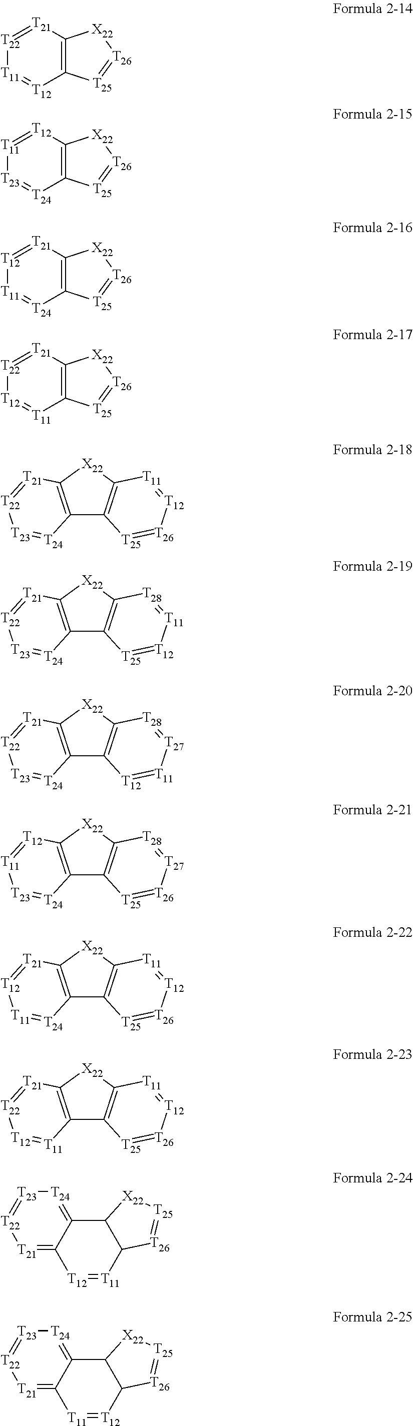 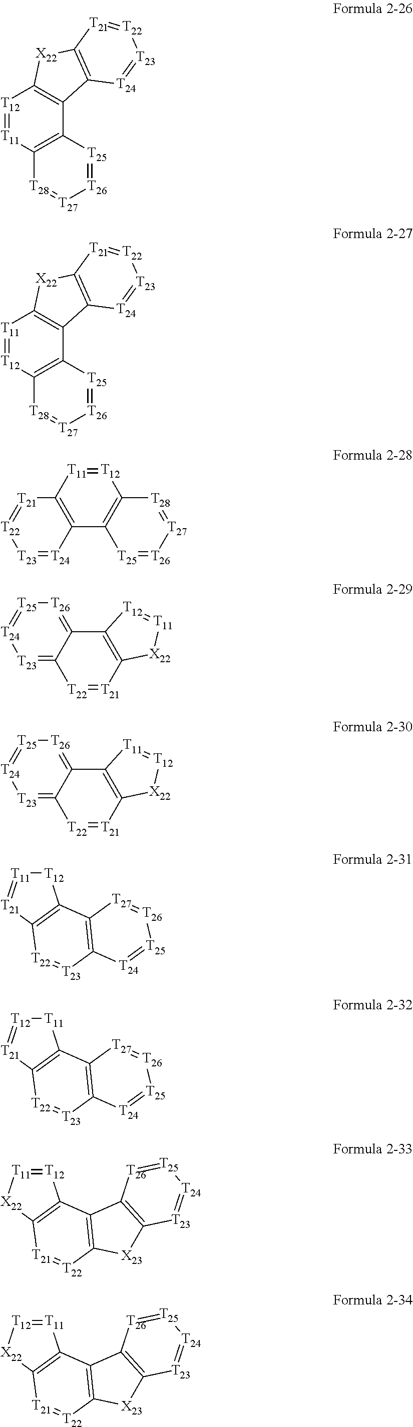 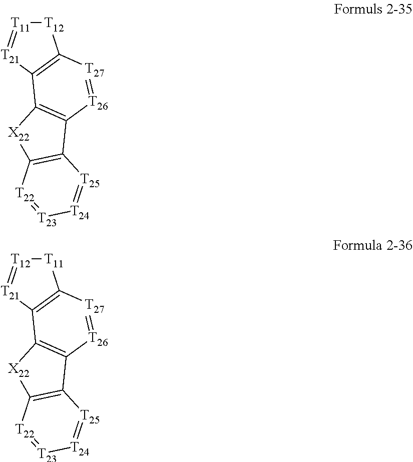
wherein, in Formulae 2-1 to 2-36,
T₁₁ and T₁₂ are the same as respectively described in connection with Formulae 2A and 2B,
X₂₂ and X₂₃ are each independently selected from O, S, Se, a moiety comprising C, a moiety comprising N, and a moiety comprising Si; and
T₂₁ to T₂₈ are each independently selected from N and a moiety comprising C.

5. The organic light-emitting device of claim 1, wherein
X₁ in Formula 1 is selected from N[(L₃)ₐ₃-(Ar₃)_{c3}], O, and S.

6. The organic light-emitting device of claim 1, wherein
X₂₁ in Formulae 2A and 2B is N[(L₂₁)ₐ₂₁-(R₂₁)_{b21}].

7. The organic light-emitting device of claim 4, wherein
X₂₁ in Formulae 2A and 2B is O, S, Se, C(R₂₃)(R₂₄), or Si(R₂₃)(R₂₄), and
at least one selected from rings A₂₁, A₂₂, and A₂₃ in Formula 2A and at least one selected from rings A₂₁ and A₂₃ in Formula 2B are each independently selected from groups represented by Formulae 2-1 to 2-3, 2-10 to 2-27, and 2-33 to 2-36, wherein X₂₂ or X₂₃ in Formulae 2-1 to 2-3, 2-10 to 2-27, and 2-33 to 2-36 is N-[(L₂₂)ₐ₂₂-(R₂₂)_{b22}].

8. The organic light-emitting device of claim 1, wherein
in Formulae 1, 2A, and 2B,
L₁ to L₃, L₂₁, and L₂₂ are each independently selected from the group consisting of:
a phenylene group, a pentalenylene group, an indenylene group, a naphthylene group, an azulenylene group, an indacenylene group, an acenaphthylene group, a fluorenylene group, a spiro-bifluorenylene group, a spiro-benzofluorene-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a perylenylene group, a pentaphenylene group, a pyrrolylene group, a thiophenylene group, a furanylene group, a silolylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an indolylene group, an isoindolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzoimidazolylene group, a benzofuranylene group, a benzothiophenylene group, a benzosilolylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a dibenzosilolylene group, a carbazolylene group, a benzocarbazolylene group, a dibenzocarbazolylene group, a thiadiazolylene group, an imidazopyridinylene group, an imidazopyrimidinylene group, an oxazolopyridinylene group, a thiazolopyridinylene group, a benzonaphthyridinylene group, an azafluorenylene group, an azaspiro-bifluorenylene group, an azacarbazolylene group, an azadibenzofuranylene group, an azadibenzothiophenylene group, and an azadibenzosilolylene group; and
a phenylene group, a pentalenylene group, an indenylene group, a naphthylene group, an azulenylene group, an indacenylene group, an acenaphthylene group, a fluorenylene group, a spiro-bifluorenylene group, a spiro-benzofluorene-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a perylenylene group, a pentaphenylene group, a pyrrolylene group, a thiophenylene group, a furanylene group, a silolylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an indolylene group, an isoindolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzoimidazolylene group, a benzofuranylene group, a benzothiophenylene group, a benzosilolylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a dibenzosilolylene group, a carbazolylene group, a benzocarbazolylene group, a dibenzocarbazolylene group, a thiadiazolylene group, an imidazopyridinylene group, an imidazopyrimidinylene group, an oxazolopyridinylene group, a thiazolopyridinylene group, a benzonaphthyridinylene group, an azafluorenylene group, an azaspiro-bifluorenylene group, an azacarbazolylene group, an azadibenzofuranylene group, an azadibenzothiophenylene group, and an azadibenzosilolylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),
wherein Q₃₁ to Q₃₃ are each independently selected from the group consisting of:
a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and
a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group.

9. The organic light-emitting device of claim 1, wherein,
in Formulae 1, 2A, and 2B,
Ar₁ to Arₐ are each independently selected from the group consisting of:
a group represented by any of Formulae 1-1 and 1-2, a C₁-C₂₀ alkyl group, a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a dibenzosilolyl group, a thiadiazolyl group, an imidazopyridinyl group, an imidazopyrimidinyl group, —Si(Q₁)(Q₂)(Q₃), —N(Q₁)(Q₂), —B(Q₁)(Q₂), —C(═O)(Q₁), —S(═O)₂(Q₁), and —P(═O)(Q₁)(Q₂); and
a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a dibenzosilolyl group, a thiadiazolyl group, an imidazopyridinyl, and an imidazopyrimidinyl group, each substituted with at least one selected from deuterium, —F, —Cl, —Br, —I, a hydroxyl group, a cyano group, a nitro group, an amidino group, a hydrazino group, a hydrazono group, a C₁-C₁₀ alkyl group, a C₁-C₁₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂), and
R₁ to R₄, R₂₁ to R₂₄, R₂₇, and R₂₈ are each independently selected from the group consisting of:
hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;
a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a dibenzosilolyl group, a thiadiazolyl group, an imidazopyridinyl group, an imidazopyrimidinyl group, —Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅); and
a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a spiro-benzofluorene-fluorenyl group, an indenofluorenyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a dibenzosilolyl group, a thiadiazolyl group, an imidazopyridinyl group, and an imidazopyrimidinyl group, each substituted with at least one selected from deuterium, —F, —Cl, —Br, —I, a hydroxyl group, a cyano group, a nitro group, an amidino group, a hydrazino group, a hydrazono group, a C₁-C₁₀ alkyl group, a C₁-C₁₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, a terphenyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),
wherein Q₁ to Q₆ and Q₃₁ to Q₃₃ are each independently selected from the group consisting of:
a C₁-C₁₀ alkyl group, a C₁-C₁₀ alkoxy group, a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group; and
a phenyl group, a biphenyl group, a terphenyl group, a naphthyl group, a pyridinyl group, a pyrimidinyl group, a pyrazinyl group, a quinolinyl group, an isoquinolinyl group, a quinoxalinyl group, and a quinazolinyl group, each substituted with at least one selected from a C₁-C₁₀ alkyl group, a C₁-C₁₀ alkoxy group, and a phenyl group: 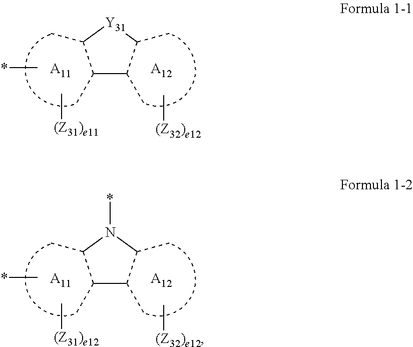
wherein, in Formulae 1-1 and 1-2,
A₁₁ and A₁₂ are each independently selected from a cyclohexene group, a benzene group, a naphthalene group, a phenanthrene group, an anthracene group, a triphenylene group, a pyrene group, a carbazole group, a fluorene group, a spiro-bifluorene group, a pyridine group, a pyrazine group, a pyrimidine group, a pyridazine group, a quinoline group, an isoquinoline group, a quinoxaline group, a quinazoline group, a triazine group, an indene group, a benzofuran group, a benzothiophene group, a dibenzofuran group, and a dibenzothiophene group,
Y₃₁ is selected from N[(L₁₁)ₐ₁₁-(Z₃₃)ₑ₁₃], C(Z₃₄)(Z₃₅), Si(Z₃₄)(Z₃₅), O, S, and Se,
L₁₁ is the same as described in connection with L₁ in Formula 1,
a11 is the same as described in connection with a1 in Formula 1,
Z₃₁ to Z₃₅ are each independently selected from the group consisting of:
hydrogen, deuterium, —F, —Cl, —Br, —I, a hydroxyl group, a cyano group, a nitro group, an amidino group, a hydrazino group, a hydrazono group, a C₁-C₂₀ alkyl group, and a C₁-C₂₀ alkoxy group;
a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, a quinolinyl group, an isoquinolinyl group, a benzoquinolinyl group, a quinoxalinyl group, a quinazolinyl group, a benzoimidazolyl group, an isobenzothiazolyl group, a benzoxazolyl group, an isobenzoxazolyl group, an oxadiazolyl group, and a triazinyl group; and
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),
e11 and e12 are each independently an integer selected from 1 to 10,
e13 is an integer selected from 1 to 3, and
* indicates a binding site to a neighboring atom.

10. The organic light-emitting device of claim 1, wherein
the first compound is represented by one selected from Formulae 1A to 1F: 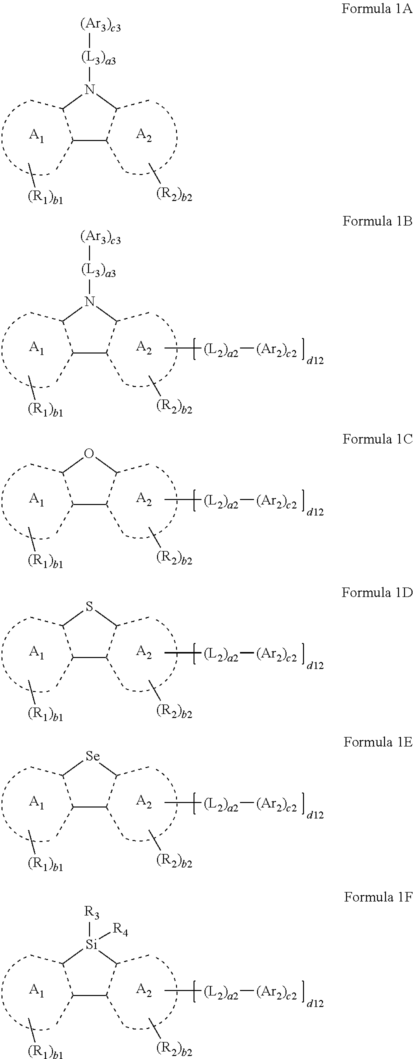
wherein, in Formulae 1A to 1F,
ring A₁, ring A₂, L₂, L₃, a2, a3, Ar₂, Ar₃, c2, c3, R₁ to R₄, b1, b2, and d12 are the same as respectively described in connection with Formula 1.

11. The organic light-emitting device of claim 10, wherein,
in Formulae 1A to 1F,
ring A₁ is selected from a benzene group, a naphthalene group, a pyridine group, and a pyrimidine group,
ring A₂ is selected from a benzene group, a naphthalene group, a phenanthrene group, an anthracene group, a phenanthroline group, an indenopyridine group, a benzofuropyrimidine group, a benzofuropyridine group, an indenofluorene group, an indenoindole group, a benzoindole group, a naphthofuran group, a benzonaphthofuran group, a pyridobenzothiophene group, a benzonaphthothiophene group, a benzocarbazole group, a quinoline group, a quinoxaline group, a pyridine group, a pyrimidine group, an indole group, a carbazole group, a fluorene group, a benzofluorene group, a benzofuran group, a benzoxazole group, an indene group, a dibenzofuran group, a dibenzothiophene group, a pyridoindole group, a group represented by Formula 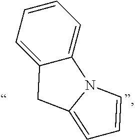 [SMILES: c1ccc2c(c1)Cc1cccn1-2]
a group represented by Formula 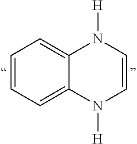
a group represented by Formula 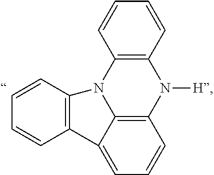
and a group represented by Formula 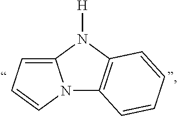 [SMILES: c1ccc2c(c1)[nH]c1cccn12]
and
R₁ and R₂ are each independently selected from hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a C₆-C₃₀ aryl group, a C₁-C₃₀ heteroaryl group, —Si(Q₄)(Q₅)(Q₆), —N(Q₄)(Q₅), —B(Q₄)(Q₅), —C(═O)(Q₄), —S(═O)₂(Q₄), and —P(═O)(Q₄)(Q₅).

12. The organic light-emitting device of claim 1, wherein
triplet energy of the second compound is about 2.2 eV or more.

13. The organic light-emitting device of claim 1, wherein
the emission layer comprises a first host and a second host, wherein the first host comprises the first compound.

14. The organic light-emitting device of claim 1, wherein
the electron transport region comprises a buffer layer, and
the buffer layer directly contacts the emission layer and comprises the second compound.

15. The organic light-emitting device of claim 1, wherein
the emission layer comprises a host and a dopant,
the host comprises the first compound, and the dopant comprises an organometallic complex represented by Formula 401: 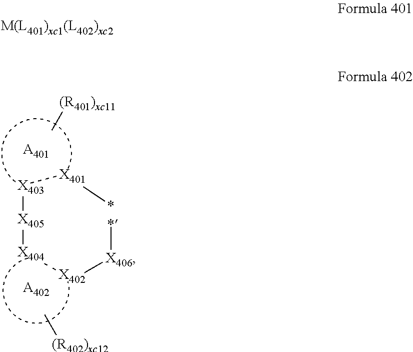
wherein, in Formula 401,
M is selected from iridium (Ir), platinum (Pt), palladium (Pd), osmium (Os), titanium (Ti), zirconium (Zr), hafnium (Hf), europium (Eu), terbium (Tb), rhodium (Rh), and thulium (Tm),
L₄₀₁ is selected from ligands represented by Formula 402,
xc1 is 1, 2, or 3, wherein when xc1 is two or more, two or more L₄₀₁(s) are identical to or different from each other,
L₄₀₂ is an organic ligand,
xc2 is an integer selected from 0 to 4, wherein when xc2 is two or more, two or more L₄₀₂(s) are identical to or different from each other,
wherein in Formula 402,
X₄₀₁ to X₄₀₄ are each independently nitrogen or carbon,
X₄₀₁ and X₄₀₃ are connected to each other via a single bond or a double bond, and X₄₀₂ and X₄₀₄ are connected to each other via a single bond or a double bond,
A₄₀₁ and A₄₀₂ are each independently a C₅-C₆₀ carbocyclic group or a C₁-C₆₀ heterocyclic group,
X₄₀₅ is a single bond, *—O—*′, *—S—*′, *—C(═O)—′, *—N(Q₄₁₁)-*, *—C(Q₄₁₁)(Q₄₁₂)-*, *—C(Q₄₁₁)=C(Q₄₁₂)-*′, *—C(Q₄₁₁)=*, or *═C(Q₄₁₁)=*′, wherein Q₄₁₁ and Q₄₁₂ are each independently hydrogen, deuterium, a C₁-C₂₀ alkyl group, a C₁-C₂₀ alkoxy group, a phenyl group, a biphenyl group, a terphenyl group, or a naphthyl group,
X₄₀₆ is a single bond, O, or S,
R₄₀₁ and R₄₀₂ are each independently selected from hydrogen, deuterium, —F, —Cl, —Br, —I, —CD₃, —CF₃, a hydroxyl group, a cyano group, a nitro group, an amidino group, a hydrazino group, a hydrazono group, a substituted or unsubstituted C₁-C₂₀ alkyl group, a substituted or unsubstituted C₁-C₂₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁) and —P(═O)(Q₄₀₁)(Q₄₀₂), wherein Q₄₀₁ to Q₄₀₃ are each independently selected from a C₁-C₁₀ alkyl group, a C₁-C₁₀ alkoxy group, a C₆-C₂₀ aryl group, and a C₁-C₂₀ heteroaryl group,
xc11 and xc12 are each independently an integer selected from 0 to 10, and
* and *′ in Formula 402 each indicate a binding site to M in Formula 401.

16. The organic light-emitting device of claim 1, wherein
the emission layer comprises a host and a dopant,
the host comprises the first compound, and the dopant comprises a compound represented by Formula 501: 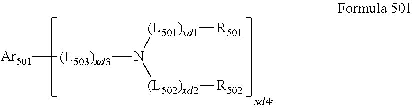
wherein, in Formula 501,
Ar₅₀₁ is a substituted or unsubstituted C₅-C₆₀ carbocyclic group or a substituted or unsubstituted C₁-C₆₀ heterocyclic group,
L₅₀₁ to L₅₀₃ are each independently selected from a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,
xd1 to xd3 are each independently an integer selected from 0 to 3,
R₅₀₁ and R₅₀₂ are each independently selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and
xd4 is an integer selected from 1 to 4.

17. The organic light-emitting device of claim 1, wherein
the electron transport region comprises a buffer layer, an electron transport layer, and an electron injection layer, and
at least one layer selected from the electron transport layer and the electron injection layer comprises an alkaline metal, an alkaline earth metal, a rare-earth metal, an alkaline metal compound, an alkaline earth-metal compound, a rare-earth metal compound, an alkaline metal complex, an alkaline earth-metal complex, a rare-earth metal complex, or a combination thereof.

18. The organic light-emitting device of claim 1, wherein
the hole transport region comprises a p-dopant, and
a lowest unoccupied molecular orbital (LUMO) of the p-dopant is about −3.5 eV or less.

19. The organic light-emitting device of claim 18, wherein
the p-dopant comprises a cyano group-containing compound.

20. The organic light-emitting device of claim 1, wherein
the emission layer is a first-color-light emission layer,
the organic light-emitting device further comprises i) at least one second-color-light emission layer or ii) at least one second-color-light emission layer and at least one third-color-light emission layer, between the first electrode and the second electrode,
a maximum emission wavelength of the first-color-light emission layer, a maximum emission wavelength of the second-color-light emission layer, and a maximum emission wavelength of the third-color-light emission layer are identical to or different from one another, and
the organic light-emitting device is configured to emit mixed light comprising first-color-light and second-color-light, or mixed light comprising first-color-light, second-color-light, and third-color-light.
